(19) United States
(12) Patent Application Publication
(10) Pub. No.: US 2016/0291461 A1
(43) Pub. Date: Oct. 6, 2016

(54) PATTERN FORMING METHOD, ELECTRONIC DEVICE MANUFACTURING METHOD, ELECTRONIC DEVICE, BLOCK COPOLYMER AND BLOCK COPOLYMER PRODUCTION METHOD

(71) Applicant: FUJIFILM Corporation, Tokyo (JP)

(72) Inventors: Hayato YOSHIDA, Haibara-gun (JP); Hiroo TAKIZAWA, Haibara-gun (JP); Keizo KIMURA, Haibara-gun (JP); Shoichi SAITOH, Haibara-gun (JP); Eriko MITANI, Haibara-gun (JP)

(73) Assignee: FUJIFILM Corporation, Tokyo (JP)

(21) Appl. No.: 15/172,639

(22) Filed: Jun. 3, 2016

Related U.S. Application Data
(63) Continuation of application No. PCT/JP2014/079877, filed on Nov. 11, 2014.

(30) Foreign Application Priority Data
Dec. 6, 2013 (JP) 2013-253598

(51) Int. Cl. G03F 7/00; H01L 21/027; G03F 7/32; C08F 297/02; G03F 7/20

(52) U.S. Cl. CPC G03F 7/0002; C08F 297/02; G03F 7/2004; G03F 7/322; H01L 21/0271

(57) ABSTRACT

There are provided a pattern forming method in which, in self-organization lithography using a graphoepitaxy method, high miniaturization of patterns can be achieved with high quality and high efficiency by a pattern forming method including (i) a step of forming a block copolymer layer containing a specific first block copolymer or a specific second block copolymer on a specific substrate, (ii) a step of phase-separating the block copolymer layer, and (iii) a step of selectively removing at least one phase of a plurality of phases of the block copolymer layer, an electronic device manufacturing method using the pattern forming method and the electronic device, and a block copolymer used in the pattern forming method and the production method thereof.

### CROSS REFERENCE TO RELATED APPLICATION

This is a continuation of International Application No. PCT/JP2014/079877 filed on November 11, and claims priority from Japanese Patent Application No. 2013-253598 filed on Dec. 6, 2013, the entire disclosures of which are incorporated herein by reference.

### BACKGROUND OF THE INVENTION

1. Field of the Invention

The present invention relates to a pattern forming method which is suitably used in an ultra microlithography process in manufacturing an ultra LSI or a high-capacity microchip or other photofabrication processes, an electronic device manufacturing method, an electronic device, a block copolymer, and a block copolymer production method.

2. Description of the Related Art

In recent years, with higher integration of integrated circuits, ultra miniaturization of patterns has progressed, and technical development of fine processing by lithography using radiation such as an ArF excimer laser, EUV light, or an electron beam, or X-rays has progressed, but with the demand for higher integration, the development of patterning techniques without using photolithography such as the development of self-organization lithography which utilizes nanoimprint or microphase separation of a block copolymer is also progressing.

In addition, while densification of a recording density of hard disk drives is progressing, technology development of bit patterned media processing a magnetic film into the size of each bit is progressing. For example, to obtain a recording density of 5 T bits/inch, formation of an ultra fine dot pattern of about 12 nm is required, and, also here, the development of self-organization lithography which utilizes microphase separation of a block copolymer is progressing.

A variety of processes have been proposed regarding self-organization lithography, and, for example, a graphoepitaxy method of controlling a microphase separation pattern by a guide pattern provided on an underlying substrate to which a block copolymer is applied, to control the placement and arrangement of a self-organization nanostructure formed by microphase separation, and a chemical registration method of controlling a microphase separation pattern by differences in the chemical properties of a substrate surface have been proposed.

In self-organization lithography, a pattern can be formed by forming a self-organization resist film including a block copolymer on a substrate provided with a guide pattern as described above, by forming a microphase separation structure by an annealing treatment in a solvent atmosphere or by heating, and by selectively removing a specific block of the block copolymer by an oxygen plasma treatment, an ozone treatment, a UV irradiation treatment, a pyrolysis treatment, or a chemical decomposition treatment.

As the block copolymer used in the pattern forming method using self-organization, a copolymer having two or more segments which can cause microphase separation from each other can be used. In the block copolymer, for example, it is advantageous in terms of forming microphase separation to use blocks in which the difference in the numerical values of the Flory-Huggins interaction parameter is large. As such a block copolymer, a block copolymer of polystyrene or a derivative thereof and polymethacrylic acid acrylate or a derivative thereof have been reported (for example, refer to WO2007/132901A, Proc. of SPIE Vol. 832383230E, and Langmuir, 2008, 24, 5527-5533).

### SUMMARY OF THE INVENTION

However, in recent years, with the demand for further miniaturization of patterns, there has been demand for the development of a technique which can achieve higher miniaturization of patterns than in the techniques described in the prior art described.

The present invention has been made in consideration of the above-described circumstance, and an object of the present invention is to provide a pattern forming method in which, in self-organization lithography using a graphoepitaxy method, high miniaturization of patterns can be achieved with high quality and high efficiency (for example, a line-and-space pattern having a pitch of 60 nm or less or a hole pattern having a hole diameter of 30 nm or less can be formed with high quality and high efficiency), an electronic device manufacturing method using the pattern forming method and the electronic device, and a block copolymer used in the pattern forming method and the production method thereof.

That is, the present invention is as follows.

[1]

A pattern forming method comprising (i) a step of forming a block copolymer layer containing a first block copolymer having a block of a repeating unit represented by the following General Formula (I) and a block of a repeating unit represented by the following General Formula (II) or a second block copolymer having a block of a repeating unit represented by the following General Formula (III) and a block of a repeating unit represented by the following General Formula (IV) on a substrate on which a guide pattern has been formed, (ii) a step of phase-separating the block copolymer layer, and (iii) a step of selectively removing at least one phase of a plurality of phases of the block copolymer layer.

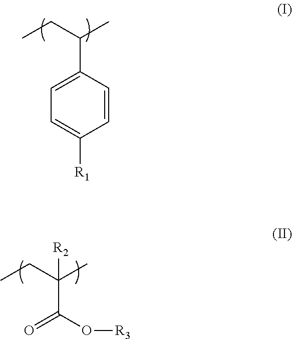

In General Formula (I), R₁ represents an alkyl group, an alkenyl group, an alkynyl group, a cycloalkyl group, an aryl group, or an aralkyl group, and R₁ may be condensed with a benzene ring by bonding to a carbon atom adjacent to the carbon atom to which R₁ has been bonded.

In General Formula (II), R₂ represents a hydrogen atom, an alkyl group, or a cycloalkyl group, and R₃ represents an alkyl group or a cycloalkyl group which may be substituted with a halogen atom or a group including an oxygen atom or a sulfur atom.

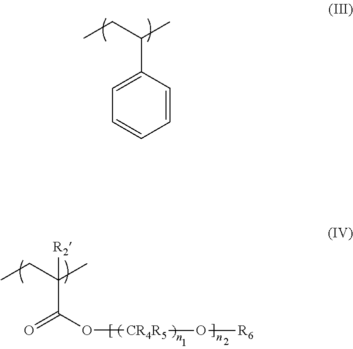

In General Formula (IV), R₂′ represents a hydrogen atom, an alkyl group, or a cycloalkyl group.

Each of R₄ and R₅ independently represents a hydrogen atom or a methyl group. A plurality of R₄'s and a plurality of R₅'s may be the same as or different from each other, respectively.

R₆ represents an alkyl group having 1 to 4 carbon atoms.

n₁ represents 2 to 4, and n₂ represents 1 to 6.

[2]

The pattern forming method according to [1], in which the block of the repeating unit represented by General Formula (II) in the first block copolymer is a block of a repeating unit represented by any one of the following General Formulas (II-1) to (II-3).

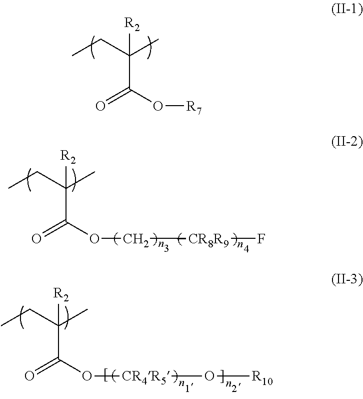

In General Formulas (II-1) to (II-3), R₂ has the same meaning as R₂ in General Formula (II).

Each of R₄′ and R₅′ independently represents a hydrogen atom or a methyl group. A plurality of R₄'s and a plurality of R₅'s may be the same as or different from each other, respectively.

R₇ represents an unsubstituted alkyl group having 1 to 12 carbon atoms or an unsubstituted cycloalkyl group having 3 to 12 carbon atoms.

Each of R₈ and R₉ independently represents a hydrogen atom or a fluorine atom. Here, at least one of R₈ or R₉ represents a fluorine atom. In a case where a plurality of R₈'s and a plurality of R₉'s are present, respectively, the plurality of R₈'s and the plurality of R₉'s may be the same as or different from each other, respectively.

R₁₀ represents a hydrogen atom, an alkyl group, a cycloalkyl group, or an aryl group.

n₁′ represents 2 to 4, n₂′ represents 1 to 6, n₃ represents 1 or 2, and n₄ represents 1 to 8.

[3]

The pattern forming method according to [1] or [2], in which the absolute value of a difference between the solubility parameter (SP value) of the repeating unit represented by General Formula (I) and the solubility parameter (SP value) of the repeating unit represented by General Formula (II) in the first block copolymer is 0.5 to 4.0 (MPa^{1/2}) and the absolute value of a difference between the solubility parameter (SP value) of the repeating unit represented by General Formula (III) and the solubility parameter (SP value) of the repeating unit represented by General Formula (IV) in the second block copolymer is 0.5 to 4.0 (MPa^{1/2}).

[4]

The pattern forming method according to any one of [1] to [3], in which the number average molecular weight of each of the first block copolymer and the second block copolymer is less than 25000.

[5]

The pattern forming method according to [4], in which the number average molecular weight of each of the first block copolymer and the second block copolymer is less than 20000.

[6]

The pattern forming method according to any one of [1] to [5], in which the guide pattern is a guide pattern formed by exposing an active light sensitive or radiation sensitive film to an ArF excimer laser, extreme ultraviolet rays, or an electron beam, and by developing the exposed active light sensitive or radiation sensitive film using a developer.

[7]

The pattern forming method according to any one of [1] to [6], in which an underlayer containing an undercoat agent is formed on the substrate and the block copolymer layer is formed on the underlayer.

[8]

The pattern forming method according to any one of [1] to [7], in which a top coating layer is formed on the block copolymer layer between the step (i) and the step (ii).

[9]

An electronic device manufacturing method, comprising the pattern forming method according to any one of [1] to [8].

[10]

An electronic device manufactured by the electronic device manufacturing method according to [9].

[11]

A block copolymer comprising a block of a repeating unit represented by the following General Formula (I) and a block of a repeating unit represented by the following General Formula (II-2) or (II-3).

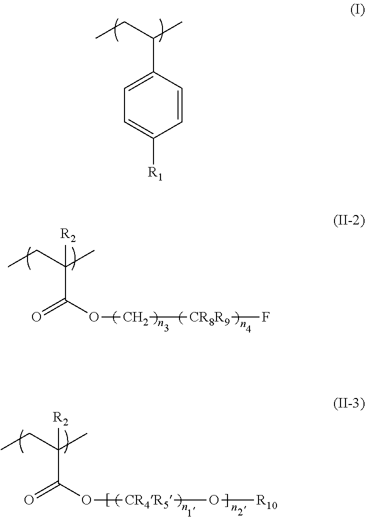

In General Formula (I), R₁ represents an alkyl group, an alkenyl group, an alkynyl group, a cycloalkyl group, an aryl group, or an aralkyl group, and R₁ may be condensed with a benzene ring by bonding to a carbon atom adjacent to the carbon atom to which R₁ has been bonded.

In General Formulas (II-2) and (II-3), R₂ represents a hydrogen atom, an alkyl group, or a cycloalkyl group.

Each of R₄′ and R₅′ independently represents a hydrogen atom or a methyl group. A plurality of R₄'s and a plurality of R₅'s may be the same as or different from each other, respectively.

Each of R₈ and R₉ independently represents a hydrogen atom or a fluorine atom. Here, at least one of R₈ or R₉ represents a fluorine atom. In a case where a plurality of R₈'s and a plurality of R₉'s are present, respectively, the plurality of R₈'s and the plurality of R₉'s may be the same as or different from each other, respectively.

R₁₀ represents a hydrogen atom, an alkyl group, a cycloalkyl group, or an aryl group.

n₁′ represents 2 to 4, n₂′ represents 1 to 6, n₃ represents 1 or 2, and n₄ represents 1 to 8.

[12]

The block copolymer according to [11], in which the number average molecular weight of the block copolymer is less than 25000.

[13]

The block copolymer according to [12], in which the number average molecular weight of the block copolymer is less than 20000.

A block copolymer production method, in which the block copolymer according to any one of [11] to [13] is synthesized by living polymerization.

[15]

The block copolymer production method according to [14], in which the living polymerization is living anion polymerization.

[16]

The block copolymer production method according to [15], in which a microreactor is used.

[17]

A pattern forming method comprising (i) a step of forming a block copolymer layer containing a block copolymer on a substrate on which a guide pattern has been formed, (ii) a step of phase-separating the block copolymer layer, and (iii) a step of selectively removing at least one phase of a plurality of phases of the block copolymer layer, in which the block copolymer is a block copolymer having a block of a first repeating unit and a block of a second repeating unit, and the absolute value of a difference between the solubility parameter (SP value) of the first repeating unit and the solubility parameter (SP value) of the second repeating unit is 0.5 to 4.0 (MPa^{1/2}).

[18]

A block copolymer for manufacturing semiconductors comprising a block of a first repeating unit and a block of a second repeating unit, in which the absolute value of a difference between the solubility parameter (SP value) of the first repeating unit and the solubility parameter (SP value) of the second repeating unit is 0.5 to 4.0 (MPa^{1/2}).

According to the present invention, it is possible to provide a pattern forming method in which, in self-organization lithography using a graphoepitaxy method, high miniaturization of patterns can be achieved with high quality and high efficiency (for example, a line-and-space pattern having a pitch of 60 nm or less or a hole pattern having a hole diameter of 30 nm or less can be formed with high quality and high efficiency), an electronic device manufacturing method using the pattern forming method and the electronic device, and a block copolymer used in the pattern forming method and the production method thereof.

### BRIEF DESCRIPTION OF THE DRAWINGS

FIG. 1(a) to FIG. 1(d) are schematic sectional views illustrating a form of forming a highly miniaturized line-and-space pattern by a graphoepitaxy method using a line-and-space pattern as a guide pattern, and FIG. 1(e) is a schematic top view thereof.

FIG. 2(a) to FIG. 2(d) are schematic sectional views illustrating another form of forming a highly miniaturized line-and-space pattern by a graphoepitaxy method using a line-and-space pattern as a guide pattern, and FIG. 2(e) is a schematic top view thereof.

FIG. 3(a) to FIG. 3(d) are schematic sectional views illustrating a form of forming a highly miniaturized hole pattern by a graphoepitaxy method using a hole pattern as a guide pattern, and FIG. 3(e) is a schematic top view thereof.

### DESCRIPTION OF THE PREFERRED EMBODIMENTS

Hereinafter, the embodiment of the present invention will be described in detail.

Regarding the description of a group (atomic group) in the present specification, in a case where the description does not indicate whether a group is substituted or unsubstituted, the description includes both a group having a substituent and a group not having a substituent. For example, “alkyl group” includes not only an alkyl group (an unsubstituted alkyl group) which does not have a substituent but also an alkyl group (a substituted alkyl group) which has a substituent.

The term “active light” or “radiation” in the present specification refers to, for example, a bright line spectrum of a mercury lamp, far-ultraviolet rays represented by an excimer laser, extreme ultraviolet rays (EUV light), X-rays, an electron beam (EB), and the like. The light in the present invention refers to the active light or the radiation.

In addition, the term “exposure” in the present specification includes not only the exposure performed using a mercury lamp, far-ultraviolet rays represented by an excimer laser, extreme ultraviolet rays, X-rays, or EUV light, but also drawing performed using a particle beam such as an electron beam, an ion beam, or the like, unless otherwise specified.

The pattern forming method of the present invention includes (i) a step of forming a block copolymer layer containing a first block copolymer having a block of a repeating unit represented by the following General Formula (I) and a block of a repeating unit represented by the following General Formula (II) or a second block copolymer having a block of a repeating unit represented by the following General Formula (III) and a block of a repeating unit represented by the following General Formula (IV) on a substrate on which a guide pattern has been formed, (ii) a step of phase-separating the block copolymer layer, and (iii) a step of selectively removing at least one phase of a plurality of phases of the block copolymer layer.

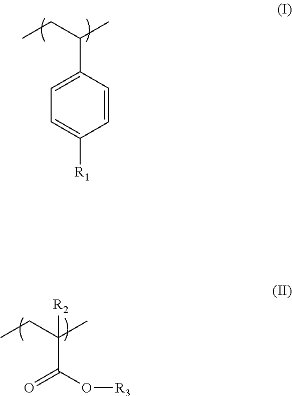

In General Formula (I), R₁ represents an alkyl group, an alkenyl group, an alkynyl group, a cycloalkyl group, an aryl group, or an aralkyl group, and R₁ may be condensed with a benzene ring by bonding to a carbon atom adjacent to the carbon atom to which R₁ has been bonded.

In General Formula (II), R₂ represents a hydrogen atom, an alkyl group, or a cycloalkyl group, and R₃ represents an alkyl group or a cycloalkyl group which may be substituted with a halogen atom or a group including an oxygen atom or a sulfur atom.

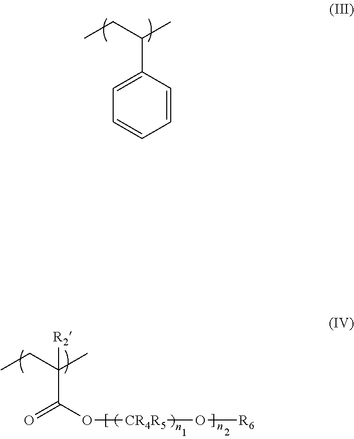

In General Formula (IV), R₂′ represents a hydrogen atom, an alkyl group, or a cycloalkyl group.

each of R₄ and R₅ independently represents a hydrogen atom or a methyl group, a plurality of R₄'s and a plurality of R₅'s may be the same as or different from each other, respectively.

R₆ represents an alkyl group having 1 to 4 carbon atoms.

n₁ represents 2 to 4, and n₂ represents 1 to 6.

The reason why high miniaturization of patterns can be achieved with high quality and high efficiency (for example, a line-and-space pattern having a pitch of 60 nm or less or a hole pattern having a hole diameter of 30 nm or less can be formed with high quality and high efficiency) in self-organization lithography using a graphoepitaxy method by the pattern forming method of the present invention is not clear, but it is thought to be as follows.

As described above, in the pattern forming method of the present invention, the block copolymer layer to be subjected to phase separation contains the first block copolymer having a block of the repeating unit represented by General Formula (I) and a block of the repeating unit represented by General Formula (II) or the second block copolymer having a block of the repeating unit represented by General Formula (III) and a block of the repeating unit represented by General Formula (IV).

Here, in the first block copolymer, by the repeating unit represented by General Formula (I) having a structure derived from 4-position substituted styrene, the hydrophobicity thereof becomes very great compared to the repeating unit represented by General Formula (II). Thus, the phase separability between the block of the repeating unit represented by General Formula (I) and the block of the repeating unit represented by General Formula (II) is very high.

In addition, in the second block copolymer, by the repeating unit represented by General Formula (IV) having an alkyleneoxy structure on a side chain, the hydrophobicity thereof becomes very small compared to the repeating unit represented by General Formula (III). Thus, the phase separability between the block of the repeating unit represented by General Formula (III) and the block of the repeating unit represented by General Formula (IV) is very high.

As described above, the phase separability of each block in the first block copolymer and the second block copolymer is very high, and thus, even in a case where a block copolymer layer (in particular, a block copolymer layer particularly containing a block copolymer having a low number average molecular weight to achieve high miniaturization of patterns) containing these copolymers is formed on a substrate on which a guide pattern has been formed, it is possible to reliably cause phase separation of the block copolymer layer. As a result, according to the present invention, it is thought that high miniaturization of patterns can be achieved with high quality and high efficiency (for example, a line-and-space pattern having a pitch of 60 nm or less or a hole pattern having a hole diameter of 30 nm or less can be formed with high quality and high efficiency).

<Pattern Forming Method>

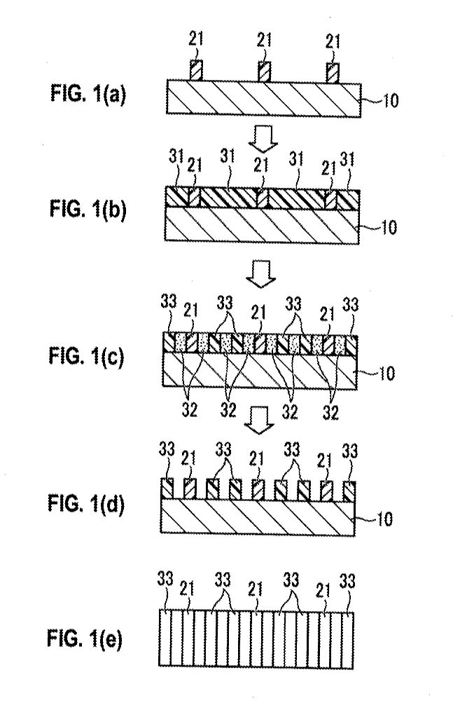

FIG. 1(a) to FIG. 1(d) are schematic sectional views illustrating a form of forming a highly miniaturized line-and-space pattern by a graphoepitaxy method using a line-and-space pattern as a guide pattern, and FIG. 1(e) is a schematic top view thereof.

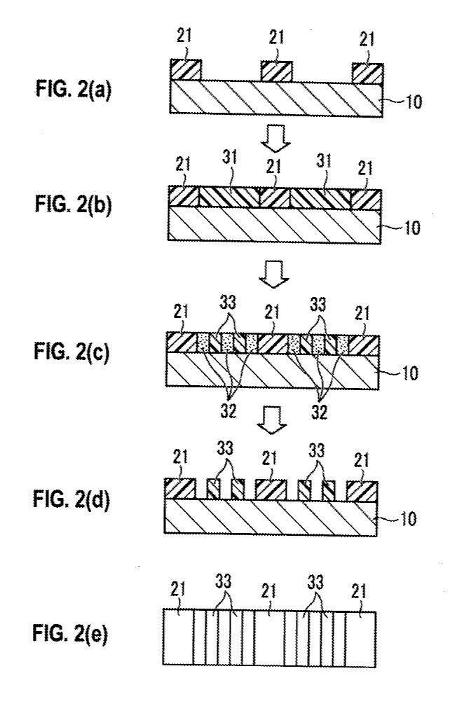

FIG. 2(a) to FIG. 2(d) are schematic sectional views illustrating another form of forming a highly miniaturized line-and-space pattern by a graphoepitaxy method using a line-and-space pattern as a guide pattern, and FIG. 2(e) is a schematic top view thereof.

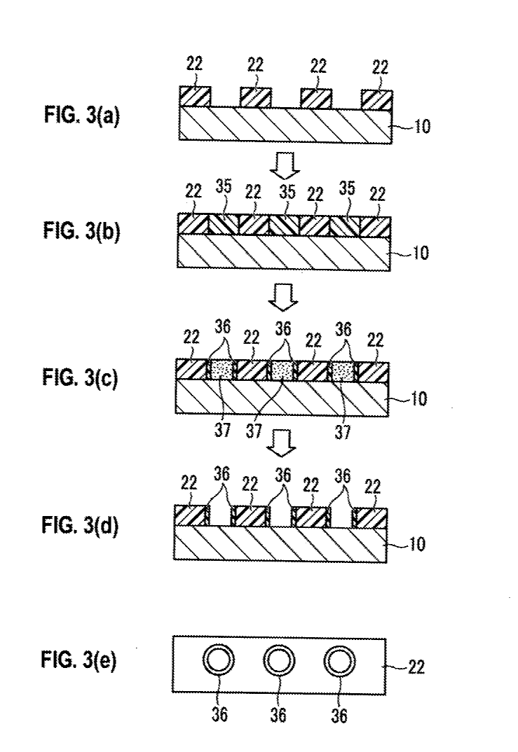

FIG. 3(a) to FIG. 3(d) are schematic sectional views illustrating a form of forming a highly miniaturized hole pattern by a graphoepitaxy method using a hole pattern as a guide pattern, and FIG. 3(e) is a schematic top view thereof.

The pattern forming method of the present invention will be described in detail below with reference to these drawings as appropriate. Moreover, in the embodiment described below, description of the members or the like described in the previously referenced drawings is simplified or omitted by denoting the same reference numerals or corresponding reference numerals in the drawings.

[(i) Step of Forming Block Copolymer Layer Containing First Block Copolymer Having Block of Repeating Unit Represented by General Formula (I) and Block of Repeating Unit Represented by General Formula (II) or Second Block Copolymer Having Block of Repeating Unit Represented by General Formula (III) and Block of Repeating Unit Represented by General Formula (IV) on Substrate on which Guide Pattern has been Formed]

The substrate in the “substrate on which a guide pattern has been formed” used in a step (i) is not particularly limited, and an inorganic substrate such as silicon, SiO₂, or SiN, and a coated inorganic substrate such as SOG, and a substrate which is generally used in a step of manufacturing a semiconductor such as IC, a step of manufacturing a circuit board for liquid crystal or a thermal head, or a lithography step of photofabrication can be used. If necessary, an antireflection film may be formed between a film and a substrate.

As the antireflection film, any type of an inorganic film type such as titanium, titanium dioxide, titanium nitride, chromium oxide, carbon, or amorphous silicon, and an organic film type formed of a light absorber and a polymer material can be used. In addition, as the organic antireflection film, a commercially available organic antireflection film such as DUV30 series or DUV-40 series manufactured by Brewer Science, Inc., or AR-2, AR-3, or AR-5 manufactured by Shipley Company, L.L.C. can also be used.

In addition, an underlayer containing an undercoat agent may be provided on a substrate.

By providing such an underlayer, it is possible to more reliably cause phase separation of the block copolymer layer in the step (ii) described in detail below, in some cases. For example, by providing an underlayer containing a material having an affinity for any block configuring the block copolymer as an undercoat agent, it is possible to suppress for only a specific phase to come into contact with the substrate in some cases. Specifically, for example, a random copolymer having each component of a block copolymer to be subjected to self-organization (DSA) or, in addition to this, a polymer obtained by copolymerizing a monomer component further having a crosslinkable/polymerisable group such as an epoxy group or a vinyl group is preferably used as the underlayer.

Such an undercoat agent is not particularly limited as long as it exhibits the function as described above, the description in paragraphs “0331” to “0333” of WO2012/169620A can be referred to, and the contents thereof are incorporated in the present specification.

The underlayer containing an undercoat agent is suitably formed by applying a liquid obtained by dissolving an undercoat agent in a solvent using a spinner and a coater and by drying the resultant product.

The thickness of the underlayer is preferably 3 nm to 100 nm, more preferably 5 nm to 50 nm, and still more preferably 10 nm to 30 nm.

A guide pattern provided on a substrate is not particularly limited, and a guide pattern 21 which forms a line-and-space pattern (refer to the schematic sectional view of FIG. 1(a)), a guide pattern 22 which forms a hole pattern (refer to the schematic sectional view of FIG. 3(a)), and the like are exemplified.

The thickness of the guide pattern is preferably 10 nm to 250 nm, more preferably 20 nm to 200 nm, and still more preferably 30 nm to 100 nm.

The guide pattern is preferably a guide pattern formed by exposing the active light sensitive or radiation sensitive film and by developing the exposed active light sensitive or radiation sensitive film using a developer.

The active light sensitive or radiation sensitive film is preferably obtained by applying an active light sensitive or radiation sensitive resin composition described below to a substrate (for example, a substrate (example: the substrates described above, silicon/silicon dioxide coating, quartz substrate deposited with silicon nitride or chromium, or the like) which is used in manufacture of precision integrated circuit elements, a mold for imprint, or the like) using a spinner or a coater and by drying this.

Examples of the active light or the radiation used in exposure include infrared light, visible light, ultraviolet light, far-ultraviolet light, X-rays, and an electron beam. The active light or the radiation, for example, more preferably has a wavelength of 250 nm or less, in particular, 220 nm or less. Examples of the active light or the radiation include a KrF excimer laser (248 nm), an ArF excimer laser (193 nm), an F₂ excimer laser (157 nm), X-rays, and an electron beam. Preferable examples of the active light or the radiation include a KrF excimer laser, an ArF excimer laser, an electron beam, X-rays, and extreme ultraviolet rays (EUV light). An ArF excimer laser, an electron beam, or extreme ultraviolet rays are more preferable.

In addition, in the exposure step, in particular, in a case where exposure by an ArF excimer laser is performed, a liquid immersion exposure method can be suitably applied. The liquid immersion exposure method can be used in combination with super-resolution techniques such as a phase shift method and a modified illumination method.

In the case of performing liquid immersion exposure, (1) after forming a film on a substrate, before a step of exposing, and/or (2) after a step of exposing the film through an immersion liquid, before a step of heating the film, a step of washing the surface of the film with an aqueous chemical solution may be performed.

Regarding the immersion liquid used when liquid immersion exposure is performed, the description in paragraphs “0059” and “0060” of JP2013-76991A can be referred to, and the contents thereof are incorporated in the present specification.

The receding contact angle of the active light sensitive or radiation sensitive film is 70° or greater at a temperature of 23±3° C. and a humidity of 45±5%, and this is suitable in the case of exposing through an immersion medium, and the receding contact angle is preferably 75° C. or greater, and more preferably 75° to 85°.

In a case where the receding contact angle is too small, the film can not be suitably used in the case of exposing through an immersion medium, and the effects of watermark defect reduction can not be sufficiently exhibited. To achieve a preferable receding contact angle, a hydrophobic resin (HR) described below is preferably included in the active light sensitive or radiation sensitive resin composition. Alternatively, by forming a coating layer (a so-called “topcoat”) by a hydrophobic resin composition on the active light sensitive or radiation sensitive film, the receding contact angle may be improved.

In a liquid immersion exposure step, an immersion liquid is required to move on the wafer following the movement which forms an exposure pattern by scanning of the exposure head on the wafer at a high speed, and therefore, the contact angle of the immersion liquid with respect to the active light sensitive or radiation sensitive film in a dynamic state becomes important, and performance to follow high-speed scanning of an exposure head is required for the resist, without remaining liquid droplets.

When exposing to an electron beam or extreme ultraviolet rays, for the purpose of suppression of outgassing, suppression of blob defects, prevention of rapid deterioration due to reverse taper shape improvement, prevention of LWR deterioration due to surface roughness, and the like, a topcoat may be formed on the upper layer of a film formed of the active light sensitive or radiation sensitive resin composition of the present invention. In addition, in a case where the active light sensitive or radiation sensitive composition is for exposure to an electron beam or extreme ultraviolet rays, the hydrophobic resin (HR) described below may be added thereto. By adding the hydrophobic resin (HR), effects such as outgassing suppression are obtained similarly to the case of forming a topcoat.

The topcoat composition used in formation of a topcoat will be described below.

The solvent of the topcoat composition is preferably water or an organic solvent. Water or an alcohol-based solvent is more preferable.

In a case where the solvent is an organic solvent, a solvent which does not dissolve a film formed of the active light sensitive or radiation sensitive resin composition is preferable. As a solvent capable of being used, an alcohol-based solvent, a fluorine-based solvent, or a hydrocarbon-based solvent is preferably used, and an alcohol-based solvent which is nonfluorine-based is more preferably used. As the alcohol-based solvent, a primary alcohol is preferable, and a primary alcohol having 4 to 8 carbon atoms is more preferable, from the viewpoint of application properties. Although a linear, a branched, or a cyclic alcohol can be used as a primary alcohol having 4 to 8 carbon atoms, a linear or a branched alcohol is preferable. Specific examples thereof include 1-butanol, 1-hexanol, 1-pentanol, and 3-methyl-1-butanol.

The solvent of the topcoat composition may be used alone or two or more types thereof may be used in combination.

In a case where the solvent of the topcoat composition is water or an alcohol-based solvent, the solvent preferably contains a water-soluble resin. It is thought that the uniformity of solubility in a developer can be enhanced by containing a water-soluble resin. Examples of the preferable water-soluble resin include polyacrylic acid, polymethacrylic acid, polyhydroxystyrene, polyvinyl pyrrolidone, polyvinyl alcohol, polyvinyl ether, polyvinyl acetal, polyacrylic imide, polyethylene glycol, polyethylene oxide, polyethylene imine, polyester polyol, polyether polyol, and polysaccharides. Polyacrylic acid, polymethacrylic acid, polyhydroxystyrene, polyvinyl pyrrolidone, or polyvinyl alcohol is particularly preferable. Moreover, the water-soluble resin is not limited only to a homopolymer, and may be a copolymer. For example, the water-soluble resin may be a copolymer which has a monomer corresponding to the repeating unit of the homopolymer described above and another monomer unit. Specifically, an acrylic acid-methacrylic acid copolymer or an acrylic acid-hydroxystyrene copolymer can also be used in the present invention.

In addition, as the resin for the topcoat composition, a resin having an acidic group described in JP2009-134177A or JP2009-91798A can also be preferably used.

Although the weight average molecular weight of the water-soluble resin is not particularly limited, the weight average molecular weight is preferably 2000 to 1000000, more preferably 5000 to 500000, and particularly preferably 10000 to 100000. Here, the weight average molecular weight of a resin is a molecular weight in terms of polystyrene measured by using GPC (carrier: THF or N-methyl-2-pyrrolidone (NMP)). The resin for the topcoat composition may be used alone or two or more types thereof may be used in combination.

Although the pH of the topcoat composition is not particularly limited, the pH is preferably 0 to 10, more preferably 0 to 8, and particularly preferably 1 to 7.

In a case where the solvent of the topcoat composition is an organic solvent, the topcoat composition may contain a hydrophobic resin as the hydrophobic resin (HR) to be described in the section of the active light sensitive or radiation sensitive resin composition. As the hydrophobic resin, the hydrophobic resin described in JP2008-209889A is also preferably used.

The concentration of the resin in the topcoat composition is preferably 0.1% by mass to 10% by mass, more preferably 0.2% by mass to 5% by mass, and particularly preferably 0.3% by mass to 3% by mass.

The topcoat material may include components other than a resin, and the proportion of the resin in the solid content of the topcoat composition is preferably 80% by mass to 100% by mass, more preferably 90% by mass to 100% by mass, and particularly preferably 95% by mass to 100% by mass.

The solid content concentration in the topcoat composition is preferably 0.1% by mass to 10% by mass, more preferably 0.2% by mass to 6% by mass, and particularly preferably 0.3% by mass to 5% by mass. In a case where the solid content concentration is within the above range, the topcoat composition can be uniformly applied to a resist film.

Examples of components other than resins capable of being added to the topcoat material include a surfactant, an acid generator, and a basic compound. Specific examples of the acid generator and the basic compound include the same compounds as compounds that generate an acid by irradiation with active light or radiation and the basic compounds described below.

In a case where a surfactant is used, the amount of the surfactant used is preferably 0.0001% by mass to 2% by mass, and more preferably 0.001% by mass to 1% by mass, with respect to the total amount of the topcoat composition.

By adding a surfactant to the topcoat composition, coating properties in a case of applying the topcoat composition can be improved. Examples of the surfactant include nonionic, anionic, cationic, and amphoteric surfactants.

As the nonionic surfactant, PLUFARAC series manufactured by BASF Corp., ELEBASE series, FINESURF series, or BLAUNON series, manufactured by Aoki Oil Industrial Co., Ltd., ADEKA PLURONIC P-103 manufactured by Adeka Corporation, EMULCEN series, AMIET series, AMINON PK-02S, EMANON CH-25, or RHEODOL series, manufactured by Kao Chemical Co., SURFLON S-141 manufactured by AGC SEIMI CHEMICAL CO., LTD., NOIGEN series manufactured by Dai-ichi Kogyo Seiyaku Co., Ltd., NEWKALGEN series manufactured by TAKEMOTO OIL & FAT Co., Ltd., DYNOL 604, ENVIROGEM AD01, OLFINE EXP series, and SURFYNOL series, manufactured by Nissin Chemical Industry Co., Ltd., FTERGENT 300 manufactured by Ryoko Chemical Co., Ltd., or the like can be used.

As the anionic surfactant, EMAL 20T or POIZ 532A manufactured by Kao Chemical Co., PHOSPHANOL ML-200 manufactured by TOHO Chemical Industry Co., Ltd., EMULSOGEN series manufactured by Clariant Japan KK, SURFLON S-11 IN or SURFLON S-211 manufactured by AGC SEIMI CHEMICAL CO., LTD., PLYSURF series manufactured by Dai-ichi Kogyo Seiyaku Co., Ltd., PIONIN Series manufactured by TAKEMOTO OIL & FAT Co., Ltd., OLFINE PD-201 or OLFINE PD-202 manufactured by Nissin Chemical Industry Co., Ltd., AKYPO RLM45 or ECT-3 manufactured by Nihon Surfactant Kogyo K.K., LIPON manufactured by Lion Corporation, or the like can be used.

As the cationic surfactant, ACETAMIN 24, ACETAMIN 86 manufactured by Kao Chemical Co., or the like can be used.

As the amphoteric surfactant, SURFLON S-131 (manufactured by AGC SEIMI CHEMICAL CO., LTD.), ENADICOL C-40H or LIPOMIN LA (manufactured by Kao Chemical Co., Ltd.), or the like can be used.

In addition, there surfactants can also be used in combination.

The topcoat can be formed by applying the topcoat composition and by drying the resultant product, in the same manner as in the method of forming an active light sensitive or radiation sensitive film formed of the active light sensitive or radiation sensitive resin composition, and the film thickness of the topcoat is preferably 10 nm to 200 nm, more preferably 20 nm to 100 nm, and particularly preferably 40 nm to 80 nm.

Development is performed by irradiating a film having a topcoat on the upper layer with an electron beam (EB), X-rays, or EUV light typically through a mask and by, preferably, baking (heating) the resultant product. Thus, a better pattern can be obtained.

Moreover, the performance required for the topcoat and the method of use thereof are explained in Chapter 7 in “Process and Ingredient of Immersion Lithography” published by CMC Publishing Co., Ltd.

When the top coat is peeled off after exposure, a developer may be used, or separately, a peeling agent may be used. As the peeling agent, a solvent which hardly penetrates into a film is preferable. From the viewpoint of being capable of performing a peeling step simultaneously with a developing treatment step of a film, the topcoat can be preferably peeled off with a developer.

In formation of a guide pattern, a step of exposing the active light sensitive or radiation sensitive film may be performed multiple times.

After film formation, before an exposure step, a prebake (PB) step may be performed. Here, the prebake step may be performed multiple times.

In addition, after an exposure step and before a developing step, a post exposure bake (PEB) step is also preferably performed. Here, the post exposure bake step may be performed multiple times.

Each of PB and PEB is preferably performed at a heating temperature of 70° C. to 130° C., and more preferably performed at a heating temperature of 80° C. to 120° C.

The heating time is preferably 30 seconds to 300 seconds, more preferably 30 seconds to 180 seconds, and still more preferably 30 seconds to 90 seconds.

The heating can be performed by means provided in a typically exposure developing device, or may be performed using a hot plate or the like.

By baking, the reaction of an exposed portion is promoted, and the sensitivity or the pattern profile is improved.

The developer used in formation of a guide pattern may be a developer containing an organic solvent or may be an alkali developer.

In a case where a developer containing an organic solvent is used, a negative type guide pattern can be formed.

In a case where an alkali developer is used, a positive type guide pattern can be formed.

In a case where the developer is a developer including an organic solvent, a step of developing using an alkali developer may be further performed, and in a case where the developer is an alkali developer, a step of developing using a developer including an organic solvent may be further performed.

In this case, a portion having weak exposure intensity is removed in an organic solvent development step, and a portion having strong exposure intensity is also removed by performing the alkali development step. Since pattern formation is performed without dissolving only a region having intermediate exposure intensity by the multiple development process performing development multiple times in this manner, a finer pattern than usual can be formed (the same mechanism as that in paragraph “0077” of JP2008-292975A).

In this case, although the order of the alkali developing step and the organic solvent development step is not particularly limited, it is more preferable that the alkali development is performed before the organic solvent development step.

In a case where the step of developing using an alkali developer is performed in formation of a guide pattern, as the alkali developer, for example, alkaline aqueous solutions such as inorganic alkalies including sodium hydroxide, potassium hydroxide, sodium carbonate, sodium silicate, sodium metasilicate, and ammonia water, primary amines including ethylamine and n-propylamine, secondary amines including diethylamine and di-n-butylamine, tertiary amines including triethylamine and methyldiethylamine, alcohol amines including dimethyl ethanolamine and triethanolamine, quaternary ammonium salts including tetramethylammonium hydroxide, tetraethylammonium hydroxide, tetrapropylammonium hydroxide, tetrabutylammonium hydroxide, and benzyltrimethylammonium hydroxide, and cyclic amines including pyrrole and piperidine can be used.

Furthermore, a suitable amount of alcohol or surfactant can also be added to the alkaline aqueous solution for use.

The alkali concentration of the alkali developer is typically 0.1% by mass to 20% by mass.

The pH of the alkali developer is typically 10.0 to 15.0.

In particular, a 2.38% by mass tetramethylammonium hydroxide aqueous solution is desirable.

After the step of developing using an alkali developer, a step of washing with a rinse liquid may be performed, but from the viewpoint of the throughput (productivity) or the amount of rinse liquid used, a step of washing with a rinse liquid may not be performed.

As the rinse liquid in the rinse treatment performed after the alkali development, pure water is used, and a suitable amount of surfactant can also be added thereto for use.

After the development treatment or the rinse treatment, a treatment of removing the developer or rinse liquid adhered to the pattern by a supercritical fluid can be performed.

In a case where the step of developing using a developer containing an organic solvent is performed in formation of a guide pattern, as the developer in the step (hereinafter, also referred to as an organic-based developer), a polar solvent or a hydrocarbon-based solvent such as a ketone-based solvent, an ester-based solvent, an alcohol-based solvent, an amide-based solvent, or an ether-based solvent can be used.

Examples of the ketone-based solvent can include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methyl cyclohexanone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, isophorone, and propylene carbonate.

Examples of the ester-based solvent include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, and propyl lactate.

Examples of the alcohol-based solvent include alcohols such as methyl alcohol, ethyl alcohol, n-propyl alcohol, isopropyl alcohol, n-butyl alcohol, sec-butyl alcohol, 4-methyl-2-pentanol, tert-butyl alcohol, isobutyl alcohol, n-hexyl alcohol, n-heptyl alcohol, n-octyl alcohol, and n-decanol, glycol-based solvents such as ethylene glycol, diethylene glycol, and triethylene glycol, and glycol ether-based solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethyl butanol.

Examples of the ether-based solvent include anisole, dioxane, and tetrahydrofuran, in addition to glycol ether-based solvents described above.

As the amide-based solvent, for example, N-methyl-2-pyrrolidone, N,N-dimethyl acetamide, N,N-dimethyl formamide, hexamethylphosphoric triamide, or 1,3-dimethyl-2-imidazolidinone can be used.

Examples of the hydrocarbon-based solvent include aromatic hydrocarbon-based solvents such as toluene and xylene, and aliphatic hydrocarbon-based solvents such as pentane, hexane, octane, and decane.

A plurality of solvents described above may be used in combination, or the solvent may be used in combination with a solvent other than the solvents described above or water. Here, in order to exhibit the effects of the present invention, the water content of the entirety of the developer is preferably less than 10% by mass, and the developer more preferably substantially does not contain water.

That is, the amount of the organic solvent used with respect to the organic-based developer is preferably 90% by mass to 100% by mass, and more preferably 95% by mass to 100% by mass, with respect to the total amount of developer.

In particular, the organic-based developer is preferably a developer containing at least one type of organic solvent selected from the group consisting of a ketone-based solvent, an ester-based solvent, an alcohol-based solvent, amide-based solvent, and an ether-based solvent.

The vapor pressure of the organic-based developer is preferably 5 kPa or lower, more preferably 3 kPa or lower, and particularly preferably 2 kPa or lower, at 20° C. In a case where the vapor pressure of the organic-based developer is 5 kPa or lower, evaporation of the developer on the substrate or in a development cup is suppressed, the temperature uniformity in the wafer surface is improved, and as a result, the dimensional evenness in the wafer surface is improved.

Specific examples of the developer having a vapor pressure of 5 kPa or lower include ketone-based solvents such as 1-octanone, 2-octanone, 1-nonanone, 2-nonanone, 2-heptanone (methyl amyl ketone), 4-heptanone, 2-hexanone, diisobutyl ketone, cyclohexanone, methyl cyclohexanone, phenyl acetone, and methyl isobutyl ketone, ester-based solvents such as butyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, butyl formate, propyl formate, ethyl lactate, butyl lactate, and propyl lactate, alcohol-based solvents such as n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, and n-decanol, glycol-based solvents such as ethylene glycol, diethylene glycol, and triethylene glycol, glycol ether-based solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethyl butanol, ether-based solvents such as tetrahydrofuran, amide-based solvents such as N-methyl-2-pyrrolidone, N,N-dimethyl acetamide, and N,N-dimethyl formamide, aromatic hydrocarbon-based solvents such as toluene and xylene, and aliphatic hydrocarbon-based solvents such as octane and decane.

Specific examples of the developer having a vapor pressure of 2 kPa or lower which is a particularly preferable range include ketone-based solvents such as 1-octanone, 2-octanone, 1-nonanone, 2-nonanone, 2-heptanone, 4-heptanone, 2-hexanone, diisobutyl ketone, cyclohexanone, methyl cyclohexanone, and phenyl acetone, ester-based solvents such as butyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, ethyl lactate, butyl lactate, and propyl lactate, alcohol-based solvents such as n-butyl alcohol, sec-butyl alcohol, tert-butyl alcohol, isobutyl alcohol, n-hexyl alcohol, n-heptyl alcohol, n-octyl alcohol, and n-decanol, glycol-based solvents such as ethylene glycol, diethylene glycol, and triethylene glycol, glycol ether-based solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethyl butanol, amide-based solvents such as N-methyl-2-pyrrolidone, N,N-dimethyl acetamide, and N,N-dimethyl formamide, aromatic hydrocarbon-based solvents such as xylene, and aliphatic hydrocarbon-based solvents such as octane and decane.

As described, in particular, in paragraphs “0032” to “0063” of JP2013-11833A, the organic-based developer may include a basic compound. Specific examples and preferable examples of the basic compound which can be included in the developer used in the present invention include the same as those of the basic compound which can be included in the active light sensitive or radiation sensitive resin composition, described below.

A suitable amount of surfactant can be added to the organic-based developer, if necessary.

The surfactant is not particularly limited, and for example, an ionic and nonionic fluorine-based surfactant and/or a silicon-based surfactant can be used. Examples of the fluorine-based surfactant and/or the silicon-based surfactant include surfactants described in JP1987-36663A (JP-S62-36663A), JP1986-226746A (JP-S61-226746A), JP1986-226745A (JP-61-226745A), JP1987-170950A (JP-62-170950A), JP1988-34540A (JP-63-34540A), JP1995-230165A (JP-H7-230165A), JP1996-62834A (JP-H8-62834A), JP1997-54432A (JP-H9-54432A), and JP1997-5988A (JP-H9-5988A), and the specifications of U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451A, and a nonionic surfactant is preferable. The nonionic surfactant is not particularly limited, and a fluorine-based surfactant or a silicon-based surfactant is more preferably used.

The amount of surfactant used is preferably 0% by mass to 2% by mass, more preferably 0.0001% by mass to 2% by mass, and particularly preferably 0.0005% by mass to 1% by mass, with respect to the total amount of developer. The surfactant may be used alone or two or more types thereof may be used in combination.

As the developing method, a method in which a substrate is dipped in a bath filled with a developer for a predetermined period of time (dipping method), a method in which developing is performed by placing a developer on the substrate surface using surface tension and this being held stationary for a predetermined period of time (puddle method), a method in which a developer is sprayed onto a substrate surface (spray method), or a method in which a substrate is spun at a constant rate, and a developer discharge nozzle is then scanned across the substrate at a constant rate while a developer is discharged continuously on the substrate from the nozzle (dynamic dispensing method) can be applied.

The above-described various developing methods include a step of discharging a developer toward a resist film from a developing nozzle of a developing device, the discharge pressure (flow rate per unit area of a developer to be discharged) of a developer to be discharged is preferably 2 mL/sec/mm² or less, more preferably 1.5 mL/sec/mm² or less, and still more preferably 1 mL/sec/mm² or less. Although the lower limit of the flow rate is not particularly limited, in consideration of throughput, 0.2 mL/sec/mm² or greater is preferable.

In a case where the discharge pressure of a developer to be discharged is within the above range, the defects of the pattern resulting from a resist residue after development can be significantly reduced.

Details of the mechanism are not clear, but, it is thought that this is probably because, in a case where the discharge pressure is within the above range, the pressure applied to the resist film by the developer decreases, or unexpected scraping or collapsing of the active light sensitive or radiation sensitive film or the guide pattern is suppressed.

Moreover, the discharge pressure (mL/sec/mm²) of a developer is a value at the developing nozzle exit in the developing device.

Examples of the method of adjusting the discharge pressure of a developer include a method of adjusting the discharge pressure using a pump and a method of adjusting the pressure by supply from a pressure tank instead of using a pump.

In addition, after a step of developing using a developer including an organic solvent, while replacing with another solvent, a step of stopping the development may be performed.

After the step of developing using a developer including an organic solvent, a step of washing with a rinse liquid may be performed, but from the viewpoint of the throughput (productivity) or the amount of rinse liquid used, a step of washing with a rinse liquid may not be performed.

The rinse liquid used in the rinsing step after the step of developing using a developer including an organic solvent is not particularly limited as long as it does not dissolve the guide pattern, and a solution including a general organic solvent can be used. As the rinse liquid, a rinse liquid containing at least one type of organic solvent selected from the group consisting of a hydrocarbon-based solvent (preferably, decane), a ketone-based solvent, an ester-based solvent, an alcohol-based solvent, an amide-based solvent, and an ether-based solvent is preferably used.

Specific examples of the hydrocarbon-based solvent, the ketone-based solvent, the ester-based solvent, the alcohol-based solvent, the amide-based solvent, and the ether-based solvent include the same as those described for the developer including an organic solvent.

After the step of developing using the developer including an organic solvent, more preferably, a step of washing using a rinse liquid containing at least one type of organic solvent selected from a ketone-based solvent, an ester-based solvent, an alcohol-based solvent, and an amide-based solvent is performed, still more preferably, a step of washing using a rinse liquid containing an alcohol-based solvent or an ester-based solvent is performed, particularly preferably, a step of washing using a rinse liquid containing a monohydric alcohol is performed, and most preferably, a step of washing using a rinse liquid containing a monohydric alcohol having 5 or more carbon atoms.

As the monohydric alcohol used in the rinsing step, a linear, branched, or cyclic monohydric alcohol is exemplified, and specifically, 1-butanol, 2-butanol, 3-methyl-1-butanol, tert-butyl alcohol, 1-pentanol, 2-pentanol, 1-hexanol, 4-methyl-2-pentanol, 1-heptanol, 1-octanol, 2-hexanol, cyclopentanol, 2-heptanol, 2-octanol, 3-hexanol, 3-heptanol, 3-octanol, or 4-octanol, can be used, and as particularly preferable monohydric alcohol having 5 or more carbon atoms, 1-hexanol, 2-hexanol, 4-methyl-2-pentanol, 1-pentanol, or 3-methyl-1-butanol can be used.

A plurality of the respective components described above may be used in combination, or the respective components may be used in combination with an organic solvent other than the organic solvents described above.

The water content of the rinse liquid is preferably 10% by mass or less, more preferably 5% by mass or less, and particularly preferably 3% by mass or less. In a case where the water content is 10% by mass or less, good development characteristics can be obtained.

The vapor pressure of the rinse liquid used after the step of developing using a developer including an organic solvent is preferably 0.05 kPa to 5 kPa, more preferably 0.1 kPa to 5 kPa, and most preferably 0.12 kPa to 3 kPa, at 20° C. In a case where the vapor pressure of the rinse liquid is 0.05 kPa to 5 kPa, the temperature evenness in the wafer surface is improved, swelling due to penetration of the rinse liquid is suppressed, and the dimensional evenness in the wafer surface is improved.

A suitable amount of surfactant can also be added to the rinse liquid for use.

In the rinsing step, the wafer developed by using a developer including an organic solvent is subjected to a washing treatment using the rinse liquid including an organic solvent described above. The method of washing treatment is not particularly limited, and, for example, a method in which a rinse liquid is discharged continuously onto a substrate while the substrate is spun at a constant rate (spin coating method), a method in which a substrate is dipped in a bath filled with a rinse liquid for a predetermined period of time (dipping method), or a method in which a rinse liquid is sprayed onto a substrate surface (spray method) can be suitably used, and among these, it is preferable that a washing treatment is performed by the spin coating method, and, after washing, a rinse liquid is removed from the substrate by rotating the substrate at a rotation speed of 2000 rpm to 4000 rpm.

After the rinsing step which can be performed after each of the step of developing using an alkali developer and the step of developing using an organic-based developer, a heating step (Post Bake) is also preferably performed. By baking, the developer and the rinse liquid remaining between the patterns and in the patterns are removed. The heating step after the rinsing step is performed typically 40° C. to 160° C., and preferably 70° C. to 95° C., and typically for 10 seconds to 3 minutes, and preferably 30 seconds to 90 seconds.

In particular, in a case where the active light sensitive or radiation sensitive resin composition contains a resin (A) having a group that generates a polar group by being decomposed due to the action of an acid described below, the guide pattern is preferably a negative type guide pattern formed by using an organic-based developer as a developer. This is because the resin in the pattern has a polar group generated by decomposition due to the action of an acid, and thus, this negative type guide pattern is less likely to be dissolved in the organic solvent in the composition containing a block copolymer described in detail below.

On the other hand, in a case where a positive type guide pattern is formed by using an alkali developer as a developer, the positive type guide pattern is also preferably subjected to a freezing treatment, if necessary.

Regarding the freezing treatment, a known method described in “New Trends of Photoresists” published by CMC Publishing Co., Ltd., pp. 138 to 175 (in particular, pp. 165 to 175), JPJP2009-294630A, JP2009-271259A, JP2009-294264A, JP2010-039034A, or JP2010-039035A can be preferably used.

For example, the step (i) of forming a block copolymer layer containing a first block copolymer or a second block copolymer (which will be described in detail below) on a substrate on which the guide pattern obtained in the above manner has been formed is performed.

For example, in the case of a graphoepitaxy method using a line-and-space pattern as a guide pattern, as shown in the schematic sectional view of FIG. 1(b), a block copolymer layer 31 is formed on a substrate 10 on which the guide pattern 21 has been formed.

In addition, for example, in the case of a graphoepitaxy method using a hole pattern as a guide pattern, as shown in the schematic sectional view of FIG. 3(b), a block copolymer layer 35 is formed on the substrate 10 on which the guide pattern 22 has been formed.

Typically, the composition containing the first block copolymer or the second block copolymer is applied to the substrate 10 using a spinner or a coater. Thereafter, by drying the resultant product, block copolymer layers 31 and 35 can be formed.

Although the thickness of each of the block copolymers 31 and 35 is not particularly limited as long as it is a thickness causing phase separation in the step (ii), the thickness is preferably 10 nm to 250 nm, the thickness is more preferably 20 nm to 200 nm, and still more preferably 30 nm to 100 nm.

[(ii) Step of Phase-Separating Block Copolymer Layer]

Next, the step (ii) of phase-separating the block copolymer layer is performed.

The step (ii) is, typically, a step of exhibiting a phase separation structure in which at least a part of a substrate is exposed by heating the block copolymer layer and by selectively removing the phase in the step (iii) described in detail below.

The heating temperature preferably satisfies the glass transition temperature of the first block copolymer or the second block copolymer or higher and the thermal decomposition temperature of the first block copolymer or the second block copolymer or lower. The heating temperature is preferably 50° C. to 300° C., more preferably 100° C. to 270° C., and still more preferably 150° C. to 250° C.

The heating time is preferably 1 second to 10 hours.

In a case where, among the plurality of phases configuring the phase-separated block copolymer layer, the phases which have not been selectively removed in the step (ii) are defined as nonremoval phases and the phases which have been selectively removed are defined as removal phases, for example, in a graphoepitaxy method using a line-and-space pattern as a guide pattern, as shown in the schematic sectional view of FIG. 1(c), a lamella structure in which removal phases 32 and nonremoval phases 33 are alternately arranged along the guide patterns 21 and 21 can be formed between the guide patterns 21 and 21. Here, in a case where the block copolymer is the first block copolymer, typically, a phase containing a block of the repeating unit represented by General Formula (II) configures the removal phase 32, and a phase containing a block of the repeating unit represented by General Formula (I) configures the nonremoval phase 33. In a case where the block copolymer is the second block copolymer, typically, a phase containing a block of the repeating unit represented by General Formula (IV) configures the removal phase 32, and a phase containing a block of the repeating unit represented by General Formula (III) configures the nonremoval phase 33.

In addition, for example, in the case of a graphoepitaxy method using a hole pattern as a guide pattern, as shown in the schematic sectional view of FIG. 3(c), a cylinder structure in which nonremoval phases 36 are disposed on the inner wall side of the guide patterns 22 which are hole patterns and removal phases 37 are disposed on the center side of the guide patterns 22, respectively, can be formed. Here, in a case where the block copolymer is the first block copolymer, typically, a phase containing a block of the repeating unit represented by General Formula (I) configures the nonremoval phase 36, and a phase containing a block of the repeating unit represented by General Formula (II) configures the removal phase 37. In a case where the block copolymer is the second block copolymer, typically, a phase containing a block of the repeating unit represented by General Formula (III) configures the nonremoval phase 36, and a phase containing a block of the repeating unit represented by General Formula (TV) configures the removal phase 37.

The shape and the size of the removal phase and the nonremoval phase are defined depending on the component ratio of each block configuring the block copolymer, the molecular weight of the block copolymer, and the like.

[(iii) Step of Selectively Removing at Least One Phase of Plurality of Phases of Block Copolymer Layer]

Next, the step (iii) of selectively removing at least one phase of a plurality of phases of the block copolymer layer.

The step (iii) is, typically, a step of exposing at least a part of a substrate by selectively removing the phase (that is, the removal phase described above).

Examples of the method of removing a removal phase include an oxygen plasma treatment, an ozone treatment, an ultraviolet irradiation treatment, a pyrolysis treatment, and a chemical decomposition treatment. As the chemical decomposition treatment, a fluorine treatment such as dry etching by fluorine can be suitably exemplified.

For example, in a graphoepitaxy method using a line-and-space pattern as a guide pattern, as shown in the schematic sectional view of FIG. 1(d) and in the schematic top view of FIG. 1(e), by selectively removing the removal phase 32 in the lamella structure described above and by leaving the nonremoval phase 33, high miniaturization of patterns (for example, a line-and-space pattern having a pitch of 60 nm or less) is achieved.

In addition, for example, in a graphoepitaxy method using a hole pattern as a guide pattern, as shown in the schematic sectional view of FIG. 3(d) and in the schematic top view of FIG. 3(e), by selectively removing the removal phase 37 in the cylinder structure described above and by leaving the nonremoval phase 36, high miniaturization of patterns (for example, a hole pattern having a hole diameter of 30 nm or less) is achieved. Moreover, it can also be said that the high miniaturization of patterns corresponds to performing a so-called shrink step on a guide pattern.

In the pattern forming method of the present invention, a topcoat layer may be formed on the block copolymer layer between the step (i) and step (ii).

By providing such a topcoat layer, it is possible to more reliably cause phase separation of the block copolymer layer in the step (ii) in some cases. For example, by providing a topcoat layer containing a material having an affinity for any block configuring the block copolymer, it is possible to suppress for only a specific phase to unevenly distribute in the surface layer of the block copolymer layer in some cases.

The material, the forming method, and the preferable thickness of such a topcoat layer are the same as those described for the underlayer described above.

As a preferable example of a form of forming a line-and-space pattern by a graphoepitaxy method using a line-and-space pattern as a guide pattern described with reference to FIG. 1(a) to FIG. 1(e), a form in which by EUV exposure and development, guide patterns of a 1:5 line-and-space pattern having a line width of 20 nm and a space width of 100 nm are formed, and by performing the steps (ii) and (iii) in the space of the guide patterns, two nonremoval phases, each of which has a line width of 20 nm, are formed at a pitch of 40 nm is exemplified.

In addition, as another preferable example of a form of forming a line-and-space pattern by a graphoepitaxy method using a line-and-space pattern as a guide pattern, a form in which, as shown in FIG. 2(a) to FIG. 2(e) corresponding to each of the steps described with reference to FIG. 1(a) to FIG. 1(e), by exposure by an ArF excimer laser (preferably, liquid immersion exposure by an ArF excimer laser) and by development, guide patterns of a 1:2 line-and-space pattern having a line width of 50 nm and a space width of 100 nm are formed, and by performing the steps (ii) and (iii) in the space of the guide patterns, two nonremoval phases, each of which has a line width of 20 nm, are formed at a pitch of 40 nm is exemplified.

### APPLICATIONS

The pattern forming method of the present invention is suitably used in production of a fine semiconductor circuit such as manufacture of an ultra LSI or a high-capacity microchip. Moreover, when producing a fine semiconductor circuit, after a resist film on which a pattern has been formed is subjected to circuit formation or etching, the remaining resist film portion is ultimately removed by a solvent or the like, and thus, unlike a so-called permanent resist used for a printed circuit board or the like, in a final product such as a microchip, a resist film derived from the actinic ray sensitive or radiation sensitive resin composition described in the present invention does not remain.

In addition, the present invention also relates to an electronic device manufacturing method including the pattern forming method of the present invention described above and an electronic device manufactured by the manufacturing method.

The electronic device of the present invention is suitably mounted on electrical and electronic equipment (home electrical appliances, OA and media-related equipment, optical equipment, communication equipment, or the like).

In addition, a mold for imprint may be produced by the pattern forming method of the present invention, and regarding the details thereof, for example, JP4109085B, JP2008-162101A, and “Fundamentals of Nanoimprint and Technical Development/Application Deployment-Substrate Technique of Nanoimprint and Latest Application Deployment”, edited by Yoshihiko Hirai (Frontier Publishing) may be referenced.

[First Block Copolymer, Second Block Copolymer, and Composition Containing First Block Copolymer or Second Block Copolymer]

The first block copolymer and the second block copolymer which the block copolymer layer contains, and a composition containing the first block copolymer or the second block copolymer for forming a block copolymer layer will be described in detail below.

The first block copolymer has a block of a repeating unit represented by the following General Formula (I) and a block of a repeating unit represented by the following General Formula (II).

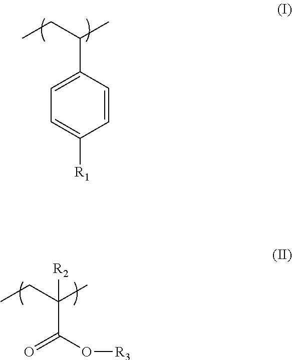

In General Formula (I), R₁ represents an alkyl group, an alkenyl group, an alkynyl group, a cycloalkyl group, an aryl group, or an aralkyl group, and R₁ may be condensed with a benzene ring by bonding to a carbon atom adjacent to the carbon atom to which R₁ has been bonded.

In General Formula (II), R₂ represents a hydrogen atom, an alkyl group, or a cycloalkyl group, and R₃ represents an alkyl group or a cycloalkyl group which may be substituted with a halogen atom or a group including an oxygen atom or a sulfur atom.

The alkyl group, the alkenyl group, the alkynyl group, the cycloalkyl group, the aryl group, or the aralkyl group represented by R₁ may further have a substituent.

Examples of the substituent which may be further included include an alkoxy group, a hydroxyl group, a halogen atom (a fluorine atom, a chlorine atom, or the like), a nitro group, an acyl group, an acyloxy group, an acyl amino group, a sulfonyl amino group, a dialkylamino group, an alkylthio group, an arylthio group, an aralkylthio group, a thiophene carbonyloxy group, a thiophene methylcarbonyloxy group, and heterocyclic residues such as a pyrrolidone residue.

The alkyl group which may have a substituent preferably has 1 to 12 carbon atoms, more preferably 2 to 9 carbon atoms, and still more preferably 4 to 6 carbon atoms.

Each of the alkynyl group and the alkenyl group, which may have a substituent preferably has 2 to 12 carbon atoms, more preferably 2 to 9 carbon atoms, and still more preferably 4 to 6 carbon atoms.

The cycloalkyl group which may have a substituent preferably has 3 to 12 carbon atoms, more preferably 3 to 9 carbon atoms, and still more preferably 3 to 6 carbon atoms.

The aryl group which may have a substituent preferably has 6 to 12 carbon atoms and more preferably 6 to 9 carbon atoms.

The aralkyl group which may have a substituent preferably has 7 to 12 carbon atoms and more preferably 7 to 9 carbon atoms.

It is preferable that the number of carbon atoms of R₁ is within the preferable range described above from the viewpoint of further improving the non-removability (typically, etching resistance) in the step (iii) and further improving the phase separability between the block of the repeating unit represented by General Formula (I) and the block of the repeating unit represented by General Formula (II), due to further improvement of the hydrophobicity of the repeating unit represented by General Formula (I).

A ring additionally formed in a case where R₁ is condensed with a benzene ring by bonding to a carbon atom (that is, a carbon atom at an ortho position configuring a benzene ring in a case where R₁ is taken as a reference) adjacent to the carbon atom to which R₁ has been bonded is preferably a benzene ring (that is, a naphthalene ring is preferably formed as the overall condensed ring structure).

The alkyl group and the cycloalkyl group represented by R₂ may further have a substituent.

Specific examples of the substituent which may be further included include the same as those described for the substituent which each group represented by R₁ may further have.

From the viewpoint of being capable of further reducing (that is, further improving removability) the non-removability (typically, etching resistance) in the step (iii) and being capable of suppressing degradation of the phase separation structure of the block copolymer layer by further raising the glass transition point (Tg) of the first block copolymer, R₂ is preferably an alkyl group which may have a substituent or an cycloalkyl group which may have a substituent, more preferably an alkyl group which may have a substituent, and still more preferably a methyl group.

As described above, the alkyl group or the cycloalkyl group represented by R₃ may have a halogen atom or a group including an oxygen atom or a sulfur atom as a substituent.

Suitable examples of the halogen atom include a fluorine atom and a chlorine atom.

Examples of the group including an oxygen atom or a sulfur atom include an alkoxy group, a hydroxyl group, a nitro group, an acyl group, an acyloxy group, an acyl amino group, a sulfonyl amino group, an alkylthio group, an arylthio group, an aralkylthio group, a thiophene carbonyloxy group, a thiophene methylcarbonyloxy group, and heterocyclic residues having an oxygen atom or a sulfur atom such as a heteroatom.

From the viewpoint of further improving the phase separability between the block of the repeating unit represented by General Formula (I) and the block of the repeating unit represented by General Formula (II), due to further improvement of the hydrophobicity of the repeating unit represented by General Formula (I), the alkyl group which may be substituted with a halogen atom or a group including an oxygen atom or a sulfur atom, represented by R₃ preferably has 1 to 12 carbon atoms, more preferably has 1 to 8 carbon atoms, and still more preferably has 1 to 4 carbon atoms. For the same reason, the cycloalkyl group which may be substituted with a halogen atom or a group including an oxygen atom or a sulfur atom, represented by R₃ preferably has 3 to 12 carbon atoms and more preferably has 3 to 8 carbon atoms.

The second block copolymer has a block of a repeating unit represented by the following General Formula (III) and a block of a repeating unit represented by the following General Formula (IV).

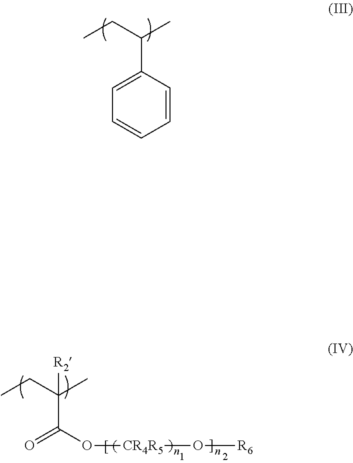

In General Formula (IV), R₂′ represents a hydrogen atom, an alkyl group, or a cycloalkyl group.

Each of R₄ and R₅ independently represents a hydrogen atom or a methyl group. A plurality of R₄'s and a plurality of R₅'s may be the same as or different from each other, respectively.

R₆ represents an alkyl group having 1 to 4 carbon atoms, and

n₁ represents 2 to 4, and n₂ represents 1 to 6.

The alkyl group and the cycloalkyl group represented by R₂′ may further have a substituent.

The preferable range of the number of carbons of each of the alkyl group and the cycloalkyl group, which may have a substituent, represented by R₂′, and specific examples of the substituent are the same as those described for R₂ in General Formula (II).

From the viewpoint of further improving the phase separability between the block of the repeating unit represented by General Formula (III) and the block of the repeating unit represented by General Formula (IV), due to further improvement of the hydrophilicity of the repeating unit represented by General Formula (IV), each of R₄ and R₅ is more preferably a hydrogen atom.

The alkyl group having 1 to 4 carbon atoms represented by R₆ may further have a substituent such as a hydroxyl group, a halogen atom (a fluorine atom, a chlorine atom, or the like), a nitro group, or the like.

From the same viewpoint as the viewpoint described for R₄′ and R₅′, R₆ preferably has 1 to 4 carbon atoms, more preferably 1 or 2 carbon atoms, and still more preferably one carbon atom.

On the other hand, in a case where the alkyl group represented by R₆ has 5 or more carbon atoms, there is a tendency that, due to further improvement of the hydrophilicity of the repeating unit represented by General Formula (IV), it is difficult to perform phase separation of the block of the repeating unit represented by General Formula (III) and the block of the repeating unit represented by General Formula (IV) with high quality and high efficiency.

From the same viewpoint as the viewpoint described for R₄′ and R₅′, n₁ is preferably 2 or 3 and more preferably 2.

n₂ is preferably 1 to 4 and more preferably 1 or 2. Thus, it is possible to suppress for the diffusion rate of the second block copolymer to become too slow, and it is possible to perform phase separation of the block copolymer layer with high quality and high efficiency.

The block of the repeating unit represented by General Formula (II) in the first block copolymer is preferably a block of a repeating unit represented by any one of the following General Formulas (II-1) to (II-3) and more preferably a block of a repeating unit represented by the following General Formula (II-2) or (II-3).

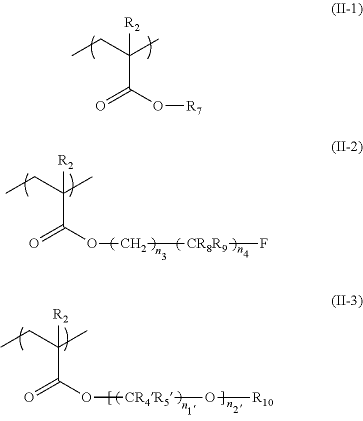

In General Formulas (II-1) to (II-3), R₂ has the same meaning as R₂ in General Formula (II).

Each of R₄′ and R₅′ independently represents a hydrogen atom or a methyl group. A plurality of R₄'s and a plurality of R₅'s may be the same as or different from each other, respectively.

R₇ represents an unsubstituted alkyl group having 1 to 12 carbon atoms or an unsubstituted cycloalkyl group having 3 to 12 carbon atoms.

Each of R₈ and R₉ independently represents a hydrogen atom or a fluorine atom. Here, at least one of R₈ or R₉ represents a fluorine atom. In a case where a plurality of R₈'s and a plurality of R₉'s are present, respectively, the plurality of R₈'s and the plurality of R₉'s may be the same as or different from each other, respectively.

R₁₀ represents a hydrogen atom, an alkyl group, a cycloalkyl group, or an aryl group.

n₁, represents 2 to 4, n₂′ represents 1 to 6, n₃ represents 1 or 2, and n₄ represents 1 to 8.

The alkyl group and the cycloalkyl group represented by R₂ may further have a substituent.

The preferable range of the number of carbons of each of the alkyl group and the cycloalkyl group, which may have a substituent, represented by R₂, and specific examples of the substituent are the same as those described for R₂ in General Formula (II).

From the viewpoint of further improving the phase separability between the block of the repeating unit represented by General Formula (I) and the block of the repeating unit represented by General Formula (II-3), with further improvement of the hydrophilicity of the repeating unit represented by General Formula (II-3), each of R₄′ and R₅′ is more preferably a hydrogen atom.

From the same viewpoint as the viewpoint described for R₄′ and R₅′, R₇ preferably has 1 to 8 carbon atoms and more preferably 1 to 4 carbon atoms.

From the same viewpoint as the viewpoint described for R₄′ and R₅′, each of R₈ and R₉ is preferably a hydrogen atom.

The alkyl group and the cycloalkyl group represented by R₁₀ may further have a substituent.

Specific examples of the substituent which may be further included include the same as the groups described for the substituent which R₂ may further have.

From the same viewpoint as the viewpoint described for R₄′ and R₅′, the alkyl group which may have a substituent, represented by R₁₀, preferably has 1 to 12 carbon atoms, more preferably 1 to 8 carbon atoms, and still more preferably 1 to 4 carbon atoms. The cycloalkyl group which may have a substituent, represented by R₁₀, preferably has 3 to 12 carbon atoms and more preferably 3 to 8 carbon atoms.

From the same viewpoint as the viewpoint described for R₄′ and R₅′, n₃ is preferably 1.

From the viewpoint that a pattern is likely to be formed in more vertical direction with respect to the substrate, n₄ is preferably 1 to 6, more preferably 1 to 4, and still more preferably 1 or 2.

Specific examples of the repeating unit represented by General Formula (I) in the first block copolymer are shown below.

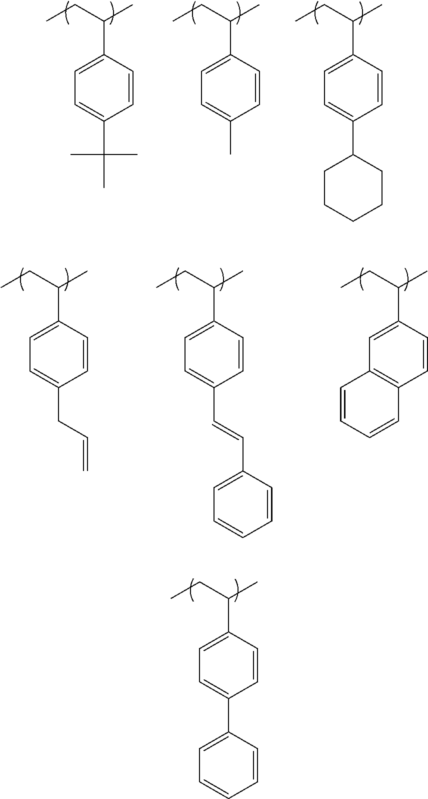

Specific examples of the repeating unit represented by General Formula (II) in the first block copolymer are shown below. Hereinafter, Me represents a methyl group, and ⁿBu represents an n-butyl group.

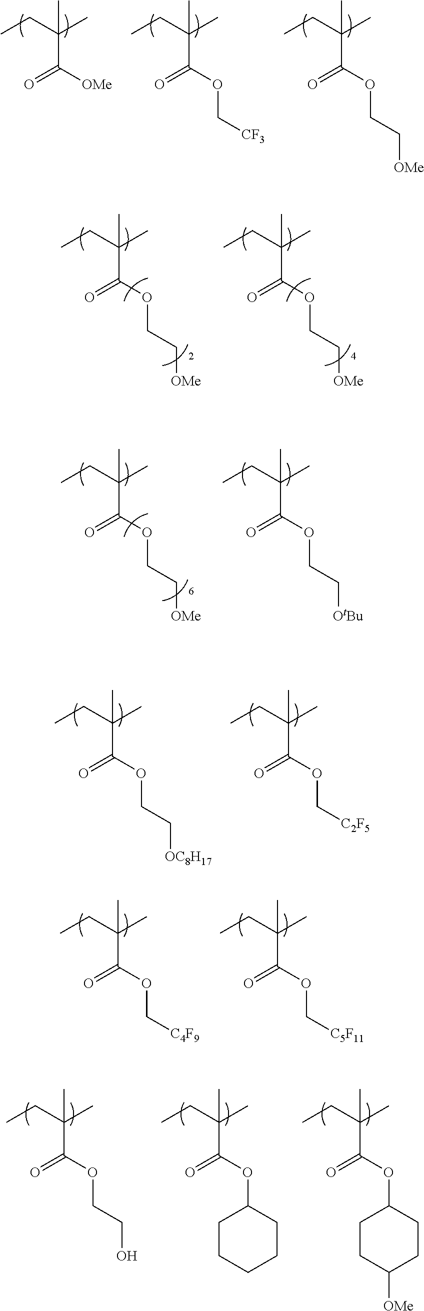

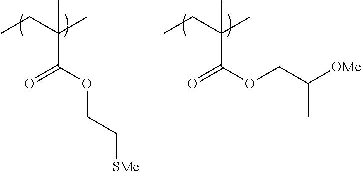

Specific examples of the repeating unit represented by General Formula (IV) in the second block copolymer are shown below. In the following formulas, Me represents a methyl group.

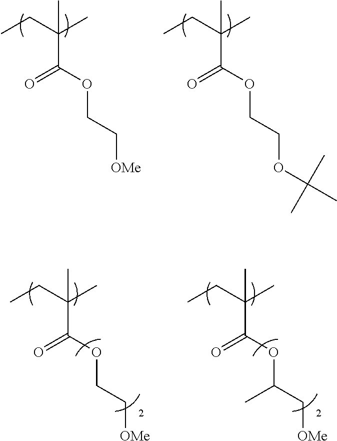

The absolute value of a difference between the solubility parameter (SP value) of the repeating unit represented by General Formula (I) and the solubility parameter (SP value) of the repeating unit represented by General Formula (II) in the first block copolymer is preferably 0.5 to 4.0 (MPa^{1/2}).

The absolute value of a difference between the solubility parameter (SP value) of the repeating unit represented by General Formula (III) and the solubility parameter (SP value) of the repeating unit represented by General Formula (IV) in the second block copolymer is preferably 0.5 to 4.0 (MPa^{1/2}).

Here, the solubility parameter (SP value) can be determined by the Hansen method. Moreover, the Hansen method is one method of calculating a SP value, known in the related art, and in this method, the SP value is indicated as a multi-dimensional vector formed of a dispersion element, a polarity element, and a hydrogen bond element.

The SP value of Hansen can be predicted by the method described in Int. J. Thermophys, 2008, 29, pp. 568-585, and the SP values described in the present specification are values predicted by the method described in the above document.

The solubility parameter (SP value) of the repeating unit configuring a specific block of a block copolymer corresponds to the solubility parameter (SP value) of the specific block (in other words, a homopolymer formed of only the above repeating unit). For example, the SP value of the styrene unit configuring polystyrene as a homopolymer is 20.8 (MPa^{1/2}), and the SP value of the methyl methacrylate unit configuring polymethyl methacrylate as a homopolymer is 20.5 (MPa^{1/2}), and thus, the difference in the SP value between the blocks of the block copolymers formed of polystyrene and polymethyl methacrylate becomes 0.3 (MPa^{1/2}).

Accordingly, the absolute value of a difference between the solubility parameter (SP value) of the repeating unit represented by General Formula (I) and the solubility parameter (SP value) of the repeating unit represented by General Formula (II) in the first block copolymer being 0.5 to 4.0 (MPa^{1/2}) means the absolute value of a difference between the solubility parameter (SP value) of the block of the repeating unit represented by General Formula (I) and the solubility parameter (SP value) of the block of the repeating unit represented by General Formula (II) being 0.5 to 4.0 (MPa^{1/2}).

Similarly, the absolute value of a difference between the solubility parameter (SP value) of the repeating unit represented by General Formula (III) and the solubility parameter (SP value) of the repeating unit represented by General Formula (IV) in the second block copolymer being 0.5 to 4.0 (MPa^{1/2}) means the absolute value of a difference between the solubility parameter (SP value) of the block of the repeating unit represented by General Formula (III) and the solubility parameter (SP value) of the block of the repeating unit represented by General Formula (IV) being 0.5 to 4.0 (MPa^{1/2}).

Thus, the difference in solubility parameters (SP value) of each repeating unit being within the above range means the difference in solubility parameters (SP value) of each block being within the above range, and thus, it is thought that it is possible to perform phase separation of the block copolymer layer with high quality and high efficiency.

The absolute value of a difference between the solubility parameter (SP value) of the repeating unit represented by General Formula (I) and the solubility parameter (SP value) of the repeating unit represented by General Formula (II) in the first block copolymer is preferably 0.5 to 3.5 (MPa^{1/2}) and more preferably 0.5 to 3.0 (MPa^{1/2}).

Similarly, the absolute value of a difference between the solubility parameter (SP value) of the repeating unit represented by General Formula (III) and the solubility parameter (SP value) of the repeating unit represented by General Formula (IV) in the second block copolymer is preferably 0.5 to 3.5 (MPa^{1/2}) and more preferably 0.5 to 3.0 (MPa^{1/2}).

In a case where the absolute value of the difference is less than 0.5 (MPa^{1/2}), in the use of a block polymer which is advantageous in terms of high miniaturization of patterns (for example, formation of a line-and-space pattern having a pitch of 60 nm or less or a hole pattern having a hole diameter of 30 nm or less) and has a low number average molecular weight (for example, the number average molecular weight is less than 25000), there is a tendency that the block polymer layer is less likely to be phase-separated.

On the other hand, in a case where the absolute value of the difference is greater than 4.0 (MPa^{1/2}), the diffusion rates of the first block copolymer and the second block copolymer become too slow, and due to this, there is a tendency that it is not possible to perform phase separation of the block copolymer layer with high quality and high efficiency.

The first block copolymer may further have a repeating unit different from the repeating unit represented by General Formula (I) and the repeating unit represented by General Formula (II) within a range in which phase separation of the block of the repeating unit represented by General Formula (I) and the block of the repeating unit represented by General Formula (II) occurs.

Similarly, the second block copolymer may further have a repeating unit different from the repeating unit represented by General Formula (III) and the repeating unit represented by General Formula (IV) within a range in which phase separation of the block of the repeating unit represented by General Formula (III) and the block of the repeating unit represented by General Formula (IV) occurs.

Although the mass ratio of each block configuring the first block copolymer and the second block copolymer is suitably determined depending on the type of the phase separation structure expressed in the step (ii) or the like, the mass ratio of the block of the repeating unit represented by General Formula (I) and the block of the repeating unit represented by General Formula (II) in the first block copolymer is preferably 40:60 to 90:10 and more preferably 45:55 to 80:20. In addition, the mass ratio of the block of the repeating unit represented by General Formula (III) and the block of the repeating unit represented by General Formula (IV) in the second block copolymer is preferably 40:60 to 90:10 and more preferably 45:55 to 80:20.

The number average molecular weight (Mn) of each of the first block copolymer and the second block copolymer is preferably 100000 or less, more preferably 50000 or less, still more preferably less than 25000, and still more preferably less than 20000, in terms of polystyrene measured by a GPC method.

The number average molecular weight (Mn) of each of the first block copolymer and the second block copolymer is preferably 3000 or greater, more preferably 5000 or greater, and still more preferably 6000 or greater, in terms of polystyrene measured by a GPC method.

The dispersity (Mw/Mn) of each of the first block copolymer and the second block copolymer is preferably 1.0 to 1.5, more preferably 1.0 to 1.2, and still more preferably 1.0 to 1.1.

Moreover, in the present specification, the number average molecular weight (Mn), the weight average molecular weight (Mw), and the dispersity of a resin including the first block copolymer and the second block copolymer can be determined by using, for example, HPL-8120 (manufactured by TOSOH CORPORATION), TSK GEL MULTIPORE HXL-M (manufactured by TOSOH CORPORATION, 7.8 mmHD×30.0 cm) as a column, and tetrahydrofuran (THF) or N-methyl-2-pyrrolidone (NMP) as an eluent.

The first block copolymer and the second block copolymer can be synthesized by a known method by radical polymerization or anionic polymerization. To lower the dispersity of the block copolymer (that is, to monodisperse), it is preferable to use living polymerization such as known living anionic polymerization or living radical polymerization. In this case, in production of the first block copolymer, a block of the repeating unit represented by General Formula (I) and a block of the repeating unit represented by General Formula (II) (preferably, a block of the repeating unit represented by any one of General Formulas (II-1) to (II-3), and more preferably, a block of the repeating unit represented by General Formula (II-2) or (II-3)) are more preferably formed by living polymerization, and in production of the second block copolymer, a block of the repeating unit represented by General Formula (III) and a block of the repeating unit represented by General Formula (IV) are more preferably formed by living polymerization.

As the living polymerization, in particular, living anionic polymerization is more preferably used since it is advantageous when monodispersing.

In addition, as described in JP-2009-67999A, it is also preferable that the living anionic polymerization is performed by using a microreactor (flow reaction system).

Specific examples of the first block copolymer (the compositional ratio of the repeating unit is in terms of a mass ratio) are shown below, but the present invention is not limited thereto. In the following formulas, Me represents a methyl group, ⁿBu represents an n-butyl group, and Ph represents a phenyl group. ΔSP represents the absolute value of a difference between the SP values described above.

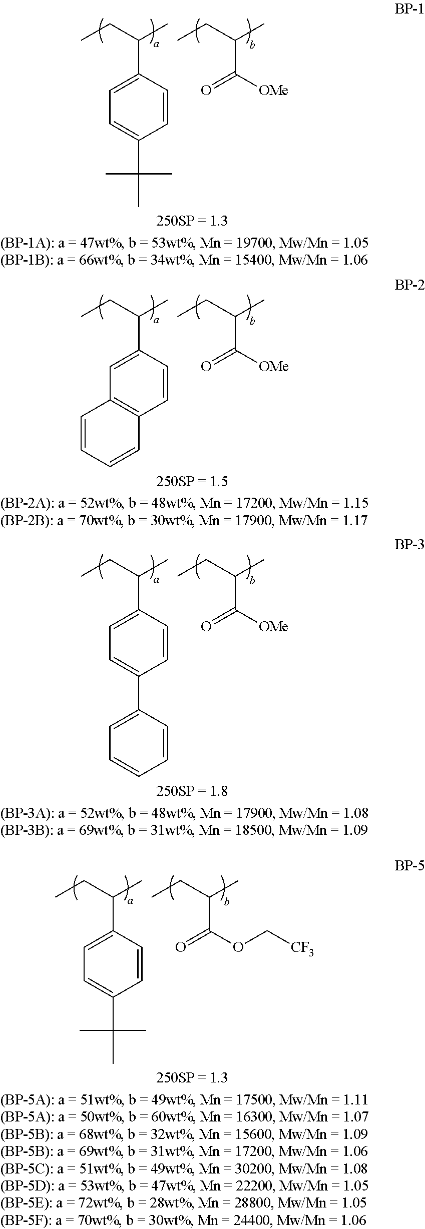

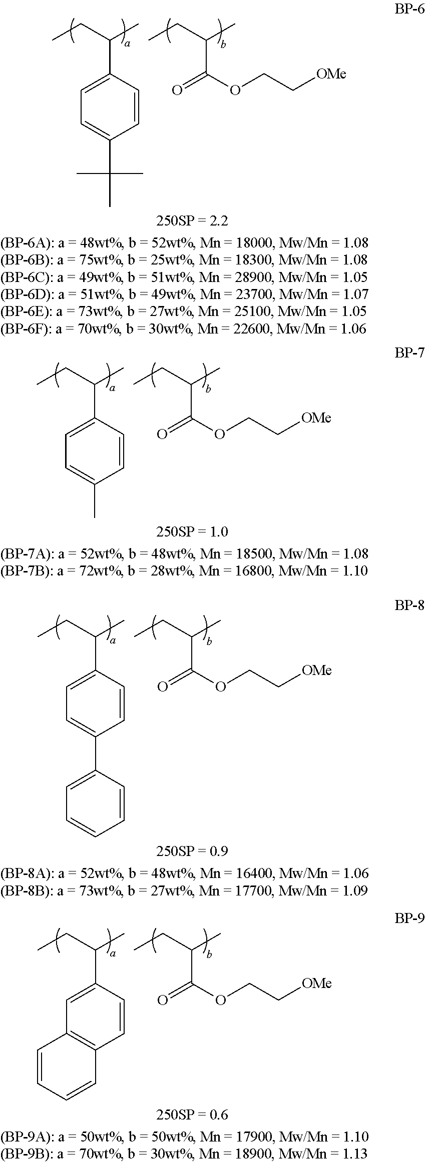

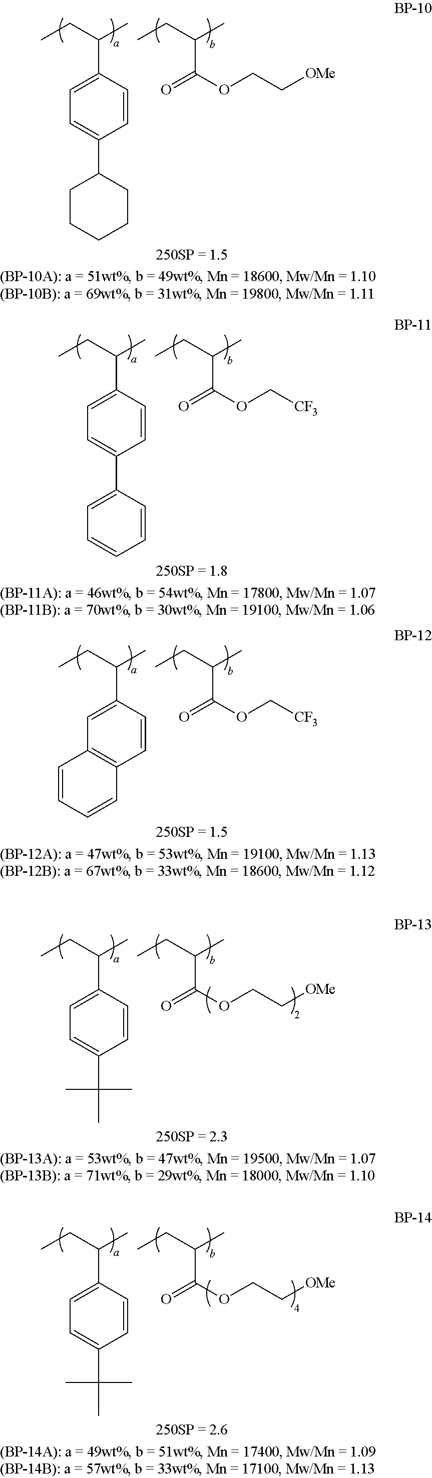

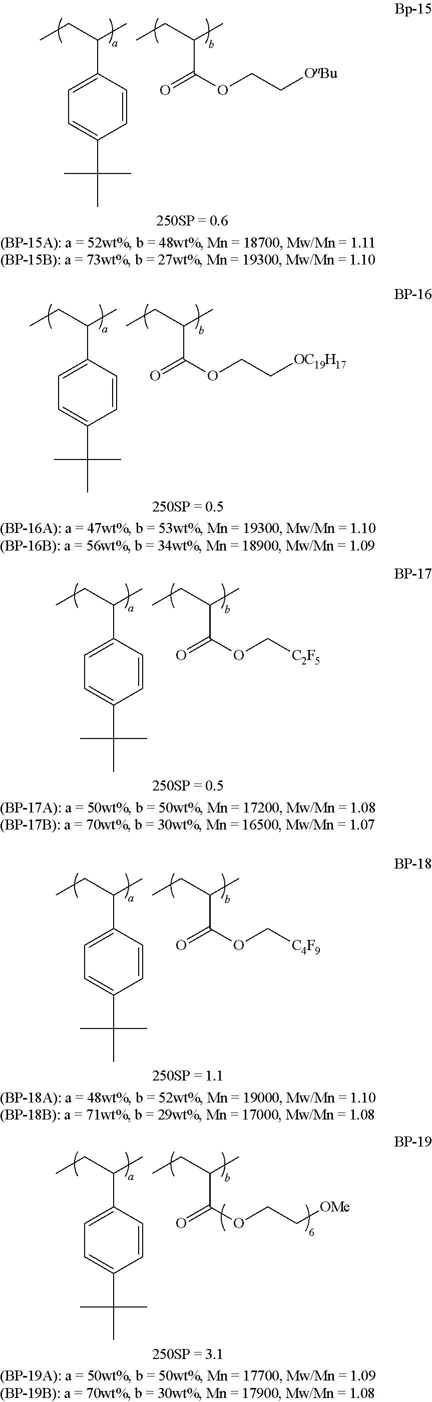

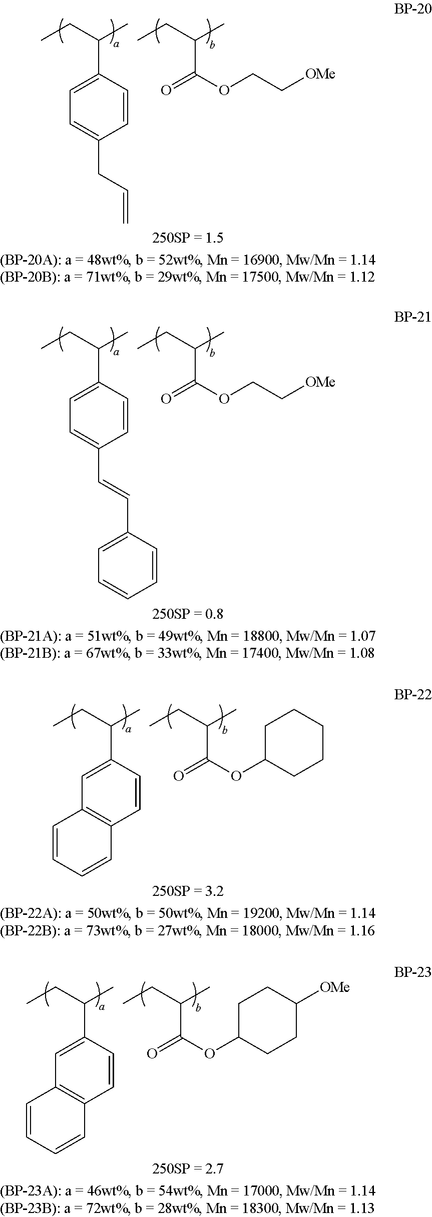

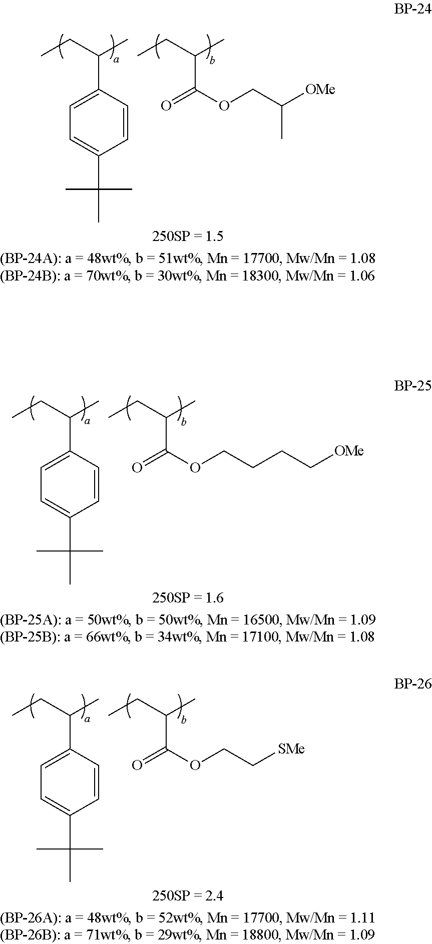

Specific examples of the second block copolymer (the compositional ratio of the repeating unit is in terms of a mass ratio) are shown below, but the present invention is not limited thereto. In the following formulas, Me represents a methyl group and Ph represents a phenyl group.

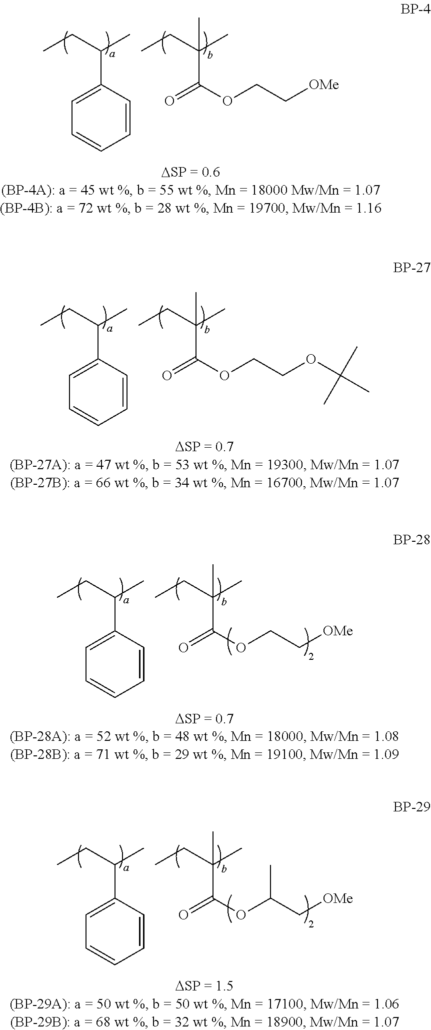

The content of the first block copolymer or the second block copolymer to the total solid content in the composition containing the first block copolymer or the second block copolymer is preferably 90% by mass to 100% by mass, more preferably 95% by mass to 100% by mass, and still more preferably 97% by mass to 100% by mass.

The composition containing the first block copolymer or the second block copolymer preferably contains an organic solvent. The composition containing the block copolymer may contain one type of organic solvents or may contain two or more types of organic solvents.

Examples of the organic solvent which the composition containing the first block copolymer or the second block copolymer preferably contains include lactones such as γ-butyrolactone; ketones such as acetone, methyl ethyl ketone, cyclohexanone, methyl-n-pentyl ketone, methyl isopentyl ketone, and 2-heptanone; polyhydric alcohols such as ethylene glycol, diethylene glycol, propylene glycol, and dipropylene glycol; polyhydric alcohol derivatives including compounds having an ester bond, such as ethylene glycol monoacetate, diethylene glycol monoacetate, propylene glycol monoacetate and dipropylene glycol monoacetate, and compounds having an ether bond, such as a monoalkyl ether (such as a monomethyl ether, monoethyl ether, monopropyl ether or monobutyl ether) or a monophenyl ether of any of the above polyhydric alcohols or compounds having an ester bond [among these polyhydric alcohol derivatives, propylene glycol monomethyl ether acetate (PGMEA) and propylene glycol monomethyl ether (PGME) are preferred]; cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; and aromatic organic solvents such as anisole, ethyl benzyl ether, cresyl methyl ether, diphenyl ether, dibenzyl ether, phenetole, butyl phenyl ether, ethylbenzene, diethylbenzene, pentylbenzene, isopropylbenzene, toluene, xylene, cymene, and mesitylene.

The solid content concentration in the composition containing the first block copolymer or the second block copolymer is typically 1.0% by mass to 10% by mass, preferably 1.5% by mass to 6.0% by mass, and still more preferably 1.5% by mass to 5.5% by mass.

The present invention also relates to a block copolymer (hereinafter, also referred to as a “specific block copolymer 1”) having the block of the repeating unit represented by General Formula (I) and the block of the repeating unit represented by General Formula (II-2) or (II-3). The specific block copolymer 1 corresponds to the first block copolymer, and the preferable ranges of the number average molecular weight and the dispersity thereof, and the synthetic method thereof are the same as those described for the first block copolymer.

In the specific block copolymer 1, as described in the first block copolymer, by the repeating unit represented by General Formula (I) having a structure derived from 4-position substituted styrene, the hydrophobicity thereof becomes very great compared to the repeating unit represented by General Formula (II-2) or (II-3). Thus, the phase separability between the block of the repeating unit represented by General Formula (I) and the block of the repeating unit represented by General Formula (II-2) or (II-3) is very high, and thus, the specific block copolymer 1 can be suitably used in a variety of applications using microphase separation of a block copolymer.

In addition, the present invention also relates to a pattern forming method (hereinafter, referred to as “another pattern forming method of the present invention”) including (i) a step of forming a block copolymer layer containing a block copolymer on a substrate on which a guide pattern has been formed, (ii) a step of phase-separating the block copolymer layer, and (iii) a step of selectively removing at least one phase of a plurality of phases of the block copolymer layer, in which the block copolymer is a block copolymer having a block of a first repeating unit and a block of a second repeating unit, and the absolute value of a difference between the solubility parameter (SP value) of the first repeating unit and the solubility parameter (SP value) of the second repeating unit is 0.5 to 4.0 (MPa^{1/2}) (hereinafter, this block copolymer is also referred to as a “specific block copolymer 2”).

Furthermore, the present invention also relates to a block copolymer for manufacturing semiconductors (that is, the specific block copolymer 2 for manufacturing semiconductors) including a block of a first repeating unit, and a block of a second repeating unit, in which the absolute value of a difference between the solubility parameter (SP value) of the first repeating unit and the solubility parameter (SP value) of the second repeating unit is 0.5 to 4.0 (MPa^{1/2}).

The calculation method of the solubility parameter (SP value), technical significance of the upper limit value and the lower limit value of the range of the absolute value of a difference in the solubility parameter (SP value), the preferable range in the range of the absolute value, and the preferable ranges of the number average molecular weight (Mn) and the dispersity (Mw/Mn) of the specific block copolymer 2 are the same as those described for the first block copolymer and the second block copolymer.

Although the specific block copolymer 2 is not particularly limited as long as the difference in the solubility parameter (SP value) satisfies the above range, as the specific block copolymer 2, the first block copolymer and the second block copolymer can be suitably exemplified.

According to another pattern forming method and the block copolymer for manufacturing semiconductors of the present invention, particularly in self-organization lithography using a graphoepitaxy method, high miniaturization of patterns can be achieved with high quality and high efficiency (for example, a line-and-space pattern having a pitch of 60 nm or less or a hole pattern having a hole diameter of 30 nm or less can be formed with high quality and high efficiency).

[Active Light Sensitive or Radiation Sensitive Resin Composition]

Next, the active light sensitive or radiation sensitive resin composition suitably used in formation of the guide pattern will be described.

In a case where an alkali developer is used as a developer, the active light sensitive or radiation sensitive resin composition is used in positive type development (development in which, when exposed, solubility is increased with respect to a developer, the unexposed portion remains as a pattern, and the exposed portion is removed). That is, in this case, the active light sensitive or radiation sensitive resin composition according to the present invention can be used as an active light sensitive or radiation sensitive resin composition for alkali development used in development using an alkali developer. Here, “for alkali development” means an application to be subjected to a step of developing using, at least, an alkali developer.

On the other hand, in a case where an alkali developer is used as a developer the active light sensitive or radiation sensitive resin composition is used in negative type development (development in which, when exposed, solubility is decreased with respect to a developer, the exposed portion remains as a pattern, and the unexposed portion is removed). That is, in this case, the active light sensitive or radiation sensitive resin composition according to the present invention can be used as an active light sensitive or radiation sensitive resin composition for organic solvent development used in development using a developer including an organic solvent. Here, “for organic solvent development” means an application to be subjected to a step of developing using a developer including at least an organic solvent.

The active light sensitive or radiation sensitive resin composition of the present invention is typically a resist composition, and may be a negative type resist composition (that is, a resist composition for organic solvent development) or a positive type resist composition (that is, a resist composition for alkali development).

The composition according to the present invention is typically a chemical amplification type resist composition.

[1] (A) Resin Having Group that Generates Polar Group by being Decomposed Due to Action of Acid

The active light sensitive or radiation sensitive resin composition preferably contains a resin (A) (hereinafter, also referred to as a “resin (A)”) having a group (hereinafter, also referred to as an “acid decomposable group”) that generates a polar group by being decomposed due to the action of an acid.

The resin (A) is, for example, a resin having an acid-decomposable group on the main chain or a side chain of the resin, or a resin having acid-decomposable groups on both the main chain and a side chain.

The definition of the polar group is the same as that described in the section of the repeating unit (c) described later, and examples of the polar group generated by decomposition of an acid-decomposable group include an alcoholic hydroxyl group, an amino group, and an acidic group.

The polar group generated by decomposition of an acid-decomposable group is preferably an acidic group.

The acidic group is not particularly limited as long as it is a group which is insolubilized in a developer including an organic solvent, and preferable examples thereof include a phenolic hydroxyl group, a carboxylic acid group, a sulfonic acid group, a fluorinated alcohol group, a sulfonamide group, a sulfonylimide group, an (alkylsulfonyl)(alkylcarbonyl) methylene group, an (alkylsulfonyl)alkylcarbonyl) imido group, a bis(alkylcarbonyl) methylene group, a bis(alkylcarbonyl) imido group, a bis(alkylsulfonyl) methylene group, a bis(alkylsulfonyl) imido group, a tris(alkylcarbonyl) methylene group, and a tris(alkylsulfonyl) methylene group, and more preferable examples thereof include acidic groups (groups which dissociate in 2.38% by mass tetramethylammonium hydroxide aqueous solution, used as a developer for a resist in the related art) such as a carboxylic acid group, a fluorinated alcohol group (preferably, hexafluoroisopropanol), a phenolic hydroxyl group, and a sulfonic acid group.

The preferable acid-decomposable group is a group in which a hydrogen atom is substituted with a group leaving due to an acid.

Examples of the group leaving due to an acid include —C(R₃₆)(R₃₇)(R₃₈), —C(R₃₆)(R₃₇)(OR₃₉), and —C(R₀₁)(R₀₂)(OR₃₉).

In the formulas, each of R₃₆ to R₃₉ independently represents an alkyl group, a cycloalkyl group, an aryl group, a group obtained by combining an alkylene group and an aryl group, or an alkenyl group. R₃₆ and R₃₇ may be bonded to each other to form a ring.

Each of R₀₁ and R₀₂ independently represents a hydrogen atom, an alkyl group, a cycloalkyl group, an aryl group, a group obtained by combining an alkylene group and an aryl group, or an alkenyl group.

The acid-decomposable group is preferably a cumyl ester group, an enol ester group, an acetal ester group, or a tertiary alkyl ester group.

(a) Repeating Unit Having Acid-Decomposable Group

The resin (A) preferably has a repeating unit (a) having an acid-decomposable group.

The repeating unit (a) is preferably a repeating unit represented by the following General Formula (V).

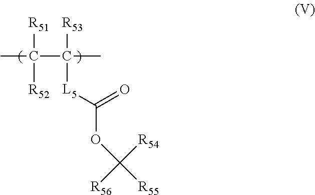

In General Formula (V), each of R₅₁, R₅₂, and R₅₃ independently represents a hydrogen atom, an alkyl group, a cycloalkyl group, a halogen atom, a cyano group, or an alkoxycarbonyl group. R₅₂ may be bonded to L₅ to form a ring, and R₅₂ in this case represents an alkylene group.

In a case where L₅ represents a single bond or a divalent connecting group and forms a ring with R₅₂, L₅ represents a trivalent connecting group.

R₅₄ represents an alkyl group, and each of R₅₅ and R₅₆ independently represents a hydrogen atom, an alkyl group, a cycloalkyl group, an aryl group, or an aralkyl group. R₅₅ to R₅₆ may be bonded to each other to form a ring. Here, R₅₅ and R₅₆ do not represent a hydrogen atom at the same time in any case.

General Formula (V) will be described in more detail.

Preferable examples of the alkyl group represented by each of R₅₁ to R₅₃ in General Formula (V) include an alkyl group having 20 or less carbon atoms such as a methyl group, an ethyl group, a propyl group, an isopropyl group, an n-butyl group, a sec-butyl group, a hexyl group, a 2-ethylhexyl group, an octyl group, or a dodecyl group, which may have a substituent, and an alkyl group having 8 or less carbon atoms is more preferable, and an alkyl group having 3 or less carbon atoms is particularly preferable.

The alkyl group included in an alkoxycarbonyl group is preferably the same alkyl group as that represented by each of R₅₁ to R₅₃ described above.

The cycloalkyl group may be monocyclic or polycyclic. Preferable examples include a monocyclic cycloalkyl group having 3 to 10 carbon atoms, such as a cyclopropyl group, a cyclopentyl group, or a cyclohexyl group, which may have a substituent.

Examples of the halogen atom include a fluorine atom, a chlorine atom, a bromine atom and an iodine atom, and a fluorine atom is particularly preferable.

Examples of the preferable substituent in each group described above can include an alkyl group, a cycloalkyl group, an aryl group, an amino group, an amide group, a ureido group, a urethane group, a hydroxyl group, a carboxyl group, a halogen atom, an alkoxy group, a thioether group, an acyl group, an acyloxy group, an alkoxycarbonyl group, a cyano group, and nitro group, and the substituent preferably has 8 or less carbon atoms.

In addition, in a case where R₅₂ represents an alkylene group and forms a ring with L₅, preferable examples of the alkylene group include alkylene groups having 1 to 8 carbon atoms such as a methylene group, an ethylene group, a propylene group, a butylene group, a hexylene group, and an octylene group. The alkylene more preferably has 1 to 4 carbon atoms, and particularly preferably has 1 or 2 carbon atoms. The ring formed by bonding of R₅₂ and L₅ is particularly preferably a 5- or 6-membered ring.

As R₅₁ and R₅₃ in Formula (V), a hydrogen atom, an alkyl group, or a halogen atom is more preferable, and a hydrogen atom, a methyl group, an ethyl group, a trifluoromethyl group (—CF₃), a hydroxymethyl group (—CH₂—OH), a chloromethyl group (—CH₂—Cl), or a fluorine atom (—F) is particularly preferable. As R₅₂, a hydrogen atom, an alkyl group, a halogen atom, or an alkylene group (which forms a ring with L₅) is more preferable, and a hydrogen atom, a methyl group, an ethyl group, a trifluoromethyl group (—CF₃), a hydroxymethyl group (—CH₂—OH), a chloromethyl group (—CH₂—Cl), a fluorine atom (—F), a methylene group (which forms a ring with L₅), or an ethylene group (which forms a ring with L₅) is particularly preferable.

Examples of the divalent connecting group represented by L₅ include an alkylene group, a divalent aromatic ring group, —COO-L₁-, —O-L₁-, and a group formed by combining two or more thereof. Here, L₁ represents an alkylene group, a cycloalkylene group, a divalent aromatic ring group, or a group obtained by combining an alkylene group and a divalent aromatic ring group.

L₅ is preferably a single bond, a group represented by —COO-L₁-, or a divalent aromatic ring group. L₁ is preferably an alkylene group having 1 to 5 carbon atoms, and more preferably a methylene group or a propylene group. As the divalent aromatic ring group, a 1,4-phenylene group, a 1,3-phenylene group, a 1,2-phenylene group, or a 1,4-naphthylene group is preferable, and a 1,4-phenylene group is more preferable.

In a case where L₅ forms a ring by bonding to R₅₂, suitable examples of the trivalent connecting group represented by L₅ can include a group obtained by excluding one arbitrary hydrogen atom from a specific example described above of the divalent connecting group represented by L₅.

The alkyl group represented by each of R₅₄ to R₅₆ is preferably an alkyl group having 1 to 20 carbon atoms, more preferably an alkyl group having 1 to 10 carbon atoms, and particularly preferably an alkyl group having 1 to 4 carbon atoms such as a methyl group, an ethyl group, an n-propyl group, an isopropyl group, an n-butyl group, an isobutyl group, or a t-butyl group.

The cycloalkyl group represented by R₅₅ or R₅₆ is preferably a cycloalkyl group having 3 to 20 carbon atoms, may be a cycloalkyl group which is monocyclic, such as a cyclopentyl group or a cyclohexyl group, and may be a cycloalkyl group which is polycyclic, such as a norbornyl group, an adamantyl group, a tetratricyclodecanyl group, or a tetracyclododecanyl group.

The ring formed by bonding of R₅₅ and R₅₆ to each other is preferably a ring having 3 to 20 carbon atoms, may be a monocyclic ring such as a cyclopentyl group or a cyclohexyl group, and may be a polycyclic ring such as a norbornyl group, an adamantyl group, a tetratricyclodecanyl group, or a tetracyclododecanyl group. In a case where R₅₅ and R₅₆ are bonded to each other to form a ring, R₅₄ is preferably an alkyl group having 1 to 3 carbon atoms, and a methyl group or an ethyl group is more preferable.

The aryl group represented by R₅₅ or R₅₆ preferably has 6 to 20 carbon atoms, and may be monocyclic or polycyclic, or may have a substituent. Examples thereof include a phenyl group, a 1-naphthyl group, a 2-naphthyl group, a 4-methylphenyl group, and a 4-methoxyphenyl group. In a case where any one of R₅₅ and R₅₆ is a hydrogen atom, the other is preferably an aryl group.

The aralkyl group represented by R₅₅ or R₅₆ may be monocyclic or polycyclic, or may have a substituent. The aralkyl group preferably has 7 to 21 carbon atoms, and examples thereof include a benzyl group and a 1-naphthylmethyl group.

The resin (A) preferably has a repeating unit represented by the following General Formula (V-1) as the repeating unit represented by General Formula (V), for the reason of superior effects of the present invention.

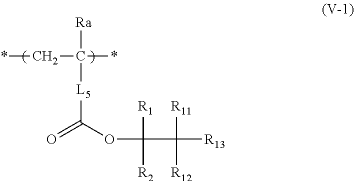

In General Formula (V-1), each of R₁ and R₂ independently represents an alkyl group, each of R₁₁ and R₁₂ independently represents an alkyl group, and R₁₃ represents a hydrogen atom or an alkyl group. R₁₁ and R₁₂ may be connected to each other to form a ring, and R₁₁ and R₁₃ may be connected to each other to form a ring.

Ra represents a hydrogen atom, an alkyl group, a cyano group, or a halogen atom, and L₅ represents a single bond or a divalent connecting group.

In General Formula (V-1), the alkyl group represented by each of R₁, R₂, and R₁₁ to R₁₃ is preferably an alkyl group having 1 to 10 carbon atoms, and examples thereof include a methyl group, an ethyl group, a propyl group, an isopropyl group, an n-butyl group, a sec-butyl group, a t-butyl group, a neopentyl group, a hexyl group, a 2-ethylhexyl group, an octyl group, and a dodecyl group.

The alkyl group represented by R₁ or R₂ is more preferably an alkyl group having 2 to 10 carbon atoms from the viewpoint of reliably achieving effects of the present invention.

At least one of R₁ or R₂ is preferably an alkyl group having 2 to 10 carbon atoms, both of R and R₂ are more preferably alkyl groups having 2 to 10 carbon atoms, and both of R₁ and R₂ are still more preferably ethyl groups.

The alkyl group represented by R₁₁ or R₁₂ is more preferably an alkyl group having 1 to 4 carbon atoms, still more preferably a methyl group or an ethyl group, and particularly preferably a methyl group.

R₁₃ is more preferably a hydrogen atom or a methyl group.

R₁₁ and R₁₂ are particularly preferably connected to each other to form a ring, and R₁₁ and R₁₃ may be connected to each other to form a ring.

The ring formed by connection of R₁₁ and R₁₂ to each other is preferably a 3- to 8-membered ring, and more preferably a 5- or 6-membered ring.

The ring formed by connection of R₁₁ and R₁₃ to each other is preferably a 3- to 8-membered ring, and more preferably a 5- or 6-membered ring.

The time when R₁₁ and R₁₃ are connected to each other to form a ring is preferably the time when R₁₁ and R₁₂ are connected to each other to form a ring.

The ring formed by connection of R₁₁ and R₁₂ (or R₁₁ and R₁₃) to each other is more preferably an alicyclic group described below as X in General Formula (V-2).

The rings formed by connection of alkyl groups represented by R₁, R₂, R₁₁ to R₁₃, or R₁₁ and R₁₂ (or R₁₁ and R₁₃) may further have substituents.

Examples of the substituents which the rings formed by connection of alkyl groups represented by R₁, R₂, R₁₁, to R₁₃, or R₁₁ and R₁₂ (or R₁₁ and R₁₃) can further have include a cycloalkyl group, an aryl group, an amino group, a hydroxy group, a carboxy group, a halogen atom, an alkoxy group, an aralkyloxy group, a thioether group, an acyl group, an acyloxy group, an alkoxycarbonyl group, a cyano group, and a nitro group. The substituents may be bonded to each other to form a ring, and examples of the ring when the substituents are bonded to each other to form a ring include a cycloalkyl group having 3 to 10 carbon atoms and a phenyl group.

The alkyl group represented by Ra may have a substituent, and is preferably an alkyl group having 1 to 4 carbon atoms.

Preferable examples of the substituent which the alkyl group represented by Ra may have include a hydroxyl group and a halogen atom.

Examples of the halogen atom represented by Ra include a fluorine atom, a chlorine atom, a bromine atom, and an iodine atom.

Ra is preferably a hydrogen atom, a methyl group, a hydroxymethyl group, a perfluoroalkyl group having 1 to 4 carbon atoms (for example, a trifluoromethyl group), and a methyl group is particularly preferable from the viewpoint of raising the glass transition point (Tg) of the resin (A) and improving resolving power and a space width roughness.

Here, in a case where L₅ is a phenylene group, Ra is preferably also a hydrogen atom.

Specific examples and preferable examples of L₅ include the same as those described as L₅ in General Formula (V).

From the viewpoint of capable of more reliably exhibiting the effects of the present invention by achieving a higher contrast (γ value is higher), R₁₁ and R₁₂ in General Formula (V-1) are preferably connected to each other to form a ring, and the repeating unit represented by General Formula (V-1) is more preferably a repeating unit represented by the following General Formula (V-2).

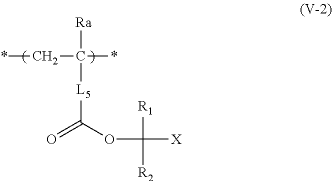

In General Formula (V-2), X represents an alicyclic group.

R₁, R₂, Ra, and L₅ have the same meaning as R₁, R₂, Ra, and L₅ in General Formula (V-1), respectively, and R₁, R₂, Ra, and L₅ in the specific examples and the preferable examples have the same meaning as R₁, R₂, Ra, and L₅ in General Formula (V-1), respectively.

The alicyclic group represented by X may be monocyclic, polycyclic, or bridged, and preferably represents an alicyclic group having 3 to 25 carbon atoms.

In addition, the alicyclic group may have a substituent, and examples of the substituent include the same substituents as those described above as the substituents which the rings formed by connection of alkyl groups represented by R₁, R₂, R₁₁ to R₁₃, or R₁₁ and R₁₂ (or R₁₁ and R₁₃) can further have and alkyl groups (a methyl group, an ethyl group, a propyl group, a butyl group, a perfluoroalkyl group (for example, a trifluoromethyl group), and the like).

X preferably represents an alicyclic group having 3 to 25 carbon atoms, more preferably represents an alicyclic group having 5 to 20 carbon atoms, and particularly preferably a cycloalkyl group having 5 to 15 carbon atoms.

In addition, X is preferably an alicyclic group having a 3- to 8-membered ring or a fused ring group thereof, and more preferably 5- or 6-membered ring or a fused ring group thereof.

Examples of the structure of the alicyclic group represented by X are shown below.

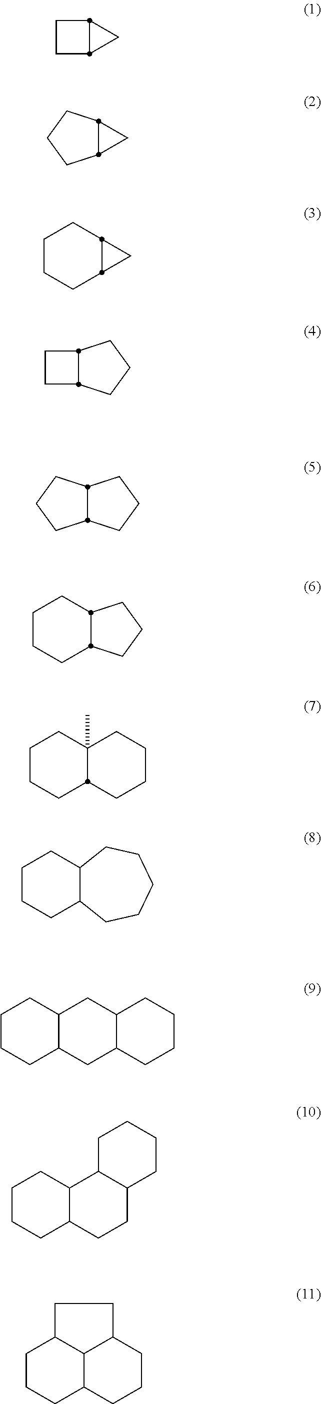

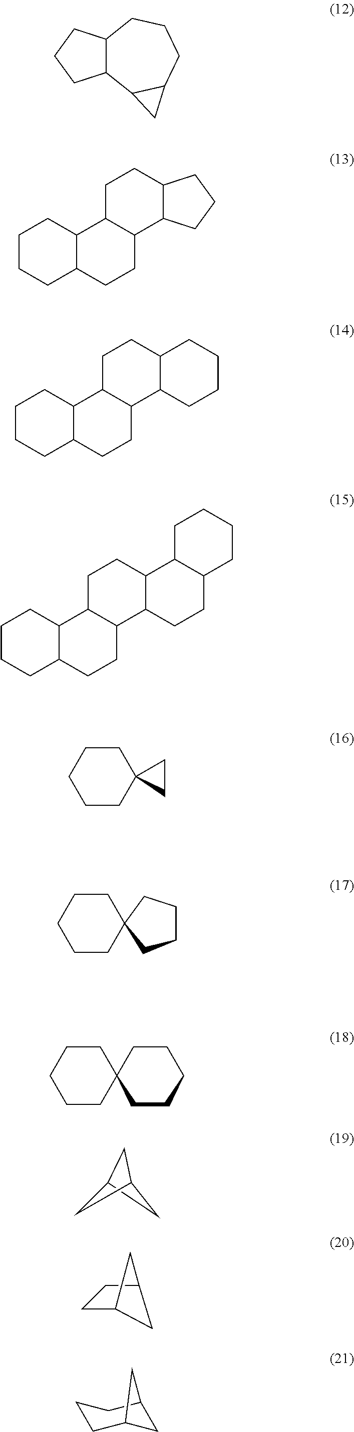

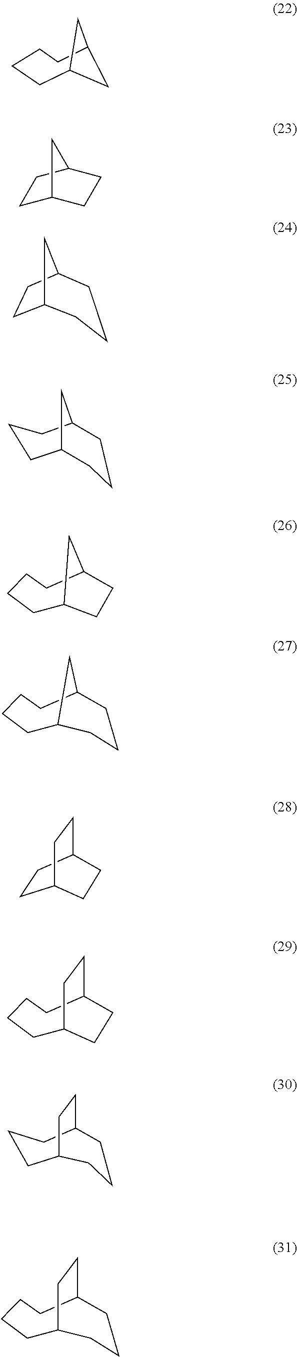

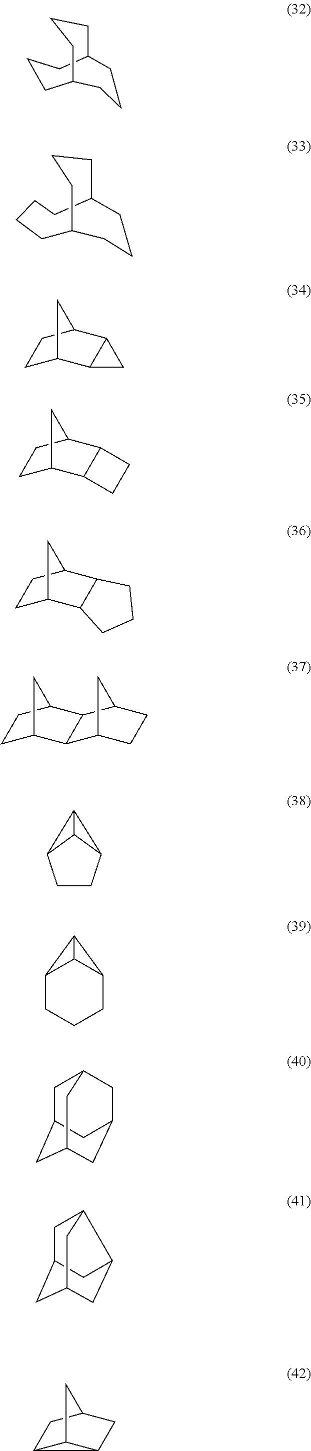

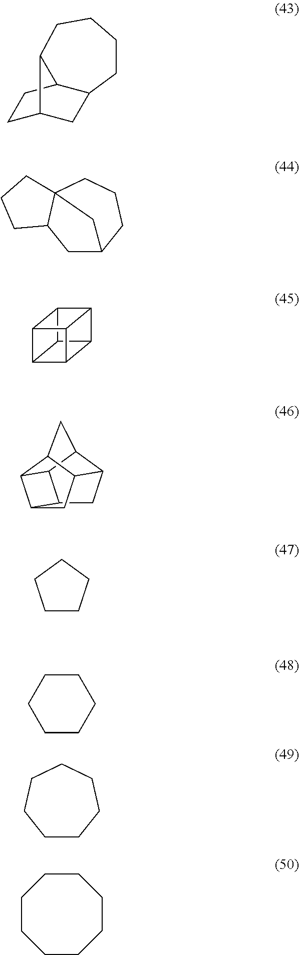

Preferable examples of the alicyclic group can include an adamantyl group, a noradamantyl group, a decalin residue, a tricyclodecanyl group, a tetracyclododecanyl group, a norbornyl group, a cedrol group, a cyclopentyl group, a cyclohexyl group, cycloheptyl group, a cyclooctyl group, a cyclodecanyl group, and a cyclododecanyl group. The alicyclic group is more preferably a cyclohexyl group, a cyclopentyl group, an adamantyl group, or a norbornyl group, still more preferably a cyclohexyl group or a cyclopentyl group, and particularly preferably a cyclohexyl group.

As the synthetic method of a monomer corresponding to the repeating unit represented by General Formula (V), a general synthetic method of a polymerizable group-containing ester can be applied, but the method is not be particularly limited.

Specific examples of the repeating unit represented by General Formula (V) will be described below, but the present invention is not limited thereto.

In the specific examples, each of Rx and Xa₁ represents a hydrogen atom, CH₃, CF₃, or CH₂OH. Each of Rxa and Rxb independently represents an alkyl group having 1 to 4 carbon atoms, an aryl group having 6 to 18 carbon atoms, or an aralkyl group having 7 to 19 carbon atoms. Z represents a substituent. p represents 0 or a positive integer, and p is preferably 0 to 2, and more preferably 0 or 1. In a case where a plurality of Z's are present, Z's may be the same as or different from each other. As Z, from the viewpoint of increasing dissolution contrast with respect to a developer before and after acid decomposition, a group consisting of only hydrogen and carbon atoms is suitably exemplified, and for example, a linear or branched alkyl group or cycloalkyl group is preferable.

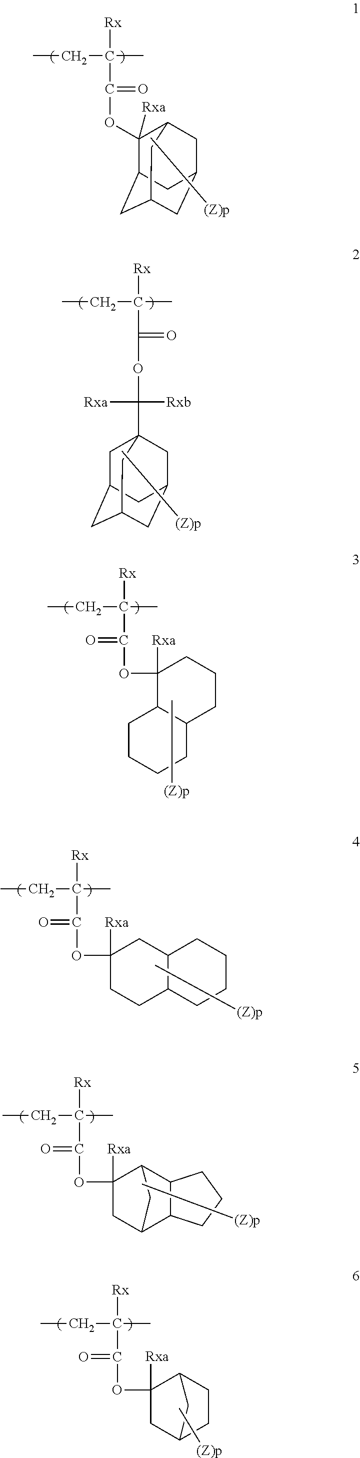

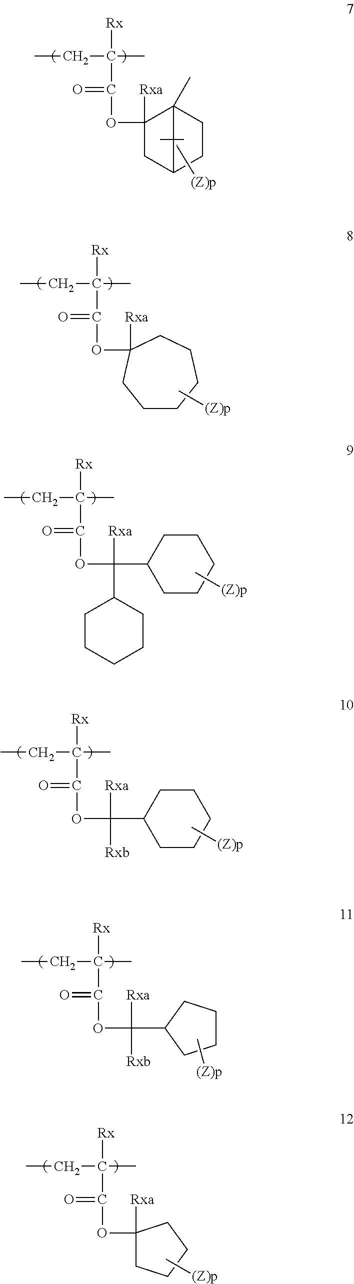

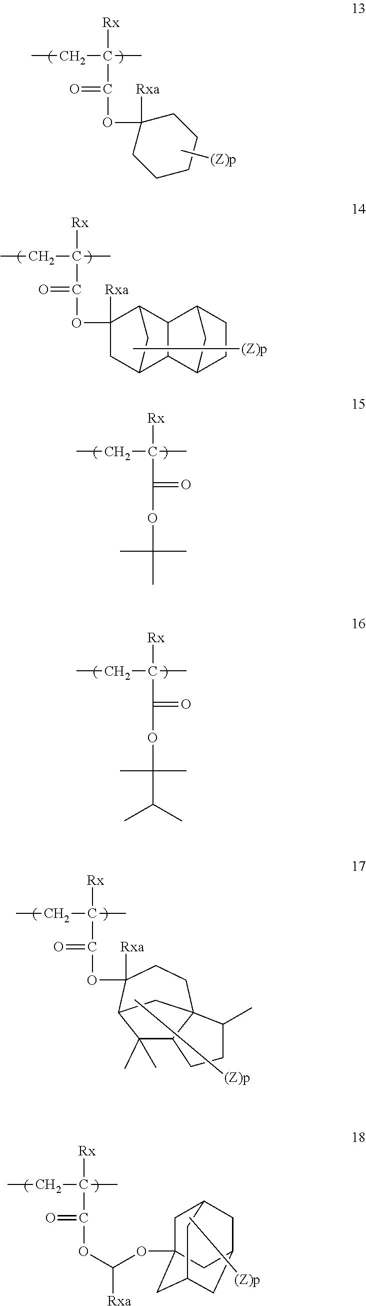

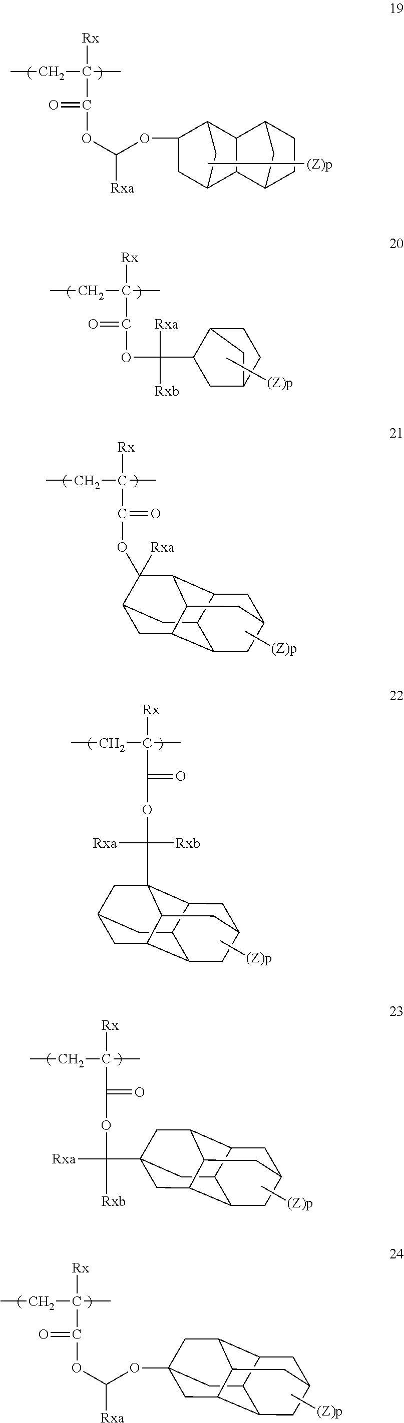

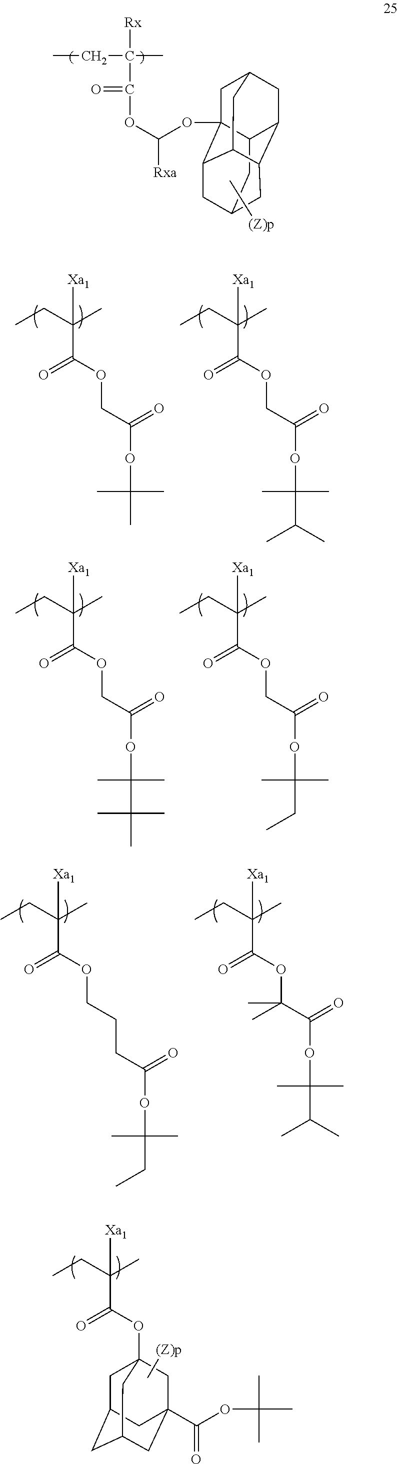

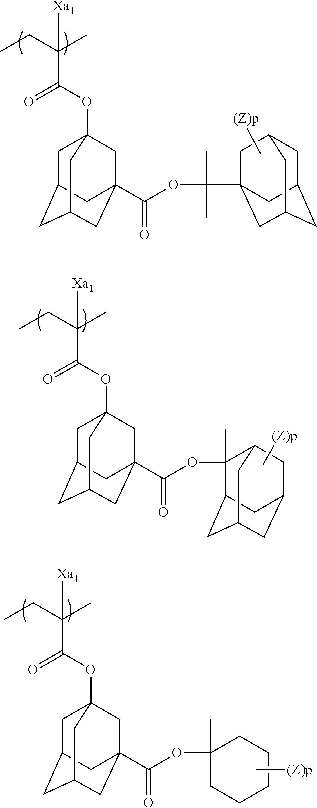

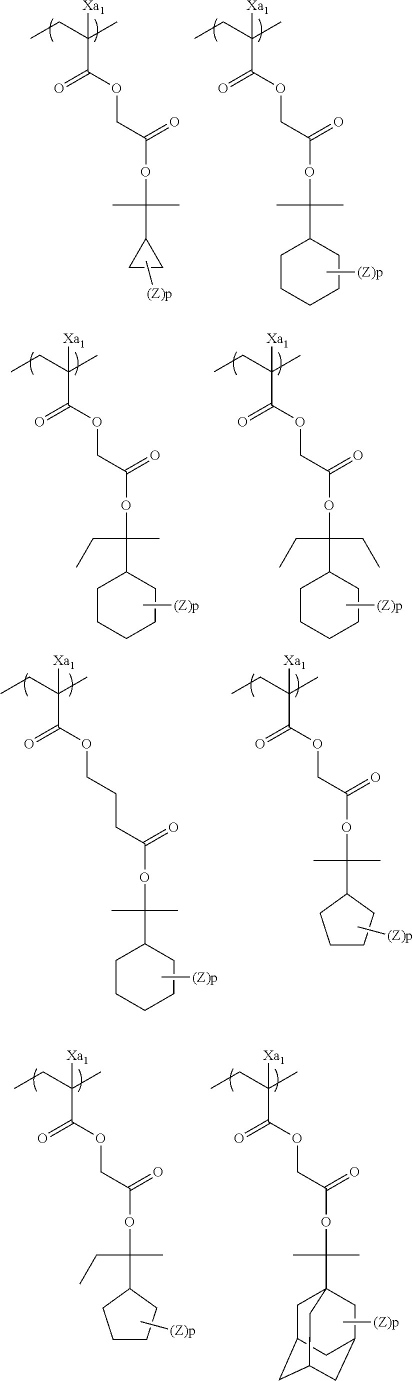

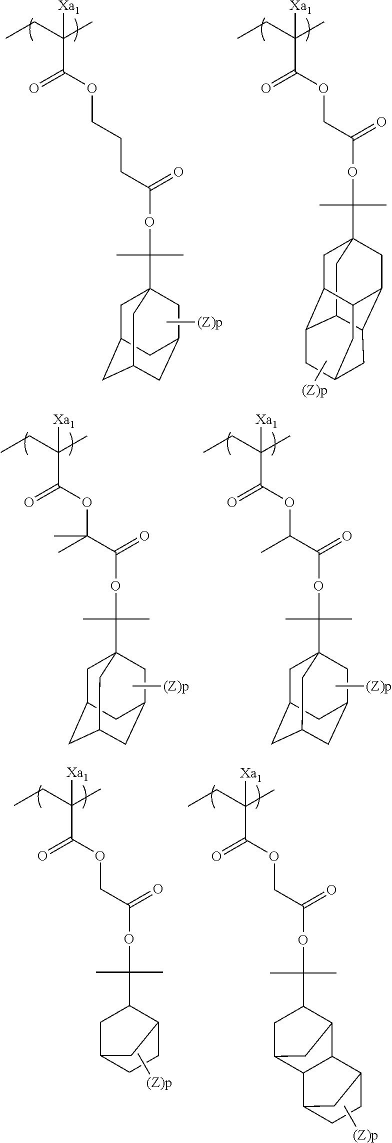

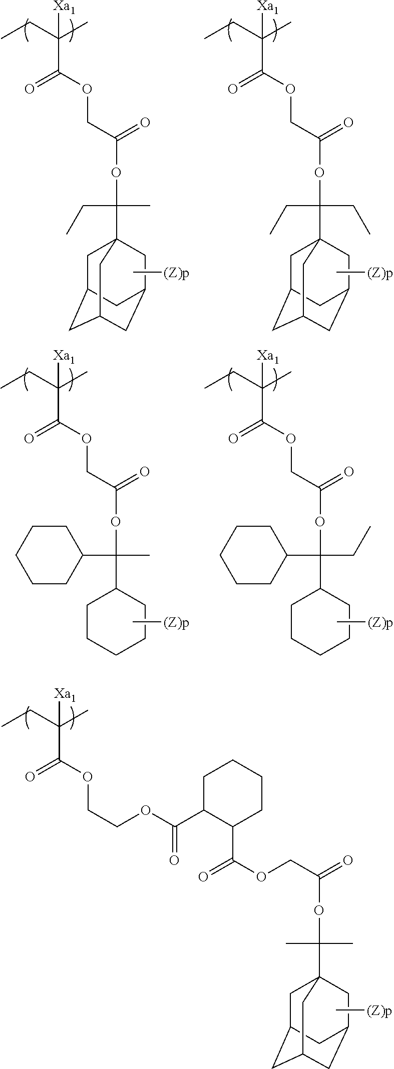

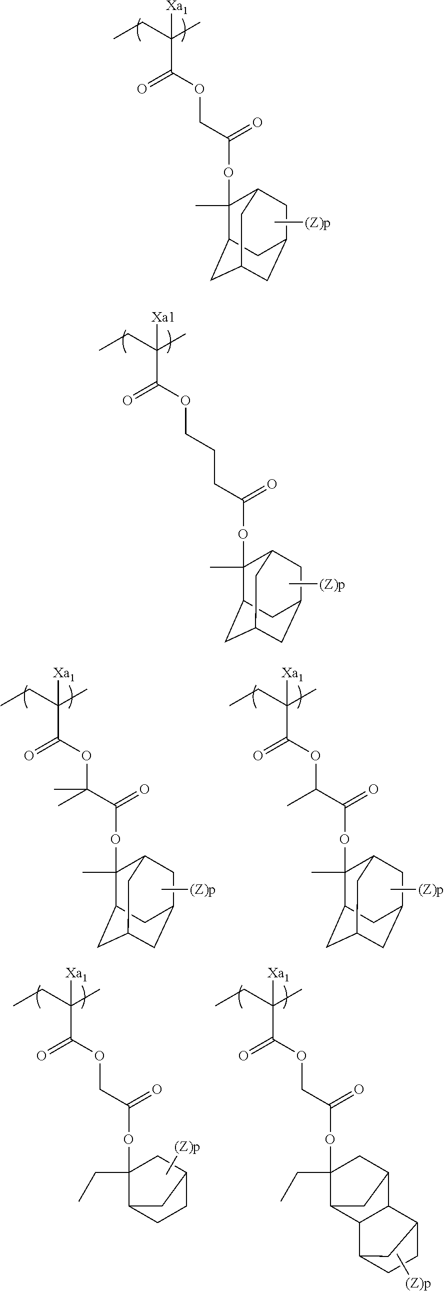

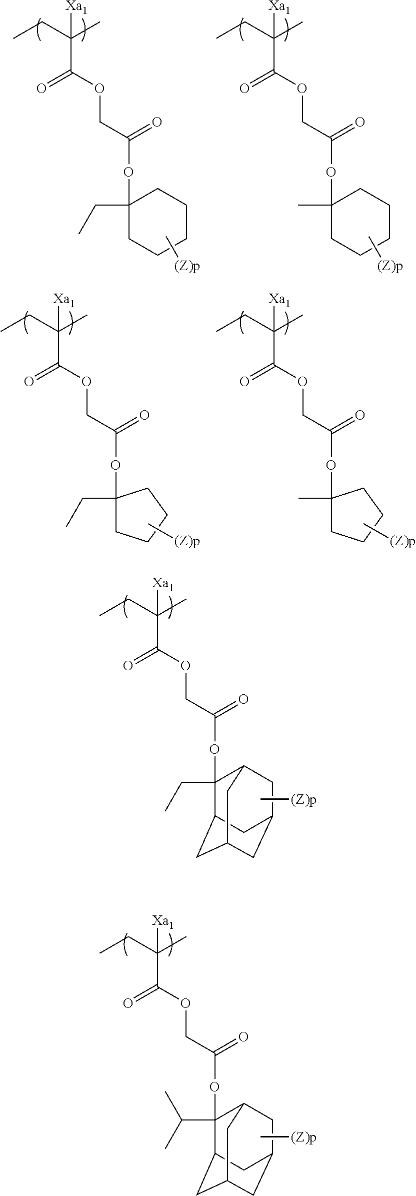

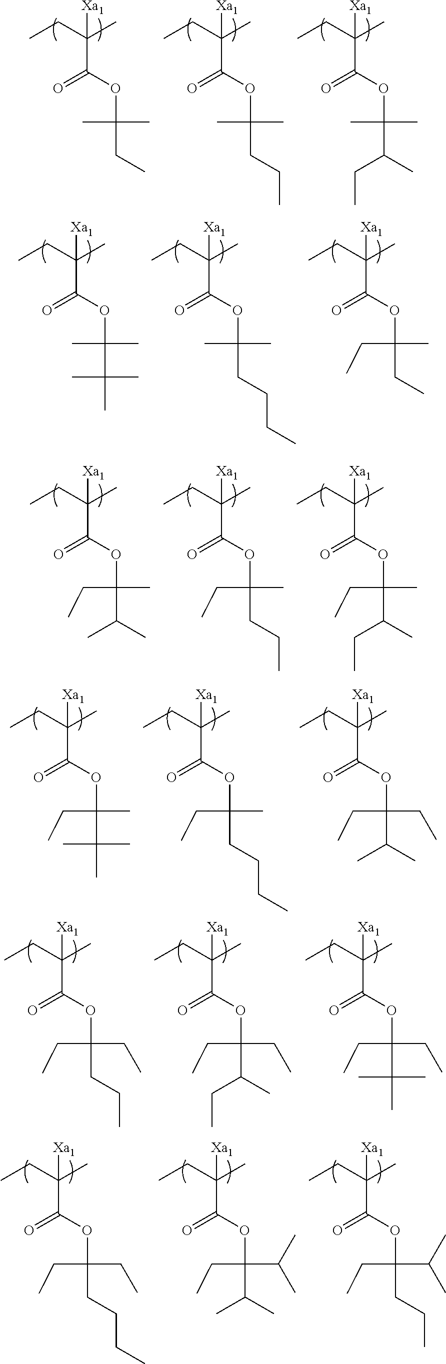

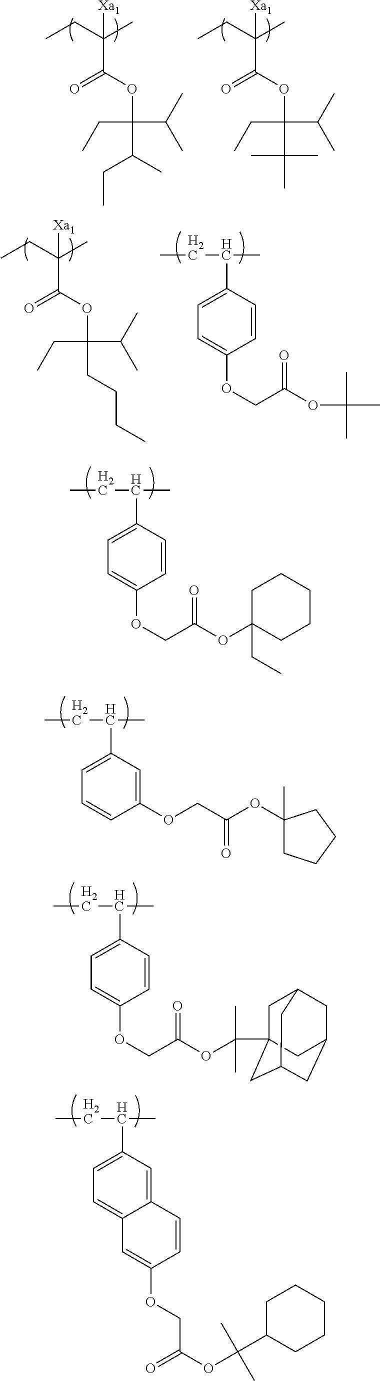

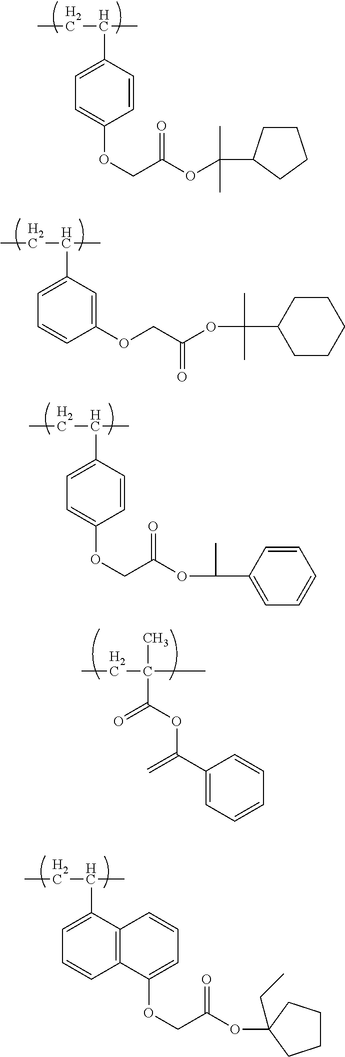

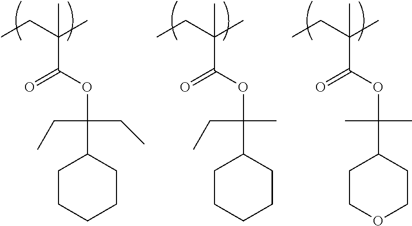

In addition, the repeating unit (a) is preferably a repeating unit represented by the following General Formula (VI).

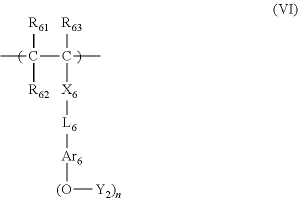

In General Formula (VI), each of R₆₁, R₆₂, and R₆₃ independently represents a hydrogen atom, an alkyl group, a cycloalkyl group, a halogen atom, a cyano group, or an alkoxycarbonyl group. Here, R₆ may be bonded to Ar₆ to form a ring, and R₆₂ in this case represents a single bond or an alkylene group.

X₆ represents a single bond, —COO—, or —CONR₆₄—. R₆₄ represents a hydrogen atom or an alkyl group.

L₆ represents a single bond or an alkylene group.

Ar₆ represents an (n+1) valent aromatic ring group, and, in the case of being bonded to R₆₂ to form a ring, represents an (n+2) valent aromatic ring group.

In a case where n is 2 or greater, each of Y₂'s independently represents a hydrogen atom or a group leaving due to the action of an acid. Here, at least one of Y₂'s represents a group leaving due to the action of an acid.

n represents an integer of 1 to 4.

General Formula (VI) will be described in more detail.

Preferable examples of the alkyl group represented by each of R₆₁ to R₆₃ in General Formula (VI) include an alkyl group having 20 or less carbon atoms such as a methyl group, an ethyl group, a propyl group, an isopropyl group, an n-butyl group, a sec-butyl group, a hexyl group, a 2-ethylhexyl group, an octyl group, or a dodecyl group, which may have a substituent, and an alkyl group having 8 or less carbon atoms is more preferable.

The alkyl group included in an alkoxycarbonyl group is preferably the same alkyl group as that represented by each of R₆₁ to R₆₃ described above.

The cycloalkyl group may be monocyclic or may be polycyclic, and preferable examples thereof include a monocyclic cycloalkyl group having 3 to 10 carbon atoms, such as a cyclopropyl group, a cyclopentyl group, or a cyclohexyl group, which may have a substituent.

Examples of the halogen atom include a fluorine atom, a chlorine atom, a bromine atom and an iodine atom, and a fluorine atom is more preferable.

In a case where R₆₂ represents an alkylene group, examples of the alkylene group include an alkylene group having 1 to 8 carbon atoms such as a methylene group, an ethylene group, a propylene group, a butylene group, a hexylene group, and an octylene group, which preferably may have a substituent.

Examples of the alkyl group represented by R₆₄ in —CONR₆₄— (R₆₄ represents a hydrogen atom or an alkyl group) represented by X₆ include the same as the alkyl group represented by each of R₆₁ to R₆₃.

X₆ is preferably a single bond, —COO—, or —CONH—, and more preferably a single bond or —COO—.

Examples of the alkylene group in L₆ include an alkylene group having 1 to 8 carbon atoms such as a methylene group, an ethylene group, a propylene group, a butylene group, a hexylene group, or an octylene group, which preferably may have a substituent. The ring formed by bonding of R₆₂ and L₆ is particularly preferably a 5- or 6-membered ring.

Ar₆ represents an (n+1) valent aromatic ring group. The divalent aromatic ring group in a case where n is 1 may have a substituent, and preferable examples thereof include an arylene group having 6 to 18 carbon atoms such as a phenylene group, a tolylene group, and a naphthylene group, or divalent aromatic ring groups including a hetero ring, such as thiophene, furan, pyrrole, benzothiophene, benzofuran, benzopyrrole, triazine, imidazole, benzimidazole, triazole, thiadiazole, or thiazole.

Suitable specific examples of the (n+1) valent aromatic ring group in a case where n is an integer of 2 or greater can include a group obtained by excluding arbitrary (n−1) hydrogen atoms from a specific example described above of the divalent aromatic ring group.

The (n+1) valent aromatic ring group may further have a substituent. Ar₆ may have a plurality of substituents, and in this case, the plurality of substituents may be bonded to each other to form a ring.

Examples of the substituent which the alkyl group, the cycloalkyl group, the alkoxycarbonyl group, the alkylene group, or the (n+1) valent aromatic ring group described above can have include the same specific examples as those of the substituent which each group represented by R₅₁ to R₅₃ in General Formula (V) described above can have.

n is preferably 1 or 2, and more preferably 1.

Each of n Y₂'s independently represents a hydrogen atom or a group leaving due to the action of an acid. Here, at least one of n Y₂'s represents a group leaving due to the action of an acid.

Examples of Y₂ which is a group leaving due to the action of an acid can include —C(R₃₆)(R₃₇)(R₃₈), —C(═O)—O—C(R₃₆)(R₃₇)(R₃₈), —C(R₀₁)(R₀₂)(OR₃₉), —C(R₀₁)(R₀₂)—C(═O)—O—C(R₃₆)(R₃₇)(R₃₈), and —CH(R₃₆)(Ar).

In the formulas, each of R₃₆ to R₃₉ independently represents an alkyl group, a cycloalkyl group, an aryl group, a group obtained by combining an alkylene group and an aryl group, or an alkenyl group. R₃₆ and R₃₇ may be bonded to each other to form a ring.

Each of R₀₁ and R₀₂ independently represents a hydrogen atom, an alkyl group, a cycloalkyl group, an aryl group, a group obtained by combining an alkylene group and an aryl group, or an alkenyl group.

Ar represents an aryl group.

The alkyl group represented by each of R₃₆ to R₃₉, R₀₁, and R₀₂ may be linear or branched, and is preferably an alkyl group having 1 to 8 carbon atoms, and examples thereof include a methyl group, an ethyl group, a propyl group, an n-butyl group, a sec-butyl group, a hexyl group, and an octyl group.

The cycloalkyl group represented by each of R₃₆ to R₃₉, R₀₁, and R₀₂ may be monocyclic or polycyclic. The monocyclic type is preferably a cycloalkyl group having 3 to 10 carbon atoms, and examples thereof can include a cyclopropyl group, a cyclobutyl group, a cyclopentyl group, a cyclohexyl group, and a cyclooctyl group. The polycyclic type is preferably a cycloalkyl group having 6 to 20 carbon atoms, and examples thereof can include an adamantyl group, a norbornyl group, an isoboronyl group, a camphanyl group, a dicyclopentyl group, an α-pinene group, a tricyclodecanyl group, a tetracyclododecyl group, and an androstanyl group. Moreover, some of the carbon atoms in a cycloalkyl group may be substituted with a heteroatom such as an oxygen atom.

The aryl group represented by each of R₃₆ to R₃₉, R₀₁, R₀₂, and Ar is preferably an aryl group having 6 to 10 carbon atoms, and examples thereof include aryl groups such as a phenyl group, a naphthyl group, and an anthryl group, and divalent aromatic ring groups including a hetero ring, such as thiophene, furan, pyrrole, benzothiophene, benzofuran, benzopyrrole, triazine, imidazole, benzimidazole, triazole, thiadiazole, and thiazole.

A group obtained by combining an alkylene group and an aryl group represented by each of R₃₆ to R₃₉, R₀₁, and R₀₂ is preferably an aralkyl group having 7 to 12 carbon atoms, and examples thereof can include a benzyl group, a phenethyl group, and naphthylmethyl group.

The alkenyl group represented by each of R₃₆ to R₃₉, R₀₁, and R₀₂ is preferably an alkenyl group having 2 to 8 carbon atoms, and examples thereof can include a vinyl group, an allyl group, a butenyl group, and a cyclohexenyl group.

A ring formed by bonding of R₃₆ and R₃₇ to each other may be monocyclic or polycyclic. The monocyclic type preferably has a cycloalkyl structure having 3 to 10 carbon atoms, and examples thereof can include a cyclopropane structure, a cyclobutane structure, a cyclopentane structure, a cyclohexane structure, a cycloheptane structure, and a cyclooctane structure. The polycyclic type preferably has a cycloalkyl structure having 6 to 20 carbon atoms, and examples thereof can include an adamantane structure, a norbornane structure, a dicyclopentane structure, a tricyclodecane structure, and a tetracyclododecane structure. Moreover, some of the carbon atoms in a cycloalkyl structure may be substituted with a heteroatom such as an oxygen atom.

Each of the groups described above represented by each of R₃₆ to R₃₉, R₀₁, R₀₂, and Ar may have a substituent, and examples of the substituent can include an alkyl group, a cycloalkyl group, an aryl group, an amino group, an amide group, a ureido group, a urethane group, a hydroxyl group, a carboxyl group, a halogen atom, an alkoxy group, a thioether group, an acyl group, an acyloxy group, an alkoxycarbonyl group, a cyano group, and nitro group, and the substituent preferably has 8 or more carbon atoms.

Y₂ which is a group leaving due to the action of an acid more preferably has the structure represented by the following General Formula (VI-A).

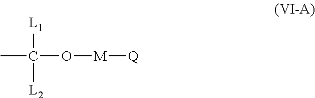

Here, each of L₁ and L₂ independently represents a hydrogen atom, an alkyl group, a cycloalkyl group, an aryl group, or a group obtained by combining an alkylene group and an aryl group.

M represents a single bond or a divalent connecting group.

Q represents an alkyl group, a cycloalkyl group which may include a heteroatom, an aryl group which may include a heteroatom, an amino group, an ammonium group, a mercapto group, a cyano group, or an aldehyde group.

At least two of Q, M, or L, may be bonded to each other to form a ring (preferably, 5- or 6-membered ring).

The alkyl group represented by L₁ or L₂ is, for example, an alkyl group having 1 to 8 carbon atoms, and specifically, preferable examples thereof can include a methyl group, an ethyl group, a propyl group, an n-butyl group, a sec-butyl group, a hexyl group, and an octyl group.

The cycloalkyl group represented by L₁ or L₂ is, for example, a cycloalkyl group having 3 to 15 carbon atoms, and specifically, preferable examples thereof can include a cyclopentyl group, a cyclohexyl group, a norbornyl group, and an adamantyl group.

The aryl group represented by L₁ or L₂ is, for example, an aryl group having 6 to 15 carbon atoms, and specifically, preferable examples thereof can include a phenyl group, a tolyl group, a naphthyl group, and anthryl group.

A group obtained by combining an alkylene group and an aryl group represented by L₁ or L₂ has, for example, 6 to 20 carbon atoms, and examples thereof include aralkyl groups such as a benzyl group and a phenethyl group.

Examples of the divalent connecting group represented by M include alkylene groups (for example, a methylene group, an ethylene group, a propylene group, a butylene group, a hexylene group, and an octylene group), cycloalkylene groups (for example, a cyclopentylene group, a cyclohexylene group, and adamantylene group), alkenylene groups (for example, an ethylene group, a propenylene group, and a butenylene group), divalent aromatic ring groups (for example, a phenylene group, a tolylene group, and a naphthylene group), —S—, —O—, —CO—, —SO₂—, —N(R₀)—, and divalent connecting groups obtained by combining a plurality of these. R₀ is a hydrogen atom or an alkyl group (which is, for example, an alkyl group having 1 to 8 carbon atoms, and specifically, a methyl group, an ethyl group, a propyl group, an n-butyl group, a sec-butyl group, a hexyl group, or an octyl group).

The alkyl group represented by Q is the same as each group represented by L₁ or L₂ described above.

In the cycloalkyl group which may include a heteroatom and the aryl group which may include a heteroatom, represented by Q, examples of an aliphatic hydrocarbon ring group which does not include a heteroatom or an aryl group which does not include a heteroatom include the cycloalkyl group and the aryl group represented by L₁ or L₂ described above, and each of the cycloalkyl group and the aryl group preferably has 3 to 15 carbon atoms.

Examples the cycloalkyl group including a heteroatom and the aryl group including a heteroatom include a group having a heterocyclic structure such as thiirane, cyclothiolane, thiophene, furan, pyrrole, benzothiophene, benzofuran, benzopyrrole, triazine, imidazole, benzimidazole, triazole, thiadiazole, thiazole, or pyrrolidone, and the cycloalkyl group and the aryl group are not limited thereto as long as, in general, the groups have a structure (a ring formed by carbon and a heteroatom or a ring formed by heteroatoms) called a hetero ring.

As a ring formed by bonding of at least two of Q, M, or L₁ to each other, a case where at least two of Q, M, or L₁ are bonded to each other to form, for example, a propylene group or a butylene group, and as a result, a 5- or 6-membered ring containing an oxygen atom is formed is exemplified.

Each of the groups represented by L₁, L₂, M, and Q in General Formula (VI-A) may have a substituent, and examples thereof include a substituent described as a substituent which each of R₃₆ to R₃₉, R₀₁, R₀₂, and Ar described above may have, and the substituent preferably has 8 or less carbon atoms.

The group represented by -M-Q is preferably a group which is configured of 1 to 30 carbon atoms and more preferably a group which is configured of 5 to 20 carbon atoms.

The resin (A) is preferably a resin having a repeating unit represented by the following General Formula (3) as the repeating unit represented by General Formula (VI).

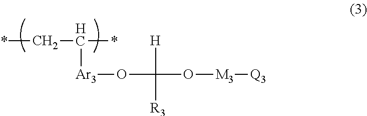

In General Formula (3), Ar₃ represents an aromatic ring group.

R₃ represents a hydrogen atom, an alkyl group, a cycloalkyl group, an aryl group, an aralkyl group, an alkoxy group, an acyl group, or a heterocyclic group.

M₃ represents a single bond or a divalent connecting group.

Q₃ represents an alkyl group, a cycloalkyl group, an aryl group, or a heterocyclic group.

At least two of Q₃, M₃, or R₃ may be bonded to each other to form a ring.

In a case where n in General Formula (VI) is 1, the aromatic group represented by Ar₃ is the same as Ar₆ in General Formula (VI), and is more preferably a phenylene group or a naphthylene group, and still more preferably a phenylene group.

Ar₃ may have a substituent, and examples of a substituent which Ar₃ can have include the same substituent as a substituent which Ar₆ in General Formula (VI) can have.

The alkyl group or the cycloalkyl group represented by R₃ has the same meaning as the alkyl group or the cycloalkyl group represented by each of R₃₆ to R₃₉, R₀₁, and R₀₂ described above.

The aryl group represented by R₃ has the same meaning as the aryl group represented by each of R₃₆ to R₃₉, R₀₁, and R₀₂ described above, and the preferable range thereof is also the same.

The aralkyl group represented by R₃ is preferably an aralkyl group having 7 to 12 carbon atoms, and examples thereof can include a benzyl group, a phenethyl group, and naphthylmethyl group.

The alkyl group portion in the alkoxy group represented by R₃ is the same as the alkyl group represented by each of R₃₆ to R₃₉, R₀₁, and R₀₂ described above, and the preferable range thereof is also the same.

Examples of the acyl group represented by R₃ include an aliphatic acyl group having 1 to 10 carbon atoms such as a formyl group, an acetyl group, a propionyl group, a butyryl group, an isobutyryl group, a valeryl group, a pivaloyl group, a benzoyl group, or a naphthoyl group, and the acyl group is preferably an acetyl group or a benzoyl group.

Examples of the heterocyclic group represented by R₃ include the cycloalkyl group including a heteroatom and the aryl group including a heteroatom, described above, and the heterocyclic group is preferably a pyridine ring group or a pyran ring group.

R₃ is preferably an alkyl group, a cycloalkyl group, an aryl group, an aralkyl group, an alkoxyl group, an acyl group, or a heterocyclic group, and more preferably a linear or branched alkyl group (specifically, a methyl group, an ethyl group, a propyl group, an i-propyl group, an n-butyl group, a sec-butyl group, a tert-butyl group, a neopentyl group, a hexyl group, a 2-ethylhexyl group, or an octyl group) having 1 to 8 carbon atoms or a cycloalkyl group (specifically, a cyclopentyl group, a cyclohexyl group, a norbornyl group, or an adamantyl group) having 3 to 15 carbon atoms. R₃ is more preferably a methyl group, an ethyl group, an i-propyl group, a sec-butyl group, a tert-butyl group, a neopentyl group, a cyclohexyl group, an adamantyl group, a cyclohexyl methyl group, or an adamantane methyl group, and particularly preferably a methyl group, a sec-butyl group, a neopentyl group, a cyclohexyl methyl group, or an adamantane methyl group.

The above-described alkyl group, cycloalkyl group, aryl group, aralkyl group, alkoxy group, acyl group, and heterocyclic group may further have a substituent, and examples of substituents which the alkyl group, the cycloalkyl group, the aryl group, the aralkyl group, the alkoxy group, the acyl group, and the heterocyclic group can have include a substituent described as a substituent which each of R₃₆ to R₃₉, R₀₁, R₀₂, and Ar described above may have.

The divalent connecting group represented by M₃ has the same meaning as M in the structure represented by General Formula (VI-A), and the preferable range thereof is also the same. M₃ may have a substituent, and examples of substituents which M₃ can have include the same substituents as substituents which M in the group represented by General Formula (VI-A) can have.

The alkyl group, the cycloalkyl group, and the aryl group represented by Q₃ have the same meaning as those represented by Q in the structure represented by General Formula (VI-A), and the preferable ranges thereof are also the same.

Examples of the heterocyclic group represented by Q₃ include the cycloalkyl group including a heteroatom and the aryl group including a heteroatom, represented by Q in the structure represented by General Formula (VI-A), and the preferable ranges thereof are also the same.

Q₃ may have a substituent, and examples of substituents which Q₃ can have include the same substituents as substituents which Q in the group represented by General Formula (VI-A) can have.

The ring formed by bonding of at least two of Q₃, M₃, or R₃ to each other has the same meaning as a ring formed by bonding of at least two of Q, M, or L₁ to each other in General Formula (VI-A), and the preferable range thereof is also the same.

Specific examples of the repeating unit represented by General Formula (VI) will be described below, but the present invention is not limited thereto.

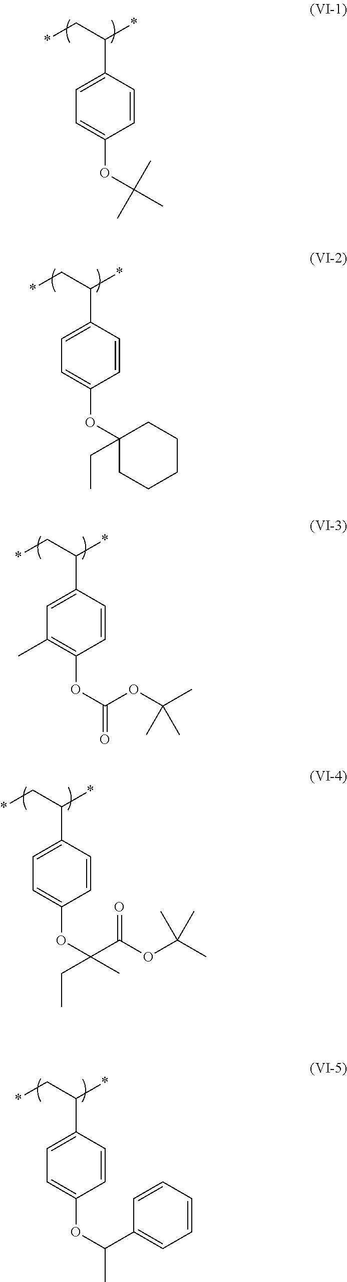

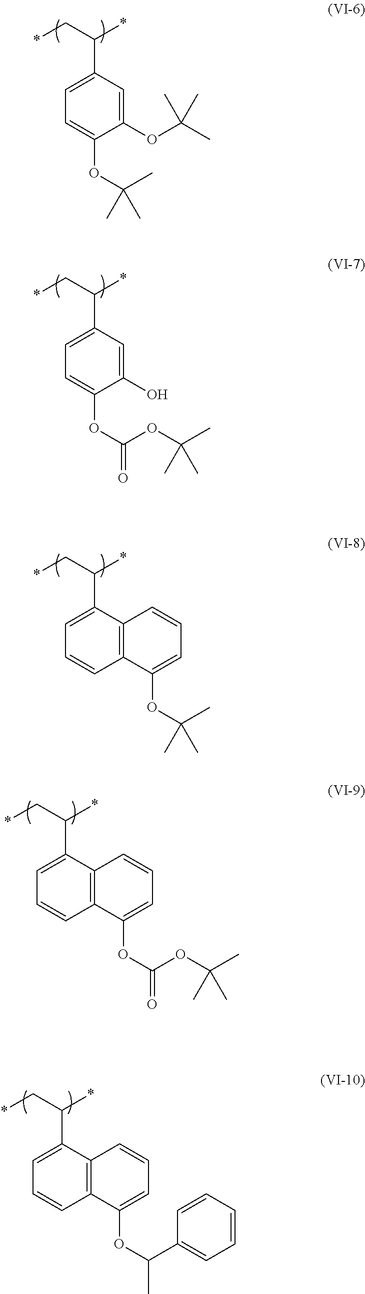

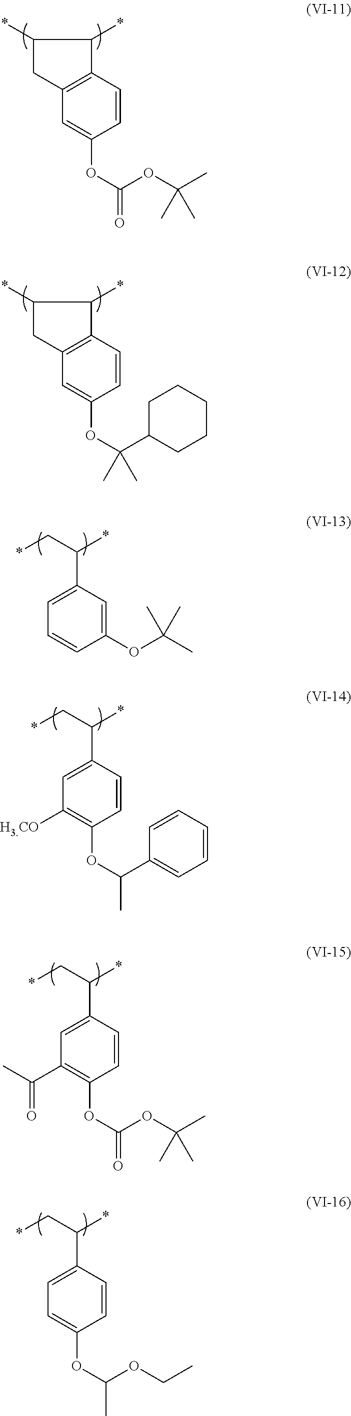

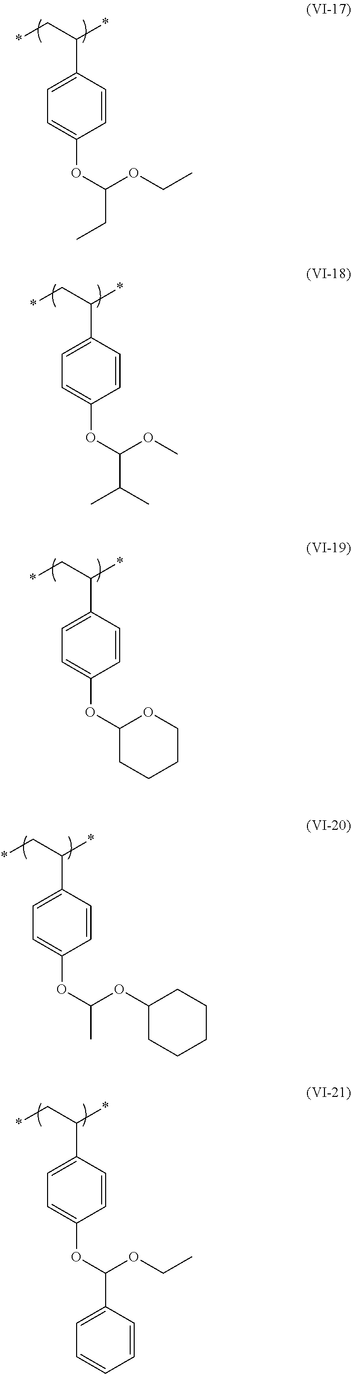

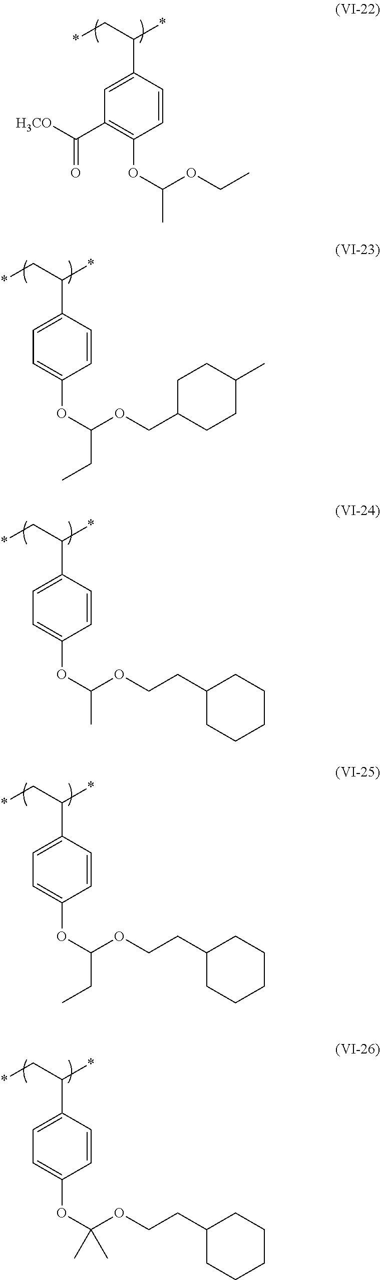

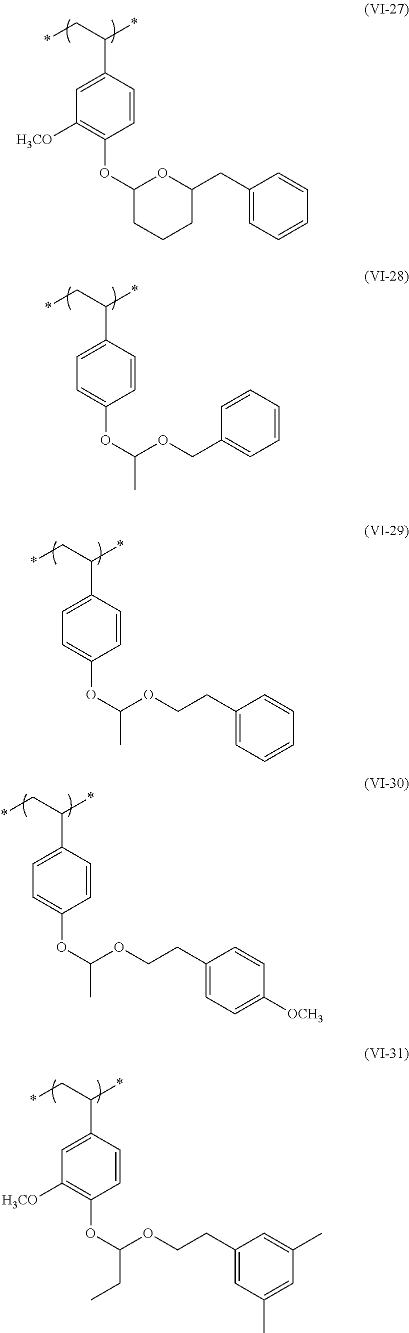

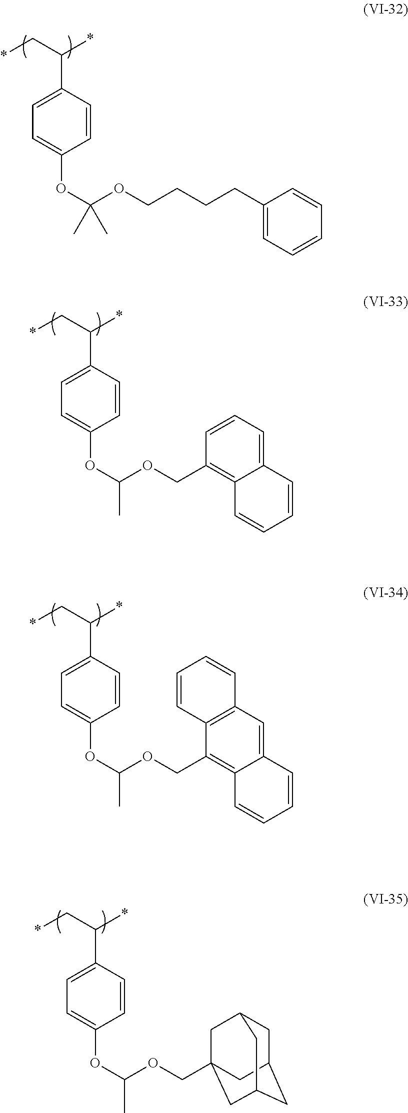

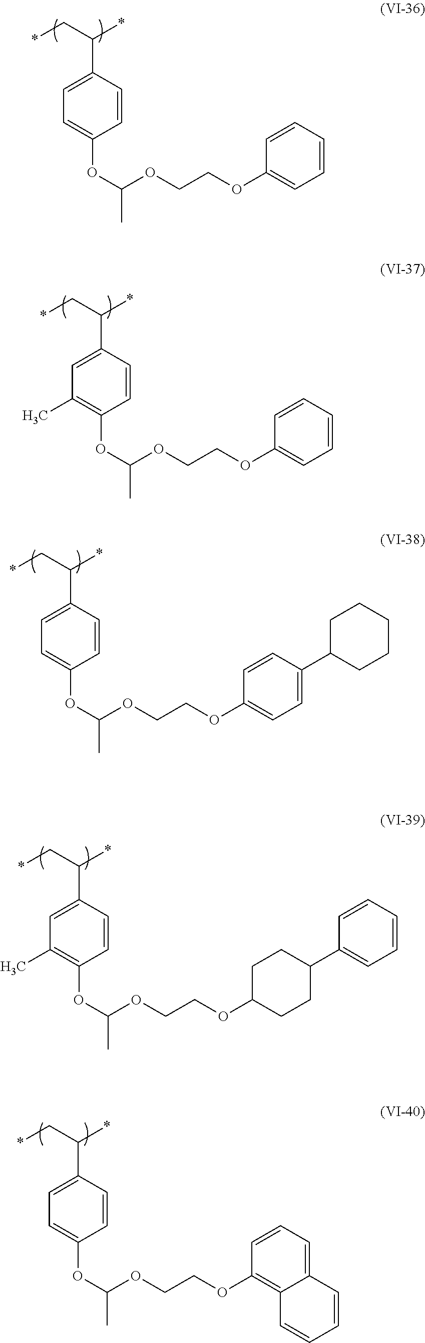

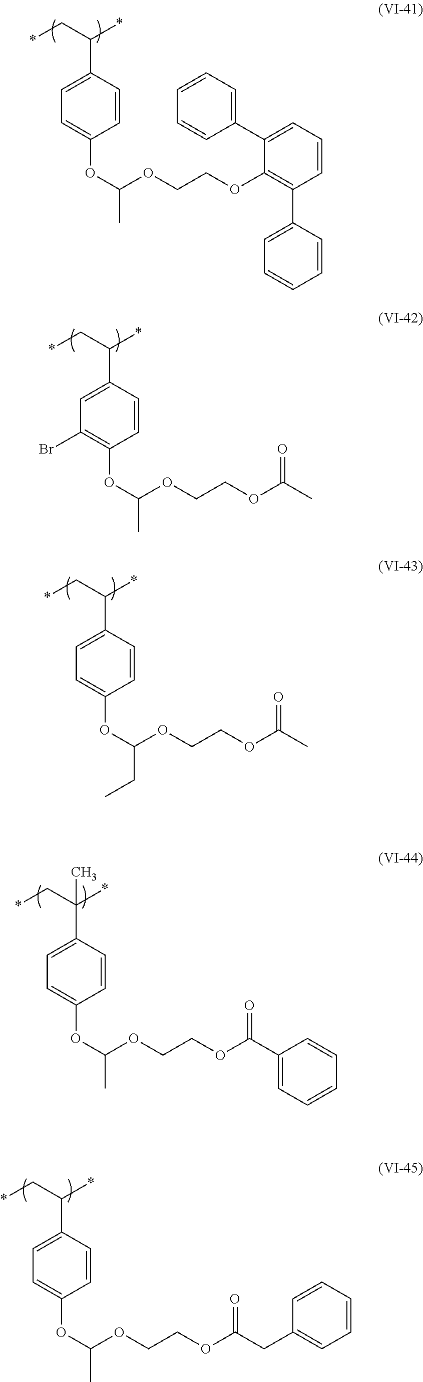

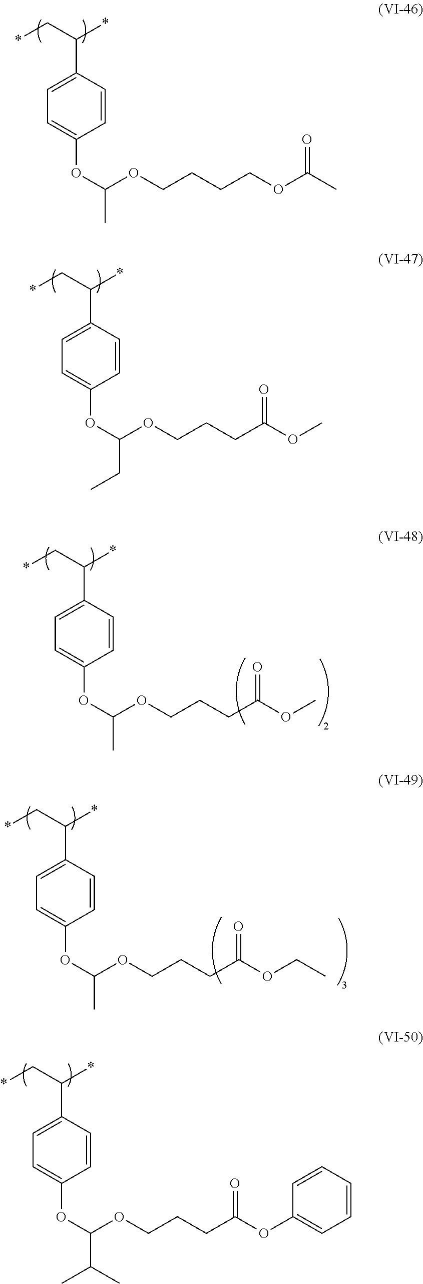

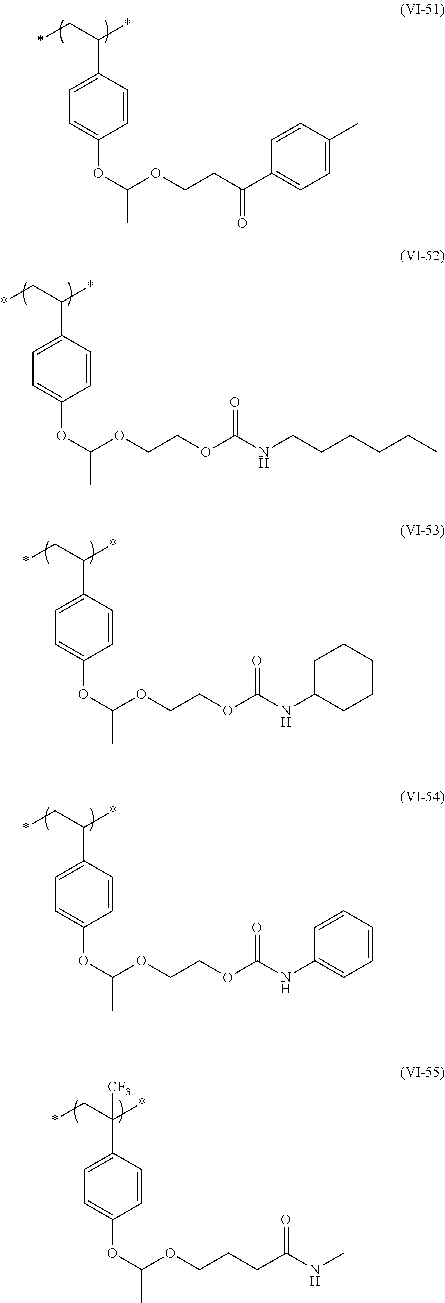

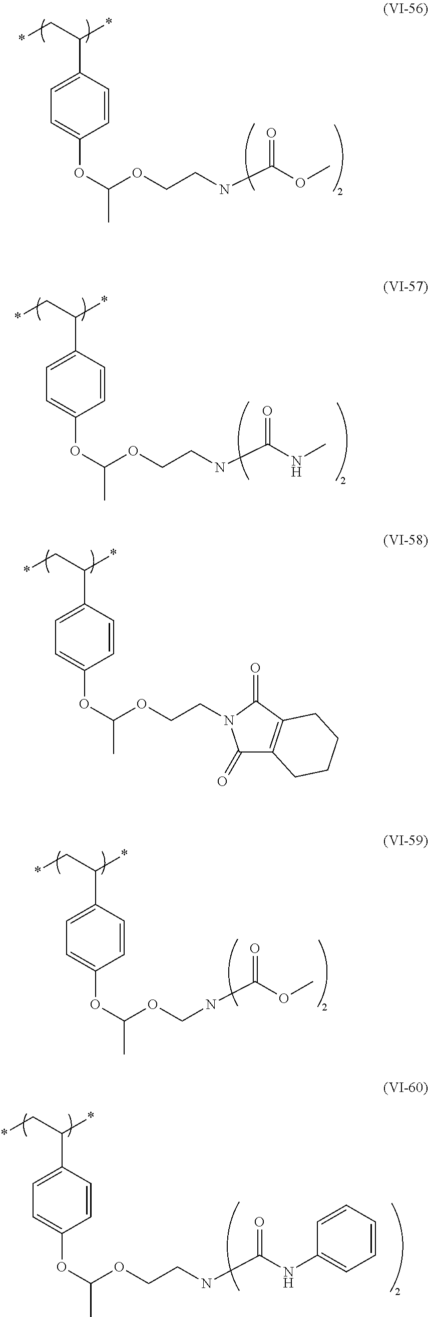

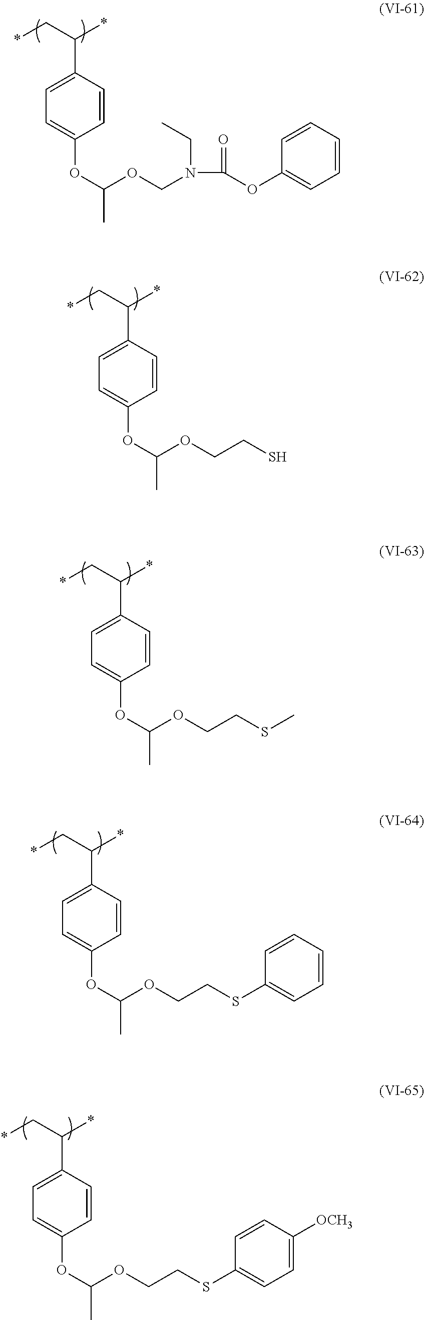

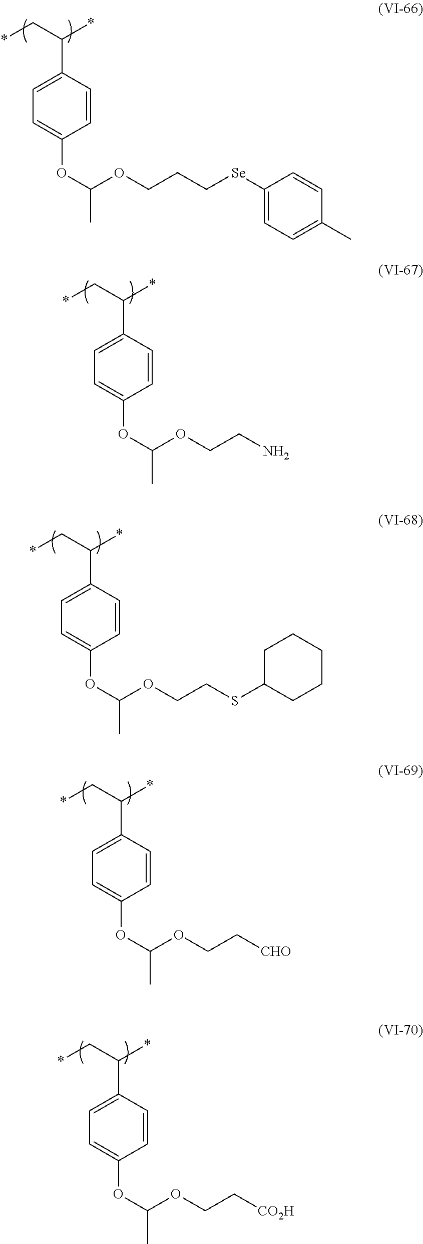

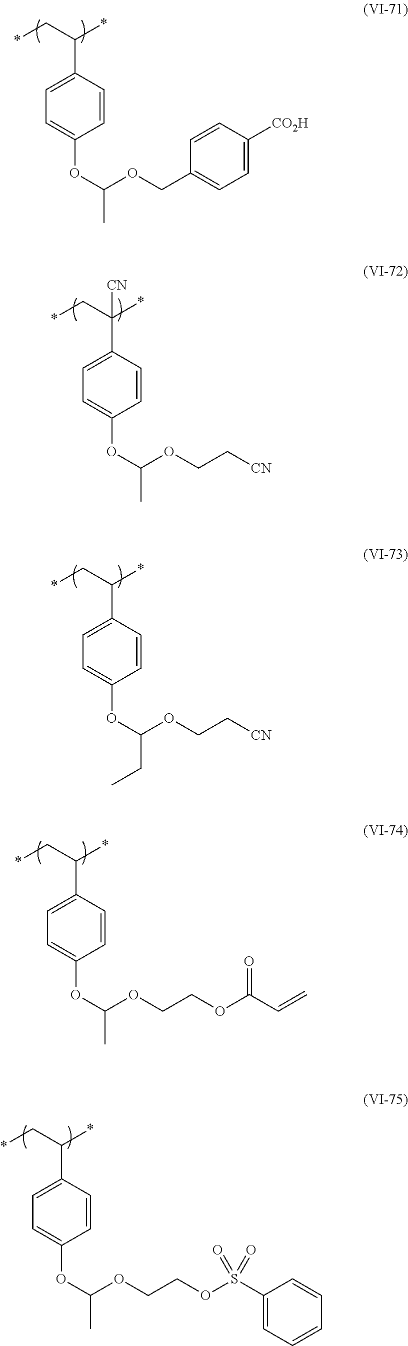

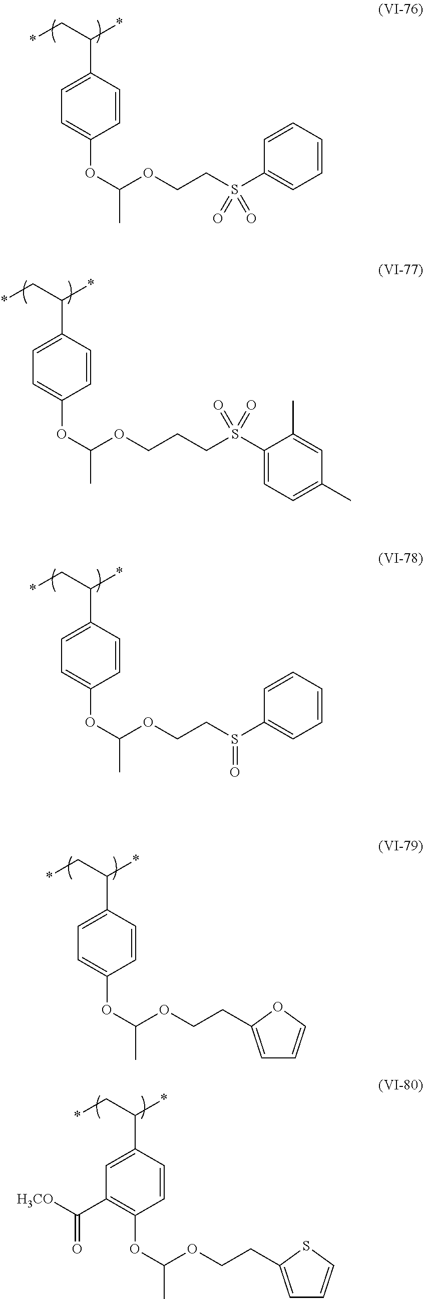

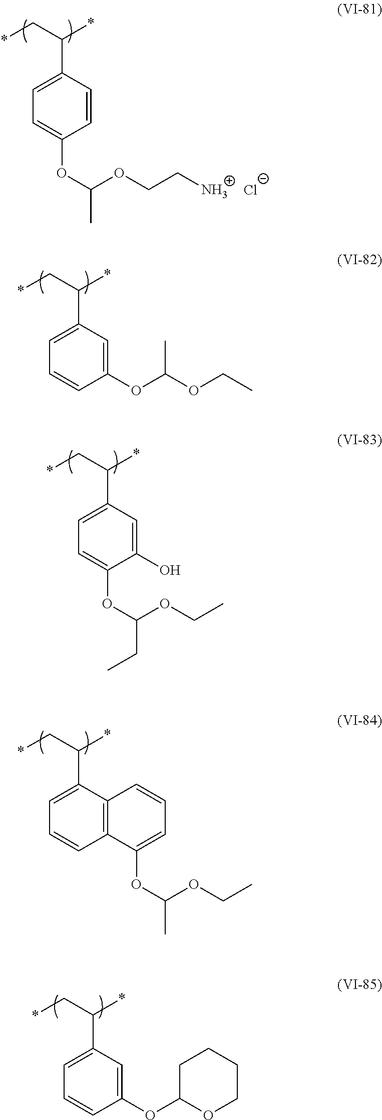

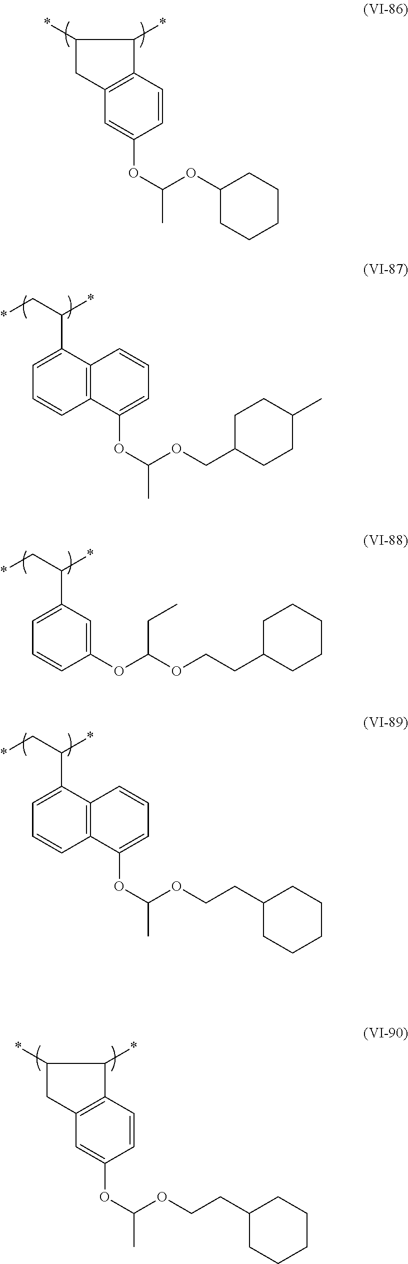

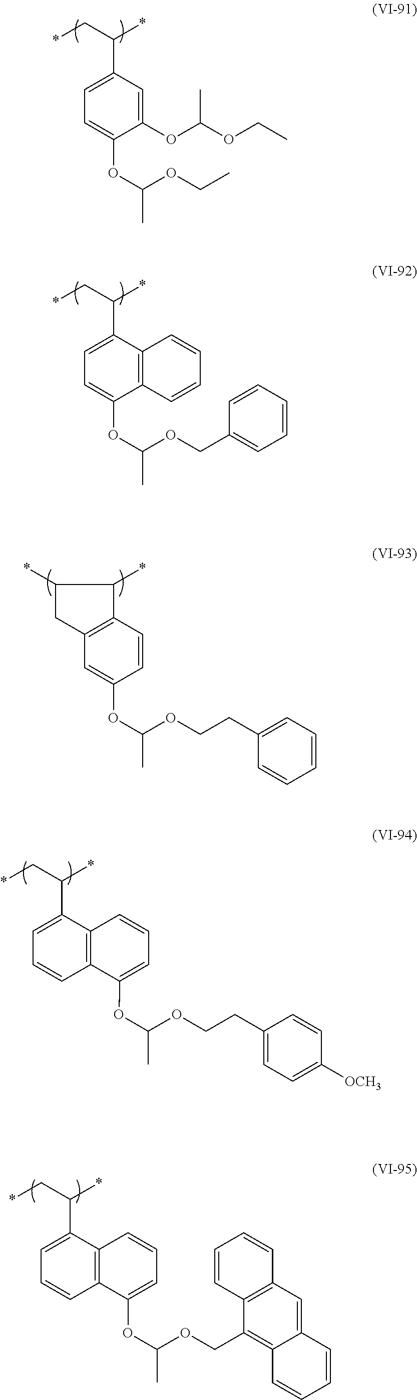

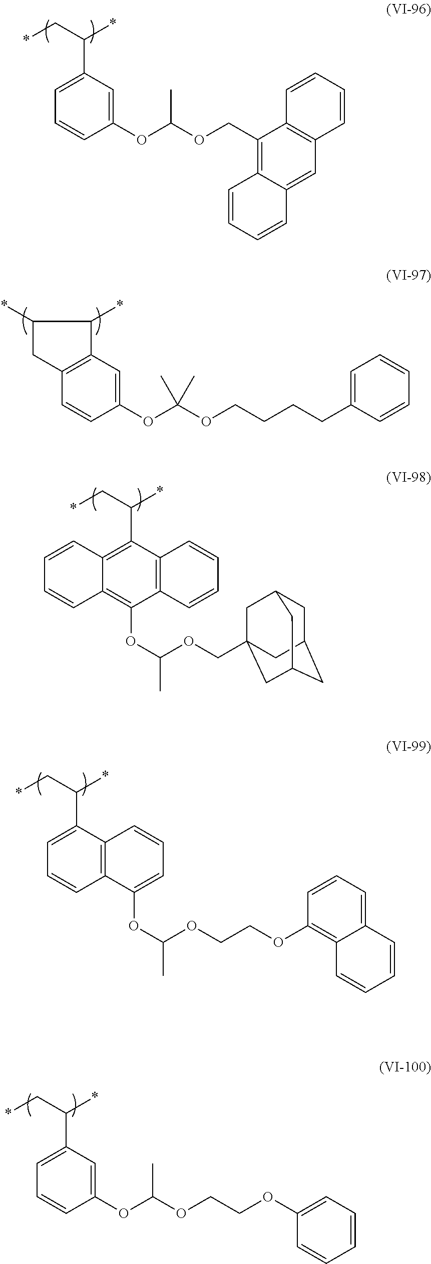

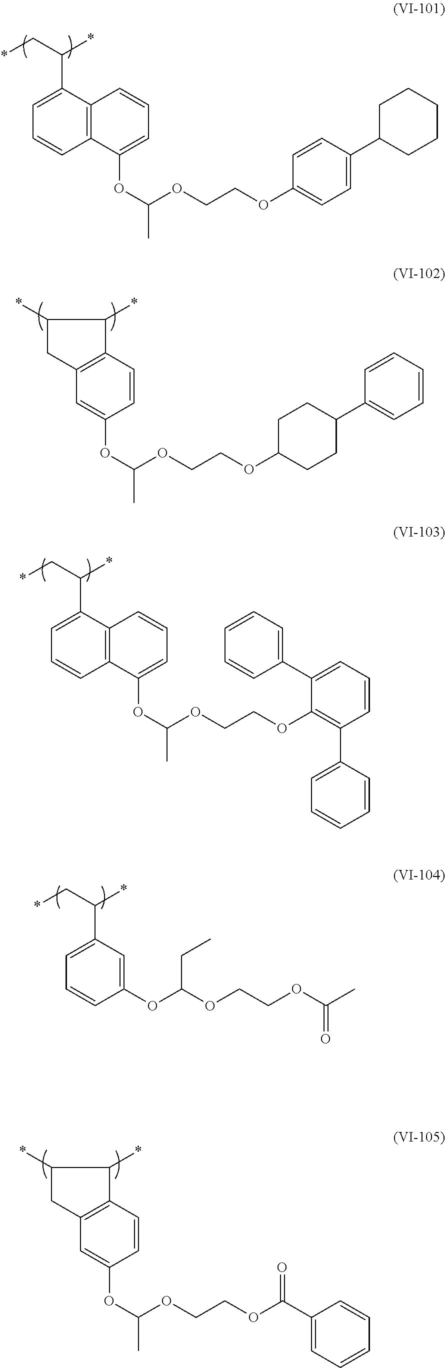

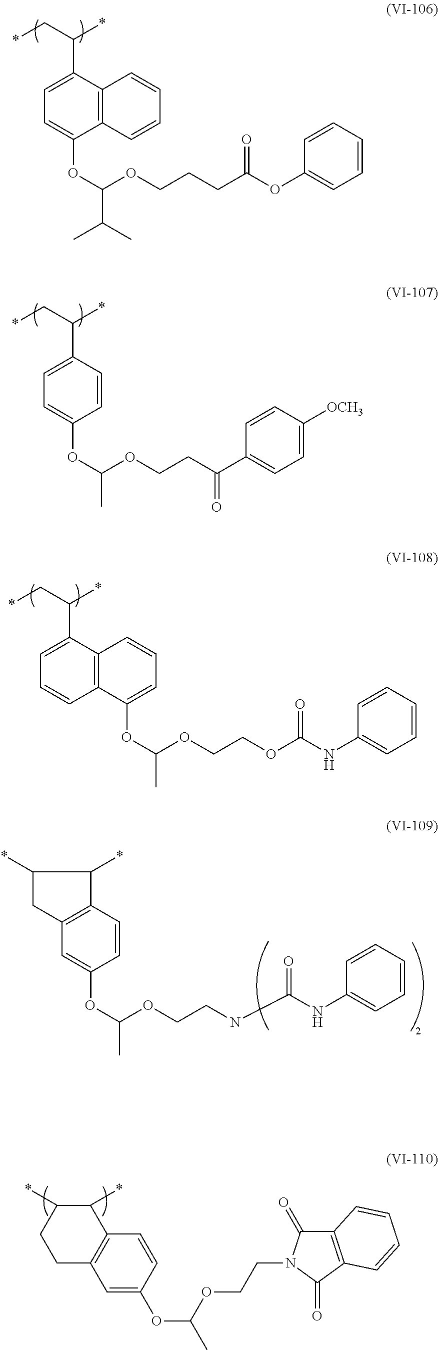

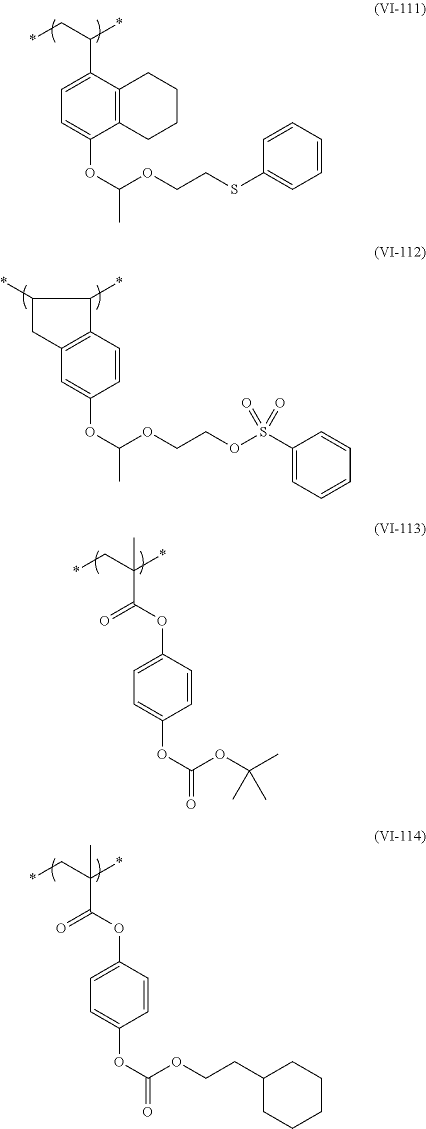

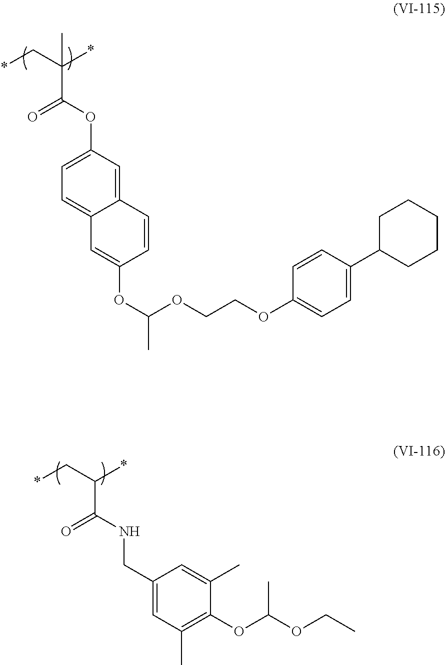

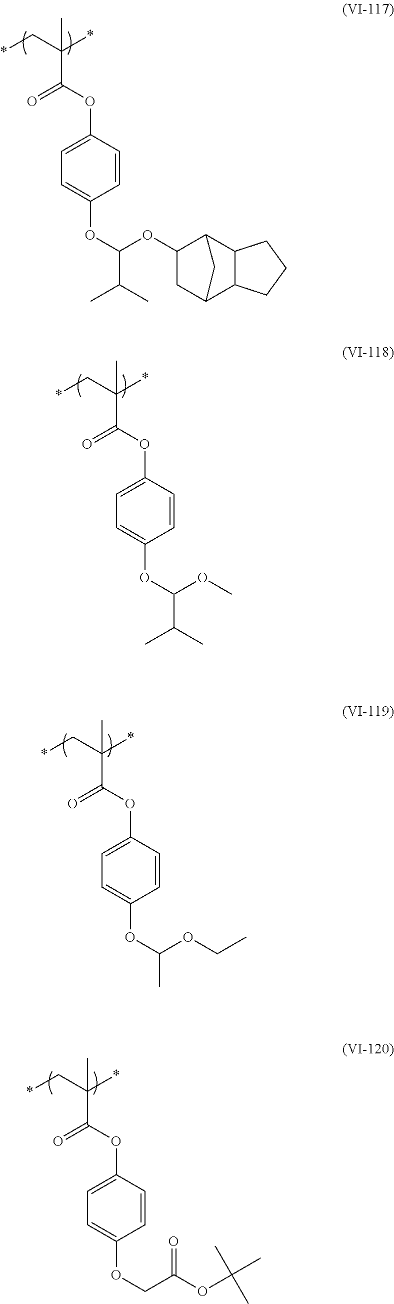

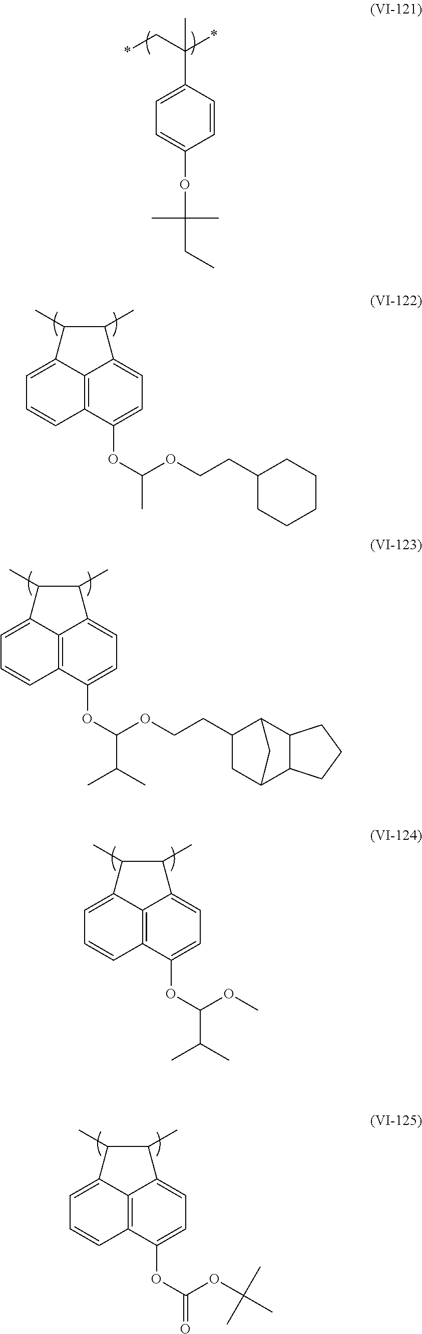

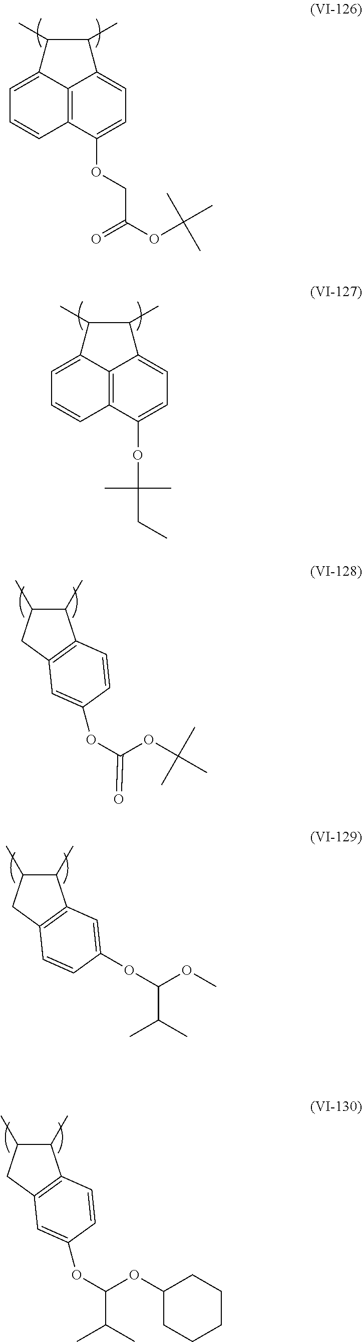

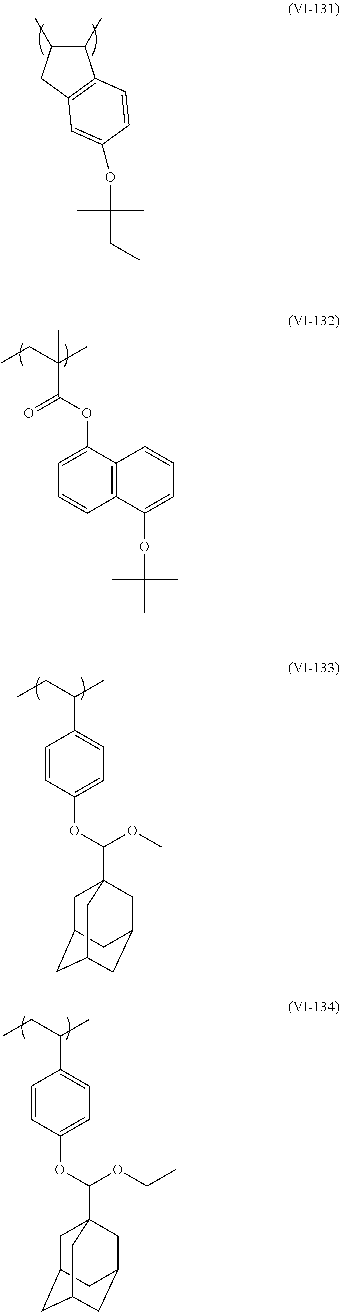

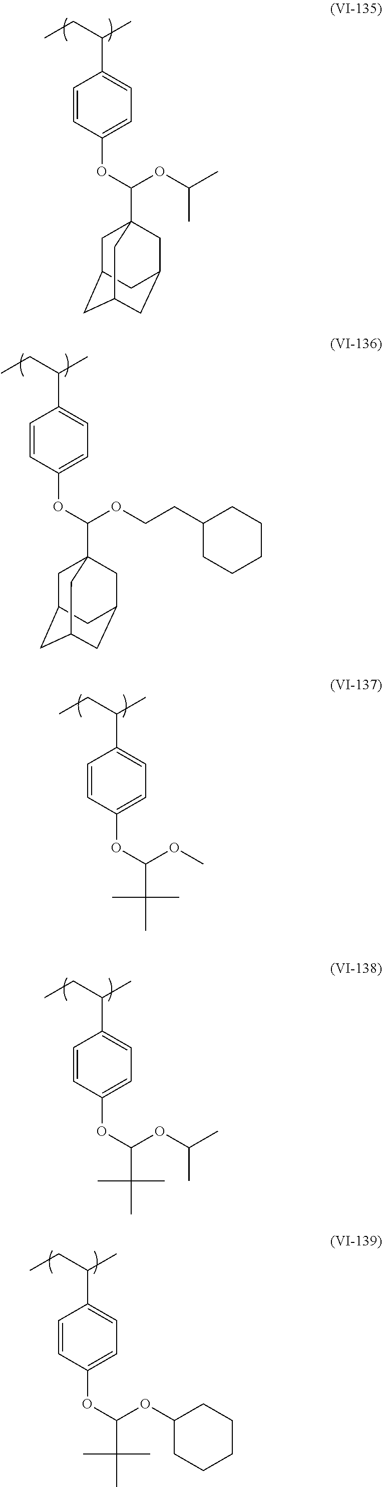

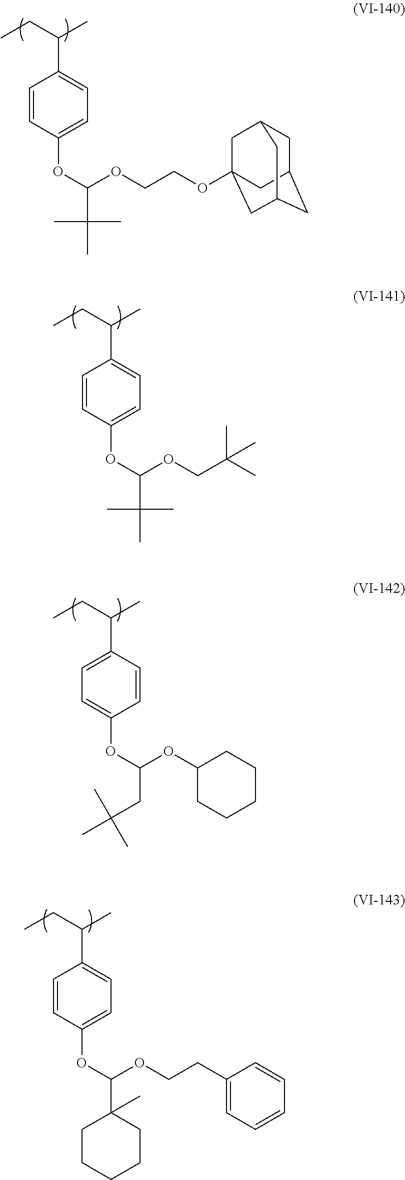

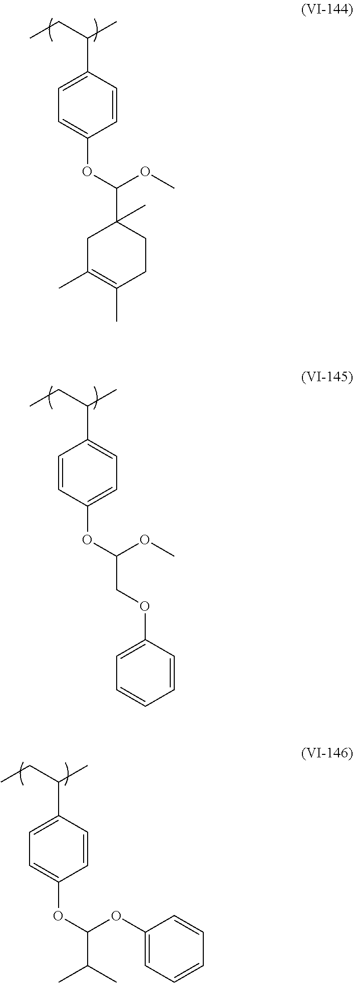

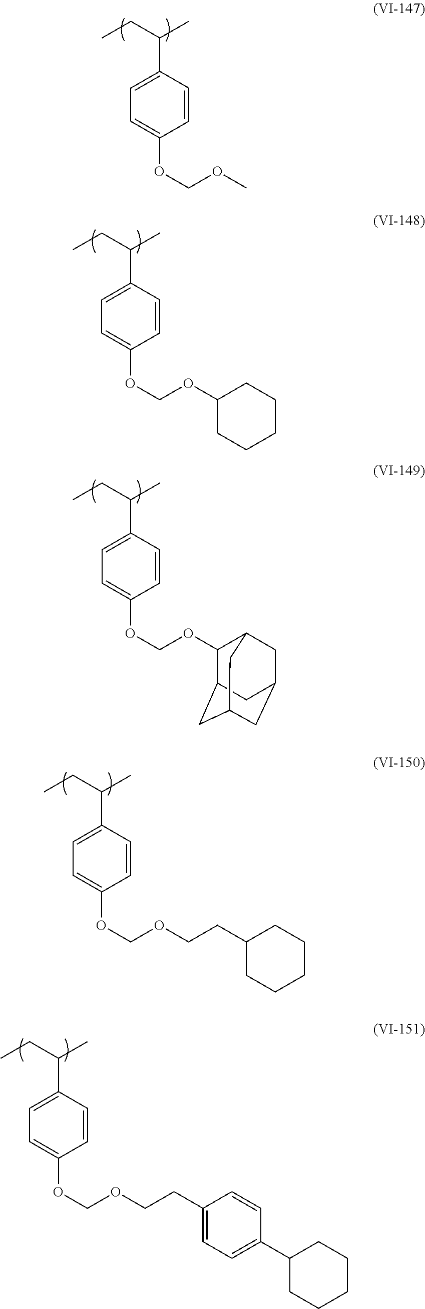

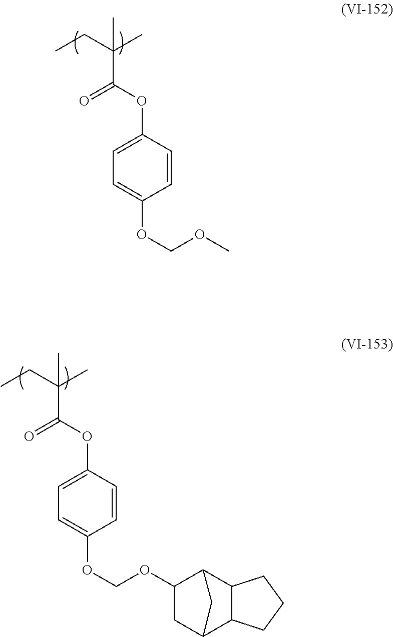

The repeating unit (a) is also preferably a repeating unit represented by the following General Formula (4).

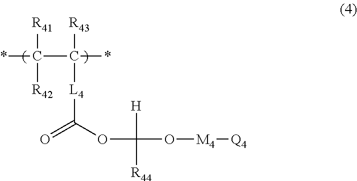

In General Formula (4), each of R₄₁, R₄₂, and R₄₃ independently represents a hydrogen atom, an alkyl group, a cycloalkyl group, a halogen atom, a cyano group, or an alkoxycarbonyl group. R₄₂ may be bonded to L₄ to form a ring, and R₄₂ in this case represents an alkylene group.

L₄ represents a single bond or a divalent connecting group, and in the case of forming a ring with R₄₂, represents a trivalent connecting group.

R₄₄ represents a hydrogen atom, an alkyl group, a cycloalkyl group, an aryl group, an aralkyl group, an alkoxy group, an acyl group, or a heterocyclic group.

M₄ represents a single bond or a divalent connecting group.

Q₄ represents an alkyl group, a cycloalkyl group, an aryl group, or a heterocyclic group.

At least two of Q₄, M₄, or R₄₄ may be bonded to each other to form a ring.

R₄₁, R₄₂, and R₄₃ have the same meaning as R₅₁, R₅₂, and R₅₃ in General Formula (V), respectively, and the preferable ranges thereof are also the same.

L₄ has the same meaning as L₅ in General Formula (V), and the preferable range thereof is also the same.

R₄₄ has the same meaning as R₃ in General Formula (3), and the preferable range thereof is also the same.

M₄ has the same meaning as M₃ in General Formula (3), and the preferable range thereof is also the same.

Q₄ has the same meaning as Q₃ in General Formula (3), and the preferable range thereof is also the same. Examples of the ring formed by bonding of at least two of Q₄, M₄, or R₄₄ to each other include the ring formed by bonding of at least two of Q₃, M₃, or R₃ to each other, and the preferable range thereof is also the same.

Specific examples of the repeating unit represented by General Formula (4) will be described below, but the present invention is not limited thereto.

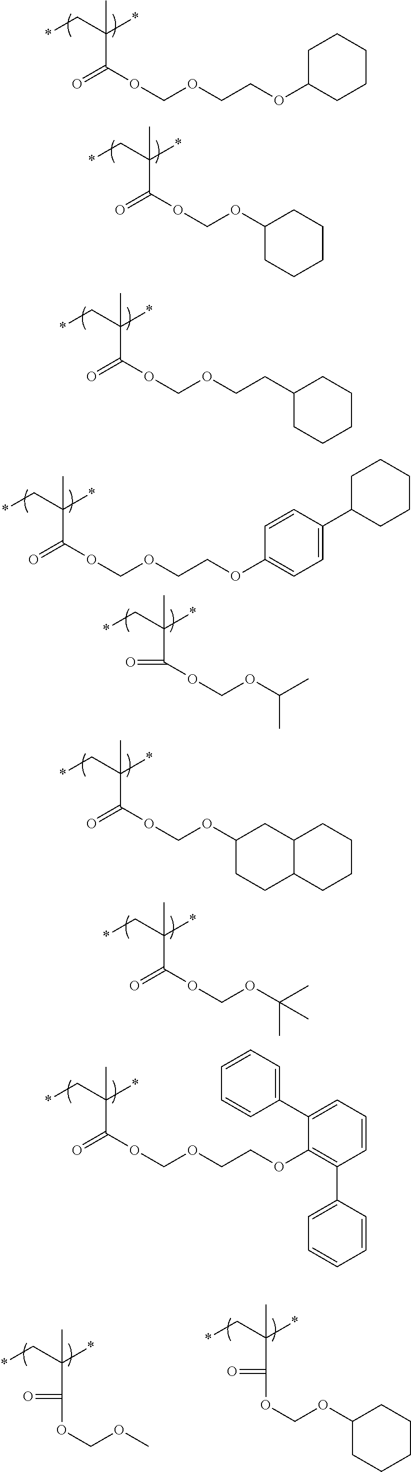

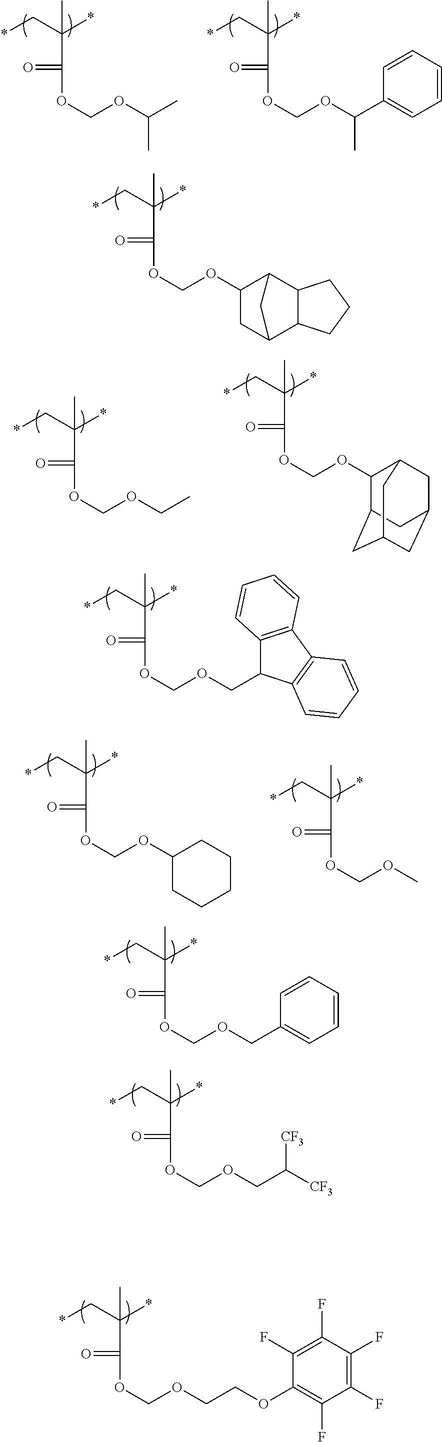

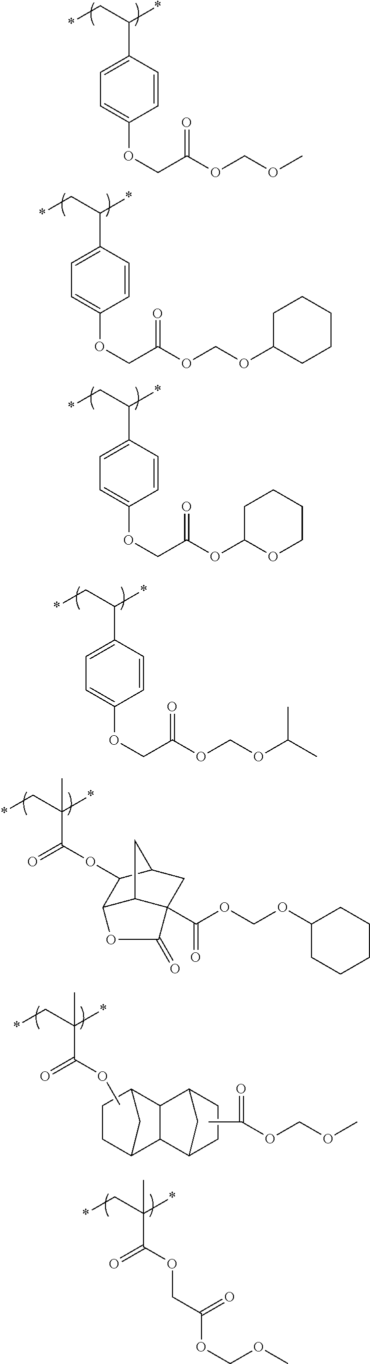

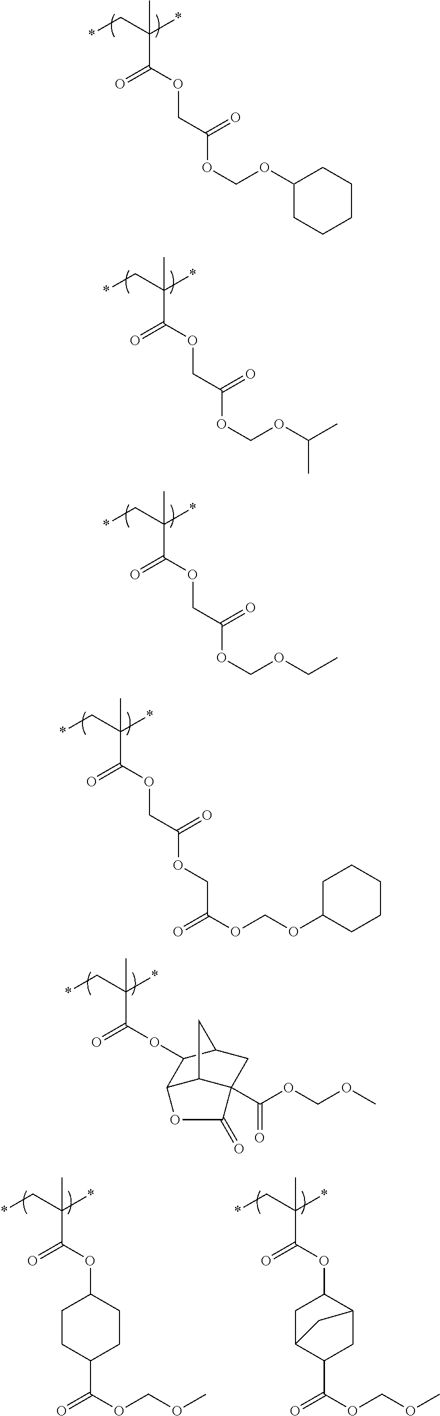

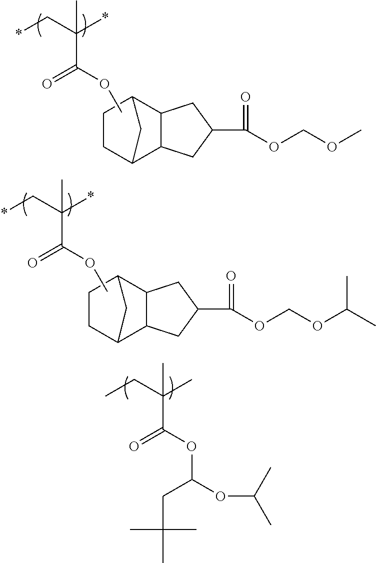

In addition, the repeating unit (a) is preferably a repeating unit represented by the following General Formula (BZ).

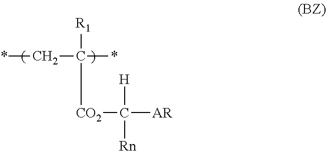

In General Formula (BZ), AR represents an aryl group. Rn represents an alkyl group, a cycloalkyl group, or an aryl group. Rn and AR may be bonded to each other to form a nonaromatic ring.

R₁ represents a hydrogen atom, an alkyl group, a cycloalkyl group, a halogen atom, a cyano group, or an alkyloxycarbonyl group.

The aryl group represented by AR is preferably an aryl group having 6 to 20 carbon atoms, such as a phenyl group, a naphthyl group, an anthryl group, or a fluorene group, and more preferably an aryl group having 6 to 15 carbon atoms.

In a case where AR is a naphthyl group, an anthryl group, or a fluorene group, the bonding position between the carbon atom bonded to Rn and AR is not particularly limited. For example, in a case where AR is a naphthyl group, the carbon atom may be bonded to an α-position of the naphthyl group or may be bonded to a β-position. Alternatively, in a case where AR is an anthryl group, the carbon atom may be bonded to the 1-position of the anthryl group, may be bonded to the 2-position, or may be bonded to the 9-position.

The aryl group as AR may have one or more substituents. Specific examples of such substituents include linear or branched alkyl groups having 1 to 20 carbon atoms, such as a methyl group, an ethyl group, a propyl group, an isopropyl group, an n-butyl group, an isobutyl group, a t-butyl group, a pentyl group, a hexyl group, an octyl group, and a dodecyl group, and alkoxy groups including these alkyl group portions, cycloalkyl groups such as a cyclopentyl group and a cyclohexyl group, and cycloalkoxy groups including these cycloalkyl group portions, and a hydroxyl group, a halogen atom, an aryl group, a cyano group, a nitro group, an acyl group, an acyloxy group, an acyl amino group, a sulfonyl amino group, an alkylthio group, an arylthio group, an aralkylthio group, a thiophene carbonyloxy group, a thiophene methylcarbonyloxy group, and heterocyclic residues such as a pyrrolidone residue. As the substituent, linear or branched alkyl groups having 1 to 5 carbon atoms or alkoxy groups including these alkyl group portions is preferable, and a paramethyl group or a paramethoxy group is more preferable.

In a case where the aryl group as AR has a plurality of substituents, at least two of the plurality of substituents may be bonded to each other to form a ring. The ring is preferably a 5- to 8-membered ring, and more preferably a 5- or 6-membered ring. In addition, the ring may be a heterocycle including a heteroatom such as an oxygen atom, a nitrogen atom, or a sulfur atom as the ring member.

Furthermore, the ring may have a substituent. Examples of the substituent include the same as those described below for a substituent which Rn may have.

In addition, the repeating unit (a) represented by General Formula (BZ) preferably contains two or more aromatic rings from the viewpoint of roughness performance. The number of aromatic rings which the repeating unit has is preferably 5 or less, and more preferably 3 or less.

In addition, in the repeating unit (a) represented by General Formula (BZ), from the viewpoint of roughness performance, AR more preferably contains two or more aromatic rings, and AR is still more preferably a naphthyl group or a biphenyl group. Typically, the number of aromatic rings which AR has is preferably 5 or less, and more preferably 3 or less.

As described above, Rn represents an alkyl group, a cycloalkyl group, or an aryl group.

The alkyl group represented by Rn may be a linear alkyl group or a branched alkyl group. Preferable examples of the alkyl group include alkyl groups including 1 to 20 carbon atoms, such as a methyl group, an ethyl group, a propyl group, an isopropyl group, a n-butyl group, an isobutyl group, a t-butyl group, a pentyl group, a hexyl group, a cyclohexyl group, an octyl group, and a dodecyl group. The alkyl group represented by Rn preferably has 1 to 5 carbon atoms and more preferably has 1 to 3 carbon atoms.

Examples of the cycloalkyl group represented by Rn include cycloalkyl groups having 3 to 15 carbon atoms, such as a cyclopentyl group and a cyclohexyl group.

Preferable examples of the aryl group represented by Rn include aryl groups having 6 to 14 carbon atoms, such as a phenyl group, a xylyl group, a toluyl group, a cumenyl group, a naphthyl group, and an anthryl group.

Each of the alkyl group, the cycloalkyl group, and the aryl group as Rn may further have a substituent. Examples of the substituent include an alkoxy group, a hydroxyl group, a halogen atom, a nitro group, an acyl group, an acyloxy group, an acyl amino group, a sulfonyl amino group, a dialkylamino group, an alkylthio group, an arylthio group, an aralkylthio group, a thiophene carbonyloxy group, a thiophene methylcarbonyloxy group, and heterocyclic residues such as a pyrrolidone residue. Among these, an alkoxy group, a hydroxyl group, a halogen atom, a nitro group, an acyl group, an acyloxy group, an acyl amino group, or a sulfonyl amino group is particularly preferable.

As described above, R₁ represents a hydrogen atom, an alkyl group, a cycloalkyl group, a halogen atom, a cyano group, or an alkyloxycarbonyl group.

Examples of the alkyl group or the cycloalkyl group represented by R₁ include the same as those described for Rn above. Each of these alkyl group and cycloalkyl group may have a substituent. Examples of the substituent include the same as those described for Rn above.

In a case where R₁ is an alkyl group or a cycloalkyl group having a substituent, particularly preferable examples of R₁ include a trifluoromethyl group, an alkyloxycarbonyl methyl group, an alkyl carbonyloxymethyl group, a hydroxymethyl group, and an alkoxymethyl group.

Examples of the halogen atom represented by R₁ include a fluorine atom, a chlorine atom, a bromine atom, and an iodine atom. Among these, a fluorine atom is particularly preferable.

As the alkyl portion included in the alkyloxycarbonyl group represented by R₁, for example, the configuration exemplified as the alkyl group represented by R₁ above can be adopted.

Rn and AR are preferably bonded to each other to form a nonaromatic ring, and as a result, in particular, it is possible to further improve the roughness performance.

The nonaromatic ring which Rn and AR may be bonded to each other to form is preferably a 5- to 8-membered ring, and more preferably a 5- or 6-membered ring.

The nonaromatic ring may be a aliphatic ring, or a heterocycle including a heteroatom such as an oxygen atom, a nitrogen atom, or a sulfur atom as the ring member.

The nonaromatic ring may have a substituent. Examples of the substituent include the same as those described above for a substituent which Rn may have.

Specific examples of the repeating unit represented by General Formula (BZ) will be described below, but the present invention is not limited thereto.

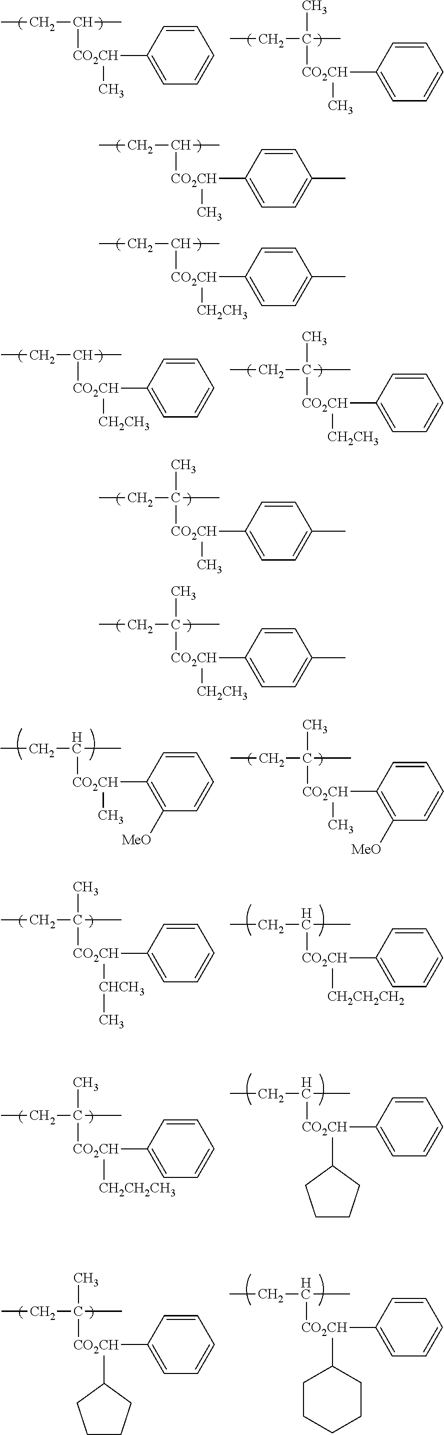

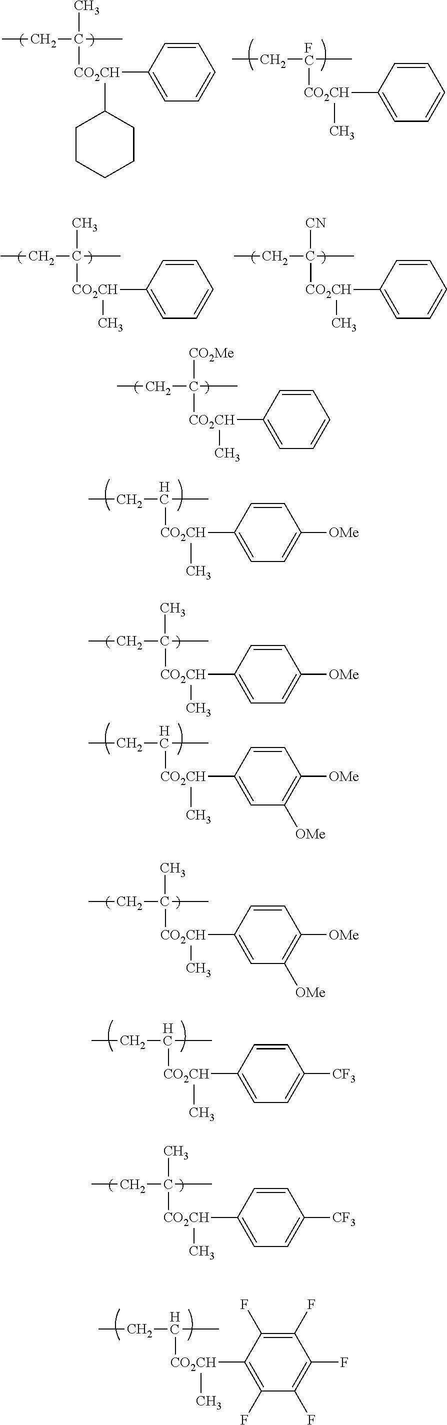

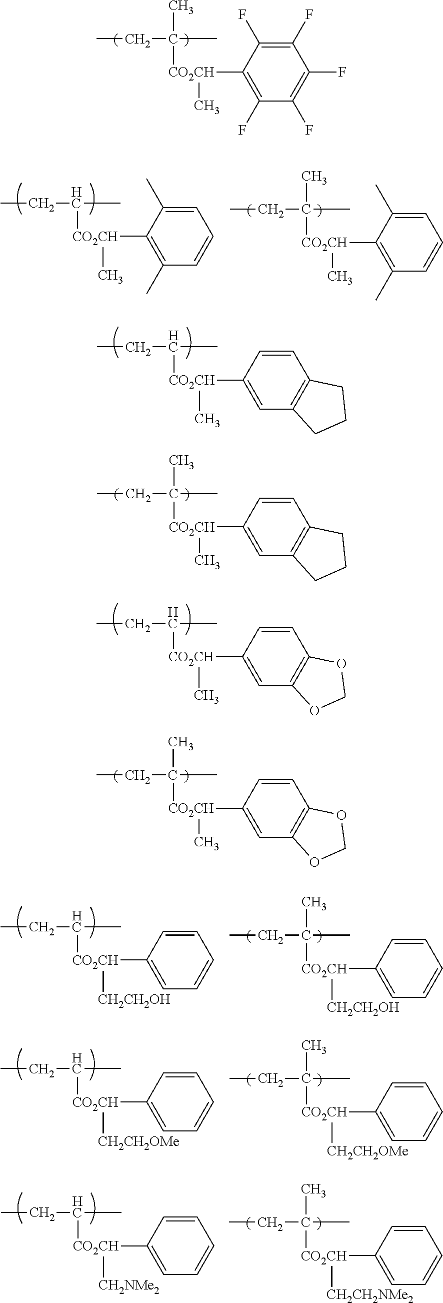

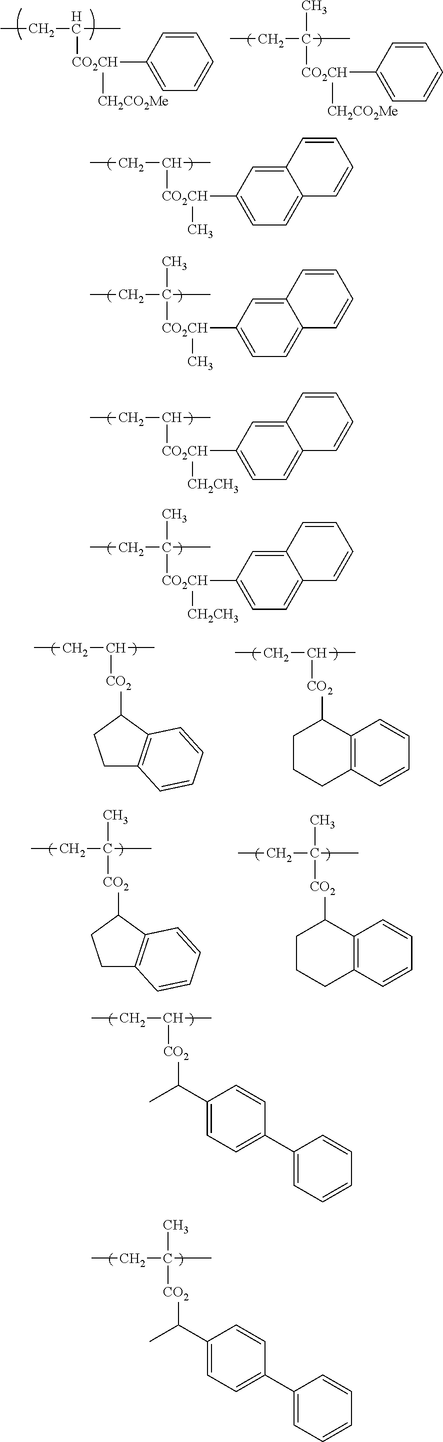

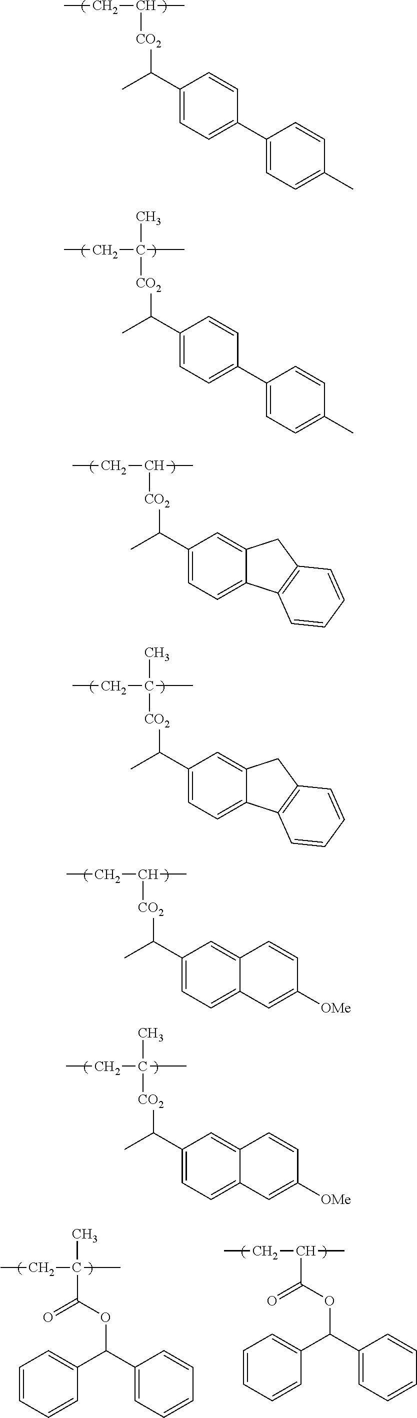

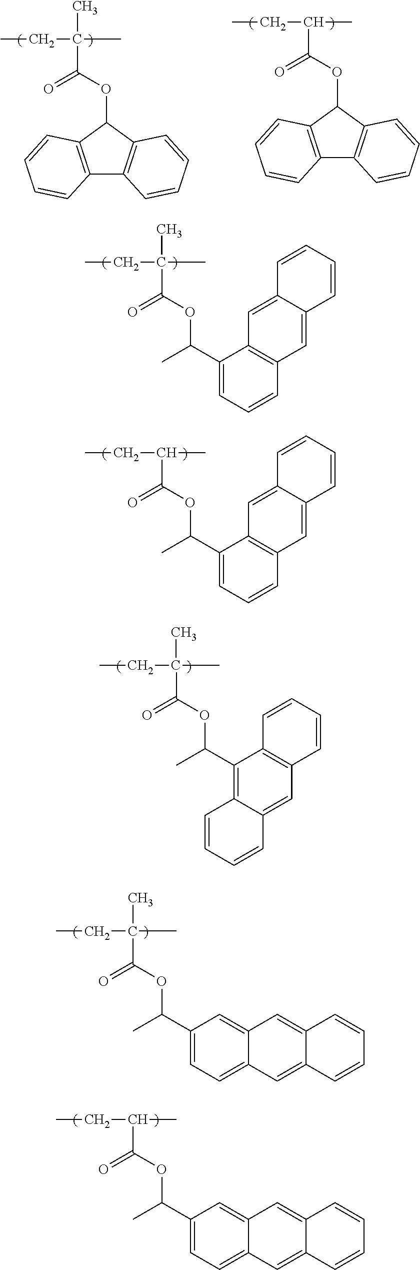

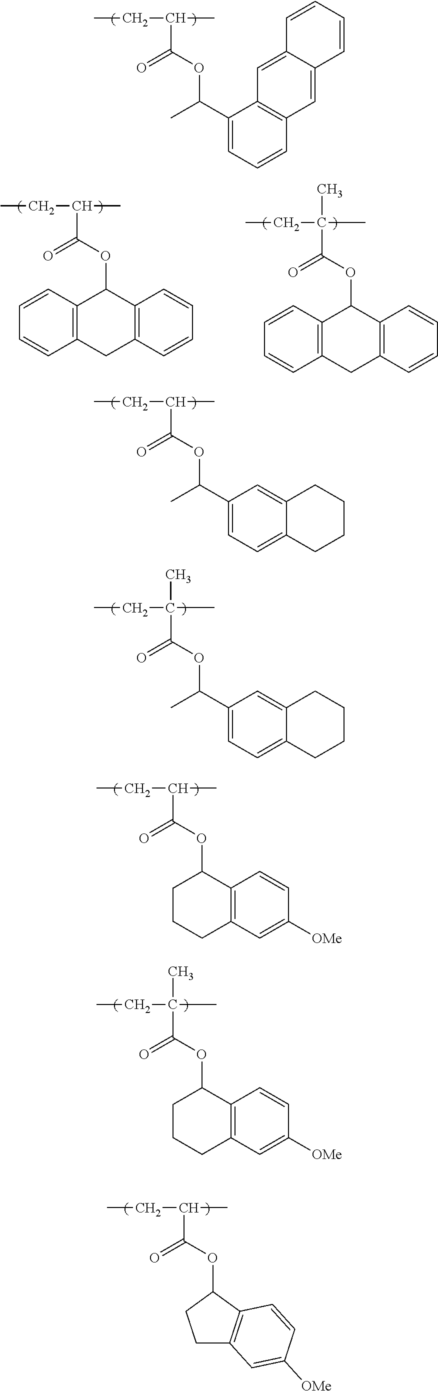

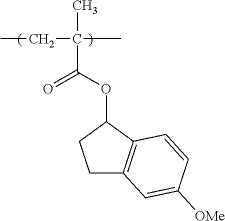

In addition, the aspect of a repeating unit having an acid-decomposable group different from the repeating unit exemplified above may be an aspect of a repeating unit that generates an alcoholic hydroxyl group. In this case, the repeating unit is preferably represented by at least one selected from the group consisting of the following General Formulas (I-1) to (I-10). The repeating unit is more preferably represented by at least one selected from the group consisting of the following General Formulas (I-1) to (I-3), and still more preferably represented by the following General Formula (I-1).

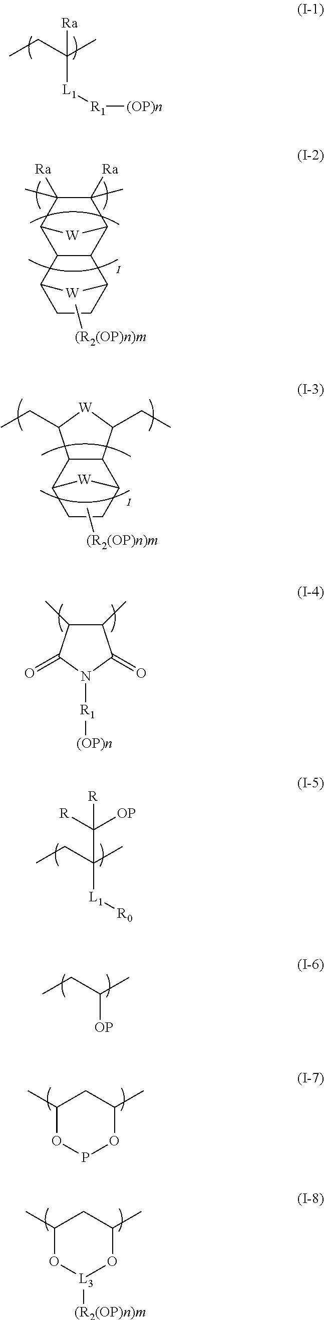

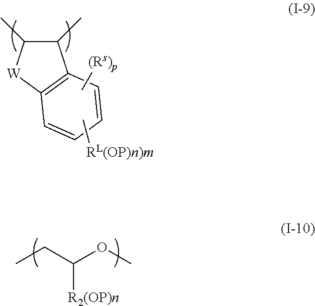

In the formulas, each of Ra's independently represents a hydrogen atom, an alkyl group, or a group represented by —CH₂—O—Ra₂. Here, Ra₂ represents a hydrogen atom, an alkyl group, or an acyl group.

R₁ represents an (n+1) valent organic group.

In a case where m is 2 or greater, each of R₂'s independently represents a single bond or an (n+1) valent organic group.

Each of OP's independently represents the group that generates an alcoholic hydroxy group by being decomposed due to the action of an acid. In a case where n is 2 or greater and/or m is 2 or greater, two or more OP's may be bonded to each other to form a ring.

W represents a methylene group, an oxygen atom, or a sulfur atom.

Each of n and m represents an integer of 1 or greater. In a case where R in General Formula (1-2), (1-3), or (1-8) is a single bond, n is 1.

l represents an integer of 0 or greater.

L₁ represents a connecting group represented by —COO—, —OCO—, —CONH—, —O—, —Ar—, —SO₃—, or —SO₂NH—. Here, Ar represents a divalent aromatic ring group.

Each of R's independently represents a hydrogen atom or an alkyl group.

R₀ represents a hydrogen atom or an organic group.

L³ represents an (m+2) valent connecting group.

In a case where m is 2 or greater, each of R^{L}'s independently represents an (n+1) valent connecting group.

In a case where p is 2 or greater, each of R^{S}'s independently represents a substituent. In a case where p is 2 or greater, a plurality of R^{S}'s may be bonded to each other to form a ring.

p represents an integer of 0 to 3.

Ra represents a hydrogen atom, an alkyl group, or a group represented by —CH₂—O—Ra₂. Ra is preferably a hydrogen atom or an alkyl group having 1 to 10 carbon atoms, and more preferably a hydrogen atom or a methyl group.

W represents a methylene group, an oxygen atom, or a sulfur atom. W is preferably a methylene group or an oxygen atom.

R₁ represents an (n+1) valent organic group. R₁ is preferably a nonaromatic hydrocarbon group. In this case, R₁ may be a chain hydrocarbon group or may be an alicyclic hydrocarbon group. R₁ is more preferably an alicyclic hydrocarbon group.

R₂ represents a single bond or an (n+1) valent organic group. R₂ is preferably a single bond or a nonaromatic hydrocarbon group. In this case, R₂ may be a chain hydrocarbon group or may be an alicyclic hydrocarbon group.

In a case where R₁ and/or R₂ is a chain hydrocarbon group, the hydrocarbon group may be linear or may be branched. In addition, the chain hydrocarbon group preferably has 1 to 8 carbon atoms. For example, in a case where R₁ and/or R₂ is an alkylene group, RI and/or R₂ is preferably a methylene group, an ethylene group, an n-propylene group, an isopropylene group, an n-butylene group, an isobutylene group, or a sec-butylene group.

In a case where R₁ and/or R₂ is an alicyclic hydrocarbon group, the alicyclic hydrocarbon group may be monocyclic or may be polycyclic. The alicyclic hydrocarbon group has, for example, a monocyclic structure, a bicyclic structure, a tricyclic structure, or a tetracyclic structure. The alicyclic hydrocarbon group typically has 5 or more carbon atoms, preferably 6 to 30 carbon atoms, and more preferably 7 to 25 carbon atoms.

Examples of the alicyclic hydrocarbon group include an alicyclic hydrocarbon having one of substructures listed below. Each of these substructures may have a substituent. In addition, the methylene group (—CH₂—) in each of these substructures may be substituted with an oxygen atom (—O—), a sulfur atom (—S—), a carbonyl group [—C(═O)—], a sulfonyl group [—S(═O)₂—], a sulfinyl group [—S(═O)—], or an imino group [—N(R)—] (R is a hydrogen atom or an alkyl group).

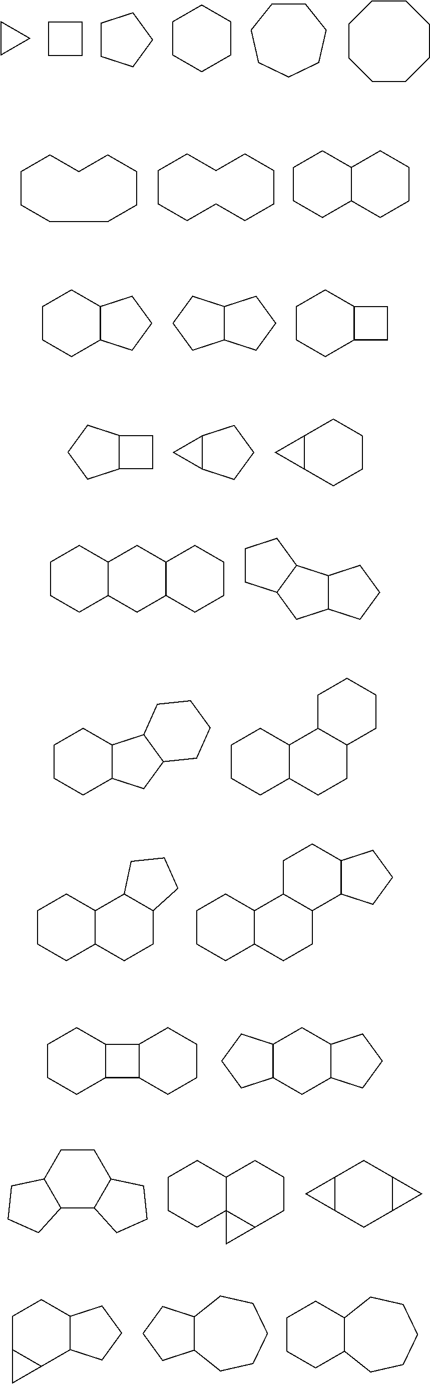

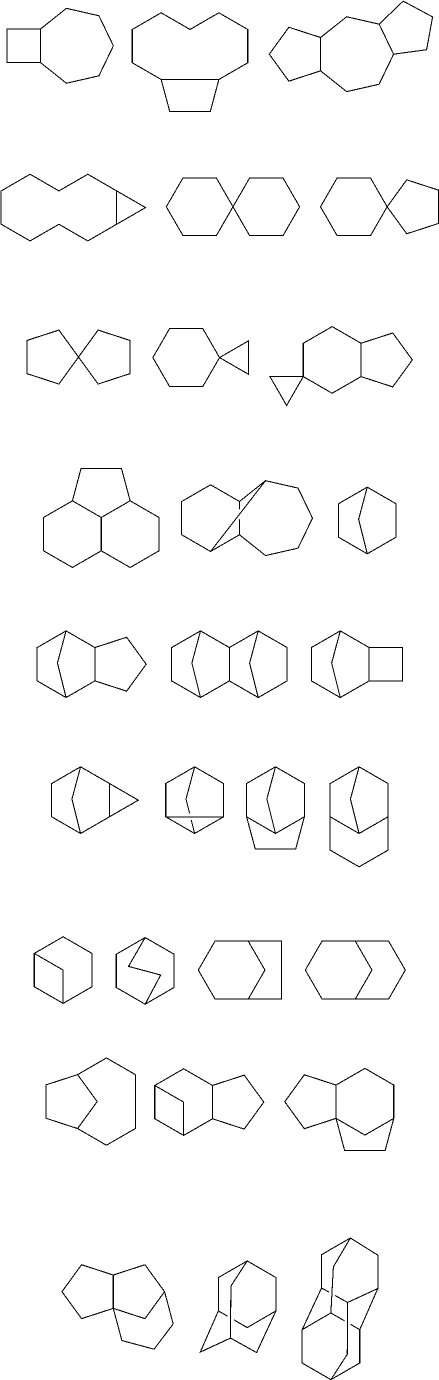

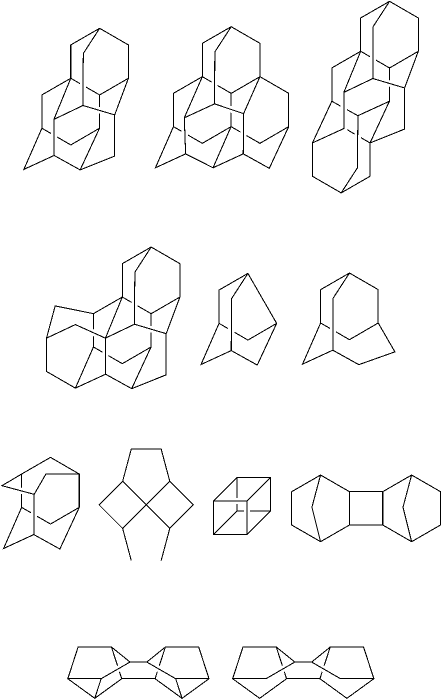

For example, in a case where R₁ and/or R₂ is a cycloalkylene group, R and/or R₂ is preferably an adamantylene group, a noradamantylene group, a decahydronaphthylene group, a tricyclodecanylene group, a tetracyclododecanylene group, a norbornylene group, a cyclopentylene group, a cyclohexylene group, a cycloheptylene group, a cyclooctylene group, a cyclodecanylene group, or a cyclododecanylene group, and more preferably an adamantylene group, a norbornylene group, a cyclohexylene group, a cyclopentylene group, a tetracyclododecanylene group, or a tricyclodecanylene group.

The nonaromatic hydrocarbon group represented by R₁ and/or R₂ may have a substituent. Examples of the substituent include an alkyl group having 1 to 4 carbon atoms, a halogen atom, a hydroxy group, an alkoxy group having 1 to 4 carbon atoms, a carboxy group, and an alkoxycarbonyl group having 2 to 6 carbon atoms. The alkyl group, the alkoxy group, and the alkoxycarbonyl group described above may further have a substituent. Examples of the substituent include a hydroxy group, a halogen atom, and an alkoxy group.

L₁ represents a connecting group represented by —COO—, —OCO—, —CONH—, —O—, —Ar—, —SO₃—, or —SO₂NH—. Here, Ar represents a divalent aromatic ring group. L₁ is preferably a connecting group represented by —COO—, —CONH—, or —Ar—, and more preferably a connecting group represented by —COO— or —CONH—.

R represents a hydrogen atom or an alkyl group. The alkyl group may be linear, or may be branched. The alky group preferably has 1 to 6 carbon atoms, and more preferably 1 to 3 carbon atoms. R is preferably a hydrogen atom or a methyl group, and more preferably a hydrogen atom.

R₀ represents a hydrogen atom or an organic group. Examples of the organic group include an alkyl group, a cycloalkyl group, an aryl group, an alkynyl group, and an alkenyl group. R₀ is preferably a hydrogen atom or an alkyl group, and more preferably a hydrogen atom or a methyl group.

L₃ represents an (m+2) valent connecting group. That is, L₃ represents a tri- or higher valent connecting group. Examples of the connecting group include groups corresponding to specific examples listed below.

R^{L} represents an (n+1) valent connecting group. That is, R^{L} represents a di- or higher valent connecting group. Examples of the connecting group include an alkylene group, a cycloalkylene group, and groups corresponding to specific examples listed below. R^{L}'s may be bonded to each other to form a ring structure, or R^{L} may be bonded to R^{S} to form a ring structure.

R^{S} represents a substituent. Examples of the substituent include an alkyl group, an alkenyl group, an alkynyl group, an aryl group, an alkoxy group, an acyloxy group, an alkoxycarbonyl group, and a halogen atom.

n is an integer of 1 or greater, n is preferably an integer of 1 to 3, and more preferably 1 or 2. In addition, in a case where n is 2 or greater, dissolution contrast with respect to a developer including an organic solvent can be further improved. Accordingly, by doing this, marginal resolving power and roughness characteristics can be further improved.

m is an integer of 1 or greater. m is preferably an integer of 1 to 3, and more preferably 1 or 2.

l is an integer of 0 or greater. l is preferably 0 or 1.

p is an integer of 0 to 3.

Specific examples of the repeating unit having a group that generates an alcoholic hydroxy group by being decomposed due to the action of an acid will be described. Moreover, each of Ra and OP in the specific examples has the same meaning as that in General Formulas (I-1) to (I-3). In addition, in a case where a plurality of OP's may be bonded to each other to form a ring, the corresponding ring structure is represented as “O—P—O” for the sake of convenience.

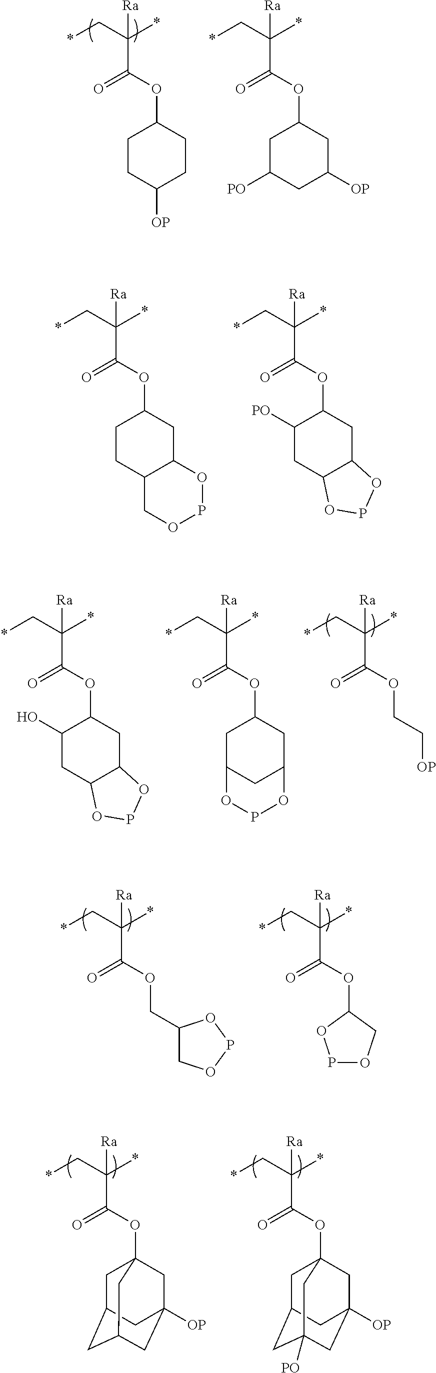

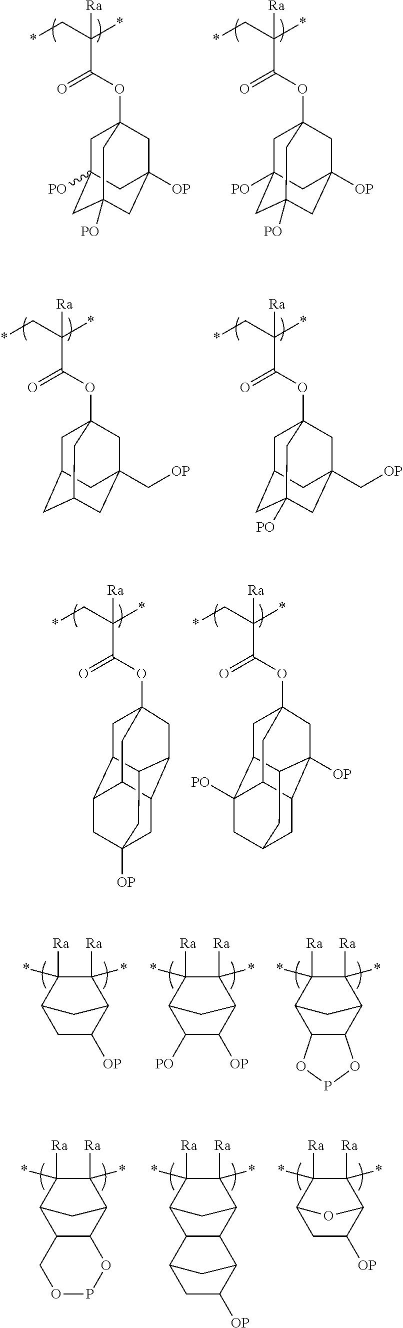

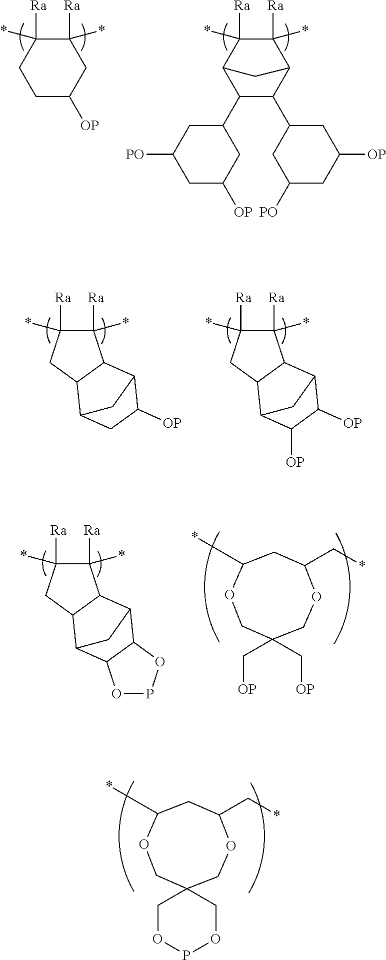

The group that generates an alcoholic hydroxy group by being decomposed due to the action of an acid is preferably represented by at least one selected from the group consisting of the following General Formulas (II-1) to (II-4).

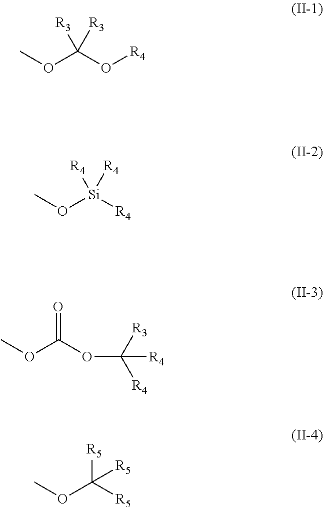

In the formulas, each of R₃'s independently represents a hydrogen atom or a monovalent organic group. R₃'s may be bonded to each other to form a ring.

Each of R₄'s independently represents a monovalent organic group. R₄'s may be bonded to each other to form a ring. R₃ and R₄ may be bonded to each other to form a ring.

Each of R₅'s independently represents a hydrogen atom, an alkyl group, a cycloalkyl group, an aryl group, an alkenyl group, or an alkynyl group. At least two of R₅'s may be bonded to each other to form a ring. Here, in a case where one or two of three R₅ are hydrogen atoms, at least one of the remaining R₅ represents an aryl group, an alkenyl group, or an alkynyl group.

The group that generates an alcoholic hydroxy group by being decomposed due to the action of an acid is also preferably represented by at least one selected from the group consisting of the following General Formulas (II-5) to (II-9).

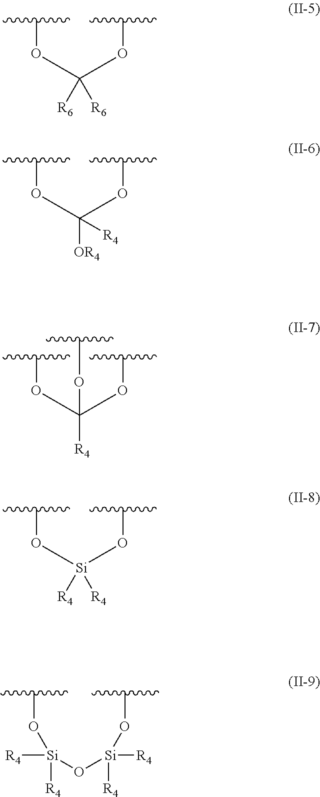

In the formulas, R₄ has the same meaning as that in General Formulas (II-1) to (II-3).

Each of R₆'s independently represents a hydrogen atom or a monovalent organic group. R₆'s may be bonded to each other to form a ring.

The group that generates an alcoholic hydroxy group by being decomposed due to the action of an acid is preferably represented by at least one selected from General Formulas (II-1) to (II-3), more preferably represented by General Formula (II-1) or (II-3), and particularly preferably represented by General Formula (II-1).

As described above, R₃ represents a hydrogen atom or a monovalent organic group. R₃ is preferably a hydrogen atom, an alkyl group, or a cycloalkyl group, and more preferably a hydrogen atom or an alkyl group.

The alkyl group represented by R₃ may be linear, or may be branched. The alkyl group represented by R₃ preferably has 1 to 10 carbon atoms, and more preferably has 1 to 3 carbon atoms. Examples of the alkyl group represented by R₃ include a methyl group, an ethyl group, an n-propyl group, an isopropyl group, and an n-butyl group.

The cycloalkyl group represented by R₃ may be monocyclic or polycyclic. The cycloalkyl group represented by R₃ preferably has 3 to 10 carbon atoms, and more preferably has 4 to 8 carbon atoms. Examples of the cycloalkyl group represented by R₃ include a cyclopropyl group, a cyclobutyl group, a cyclopentyl group, a cyclohexyl group, a norbornyl group, and an adamantyl group.

In addition, in General Formula (II-1), at least one of R₃'s is preferably a monovalent organic group. In a case where such a configuration is adopted, it is possible to achieve particularly higher sensitivity.

R₄ represents a monovalent organic group. R₄ is preferably an alkyl group or a cycloalkyl group, and more preferably an alkyl group. Each of these alkyl group and cycloalkyl group may have a substituent.

The alkyl group represented by R₄ preferably does not have a substituent or has one or more aryl groups and/or one or more silyl groups as a substituent. The unsubstituted alkyl group preferably has 1 to 20 carbon atoms. The alkyl group portion in the alkyl group substituted with one or more aryl groups preferably has 1 to 25 carbon atoms. The alkyl group portion in the alkyl group substituted with one or more silyl groups preferably has 1 to 30 carbon atoms. In addition, in a case where the cycloalkyl group represented by R₄ does not have a substituent, the cycloalkyl group preferably has 3 to 20 carbon atoms.

R₅ represents a hydrogen atom, an alkyl group, a cycloalkyl group, an aryl group, an alkenyl group, or an alkynyl group. Here, in a case where one or two of three R₅ are hydrogen atoms, at least one of the remaining R₅ represents an aryl group, an alkenyl group, or an alkynyl group. R₅ is preferably a hydrogen atom or an alkyl group. The alkyl group may have a substituent or may not have a substituent. In a case where the alkyl group does not have a substituent, the alkyl group preferably has 1 to 6 carbon atoms and more preferably has 1 to 3 carbon atoms.

As described above, R₆ represents a hydrogen atom or a monovalent organic group. R₆ is preferably a hydrogen atom, an alkyl group, or a cycloalkyl group, more preferably a hydrogen atom or an alkyl group, and still more preferably an alkyl group not having a hydrogen atom or a substituent. R₆ is preferably a hydrogen atom or an alkyl group having 1 to 10 carbon atoms and more preferably a hydrogen atom or an alkyl group not having a substituent, having 1 to 10 carbon atoms.

Moreover, examples of the alkyl group or the cycloalkyl group represented by R₄, R₅, or R₆ include the same as those described for R₃ above.

Specific examples of the group that generates an alcoholic hydroxy group by being decomposed due to the action of an acid will be described below.

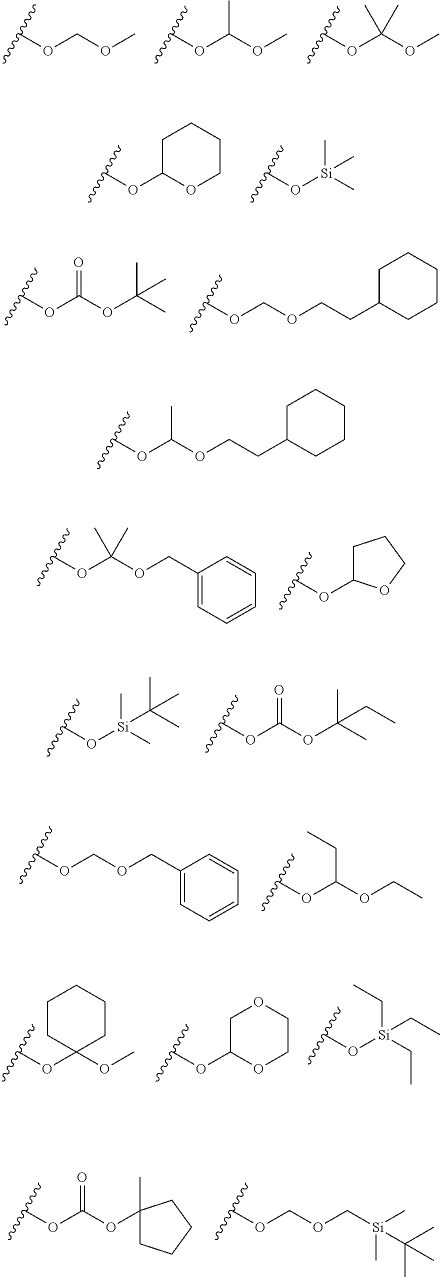

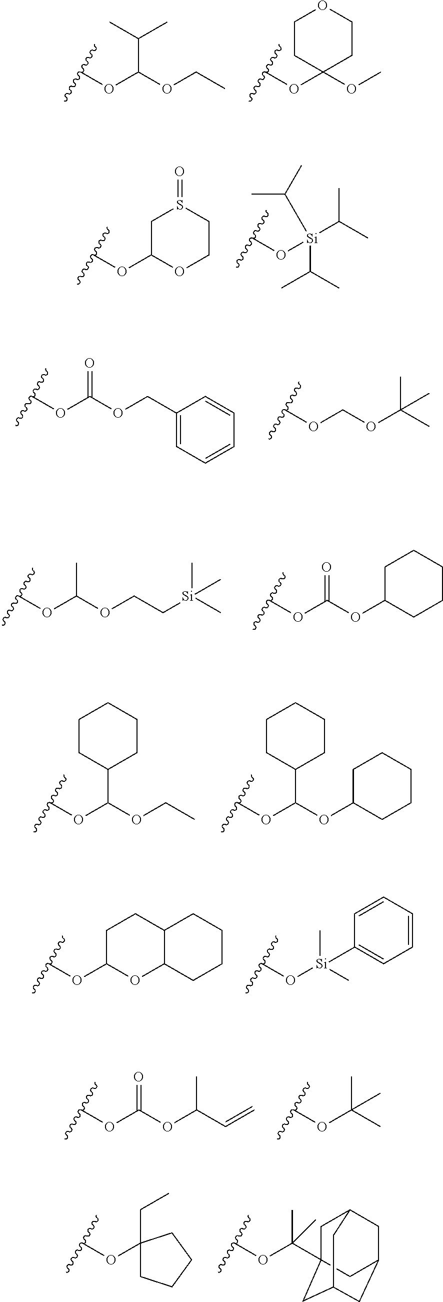

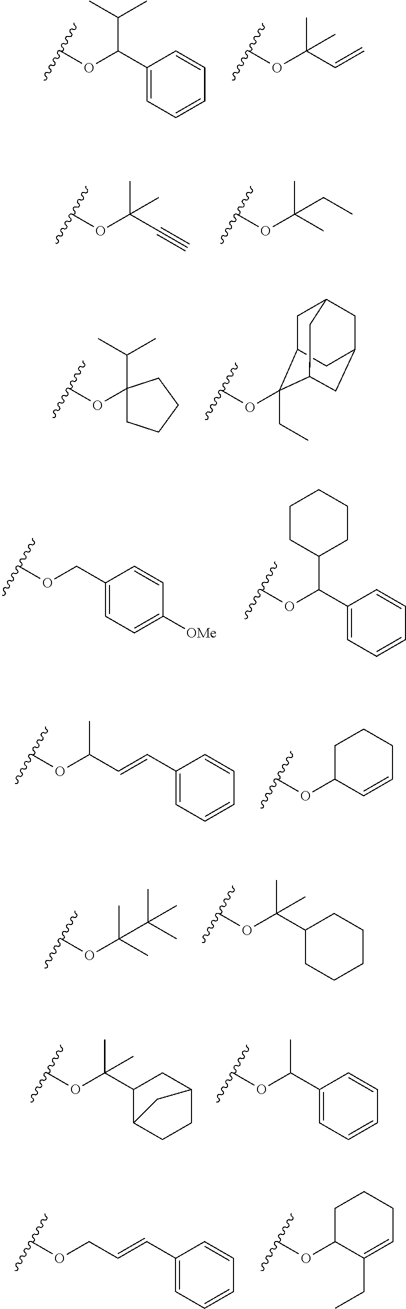

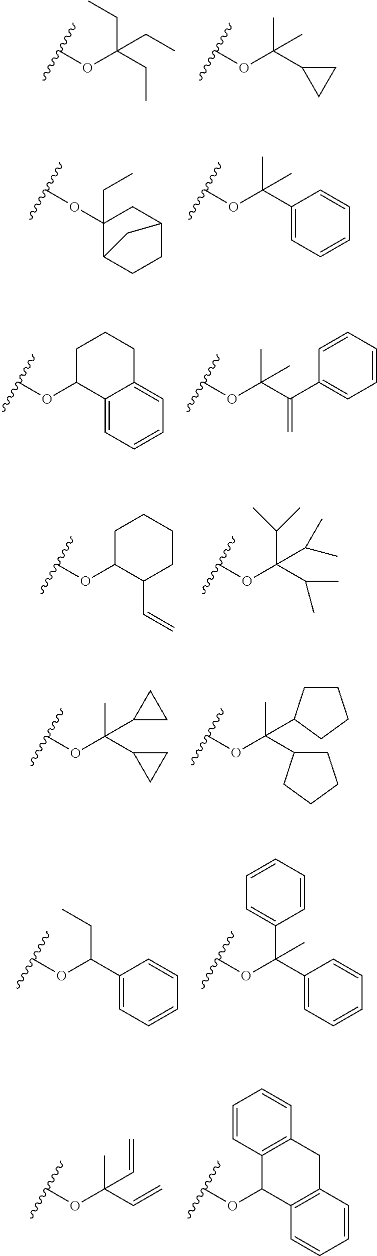

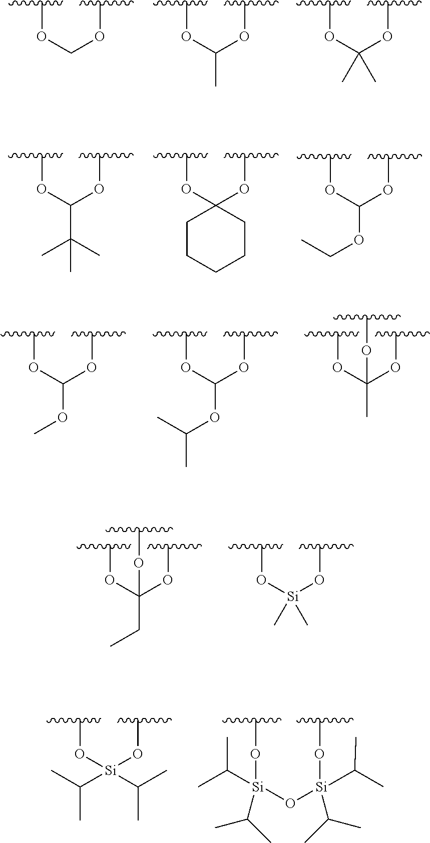

Specific examples of the repeating unit having a group that generates an alcoholic hydroxy group by being decomposed due to the action of an acid will be described below. In the specific examples, Xa₁ represents a hydrogen atom, CH₃, CF₃, or CH₂OH.

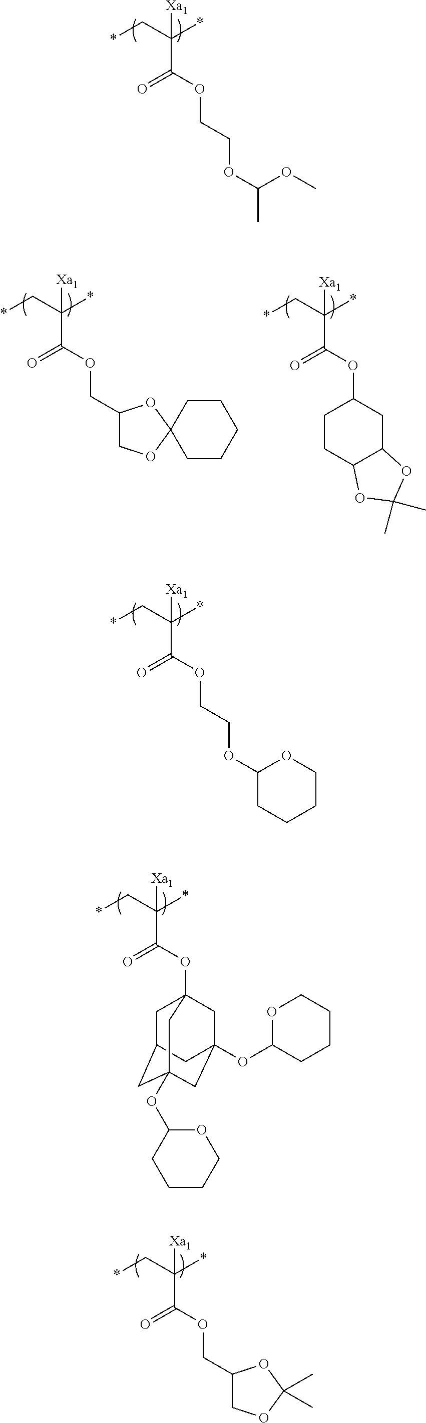

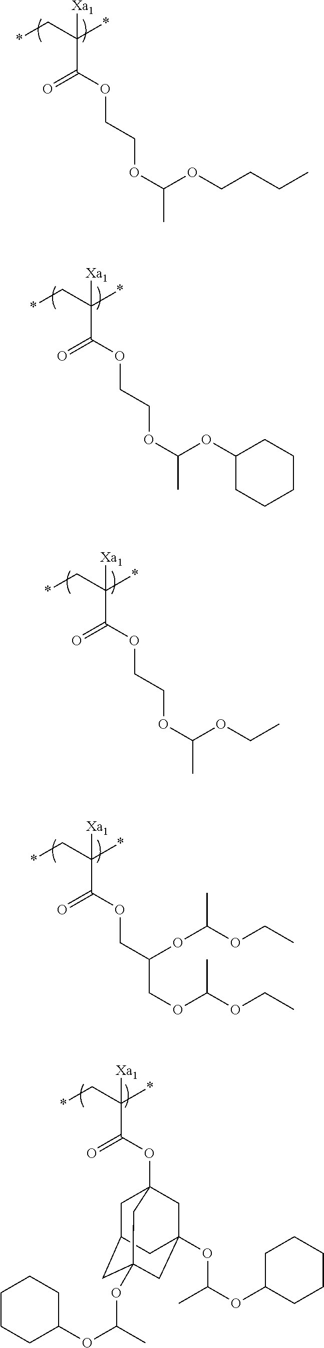

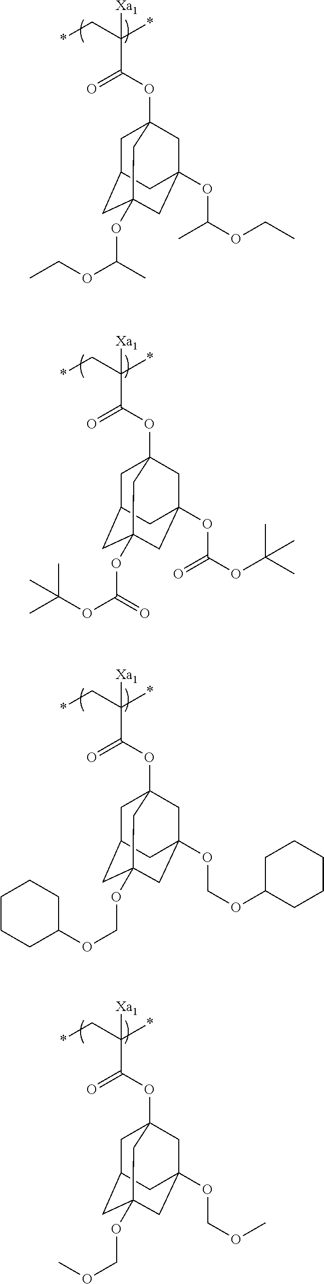

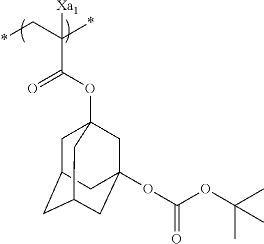

The resin (A) is preferably a resin having the repeating unit represented by General Formula (V), (VI), or (4) as the repeating unit (a) having an acid-decomposable group.

As a preferable form of the present invention, a form in which the resin (A) is a resin having the repeating unit represented by General Formula (VI) as the repeating unit (a) and using an alkali developer as a developer, a positive type guide pattern is formed.

In addition, as another preferable form of the present invention, a form in which the resin (A) is a resin having the repeating unit represented by General Formula (V) or (4) as the repeating unit (a) and using a developer containing an organic solvent as a developer, a negative type guide pattern is formed.

The repeating unit (a) having an acid-decomposable group may be one type, or two or more types thereof may be used in combination.

The content (in the case of containing a plurality of types, the total) of the repeating unit having an acid-decomposable group in the resin (A) is 15 mol % to 95 mol % and preferably 20 mol % to 95 mol %, with respect to the entirety of repeating units in the resin (A).

In particular, when performing organic solvent development, the content (in the case of containing a plurality of types, the total) of the repeating unit having an acid-decomposable group in the resin (A) is 20 mol % or greater and more preferably 45 mol % or greater with respect to the entirety of repeating units in the resin (A). In addition, the content of the repeating unit having an acid-decomposable is preferably 80 mol % or less and more preferably 75 mol % or less with respect to the entirety of repeating units in the resin (A).

(b) Repeating Unit Represented by General Formula (1)

In particular, in the case of irradiating with KrF excimer laser light, an electron beam, X-rays, or a high energy light beam having a wavelength of 50 nm or less (for example, EUV light), the resin (A) preferably has a repeating unit represented by the following General Formula (1).

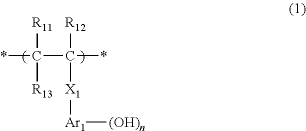

In General Formula (1), each of R₁₁, R₁₂, and R₁₃ independently represents a hydrogen atom, an alkyl group, a cycloalkyl group, a halogen atom, a cyano group, or an alkoxycarbonyl group. R₁₃ may be bonded to Ar₁ to form a ring, and R₁₃ in this case represents an alkylene group.

X₁ represents a single bond or a divalent connecting group.

Ar₁ represents an (n+1) valent aromatic ring group, and, in the case of being bonded to R₁₃ to form a ring, represents an (n+2) valent aromatic ring group.

n represents an integer of 1 to 4.

Specific examples of the alkyl group, the cycloalkyl group, the halogen atom, or the alkoxycarbonyl group, represented by each of R₁₁, R₁₂, and R₁₃ in Formula (1), or substituents which these groups can have are the same as those described for each group represented by R₅₁, R₅₂, and R₅₃ in General Formula (V).

Ar₁ represents an (n+1) valent aromatic ring group. The divalent aromatic ring group in a case where n is 1 may have a substituent, and preferable examples thereof include arylene groups having 6 to 18 carbon atoms such as a phenylene group, a tolylene group, a naphthylene group, and an anthracenylene group, and aromatic ring groups including a hetero ring, such as thiophene, furan, pyrrole, benzothiophene, benzofuran, benzopyrrole, triazine, imidazole, benzimidazole, triazole, thiadiazole, and thiazole.

Suitable specific examples of the (n+1) valent aromatic ring group in a case where n is an integer of 2 or greater can include a group obtained by excluding arbitrary (n−1) hydrogen atoms from the specific examples described above of the divalent aromatic ring group.

The (n+1) valent aromatic ring group may further have a substituent.

Examples of the substituent which the alkylene group or the (n+1) valent aromatic ring group described above can have include the alkyl group represented by each of R₅₁ to R₅₃ in General Formula (V), alkoxy groups such as a methoxy group, an ethoxy group, a hydroxyethoxy group, a propoxy group, a hydroxypropoxy group, and a butoxy group, and aryl groups such as a phenyl group.

Examples of the divalent connecting group represented by X₁ include —COO—, —OCO—, —CO—, —O—, —S—, —SO—, —SO₂—, —CONR— (in the formula, R represents a hydrogen atom or an alkyl group), an alkylene group (preferably having 1 to 6 carbon atoms), a cycloalkylene group (preferably having 3 to 10 carbon atoms), and alkenylene group (preferably having 2 to 6 carbon atoms), and divalent connecting groups formed by combining a plurality of these.

X₁ is preferably a single bond, —COO—, or —CONH—, and more preferably a single bond or —COO—.

Ar₁ is more preferably an aromatic ring group having 6 to 18 carbon atoms which may have a substituent, and particularly preferably a benzene ring group, a naphthalene ring group, or a biphenylene ring group.

The repeating unit (b) preferably has a hydroxystyrene structure.

That is, Ar₁ is preferably a benzene ring group.

n represents an integer of 1 to 4, preferably represents 1 or 2, and more preferably represents 1.

Specific examples of the repeating unit represented by General Formula (1) will be described below, but the present invention is not limited thereto. In the formula, a represents 1 or 2.

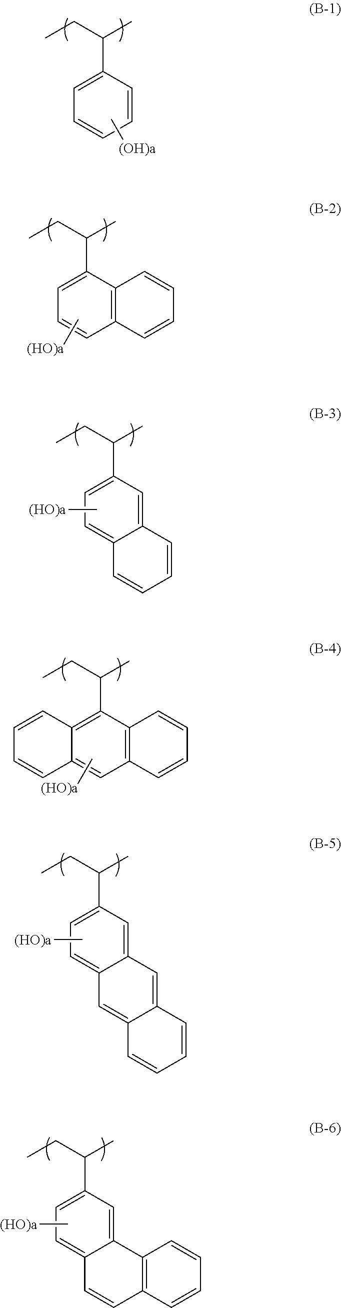

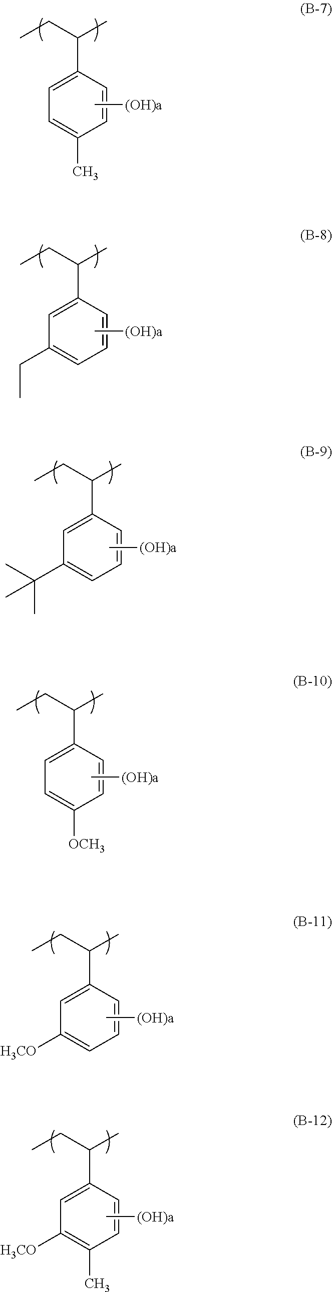

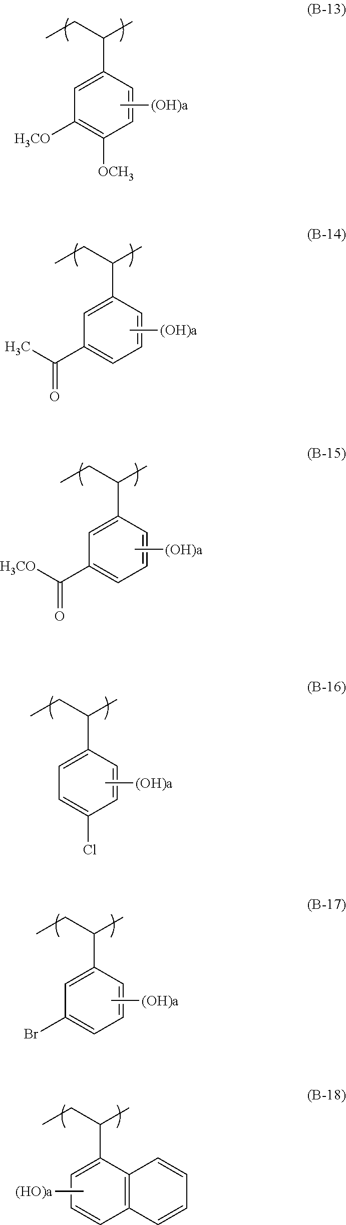

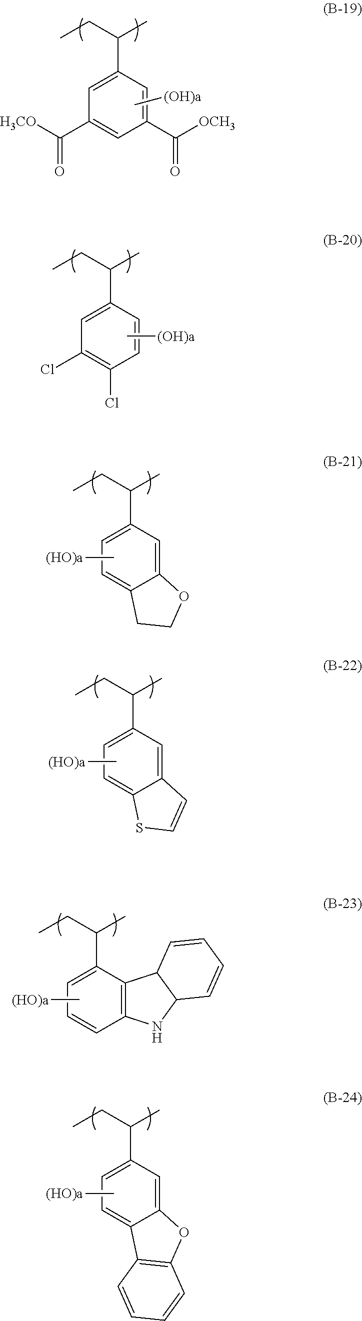

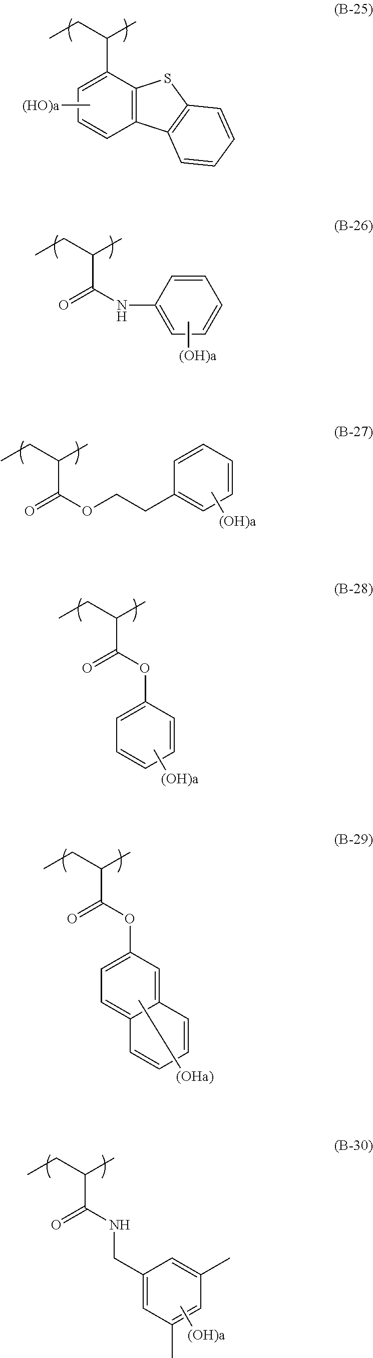

The resin (A) may include two or more types of the repeating unit represented by General Formula (1).

The content of the repeating unit represented by General Formula (1) (in the case of containing a plurality of types, the sum total content) is preferably within a range of 3 mol % to 98 mol %, more preferably within a range of 10 mol % to 80 mol %, and still more preferably within a range of 25 mol % to 70 mol %, with respect to the entirety of repeating units in the resin (A).

(c) Repeating Unit Having Polar Group Other than Repeating Unit Represented by General Formula (1)

The resin (A) preferably includes a repeating unit (c) having a polar group. By including the repeating unit (c), for example, the sensitivity of the active light sensitive or radiation sensitive resin composition can be improved. The repeating unit (c) is preferably a non-acid-decomposable repeating unit (that is, a repeating unit which does not have an acid-decomposable group).

Regarding “polar group” which can be included in the repeating unit (c) and the repeating unit having the polar group, the description in paragraphs “0149” to “0157” of JP2013-76991A can be referred to, and the contents thereof are incorporated in the present specification.

In a case where the repeating unit (c) has an alcoholic hydroxy group or a cyano group as a polar group, as one aspect of a preferable repeating unit, a repeating unit having an alicyclic hydrocarbon structure substituted with a hydroxyl group or a cyano group is exemplified. At this time, an acid-decomposable group is not preferably included. As the alicyclic hydrocarbon structure in the alicyclic hydrocarbon structure substituted with a hydroxyl group or a cyano group, an adamantyl group, a diamantyl group, or a norbornane group is preferable. As a preferable alicyclic hydrocarbon structure substituted with a hydroxyl group or a cyano group, substructures represented by the following General Formulas (VIIa) to (VIIc) are preferable. Thus, adhesion to a substrate and developer affinity are improved.

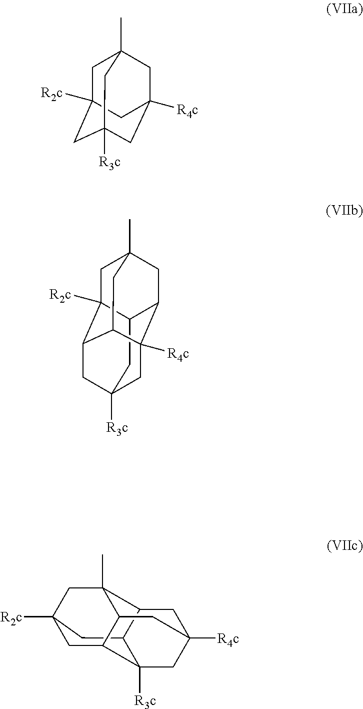

In General Formulas (VIIa) to (VIIc), each of R₂c to R₄c independently represents a hydrogen atom, a hydroxyl group, or a cyano group. Here, at least one of R₂c to R₄c is a hydroxyl group. Preferably, one or two of R₂c to R₄c are hydroxyl groups, and the other is a hydrogen atom. In General Formula (VIIa), more preferably, two of R₂c to Rac are hydroxyl groups, and the other is a hydrogen atom.

As a repeating unit having a substructure represented by each of General Formulas (VIIa) to (VIIc), the repeating units represented by the following General Formulas (AIIa) to (AIIc) can be exemplified.

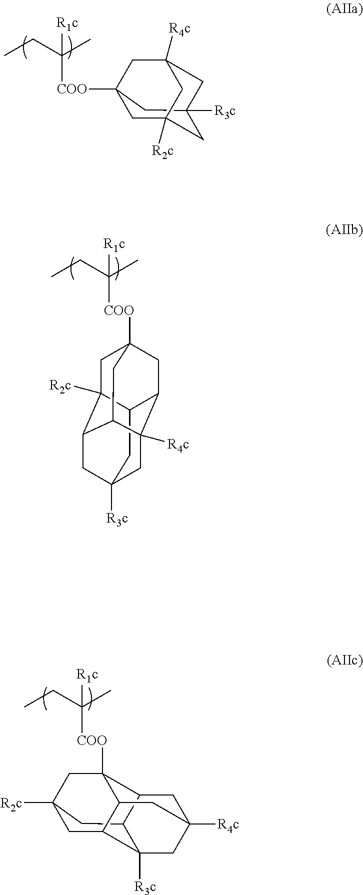

In General Formulas (AIIa) to (AIIc). R₁c represents a hydrogen atom, a methyl group, a trifluoromethyl group, or a hydroxymethyl group.

R₂c to R₄c have the same meaning as R₂c to R₄c in General Formulas (VIIa) to (VIIc), respectively.

Although the resin (A) may contain or may not contain a repeating unit having a hydroxyl group or a cyano group, in a case where the resin (A) contains the repeating unit, the content of the repeating unit having a hydroxyl group or a cyano group is preferably 1 mol % to 60 mol %, more preferably 3 mol % to 50 mol %, and still more preferably 5 mol % to 40 mol %, with respect to the entirety of repeating units in the resin (A).

Specific examples of the repeating unit having a hydroxyl group or a cyano group are described below, but the present invention is not limited thereto.

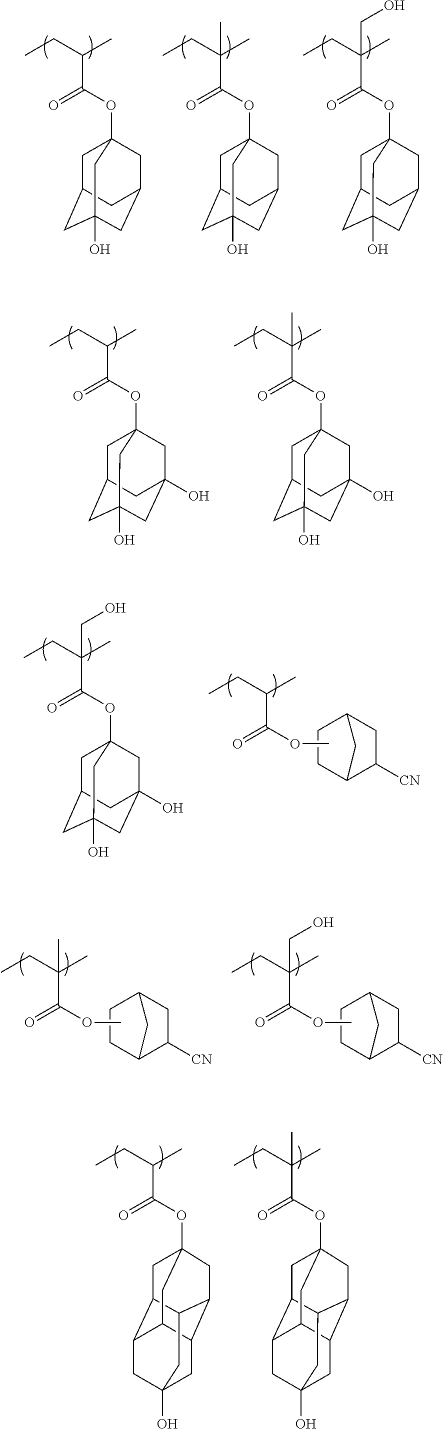

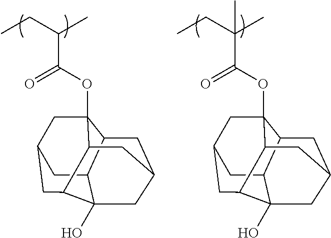

The repeating unit (c) may be a repeating unit having a lactone structure as a polar group.

As the repeating unit having a lactone structure, a repeating unit represented by the following General Formula (AII) is more preferable.

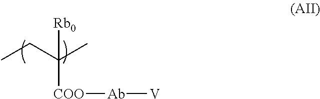

In General Formula (AII), Rb₀ represents a hydrogen atom, a halogen atom, or an alkyl group (preferably having 1 to 4 carbon atoms) which may have a substituent.

Preferable examples of the substituent which the alkyl group represented by Rb₀ may have include a hydroxyl group and a halogen atom. Examples of the halogen atom represented by Rb₀ include a fluorine atom, a chlorine atom, a bromine atom, and an iodine atom. Rb₀ is preferably a hydrogen atom, a methyl group, a hydroxymethyl group, or a trifluoromethyl group, and particularly preferably a hydrogen atom or a methyl group.

Ab represents a single bond, an alkylene group, a divalent connecting group having a monocyclic or polycyclic cycloalkyl structure, an ether bond, an ester bond, a carbonyl group, or a divalent connecting group obtained by combining these. Ab is preferably a single bond or a divalent connecting group represented by -Ab₁-CO₂—.

Ab₁ is a linear or branched alkylene group or a monocyclic or polycycliccy cloalkylene group, and preferably a methylene group, an ethylene group, a cyclohexylene group, an adamantylene group, or a norbornylene group.

V represents a group having a lactone structure.

As the group having a lactone structure, any group can be used as long as the group has a lactone structure, but the group preferably has a 5- to 7-membered ring lactone structure. It is preferable that another ring structure be condensed with the 5- to 7-membered ring lactone structure while forming a bicyclo structure or a spiro structure. The group more preferably has a repeating unit having a lactone structure represented by any one of the following General Formulas (LC1-1) to (LC1-17). In addition, the lactone structure may be directly bonded to the main structure. A preferable structure is (LC1-1), (LC1-4), (LC1-5), (LC1-6), (LC1-8), (LC1-13), or (LC1-14).

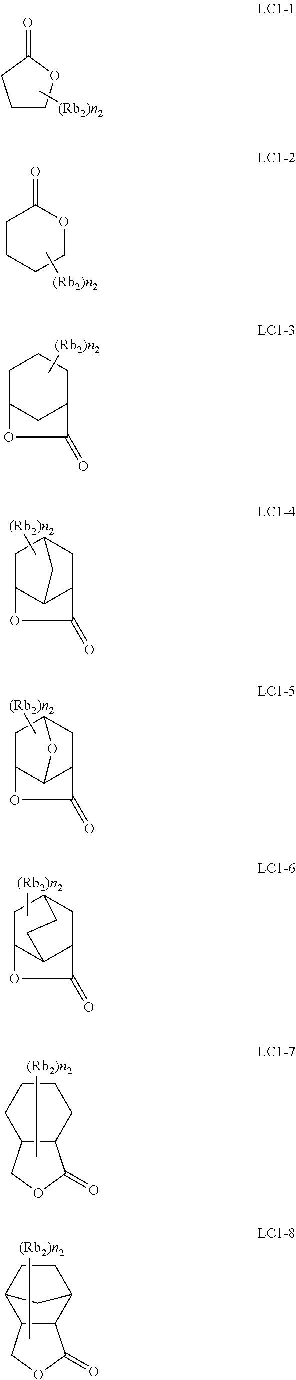

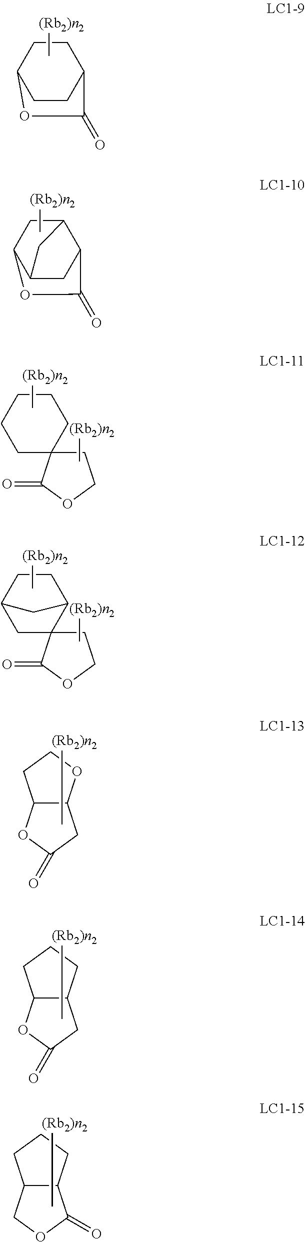

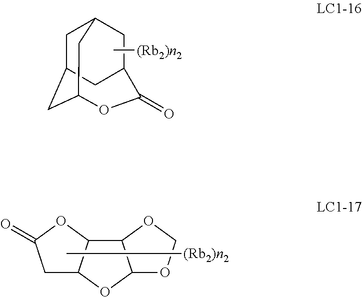

The lactone structure portion may have or may not have a substituent (Rb₂). Preferable examples of the substituent (Rb₂) include an alkyl group having 1 to 8 carbon atoms, a monovalent cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, and an acid-decomposable group. The substituent (Rb₂) is more preferably an alkyl group having 1 to 4 carbon atoms, a cyano group, or an acid-decomposable group. n₂ represents an integer of 0 to 4. When n₂ is 2 or greater, a plurality of substituents (Rb₂) present in a molecule may be the same as or different from each other, and a plurality of substituents (Rb₂) present in a molecule may be bonded to each other to form a ring.

The repeating unit having a lactone group typically has optical isomers, and any optical isomer may be used. In addition, one type of optical isomers may be used alone, or two or more types of optical isomers may be used in combination. In a case where one type of optical isomers is mainly used, the optical purity (ee) is preferably 90% or greater, and more preferably 95% or greater.

The resin (A) may contain or may not contain a repeating unit having a lactone structure, and in a case where the resin (A) contains the repeating unit having a lactone structure, the content of the repeating unit in the resin (A) is preferably within a range of 1 mol % to 70 mol %, more preferably within a range of 3 mol % to 65 mol %, and still more preferably within a range of 5 mol % to 60 mol %, with respect to the entirety of repeating units.

Specific examples of the repeating unit having a lactone structure in the resin (A) are shown below, but the present invention is not limited thereto. In the formulas, Rx represents H, CH₃, CH₂OH, or CF₃.

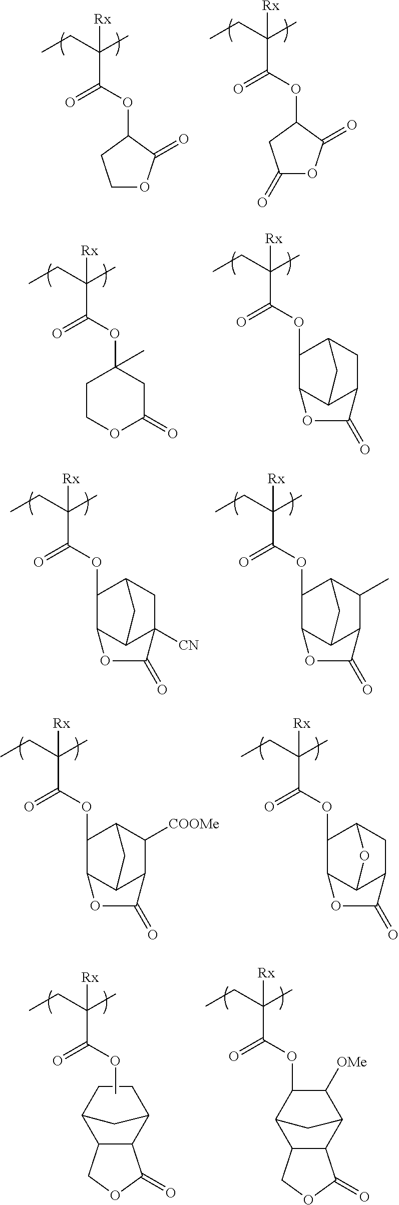

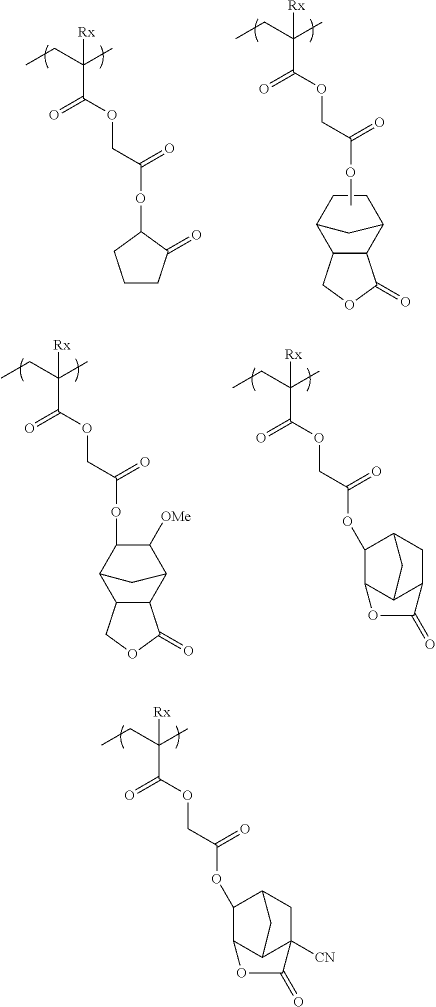

In addition, the repeating unit (c) may be a repeating unit having a sultone structure as a polar group.

As the sultone structure, a structure represented by the following General Formula (SL1-1) or (SL1-2). Rb₂ and n₂ in the formula have the same definition as those in General Formulas (LC1-1) to (LC1-17), respectively.

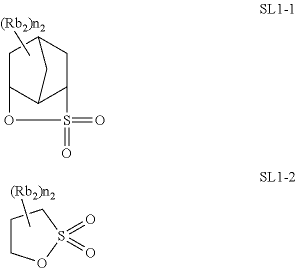

As the repeating unit including a sultone group which the resin (A) has, a repeating unit formed by substituting the lactone group in the repeating unit having an lactone group described above with a sultone group is preferable.

The repeating unit (c) may be a repeating unit having a cyclic carbonic acid ester structure as a polar group.

The repeating unit having a cyclic carbonic acid ester structure is preferably the repeating unit represented by the following General Formula (A-1).

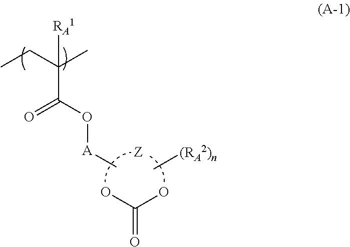

In General Formula (A-1), R_{A}¹ represents a hydrogen atom or an alkyl group.

In a case where n of R_{A2} is 2 or greater, each of R_{A}²'s independently represents a substituent.

A represents a single bond or a divalent connecting group.

Z represents an atomic group which forms a monocyclic or polycyclic structure together with a group represented by —O—C(—O)—O— in the formula.

n represents an integer of 0 or greater.

General Formula (A-1) will be described in detail.

The alkyl group represented by R_{A}¹ may have a substituent such as a fluorine atom. R_{A}¹ is preferably a hydrogen atom, a methyl group, or a trifluoromethyl group, and more preferably a methyl group.

The substituent represented by R_{A}², for example, is an alkyl group, a cycloalkyl group, a hydroxyl group, an alkoxy group, an amino group, or an alkoxycarbonylamino group. As the substituent, an alkyl group having 1 to 5 carbon atoms is preferable, and examples thereof can include a linear alkyl group having 1 to 5 carbon atoms; and a branched alkyl group having 3 to 5 carbon atoms. The alkyl group may have a substituent such as a hydroxyl group.

n is an integer of 0 or greater, which represents the number of substituents. For example, n is preferably 0 to 4, and more preferably 0.

Examples of the divalent connecting group represented by A include an alkylene group, a cycloalkylene group, an ester bond, an amide bond, an ether bond, a urethane bond, a urea bond, and combinations thereof. As the alkylene, an alkylene group having 1 to 10 carbon atoms is preferable, and an alkylene group having 1 to 5 carbon atoms is more preferable.

In a form of the present invention, A is preferably a single bond or an alkylene group.

As a monocycle including —OC(═O)—O—, represented by Z, a 5- to 7-membered ring having n_{A} of 2 to 4, in the cyclic carbonic acid ester represented by the following General Formula (a), is exemplified, and a 5-membered ring or a 6-membered ring (n_{A}=2 or 3) is preferable, and 5-membered ring (n_{A}=2) is more preferable.

As a polycycle including —OC(═O)—O—, represented by Z, a structure in which a fused ring is formed by a cyclic carbonic acid ester represented by the following General Formula (a) together with a further or two more ring structures or a structure in which a spiro ring is formed is exemplified. “Other ring structures” capable of forming a fused ring or a spiro ring may be an alicyclic hydrocarbon group, may be an aromatic hydrocarbon group, or may be a heterocycle.

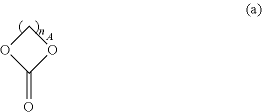

The resin (A) may include one type of repeating units having a cyclic carbonic acid ester structure, or may include two or more types thereof.

In the resin (A), the content of the repeating unit having a cyclic carbonic acid ester structure (preferably, the repeating unit represented by General Formula (A-1)) is preferably 3 mol % to 80 mol %, more preferably from 3 mol % to 60 mol %, particularly preferably 3 mol % to 30 mol %, and most preferably from 10 mol % to 15 mol/%, with respect to the entirety of repeating units configuring the resin (A). In a case where the content is within the above range, developability, low defectivity, low LWR, low PEB temperature dependence, and profile in formation of a guide pattern can be improved.

Specific examples of the repeating unit represented by General Formula (A-1) will be described below, but the present invention is not limited thereto.

Moreover, R_{A}¹ in the following specific examples has the same meaning as R_{A}¹ in General Formula (A-1).

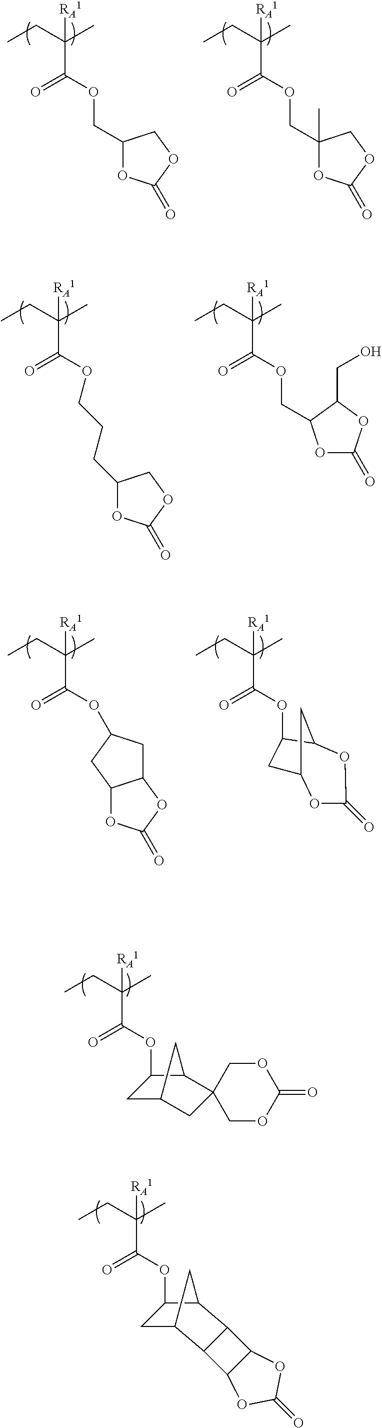

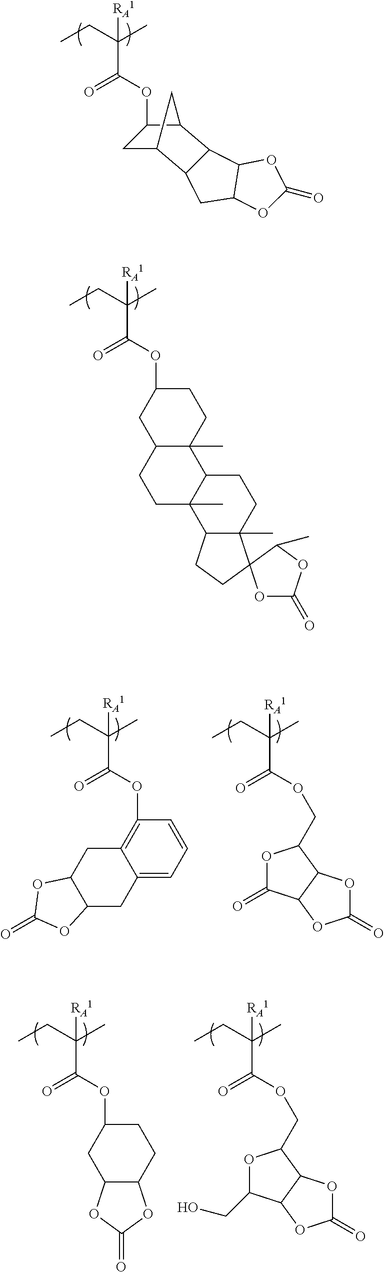

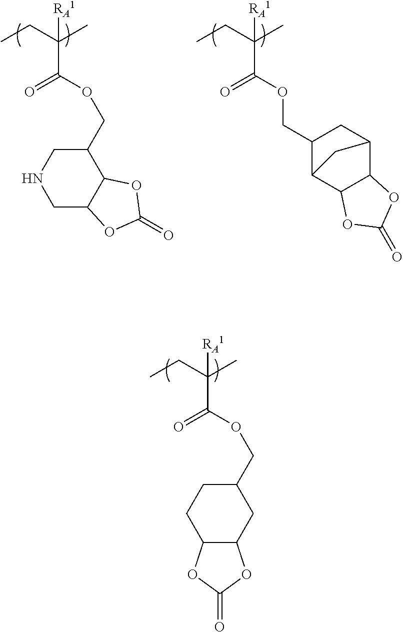

In addition, it is also a particularly preferable aspect that a polar group which the repeating unit (c) can have is an acidic group. Preferable examples of the acidic group include a phenolic hydroxyl group, a carboxylic acid group, a sulfonic acid group, a fluorinated alcohol group (for example, a hexafluoroisopropanol group), a sulfonamide group, a sulfonyl imide group, a (alkylsulfonyl)alkylcarbonyl)methylene group, a (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group. Among these, the repeating unit (c) is more preferably a repeating unit having a carboxyl group. Due to a repeating unit having an acidic group being contained, resolution in contact hole use increases. Examples of the repeating unit having an acidic group include a repeating unit of which an acidic group is directly bonded to the main chain of a resin as a repeating unit by acrylic acid or methacrylic acid and a repeating unit of which an acidic group is bonded to the main chain of a resin through a connecting group, and any repeating unit introduced to a terminal of a polymer chain using a polymerization initiator or a chain transfer agent having an acidic group at the time of polymerization is preferable. A repeating unit by acrylic acid or methacrylic acid is particularly preferable.

The acidic group which the repeating unit (c) can have may include or may not include an aromatic ring, and in a case where the acidic group has an aromatic ring, the acidic group is preferably selected from acidic groups other than a phenolic hydroxyl group. In a case where the repeating unit (c) has an acidic group, the content of the repeating unit having an acidic group is preferably 30 mol % or less, and more preferably 20 mol % or less, with respect to the entirety of repeating units in the resin (A). In a case where the resin (A) contains a repeating unit having an acidic group, the content of the repeating unit having an acidic group in the resin (A) is typically 1 mol % or greater.

Specific examples of the repeating unit having an acidic group are shown below, but the present invention is not limited thereto.

In the specific examples, Rx represents H, CH₃, CH₂OH, or CF₃.

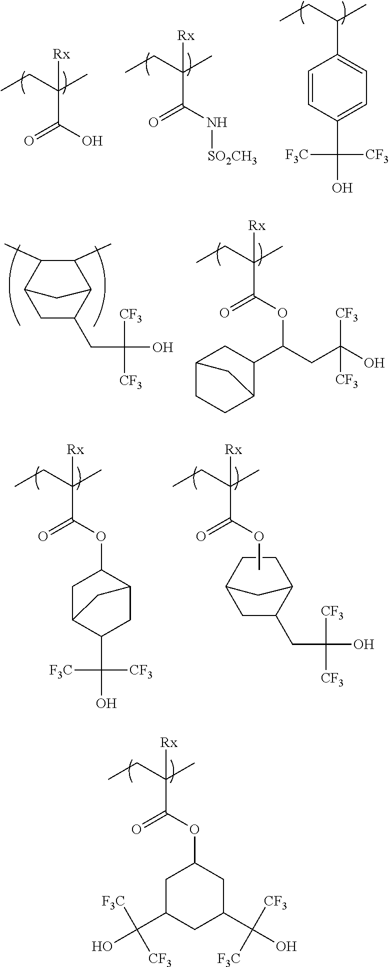

(d) Repeating Unit Having Plurality of Aromatic Rings

The resin (A) may have a repeating unit (d) having a plurality of aromatic rings.

Regarding the repeating unit (d) having a plurality of aromatic rings, the description in paragraphs “0194” to “0207” of JP2013-76991A can be referred to, and the contents thereof are incorporated in the present specification.

The resin (A) may contain or may not contain the repeating unit (d), and in a case where the resin (A) contains the repeating unit (d), the content of the repeating unit (d) is preferably within a range of 1 mol % to 30 mol %, more preferably within a range of 1 mol % to 20 mol %, and still more preferably within a range of 1 mol % to 15 mol/o, with respect to the entirety of repeating units in the resin (A). The repeating unit (d) included in the resin (A) may be included in combination of two or more types thereof.

The resin (A) in the present invention may suitably have a repeating unit other than the repeating units (a) to (d). One example of such a repeating unit is a repeating unit which has an alicyclic hydrocarbon structure without a polar group (for example, an acid group, a hydroxyl group, or a cyano group described above) and does not exhibit acid-decomposability. Thus, the solubility of a resin is suitably adjusted in development using a developer including an organic solvent. As such a repeating unit, the repeating unit represented by General Formula (IV) is exemplified.

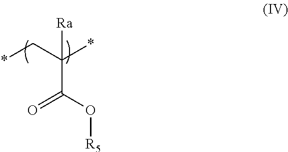

In General Formula (IV), R₅ has at least one ring structure, and represents a hydrocarbon group not having a polar group.

Ra represents a hydrogen atom, an alkyl group, or a CH₂—O—Ra₂ group. In the formula, Ra₂ represents a hydrogen atom, an alkyl group, or an acyl group. Ra is preferably a hydrogen atom, a methyl group, a hydroxymethyl group, or a trifluoromethyl group, and particularly preferably a hydrogen atom or a methyl group.

Regarding the respective groups in General Formula (IV), the description in paragraphs “0212” to “0216” of JP2013-76991A can be referred to, and the contents thereof are incorporated in the present specification.

Although the resin (A) may contain or may not contain a repeating unit which has an alicyclic hydrocarbon structure without a polar group and does not exhibit acid-decomposability, in a case where the resin (A) contains the repeating unit, the content of the repeating unit is preferably 1 mol % to 20 mol %, and more preferably 5 mol % to 15 mol %, with respect to the entirety of repeating units in the resin (A).

Specific examples of the repeating unit which has an alicyclic hydrocarbon structure without a polar group and does not exhibit acid-decomposability are shown below, but the present invention is not limited thereto. In the formulas, Ra represents H, CH₃, CH₂OH, or CF₃.

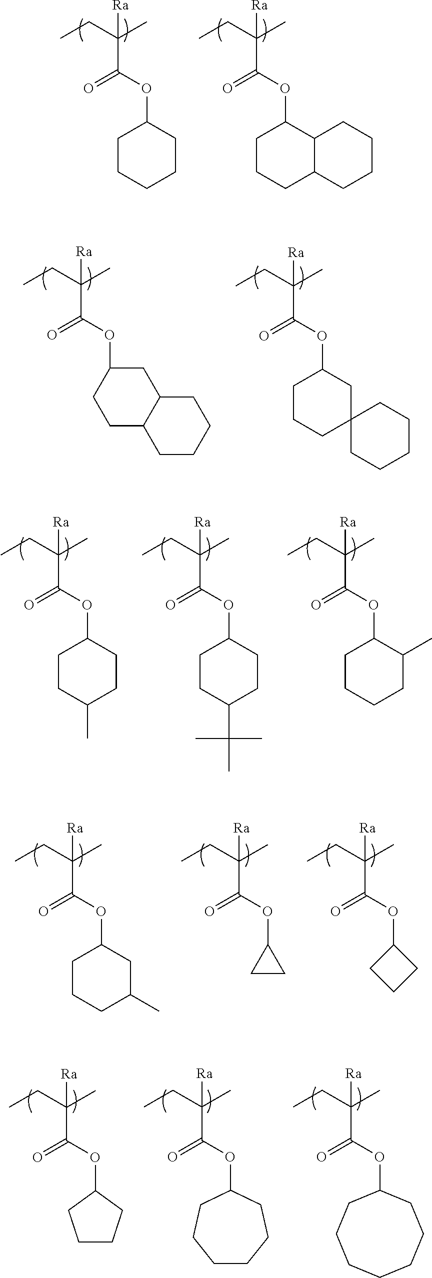

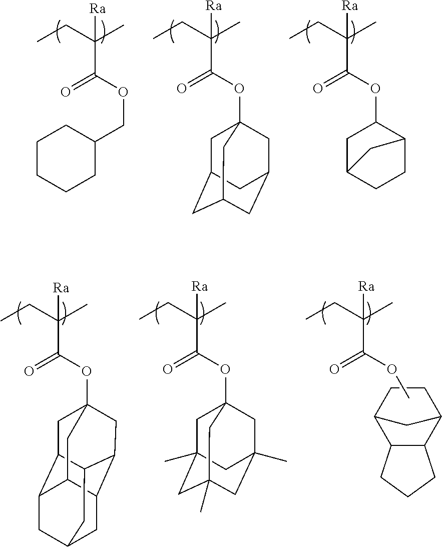

In addition, the resin (A) may further include a repeating unit represented by the following General Formula (5).

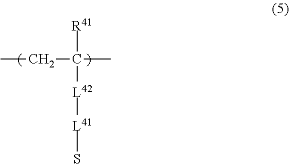

R⁴¹ represents a hydrogen atom or a methyl group. L⁴¹ represents a single bond or a divalent connecting group. L⁴² represents a divalent connecting group. S represents a structural portion on a side chain that generates an acid by being decomposed by irradiation with active light or radiation.

Specific examples of the repeating unit represented by General Formula (5) will be described below, but the present invention is not limited thereto. Regarding specific examples of the repeating unit represented by General Formula (5), the description in paragraphs “0168” to “0210” of JP2013-80002A and “0191” to “0203” of JP2013-137537A can be referred to, and the contents thereof are incorporated in the present specification.

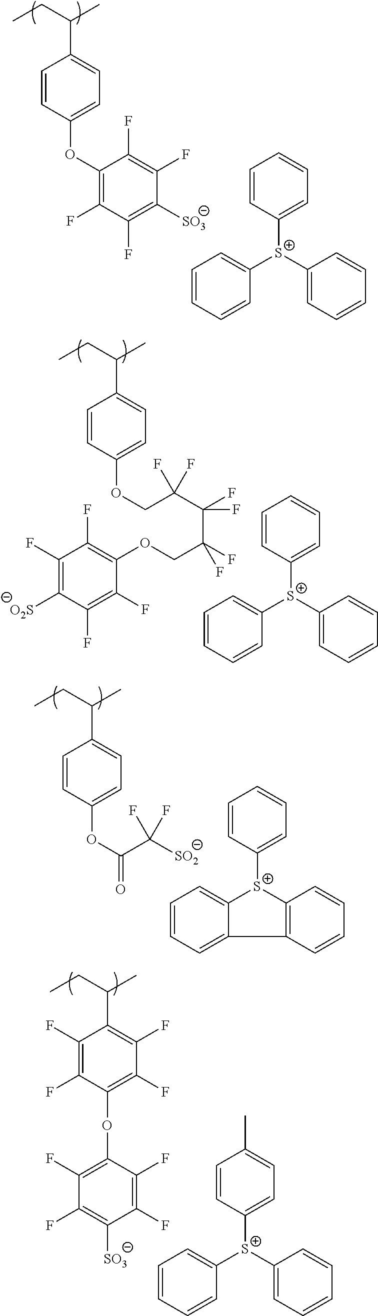

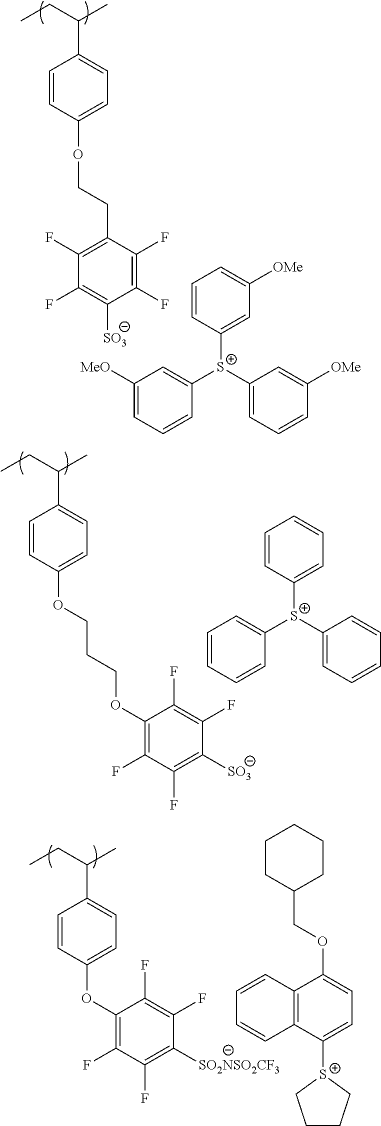

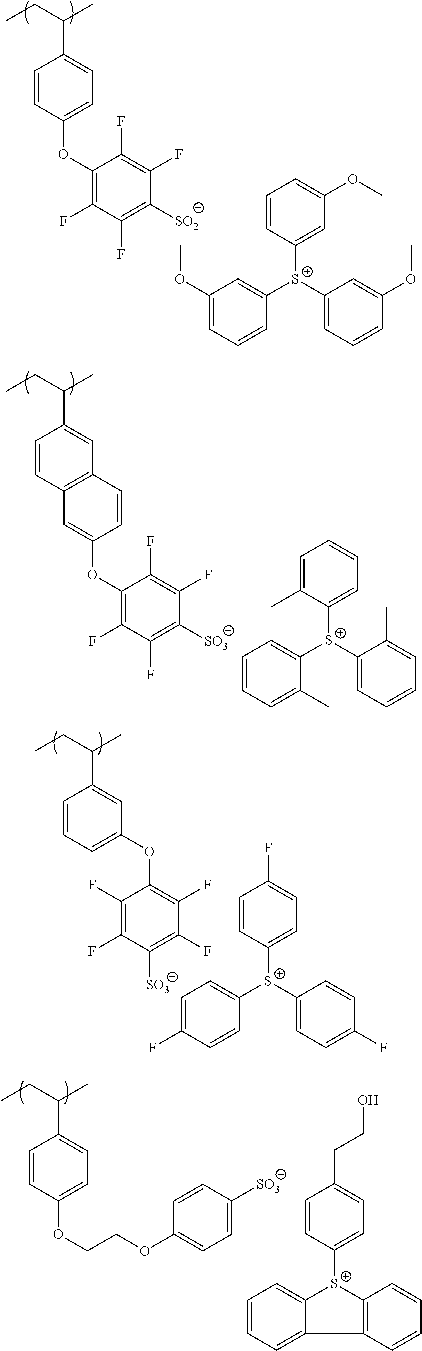

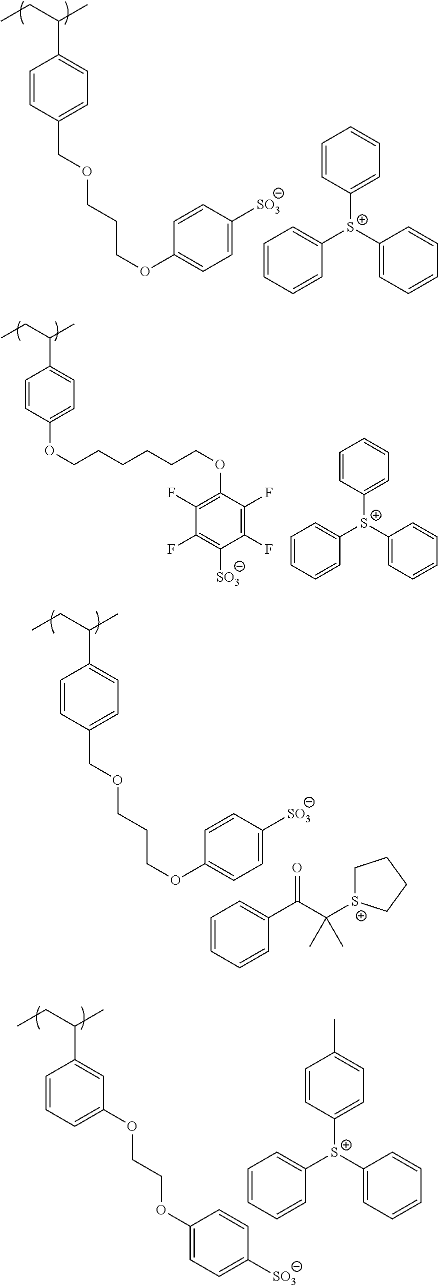

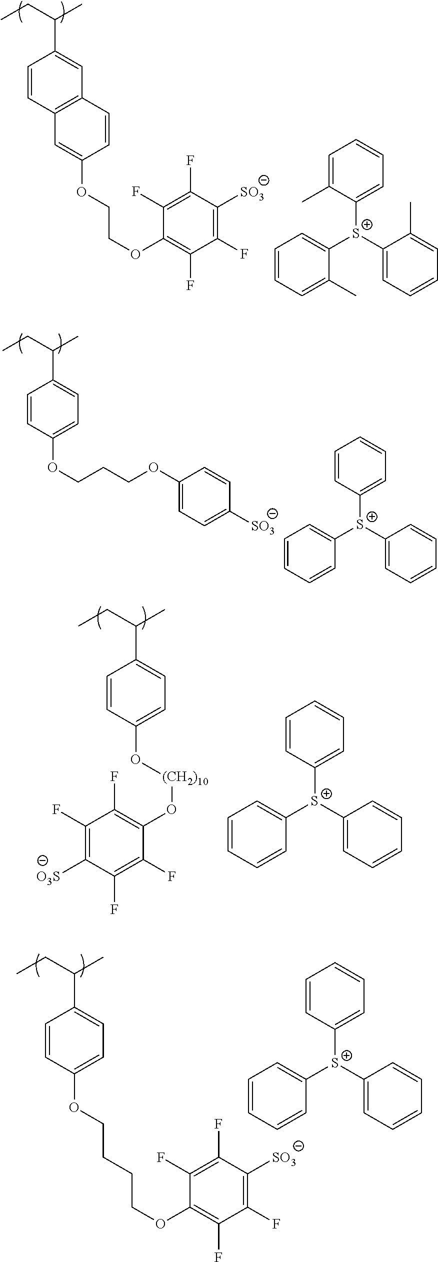

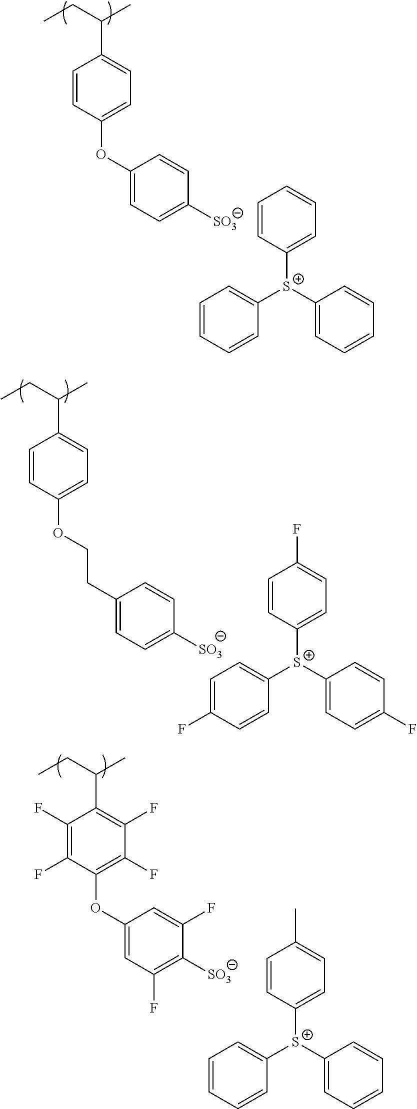

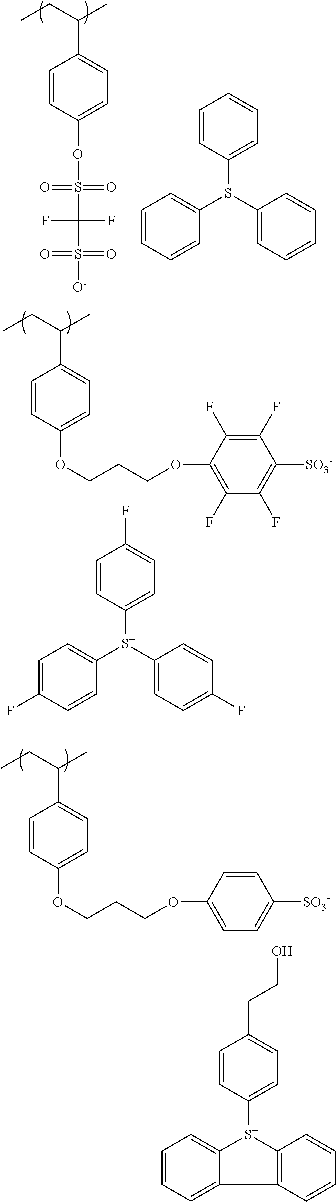

The content of the repeating unit represented by General Formula (5) in the resin (A) is preferably within a range of 1 mol % to 40 mol %, more preferably within a range of 2 mol % to 30 mol %, and particularly preferably within a range of 5 mol % to 25 mol %, with respect to the entirety of repeating units in the resin (A).

In addition, the resin (A) may include the following monomer component in consideration of rise of Tg, improvement of dry etching resistance, and effect of an internal filter with respect to the out of band light described above.

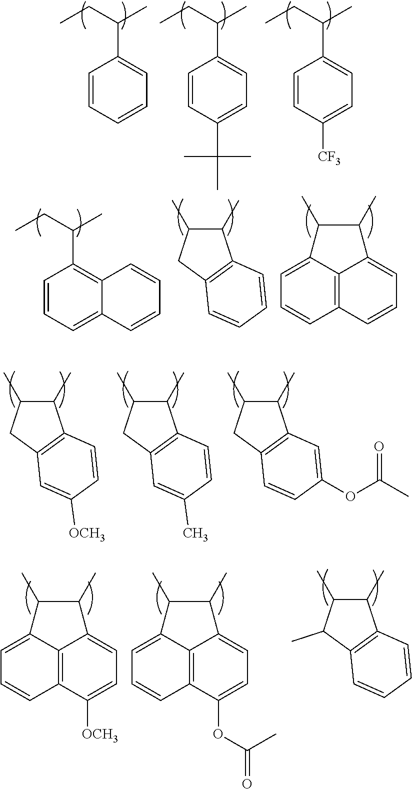

In the resin (A), the content molar ratio of respective repeating structural units is suitably set to adjust dry etching resistance or standard developer suitability of a resist, adhesion to substrate, a resist profile, and resolving power, heat resistance, and sensitivity which are properties generally required for a resist.

Specific examples of the resin (A) will be shown below, but the present invention is not limited thereto.

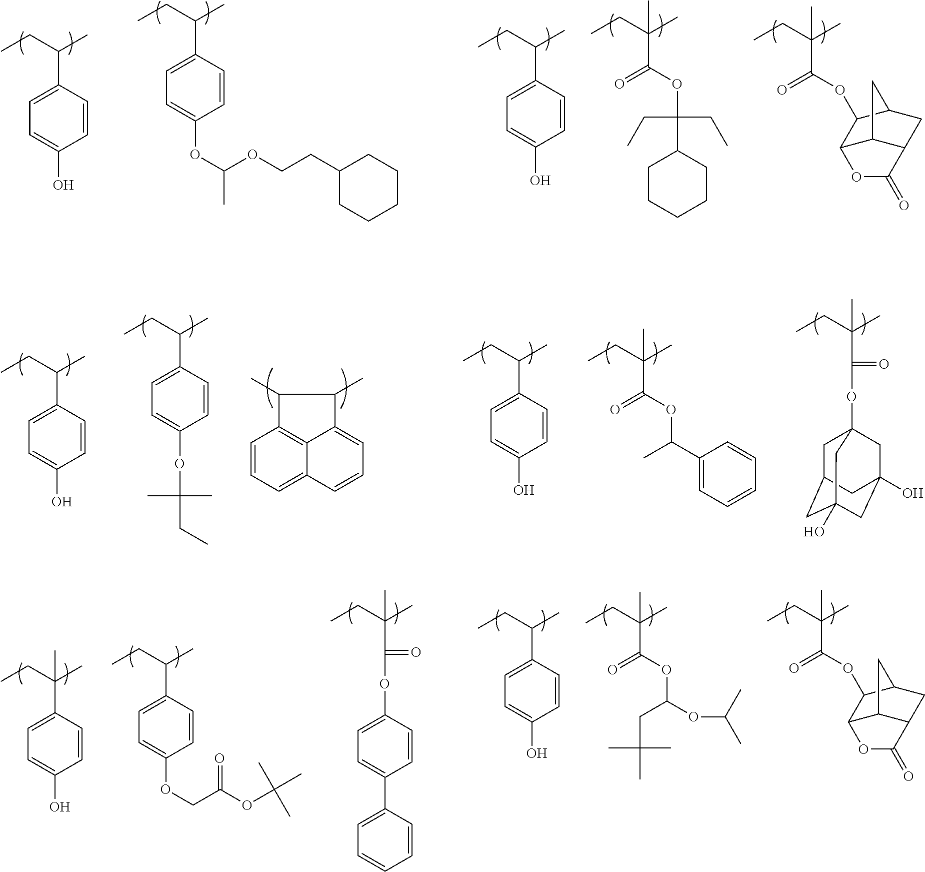

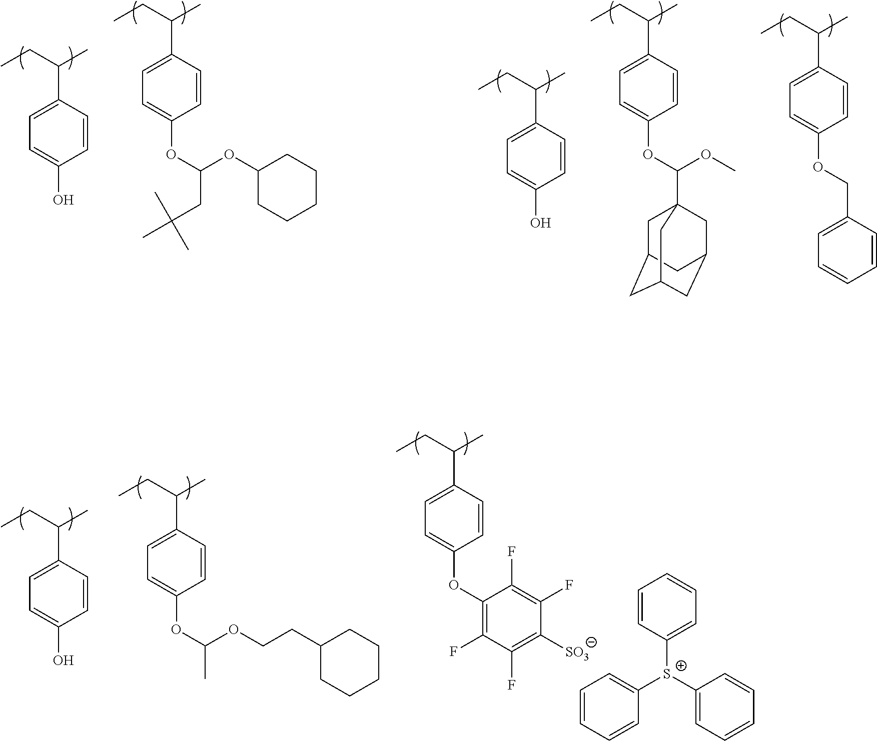

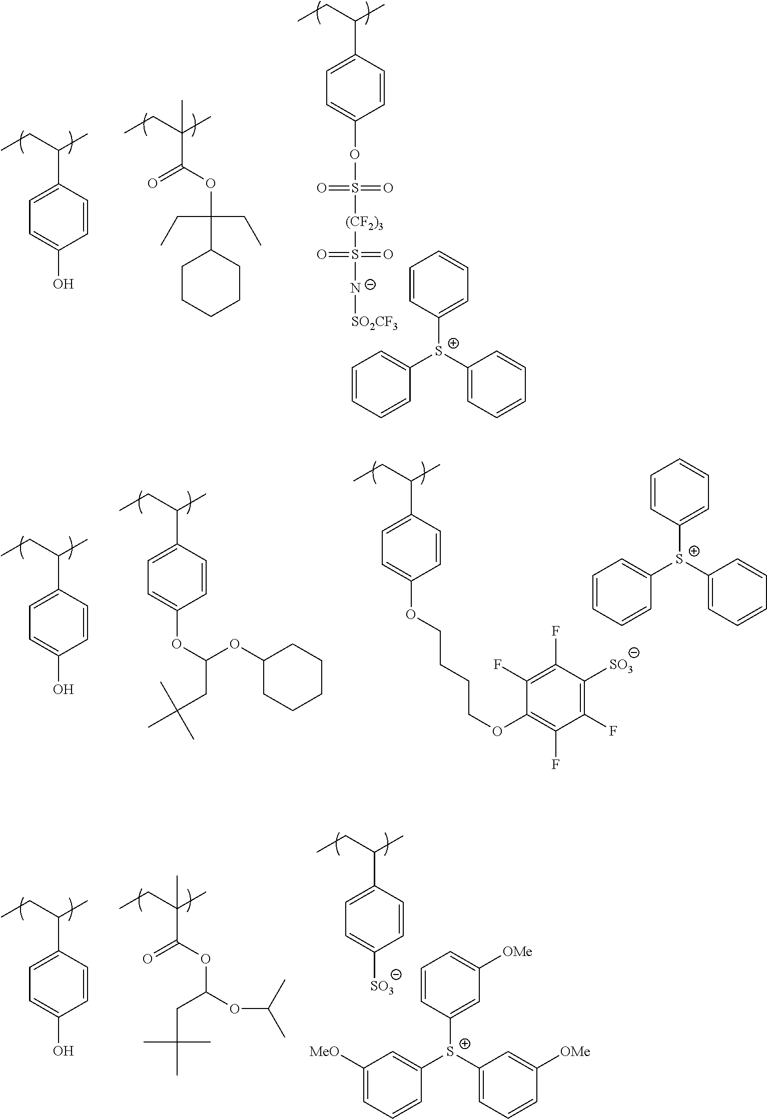

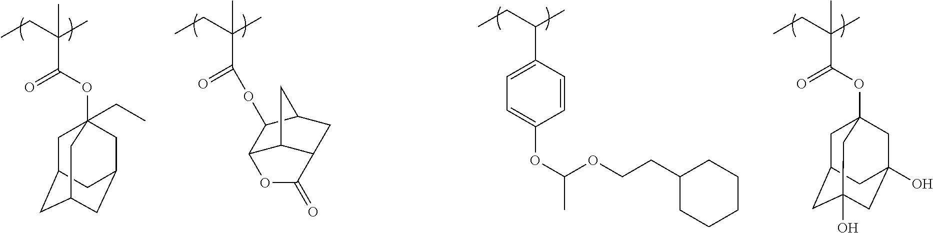

The form of the resin (A) may be any form of a random form, a block form, a comb form, and a star form.

The resin (A) can be synthesized by, for example, polymerizing an unsaturated monomer corresponding to each structure through radical polymerization, cationic polymerization, or anionic polymerization. In addition, by performing a polymer reaction after polymerization is performed using an unsaturated monomer corresponding to a precursor of each structure, a target resin can also be obtained.

Examples of a general synthetic method include a collective polymerization method of performing polymerization by dissolving an unsaturated monomer and a polymerization initiator in a solvent and heating the resultant product and a dropping polymerization method of adding a solution containing an unsaturated monomer and an polymerization initiator dropwise to a heated solvent over a period of 1 hour to 10 hours, and the dropping polymerization method is preferable.

Examples of the solvent used in the polymerization include solvents which can be used in preparing an active light sensitive or radiation sensitive resin composition described below, and it is more preferable that the polymerization is performed using the same solvent as that used in the composition of the present invention. Thus, generation of particles during storage can be suppressed.

The polymerization reaction is preferably performed in an inert gas atmosphere such as nitrogen or argon. The polymerization is initiated using a commercially available radical initiator as a polymerization initiator (an azo-based initiator, peroxide, or the like). As the radical initiator, an azo-based initiator is preferable, and an azo-based initiator having an ester group, a cyano group, or a carboxyl group is preferable. Preferable examples of the initiator include azobisisobutyronitrile, azobisdimethylvaleronitrile, and dimethyl 2,2′-azobis(2-methylpropionate). If necessary, polymerization may be performed in the presence of a chain transfer agent (for example, alkyl mercaptan).

The concentration of the reaction is 5% by mass to 70% by mass, and preferably 10% by mass to 50% by mass. The reaction temperature is typically 10° C. to 150° C., preferably 30° C. to 120° C., and more preferably 40° C. to 100° C.

The reaction time is typically 1 hour to 48 hours, preferably 1 hour to 24 hours, and more preferably 1 hour to 12 hours.

After the reaction ends, cooling is performed to room temperature, and purification is performed. A usual method such as a liquid-liquid extraction method in which a residual monomer or an oligomer component is removed by washing with water or combining suitable solvents, a purification method in a solution state such as ultrafiltration which extracts and removes only substances having a specific molecular weight or less, a reprecipitation method in which a residual monomer or the like is removed by adding a resin solution dropwise to a poor solvent to coagulate the resin in the poor solvent, or a purification method in a solid state in which filtered resin slurry is washed with a poor solvent can be applied to the purification. For example, by bringing into contact with a solvent (poor solvent), which does poorly dissolve or does not dissolve the resin, corresponding to 10 times or less the volume amount of the reaction solution, or preferably 5 times to 10 times the volume amount of the reaction solution, the resin is solidified and precipitated.

The solvent (precipitation or reprecipitation solvent) used in precipitation or reprecipitation operation from the polymer solution may be a poor solvent for the polymer, and depending on the type of polymer, the solvent can be suitably selected from hydrocarbon, halogenated hydrocarbon, a nitro compound, ether, ketone, ester, carbonate, alcohol, carboxylic acid, water, and a mixed solvent including these solvents and used. Among these, as a precipitation or reprecipitation solvent, a solvent including at least alcohol (in particular, methanol) or water is preferable.

Although the amount of precipitation or reprecipitation solvent used can be suitably selected in consideration of efficiency or yield, the amount used is generally 100 parts by mass to 10000 parts by mass, preferably 200 parts by mass to 2000 parts by mass, and more preferably 300 parts by mass to 1000 parts by mass, with respect to 100 parts by mass of the polymer solution.

Although the temperature at the time of precipitation or reprecipitation can be suitably selected in consideration of efficiency or operability, the temperature is typically about 0° C. to 50° C., and preferably around room temperature (for example, about 20° C. to 35° C.). Precipitation or reprecipitation operation can be performed by a known method such as a batch type or a continuous type using a generally used mixing vessel such as a stirring vessel.

The precipitated or reprecipitated polymer is typically subjected to generally used solid-liquid separation such as filtration or centrifugation, dried, and then, provided for use. The filtration is preferably performed under pressure using a solvent-resistant filter medium. The drying is performed at a temperature of about 30° C. to 100° C. at normal pressure or under reduced pressure (preferably, under reduced pressure), and preferably at a temperature of about 30° C. to 50° C.

Moreover, once the resin is precipitated, and after being separated, the resin is again dissolved in a solvent, and may be brought into contact with a solvent which does poorly dissolve or does not dissolve the resin. That is, a method which includes a step of precipitating a resin by bringing into contact with a poorly soluble or insoluble solvent which does not dissolve the polymer after the radical polymerization reaction ends (step a), a step of separating the resin from the solution (step b), a step of preparing a resin solution A by dissolving the resin in a solvent (step c), thereafter, by bringing the resin solution A into contact with a solvent in which the resin is poorly soluble or insoluble, corresponding to 10 times or less the volume amount (preferably 5 times or less the volume amount) of the resin solution A, the resin solid is precipitated (step d), and a step of separating the precipitated resin (step e) may be performed.

The polymerization reaction is preferably performed in an inert gas atmosphere such as nitrogen or argon. The polymerization is initiated using a commercially available radical initiator as a polymerization initiator (an azo-based initiator, peroxide, or the like). As the radical initiator, an azo-based initiator is preferable, and an azo-based initiator having an ester group, a cyano group, or a carboxyl group is preferable. Preferable examples of the initiator include azobisisobutyronitrile, azobisdimethylvaleronitrile, and dimethyl 2,2′-azobis(2-methylpropionate). As necessary, an initiator is additionally added or added by being divided, and after the reaction ends, the reaction product is put into a solvent, and a target polymer is recovered by a powder recovery method or a solid recovery method. The concentration of the reaction is 5% by mass to 50% by mass, and preferably 10% by mass to 30% by mass. The reaction temperature is typically 10° C. to 150° C., preferably 30° C. to 120° C., and more preferably 60° C. to 100° C.

In particular, in a case where an active light sensitive or radiation sensitive film obtained from the active light sensitive or radiation sensitive resin composition is irradiated with ArF excimer laser light, from the viewpoint of transparency to ArF light, the resin (A) used in the composition of the present invention preferably substantially does not have an aromatic ring (specifically, with respect to the entirety of repeating units in the resin, the content of the repeating unit having an aromatic group is preferably 5 mol % or less, more preferably 3 mol % or less, and ideally 0 mol %, that is, not having an aromatic group), and the resin (A) preferably has a monocyclic or polycyclic alicyclic hydrocarbon structure.

In a case where the composition of the present invention includes a hydrophobic resin (HR) described below, from the viewpoint of compatibility with the hydrophobic resin (HR), the resin (A) preferably does not contain a fluorine atom and a silicon atom.

In addition, in this case, the resin (A) is preferably a resin in which all of repeating units are configured of (meth)acrylate-based repeating units. In this case, any one of a resin in which all of repeating units are methacrylate-based repeating units, a resin in which all of repeating units are acrylate-based repeating units, and a resin in which all of repeating units are methacrylate-based repeating units and acrylate-based repeating units can also be used, and the acrylate repeating unit is preferably 50 mol % of the entirety of repeating units.

In addition, in particular, in a case where an active light sensitive or radiation sensitive film obtained from the active light sensitive or radiation sensitive resin composition is irradiated with KrF excimer laser light, an electron beam, X-rays, or a high energy light beam having a wavelength of 50 nm or less (for example, EUV light), the resin (A) may have a repeating unit having an aromatic ring, and, as described above, preferably has the repeating unit represented by General Formula (1). The repeating unit having an aromatic ring is not particularly limited and also exemplified in the description for each repeating unit described above, and examples thereof include a styrene unit, a hydroxystyrene unit, a phenyl (meth)acrylate units, and a hydroxyphenyl (meth)acrylate unit. More specific examples of the resin (A) in this case include a resin having a hydroxystyrene-based repeating unit and a hydroxystyrene-based repeating unit protected with an acid-decomposable group and a resin having the repeating unit having an aromatic ring and a repeating unit in which the carboxylic acid portions of (meth)acrylic acid is protected with an acid-decomposable group.

Although the molecular weight of the resin (A) is not particularly limited, the weight average molecular weight is preferably within a range of 1000 to 100000, more preferably within a range of 1500 to 60000, and particularly preferably within a range of 2000 to 30000. In a case where the weight average molecular weight is within a range of 1000 to 100000, degradation of heat resistance or dry etching resistance can be prevented, and degradation of developability or degradation of film-forming properties due to increase in viscosity can be prevented. Here, the weight average molecular weight of a resin is a molecular weight in terms of polystyrene measured by using GPC (carrier: THF or N-methyl-2-pyrrolidone (NMP)).

The dispersity (Mw/Mn) is preferably 1.00 to 5.00, more preferably 1.00 to 3.50, and still more preferably 1.00 to 2.50. As the molecular weight distribution is lower, the resolution and the resist shape become better, and the side wall of the guide pattern becomes smoother, and thus, the roughness becomes excellent.

The resin (A) of the present invention can be used alone, or two or more types thereof can be used in combination. The content of the resin (A) is preferably 20% by mass to 99% by mass, more preferably 30% by mass to 99% by mass, and still more preferably 40% by mass to 99% by mass, based on the total solid content in the active light sensitive or radiation sensitive resin composition.

[2] (B) Compound That Generates Acid by Irradiation with Active Light or Radiation The active light sensitive or radiation sensitive resin composition preferably contains a compound that typically generates an acid by irradiation with active light or radiation (hereinafter, also referred to as an “acid generator” or a “compound (B)”).

Although the acid generator is not particularly limited as long as it is a known acid generator, the acid generator is preferably a compound that generates an organic acid, for example, at least any one of sulfonic acid, bis(alkylsulfonyl)imide, and tris(alkylsulfonyl)methide by irradiation with active light or radiation.

The compound (B) that generates an acid by irradiation with active light or radiation may have a form of a low molecular weight compound, or may have a form in which the compound (B) is incorporated into a part of a polymer. In addition, a form of a low molecular weight compound and a form in which the compound is incorporated into a part of a polymer may be used in combination.

In a case where the compound (B) that generates an acid by irradiation with active light or radiation has a form of a low molecular weight compound, the molecular weight of the compound (B) is preferably 3000 or less, more preferably 2000 or less, and still more preferably 1000 or less.

In a case where the compound (B) that generates an acid by irradiation with active light or radiation has a form in which the compound (B) is incorporated into a part of a polymer, the compound (B) may be incorporated into a part of the resin (A) to configure the resin (A) or may be incorporated into a resin different from the resin (A).

More preferably, the compounds represented by the following General Formula (ZI), (ZII), or (ZIII) can be exemplified.

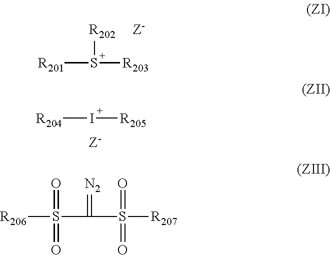

In General Formula (ZI), each of R₂₀₁, Ra₂₀₂, and R₂₀₃ independently represents an organic group.

The organic group represented by R₂₀₁, R₂₀₂, or R₂₀₃ generally has 1 to 30 carbon atoms and preferably has 1 to 20 carbon atoms.

Two of R₂₀₁ to R₂₀₃ may be bonded to each other to form a ring structure, and an oxygen atom, a sulfur atom, an ester bond, an amide bond, or a carbonyl group may be included in the ring. Examples of the group that two of R₂₀₁ to R₂₀₃ form by bonding to each other can include an alkylene group (for example, a butylene group and a pentylene group).

Z⁻ represents a non-nucleophilic anion (anion which is significantly low in ability causing a nucleophilic reaction).

Examples of the non-nucleophilic anion include a sulfonate anion (an aliphatic sulfonate anion, an aromatic sulfonate anion, or a camphorsulfonate anion), a carboxylate anion (an aliphatic carboxylate anion, an aromatic carboxylate anion, or an aralkylcarboxylate anion), a sulfonylimide anion, a bis(alkylsulfonyl) imide anion, and a tris(alkylsulfonyl) methide anion.

Regarding the aliphatic portion in the aliphatic sulfonate anion and the aliphatic carboxylate anion, and the aromatic group in the aromatic sulfonate anion and the aromatic carboxylate anion, the description in paragraphs “0234” to “0235” of JP2013-76991A can be referred to, and the contents thereof are incorporated in the present specification.

The alkyl group, the cycloalkyl group, the aryl group described above may have a substituent. Regarding the specific examples, the description in paragraph “0236” of JP2013-76991A can be referred to, and the contents thereof are incorporated in the present specification.

Regarding aralkyl carboxylate anion, sulfonylimide anion, bis(alkylsulfonyl)imide anion, and tris(alkylsulfonyl)methide anion, the description in paragraphs “0237” to “0239” of JP2013-76991A can be referred to, and the contents thereof are incorporated in the present specification.

Regarding other non-nucleophilic anions, the description in paragraph “0240” of JP2013-76991A can be referred to, and the contents thereof are incorporated in the present specification.

As the non-nucleophilic anion, an aliphatic sulfonate anion in which at least α-position of sulfonic acid is substituted with a fluorine atom, an aromatic sulfonate anion substituted with a fluorine atom or a group having a fluorine atom, a bis (alkylsulfonyl)imide anion in which the alkyl group is substituted with a fluorine atom, or a tris(alkylsulfonyl)methide anion in which the alkyl group is substituted with a fluorine atom is preferable. The non-nucleophilic anion is more preferably a perfluoro aliphatic sulfonate anion (which more preferably has 4 to 8 carbon atoms) or a benzenesulfonate anion having a fluorine atom, and still more preferably a nonafluorobutanesulfonate anion, a perfluorooctanesulfonate anion, a pentafluorobenzenesulfonate anion, or a 3,5-bis(trifluoromethyl)benzenesulfonate anion.

From the viewpoint of acid strength, the pKa of the generated acid is preferably −1 or less for sensitivity enhancement.

In addition, as the non-nucleophilic anion, an anion represented by the following General Formula (AN1) is also exemplified as a preferable aspect.

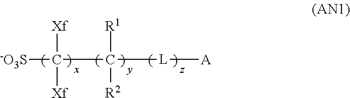

In the formula, each of Xf's independently represents a fluorine atom or an alkyl group substituted with at least one fluorine atom.

Each of R¹ and R² independently represents a hydrogen atom, a fluorine atom, or an alkyl group, and in a case where a plurality of R¹'s and R²'s are present, R¹'s and R²'s may be the same as or different from each other.

L represents a divalent connecting group, and in a case where a plurality of L's are present, L's may be the same as or different from each other.

A represents a cyclic organic group.

x represents an integer of 1 to 20, y represents an integer of 0 to 10, and z represents an integer of 0 to 10.

General Formula (AN1) will be described in more detail.

The alkyl group in the alkyl group substituted with a fluorine atom represented by Xf preferably has 1 to 10 carbon atoms, and more preferably 1 to 4 carbon atoms. In addition, the alkyl group substituted with a fluorine atom represented by Xf is preferably a perfluoroalkyl group.

Xf is preferably a fluorine atom or a perfluoroalkyl group having 1 to 4 carbon atoms. Specific examples of Xf include a fluorine atom, CF₃, C₂F₅, C₃F₇, C₄F₉, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, and among these, a fluorine atom or CF₃ is preferable. In particular, both of Xf's are preferably fluorine atoms.

The alkyl group represented by R¹ or R² may have a substituent (preferably a fluorine atom), and the alkyl group is preferably an alkyl group having 1 to 4 carbon atoms, and more preferably a perfluoroalkyl group having 1 to 4 carbon atoms. Specific examples of the alkyl group having a substituent, represented by R¹ or R², include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, and among these, CF₃ is preferable.

Each of R¹ and R² is preferably a fluorine atom or CF₃.

x is preferably 1 to 10, and more preferably 1 to 5.

y is preferably 0 to 4, and more preferably 0.

z is preferably 0 to 5, and more preferably 0 to 3.

The divalent connecting group represented by L is not particularly limited, and examples thereof can include —COO—, —OCO—, —CO—, —O—, —S—, —SO—, —SO₂—, an alkylene group, a cycloalkylene group, an alkenylene group, and a connecting group obtained by connecting a plurality of these, and a connecting group having 12 or less carbon atoms in total is preferable. Among these, —COO—, —OCO—, —CO—, or —O— is preferable, and —COO— or —OCO— is more preferable.

The cyclic organic group represented by A is not particularly limited as long as it has a ring structure, and examples thereof include an alicyclic group, an aryl group, and a heterocyclic group (which includes not only a heterocyclic group having aromaticity but also a heterocyclic group having no aromaticity).

The alicyclic group may be monocyclic or polycyclic, and as the alicyclic group, a monocyclic cycloalkyl group such as a cyclopentyl group, a cyclohexyl group, or a cyclooctyl group, or polycyclic cycloalkyl groups such as a norbornyl group, a tricyclodecanyl group, a tetracyclodecanyl group, a tetracyclododecanyl group, or an adamantyl group is preferable. Among these, an alicyclic group with a bulky structure having 7 or more carbon atoms such as a norbornyl group, a tricyclodecanyl group, a tetracyclodecanyl group, a tetracyclododecanyl group, or an adamantyl group is preferable from the viewpoint of being capable of suppressing in-film diffusibility in a heating step after exposure and MEEF improvement.

Examples of the aryl group include a benzene ring group, a naphthalene ring group, a phenanthrene ring group, and an anthracene ring group.

Examples of the heterocyclic group include groups derived from a furan ring, a thiophene ring, a benzofuran ring, a benzothiophene ring, a dibenzofuran ring, a dibenzothiophene ring, and a pyridine ring. Among these, a group derived from a furan ring, a thiophene ring, or a pyridine ring is preferable.

In addition, as the cyclic organic group, a lactone structure can also be exemplified, and specific examples thereof can include the lactone structures represented by General Formulas (LC1-1) to (LC1-17), which the resin (A) may have.

The above-described cyclic organic group may has a substituent, and regarding the substituent, the description in paragraph “0251” of JP2013-76991A can be referred to, and the contents thereof are incorporated in the present specification.

Examples of the organic group represented by R₂₀₁, R₂₀₂, or R₂₀₃ include an aryl group, an alkyl group, and a cycloalkyl group.

Preferably, at least one of R₂₀₁, R₂₀₂, or R₂₀₃ is an aryl group, and more preferably, all of three are aryl groups. Regarding the aryl group, the alkyl group, and the cycloalkyl group, the description in paragraph “0252” of JP2013-76991A can be referred to, and the contents thereof are incorporated in the present specification.

In addition, regarding the structure represented by General Formula (A1) in a case where two of R₂₀₁ to R₂₀₃ are bonded to each other to form a ring structure, the description in paragraphs “0253” to “0257” of JP2013-76991A can be referred to, and the contents thereof are incorporated in the present specification.

Moreover, in a case where at least one of R₂₀₁, R₂₀₂, or R₂₀₃ is not an aryl group, examples of a preferable structure can include cationic structures of compounds exemplified in paragraphs “0046” to “0048” of JP2004-233661A, paragraphs “0040” to “0046” of JP2003-35948A, and exemplified as Formulas (I-1) to (I-70) in the specification of US2003/0224288A1, and compounds exemplified as Formulas (IA-1) to (IA-54), and Formulas (IB-1) to (IB-24) in the specification of US2003/0077540A1.

In General Formulas (ZII) and (ZIII), each of R₂₀₄ to R₂₇ independently represents an aryl group, an alkyl group, or a cycloalkyl group.

The aryl group, the alkyl group, and the cycloalkyl group represented by each of R₂₀₄ to R₂₀₇ are the same as the aryl group described as the aryl group, the alkyl group, and the cycloalkyl group represented by each of R₂₀₁ to R₂₀₃ in the compound (ZI).

The aryl group, the alkyl group, and the cycloalkyl group represented by each of R₂₀₄ to R₂₀₇ may have a substituent. Examples of the substituent include the substituents that the aryl group, the alkyl group, and the cycloalkyl group represented by each of R₂₀₁ to R₂₀₃ in the compound (ZI) may have.

Z represents a non-nucleophilic anion, and as Z⁻, the same as the non-nucleophilic anion in General Formula (ZI) can be exemplified.

As the acid generator, the compounds represented by General Formula (ZIV), (ZV), or (ZVI) described in paragraphs “0262” to “0264” of JP2013-76991A are also exemplified.

Among the acid generators, particularly preferable examples are shown below.

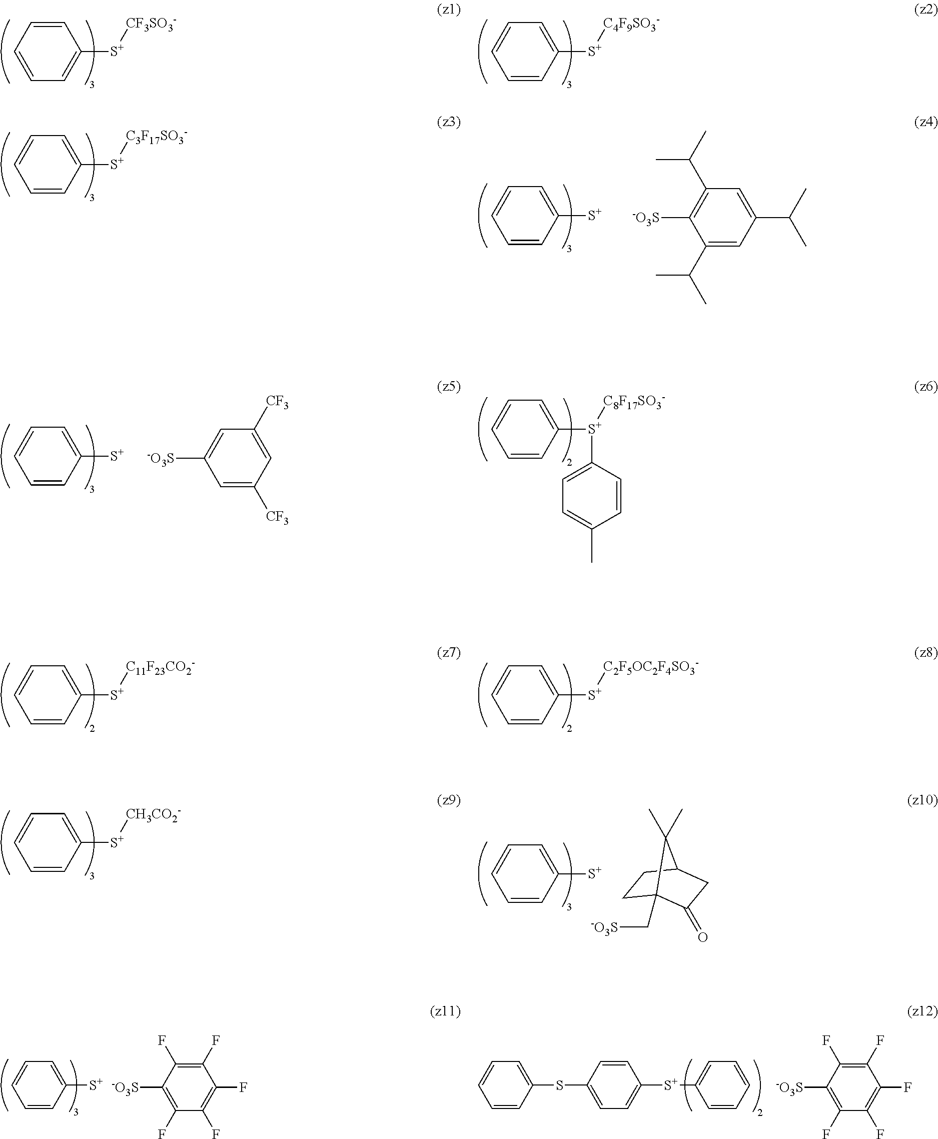

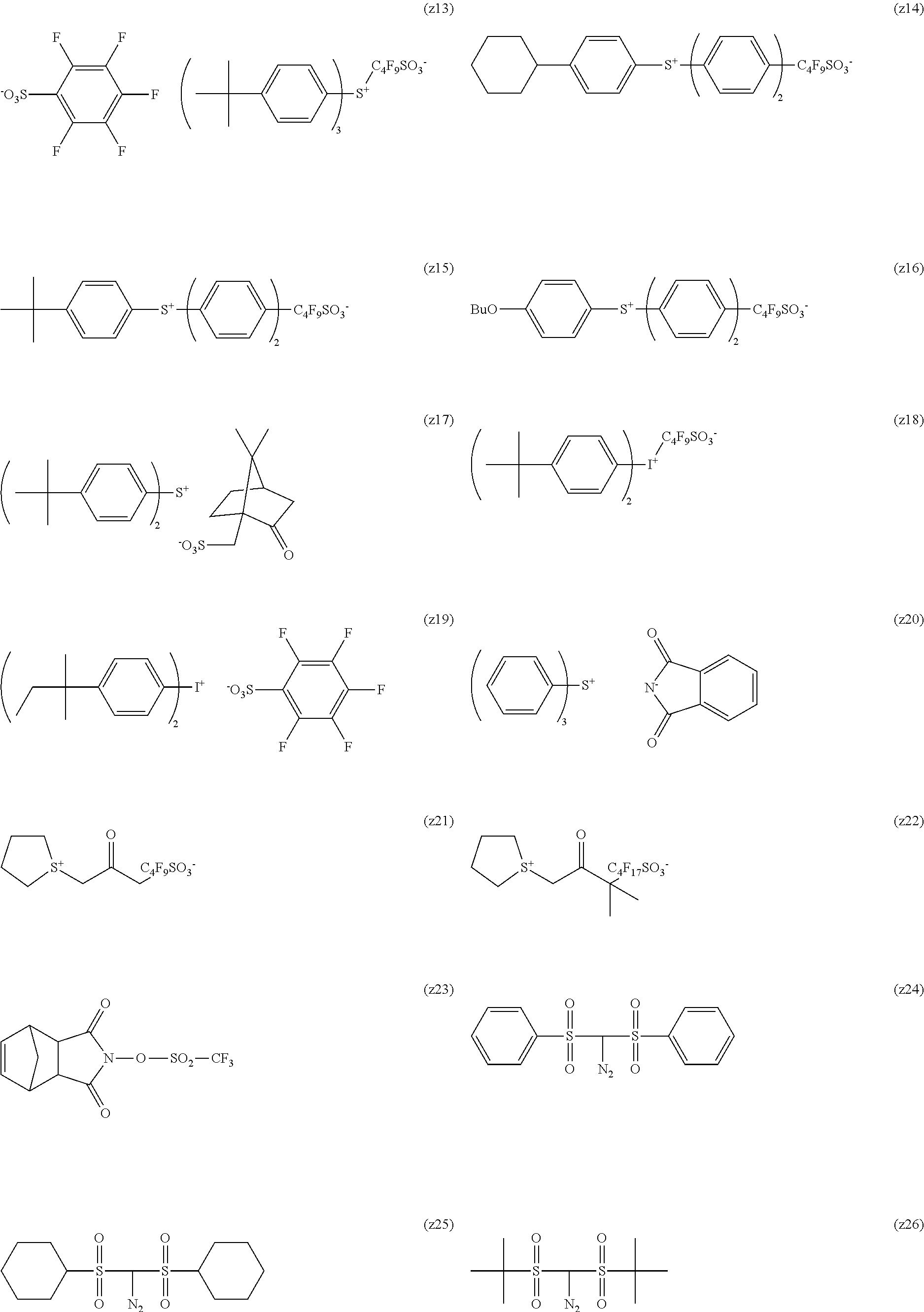

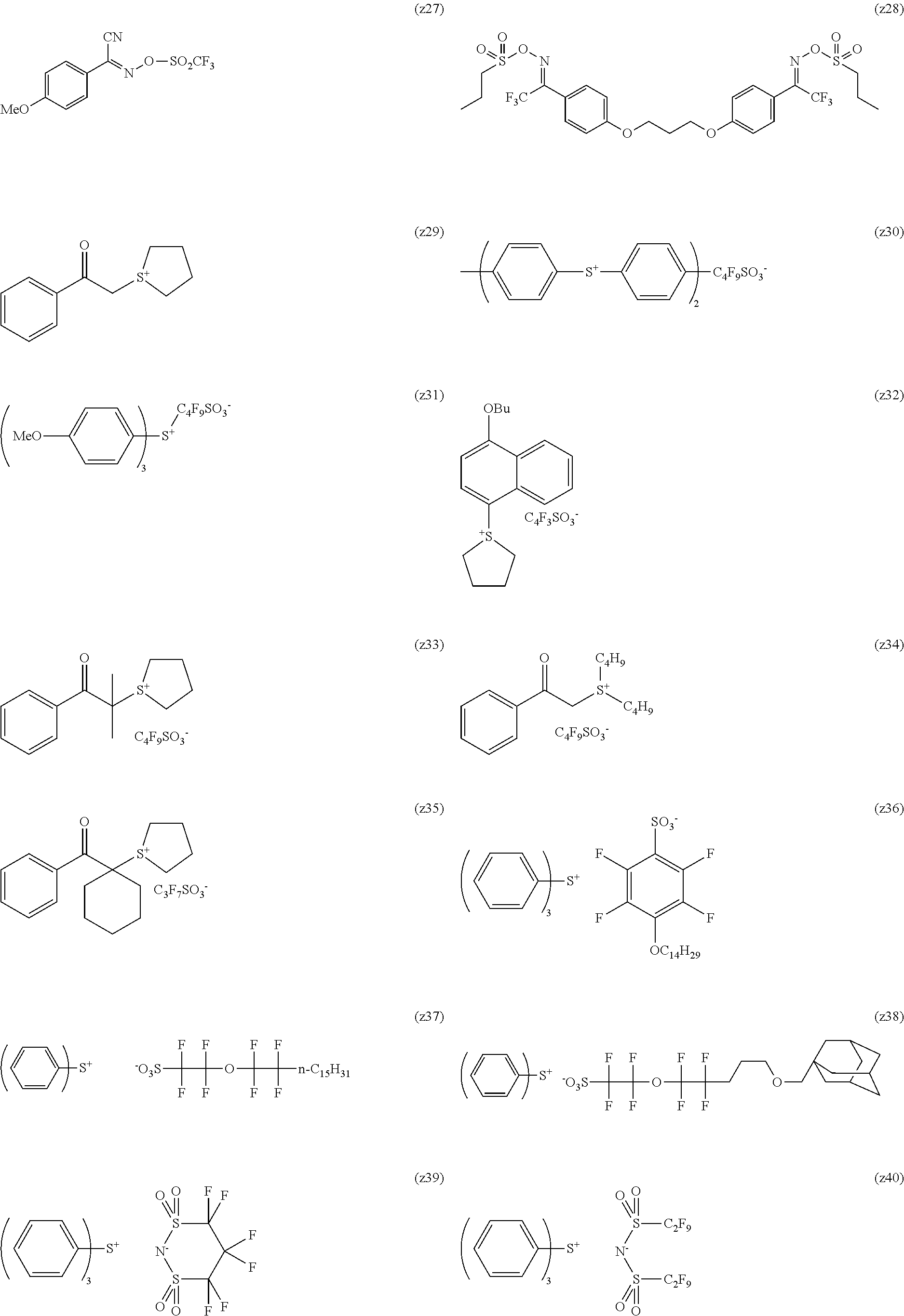

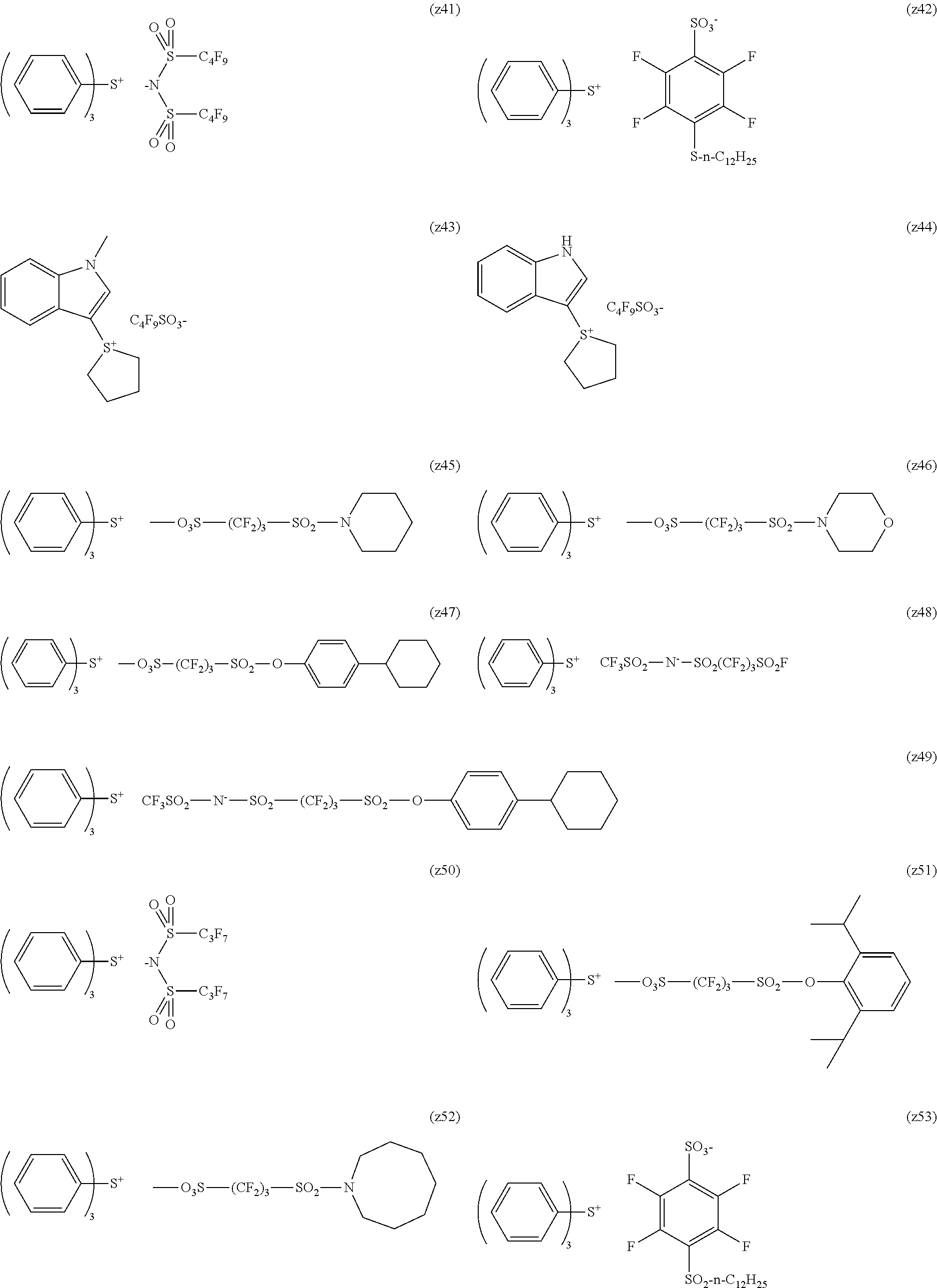

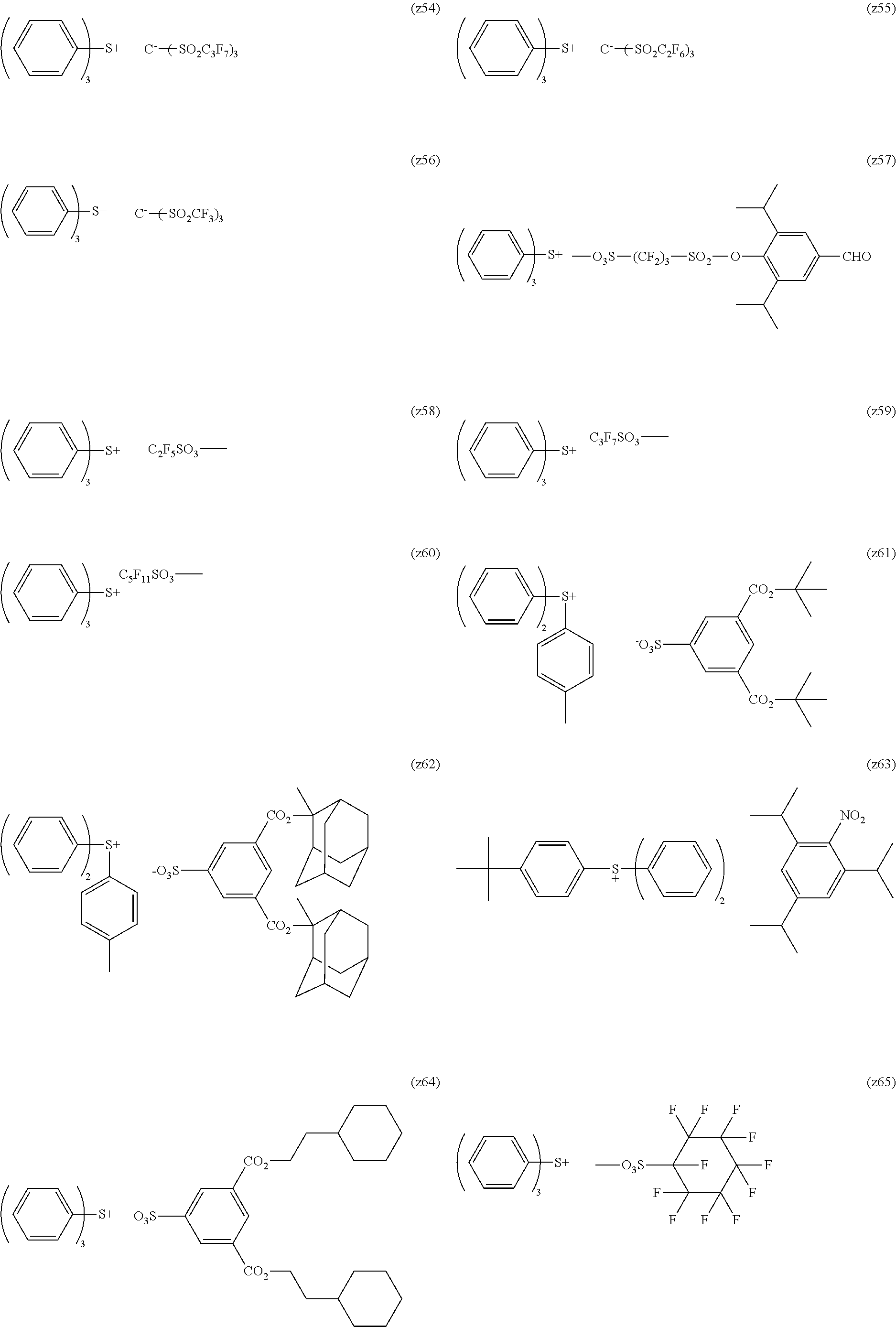

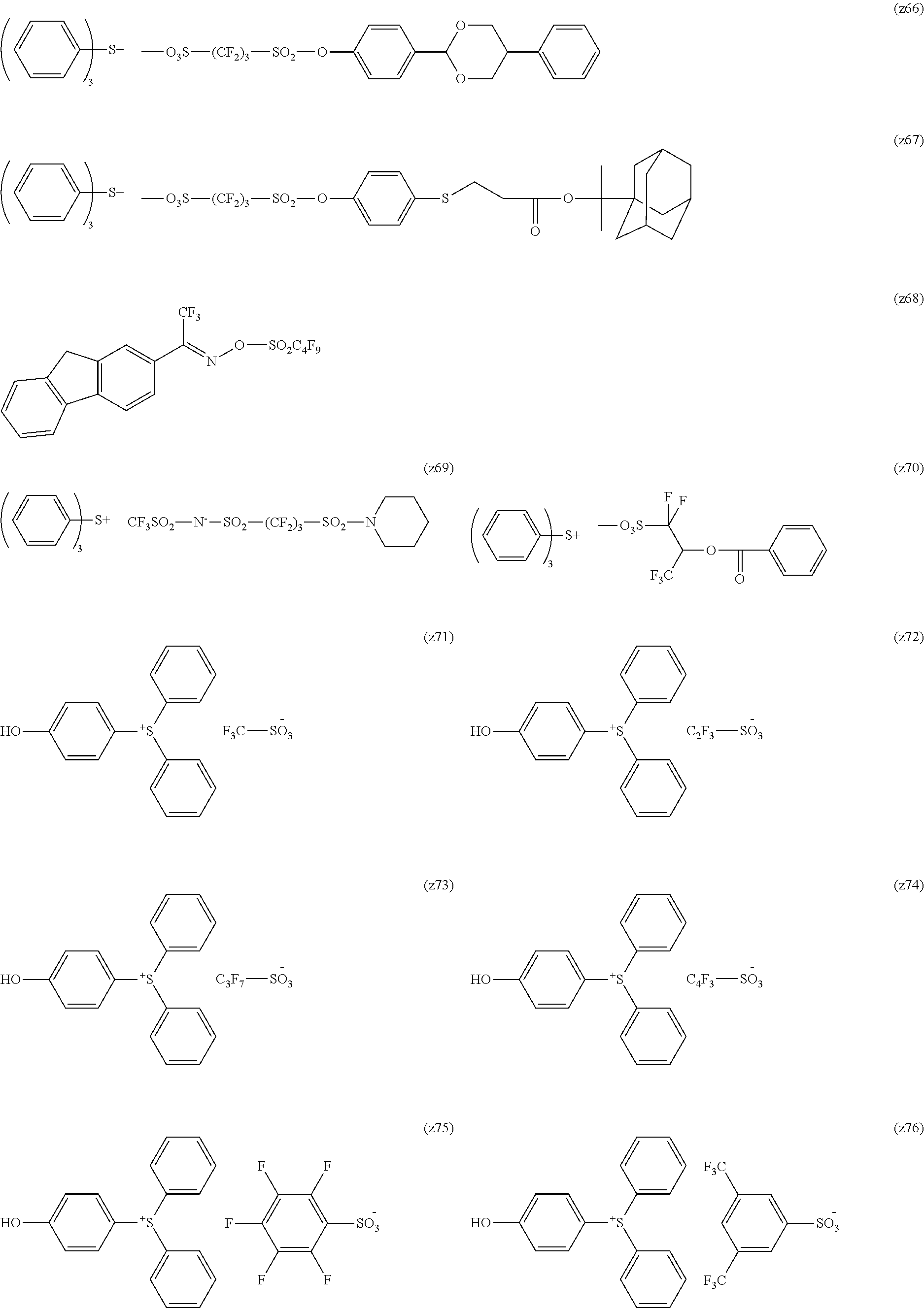

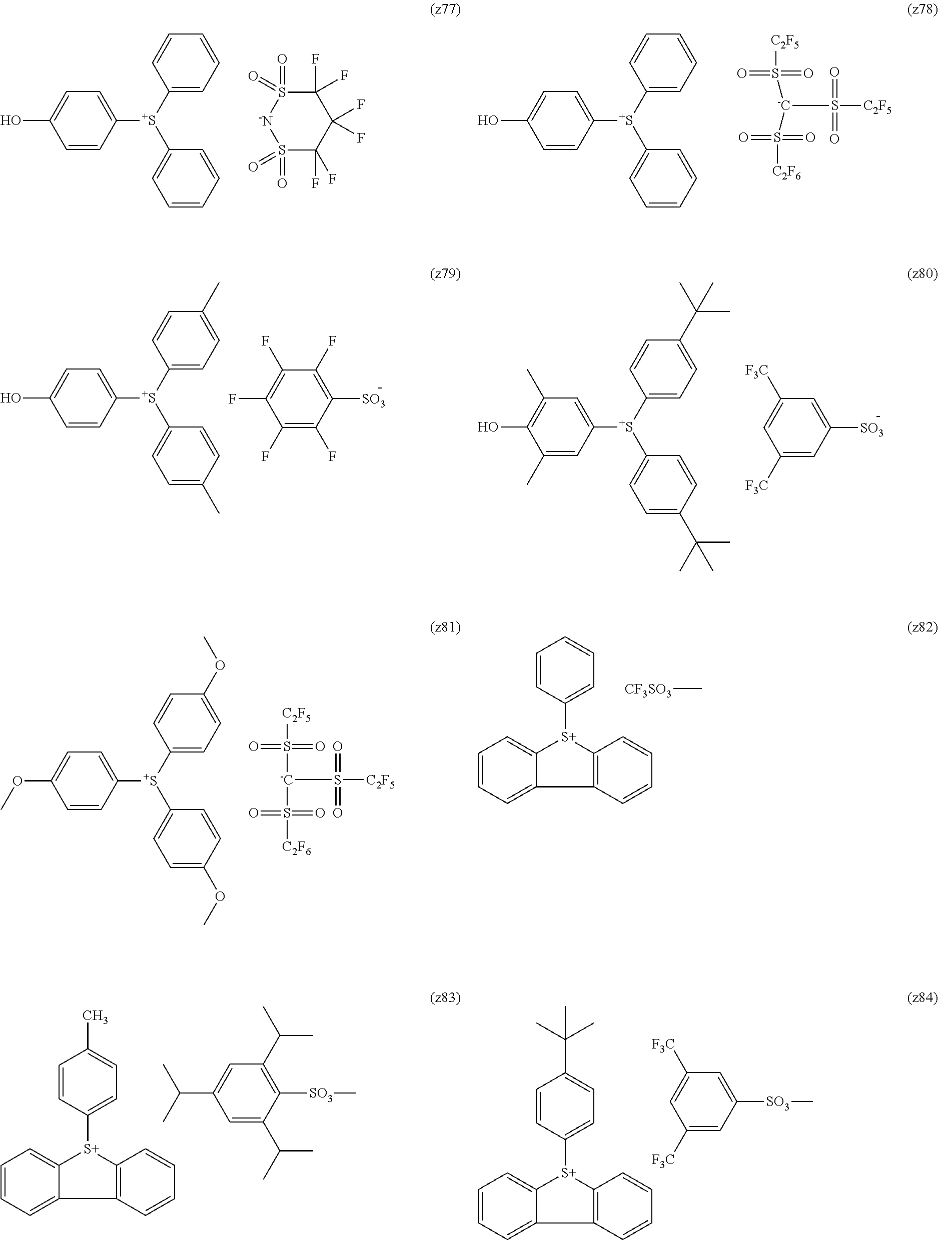

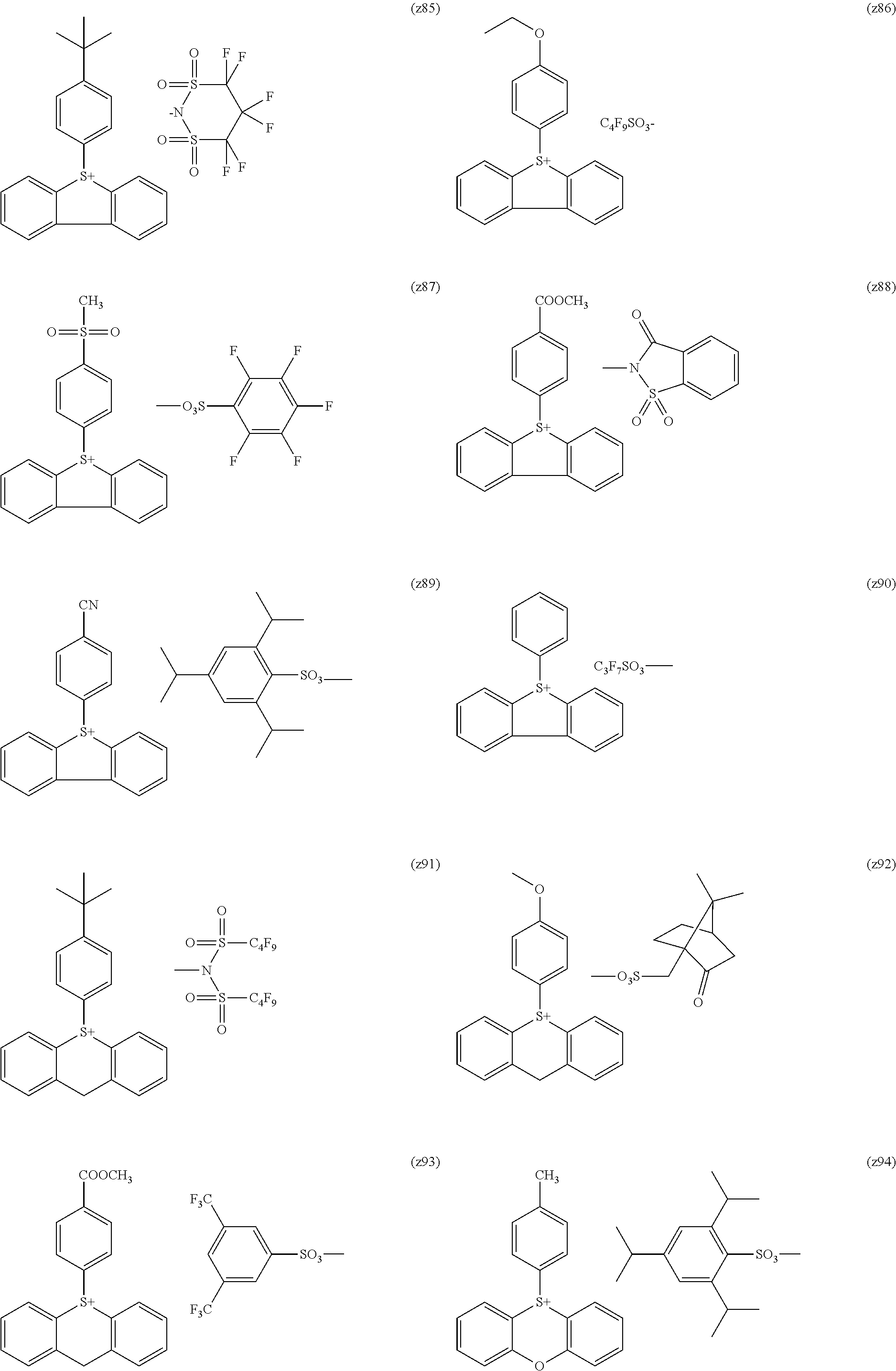

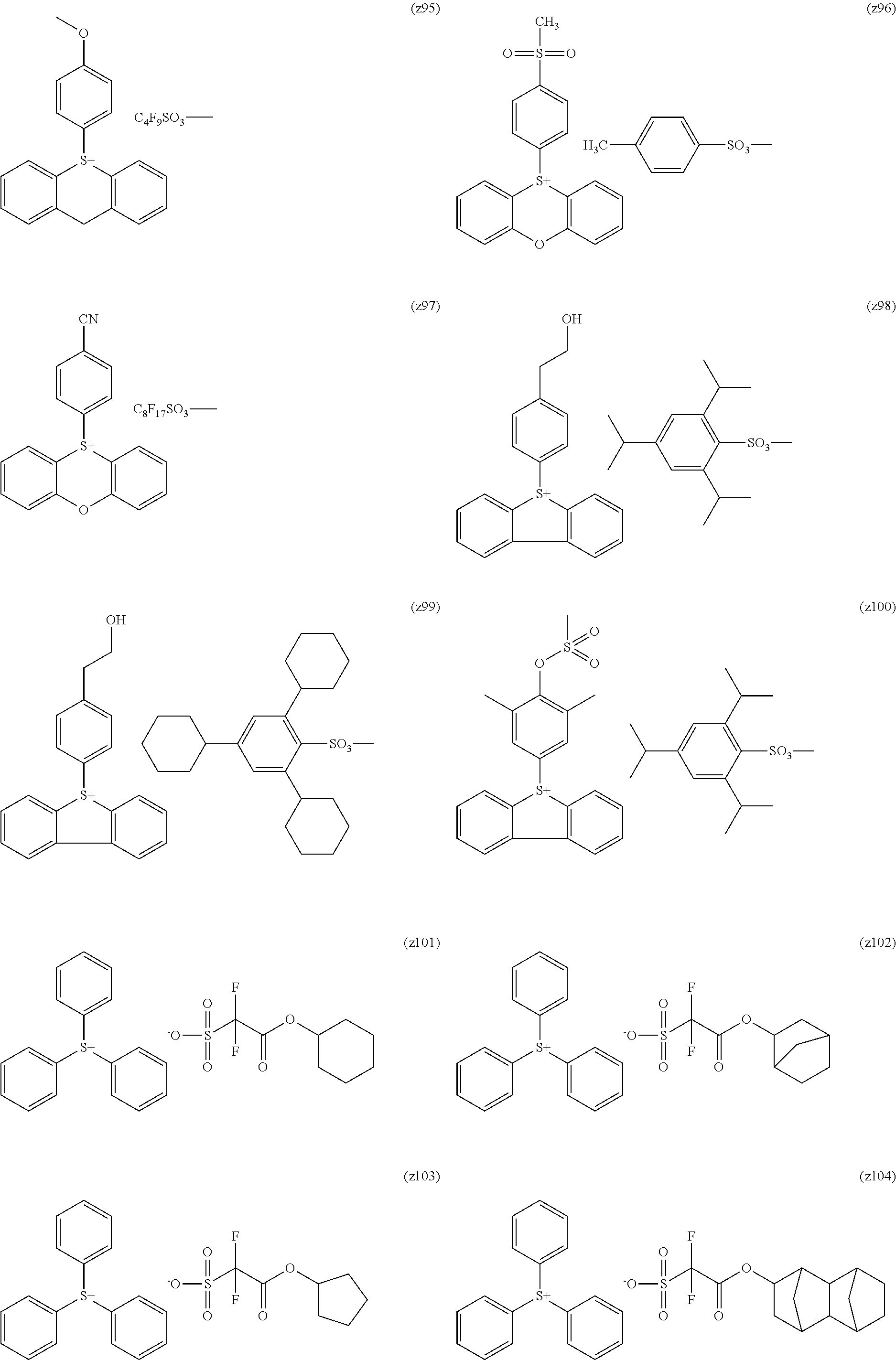

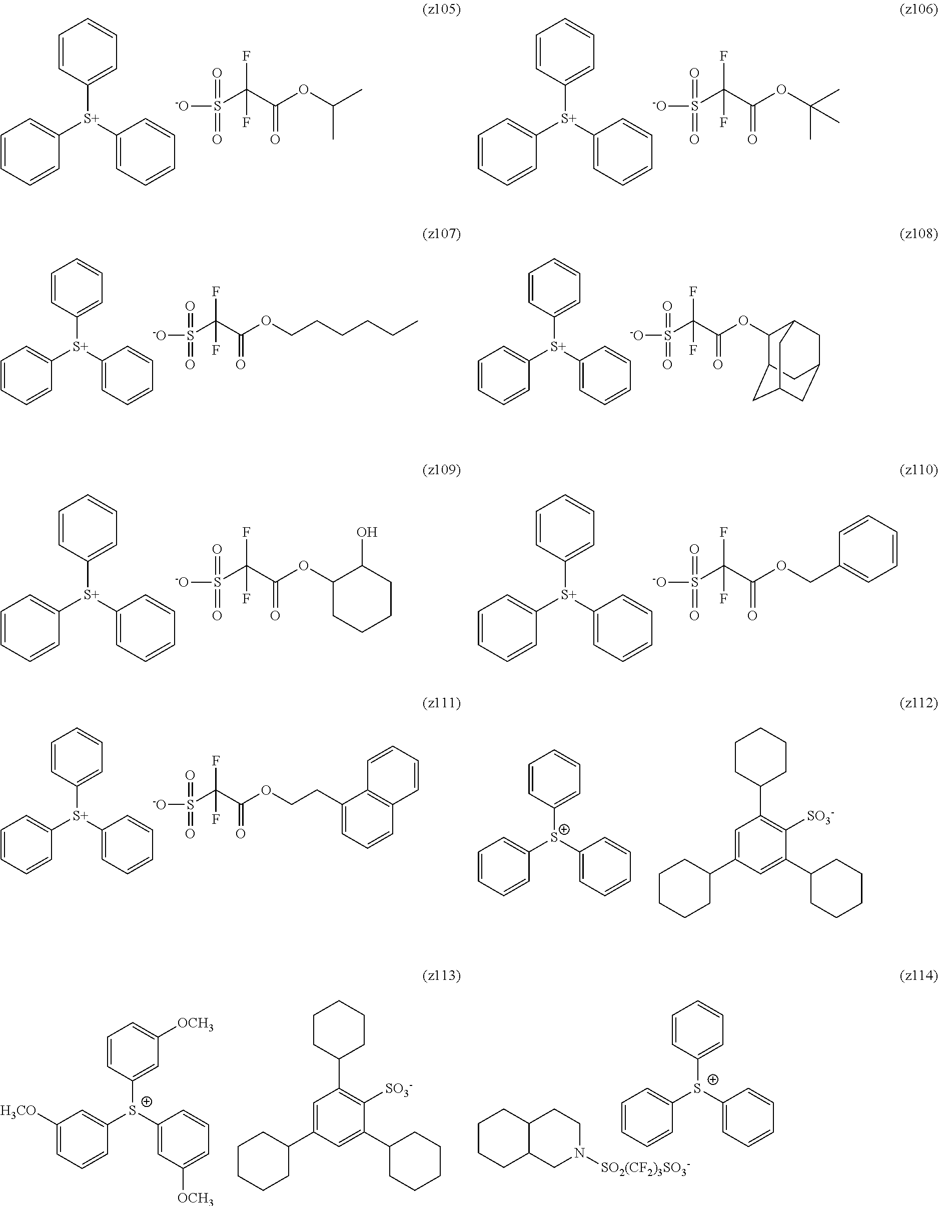

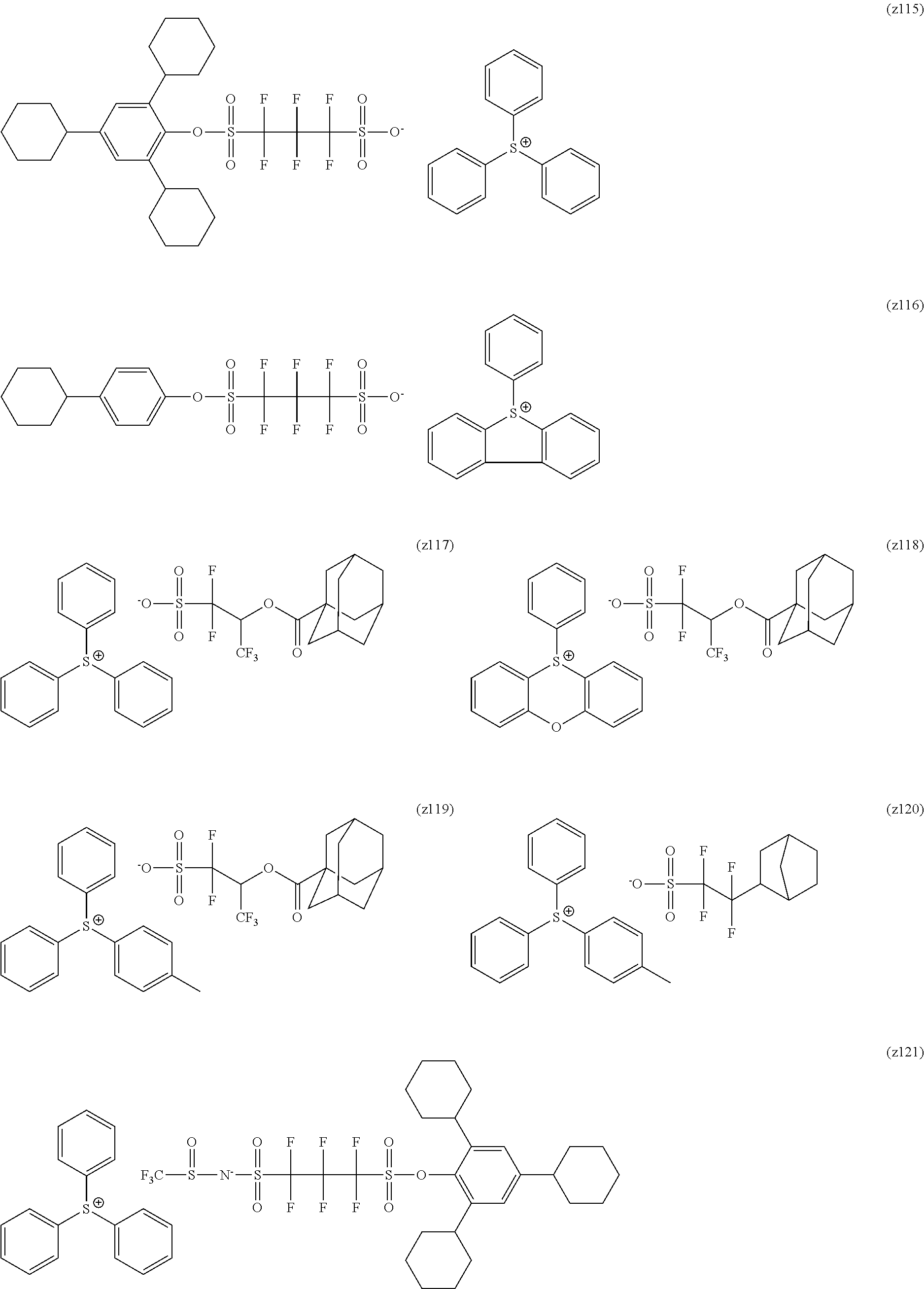

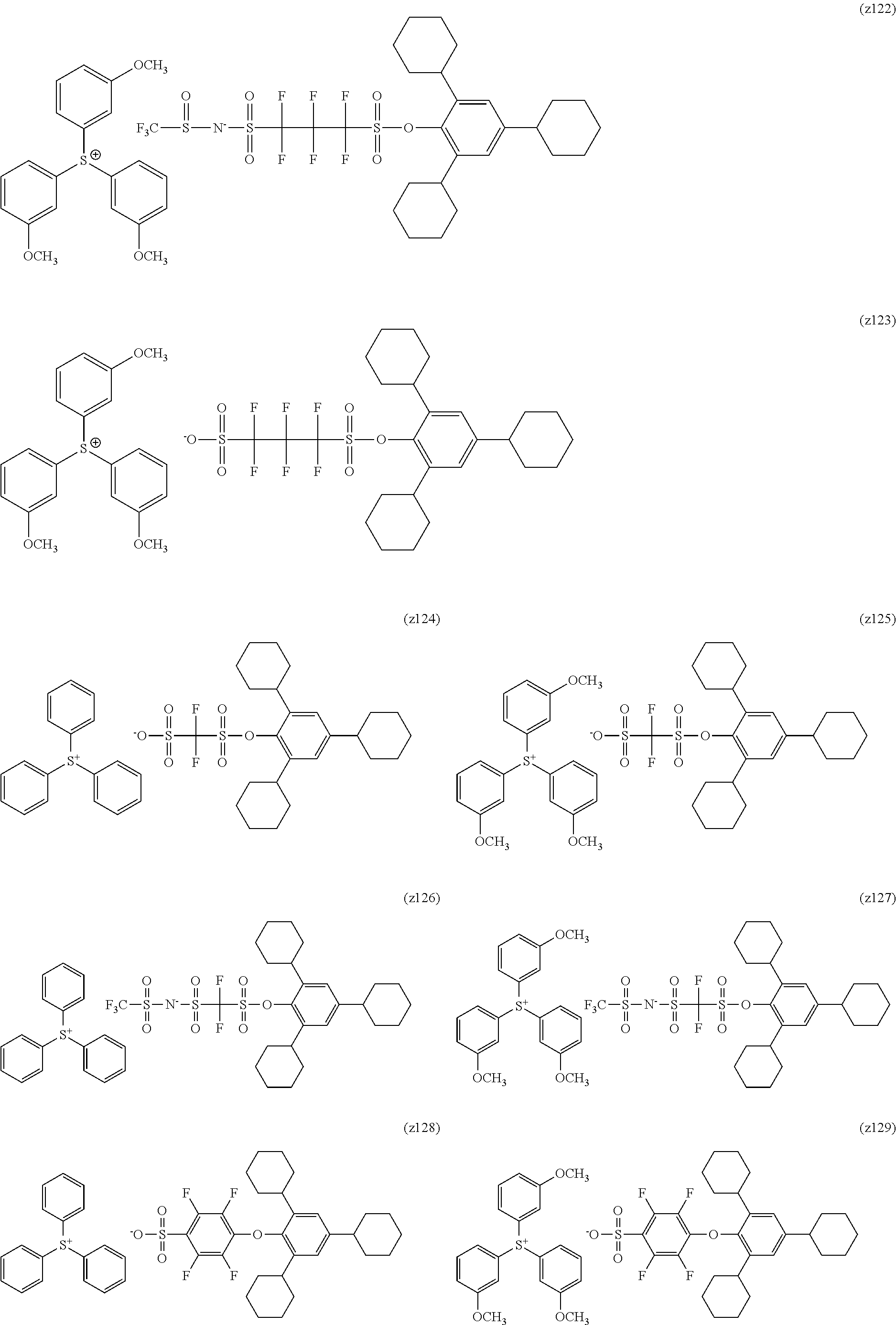

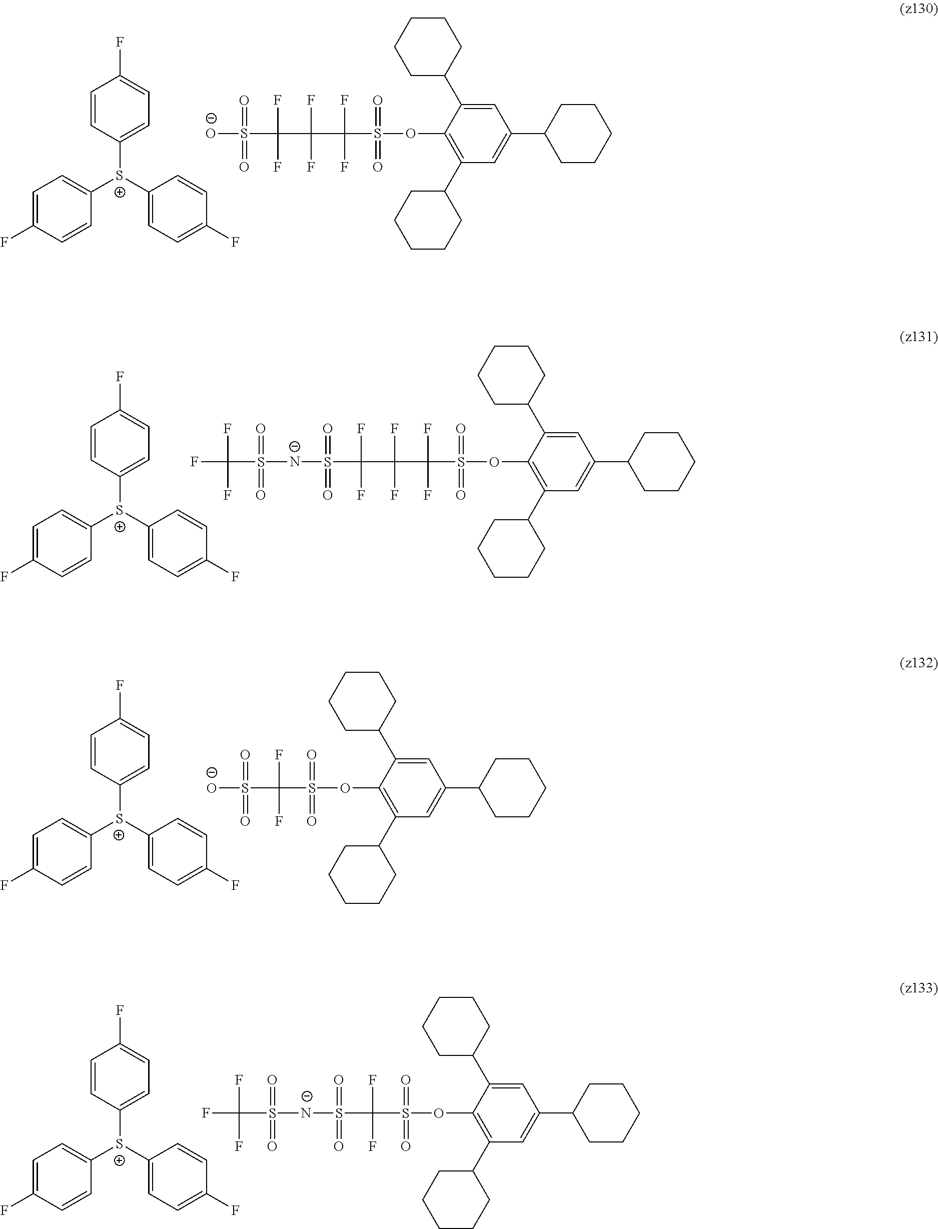

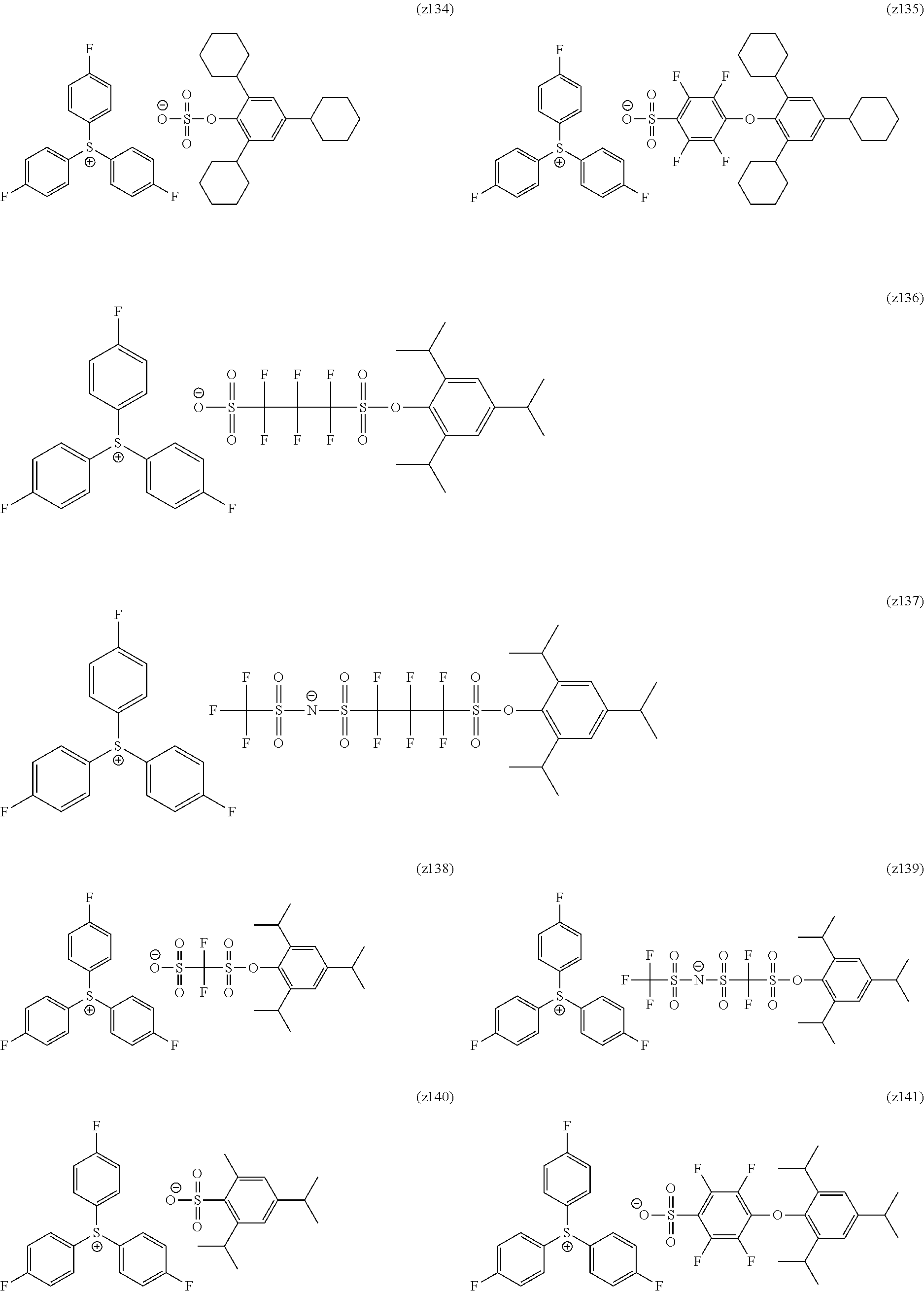

In the present invention, the compound (B) is preferably a compound that generates an acid having a volume of 240 Å³ or greater, more preferably a compound that generates an acid having a volume of 300 Å³ or greater, still more preferably a compound that generates an acid having a volume of 350 Å³ or greater, and particularly preferably a compound that generates an acid having a volume of 400 Å³ or greater, by irradiation with active light or radiation, from the viewpoint of suppressing diffusion of the acid generated by exposure to the unexposed portion and improving resolution. Here, from the viewpoint of sensitivity and coating solvent solubility, the volume is preferably 2000 Å³ or less, and more preferably 1500 Å³ or less. The volume value is determined by using “WinMOPAC” manufactured by FUJITSU. That is, fist, the chemical structure of the acid according to each example is input, then, using this structure as an initial structure, the most stable conformation of each acid is determined by molecular force field calculation using an MM3 method, and then, by performing molecular orbital calculation using a PM3 method on these most stable conformations, the “accessible volume” of each acid can be calculated.

The acid generator can be used alone, or two or more types thereof can be used in combination.

The content of the acid generator in the active light sensitive or radiation sensitive resin composition is preferably 0.1% by mass to 50% by mass, more preferably 0.5% by mass to 40% by mass, and still more preferably 1% by mass to 30% by mass, based on the total solid content in the composition.

[3] (C) Solvent (Coating Solvent)

The solvent which can be used when preparing the active light sensitive or radiation sensitive resin composition is not particularly limited as long as each component is dissolved therein and examples thereof include an alkylene glycol monoalkyl ether carboxylate (propylene glycol monomethyl ether acetate (PGMEA; also referred to as 1-methoxy-2-acetoxypropane) and the like), an alkylene glycol monoalkyl ether (propylene glycol monomethyl ether (PGME; 1-methoxy-2-propanol) and the like), an alkyl lactate ester (ethyl lactate, methyl lactate, and the like), a cyclic lactone (γ-butyrolactone and the like which preferably has 4 to 10 carbon atoms), a chain-like or a cyclic ketone (2-heptanone, cyclohexanone, and the like which preferably has 4 to 10 carbon atoms), an alkylene carbonate (ethylene carbonate, propylene carbonate, and the like), an alkyl carboxylate (an alkyl acetate such as butyl acetate is preferable), and an alkyl alkoxyacetate (ethyl ethoxypropionate). Other examples of the solvent which can be used include the solvents described in paragraphs “0244” and later of US2008/0248425A1.

Among these, an alkylene glycol monoalkyl ether carboxylate, or an alkylene glycol monoalkyl ether is preferable.

These solvents may be used alone or in a mixture of two or more types thereof. In a case where two or more types are mixed, it is preferable to mix a solvent having a hydroxyl group and a solvent not having a hydroxyl group. The mass ratio of the solvent having a hydroxyl group and the solvent not having a hydroxyl group is 1/99 to 99/1, preferably 10/90 to 90/10, and still more preferably 20/80 to 60/40.

The solvent having a hydroxyl group is preferably alkylene glycol monoalkyl ether, and the solvent not having a hydroxyl group is preferably alkylene glycol mono alkyl ether carboxylate.

[4] (D) Basic Compound

The active light sensitive or radiation sensitive resin composition preferably further includes a basic compound (D). The basic compound (D) is preferably a compound having stronger basicity compared to phenol. In addition, the basic compound is preferably an organic basic compound, and more preferably a nitrogen-containing basic compound.

The nitrogen-containing basic compound which is able to be used is not particularly limited, but for example, the compounds which are classified into (1) to (7) below can be used.

(1) Compound Represented by General Formula (BS-1)

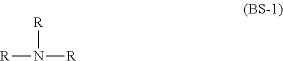

In General Formula (BS-1), each of R's independently represents a hydrogen atom or an organic group. Here, at least one of three R's is an organic group. This organic group is a linear or branched alkyl group, a monocyclic or polycyclic cycloalkyl group, an aryl group, or an aralkyl group.

The number of carbon atoms in the alkyl group represented by R is not particularly limited, but is typically 1 to 20, and preferably 1 to 12.

The number of carbon atoms in the cycloalkyl group represented by R is not particularly limited, but is typically 3 to 20, and preferably 5 to 15.

The number of carbon atoms in the aryl group represented by R is not particularly limited, but is typically 6 to 20, and preferably 6 to 10. Specific examples thereof include a phenyl group and a naphthyl group.

The number of carbon atoms in the aralkyl group represented by R is not particularly limited, but is typically 7 to 20, and preferably 7 to 11. Specifically, examples thereof include a benzyl group.

A hydrogen atom in the alkyl group, the cycloalkyl group, the aryl group, or the aralkyl group represented by R may be substituted with a substituent. Examples of the substituent include an alkyl group, a cycloalkyl group, an aryl group, an aralkyl group, a hydroxy group, a carboxy group, an alkoxy group, an aryloxy group, an alkylcarbonyloxy group, and an alkyloxycarbonyl group.

Moreover, at least two of R's in the compound represented by General Formula (BS-1) are preferably organic groups.

Specific examples of the compound represented by General Formula (BS-1) include tri-n-butyl amine, tri-n-pentyl amine, tri-n-octyl amine, tri-n-decyl amine, triisodecyl amine, dicyclohexyl methyl amine, tetradecyl amine, pentadecyl amine, hexadecyl amine, octadecyl amine, didecyl amine, methyl octadecyl amine, dimethyl undecyl amine, N,N-dimethyl dodecyl amine, methyl dioctadecyl amine, N,N-dibutyl aniline, N,N-dihexyl aniline, 2,6-diisopropyl aniline, and 2,4,6-tri(t-butyl)aniline.

In addition, as the preferable basic compound represented by General Formula (BS-1), an alkyl group in which at least one R is substituted with a hydroxy group is exemplified. Specific examples thereof include triethanol amine and N,N-dihydroxyethyl aniline.

Moreover, the alkyl group represented by R may have an oxygen atom in the alkyl chain. That is, an oxyalkylene chain may be formed. As the oxyalkylene chain, —CH₂CH₂O— is preferable. Specific examples thereof include tris(methoxyethoxyethyl)amine and a compound disclosed after line 60 of column 3 in the specification of US6040112A.

Among basic compounds represented by General Formula (BS-1), examples of a compound having such a hydroxyl group or an oxygen atom include the followings.

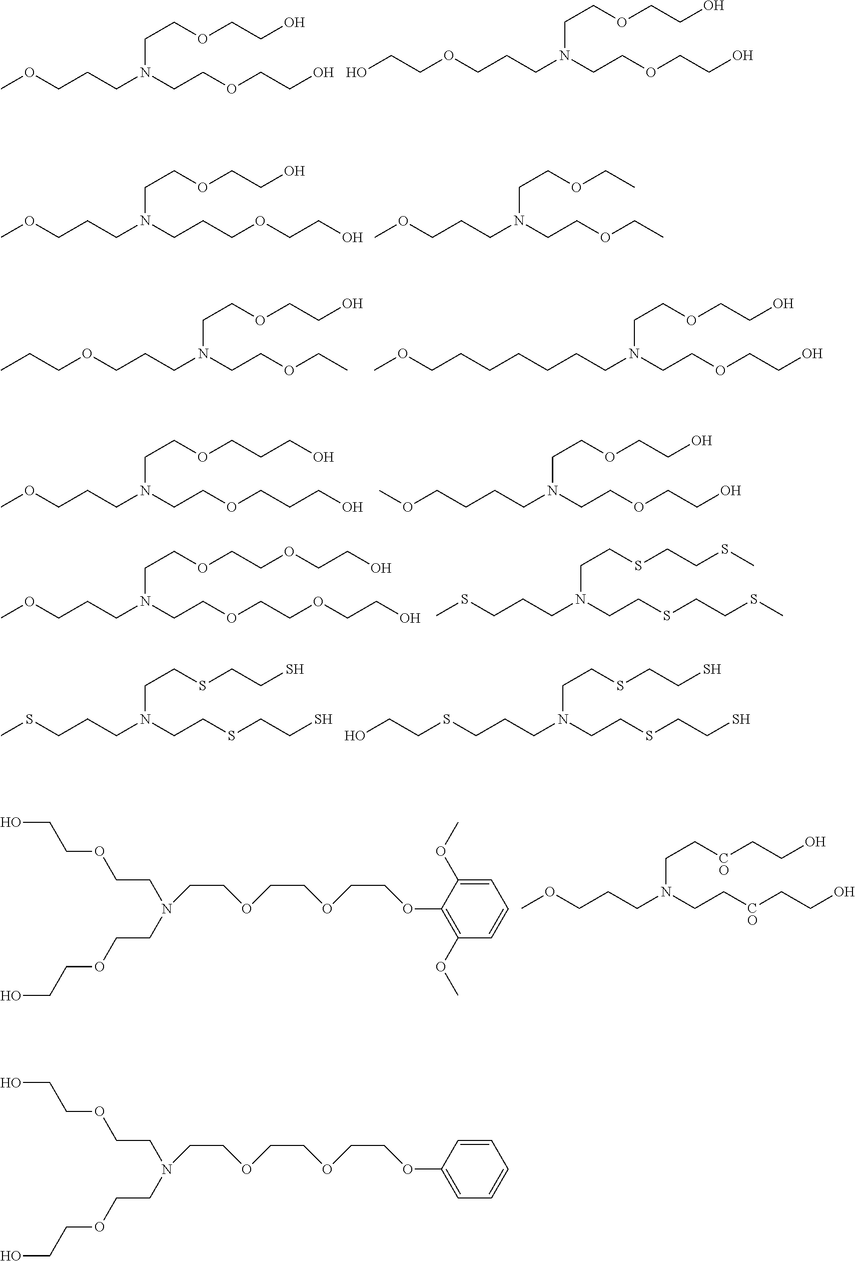

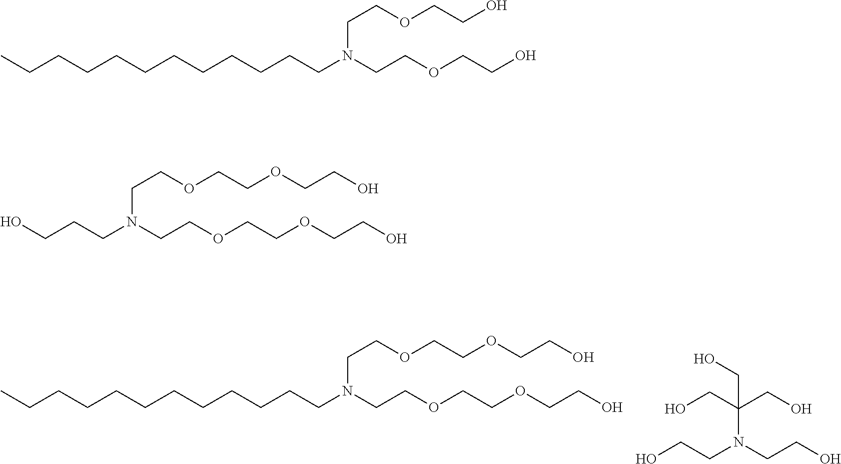

(2) Compound Having Nitrogen-Containing Heterocyclic Structure

The nitrogen-containing heterocycle may have aromatic properties, or may not have aromatic properties. In addition, the nitrogen-containing heterocycle may have a plurality of nitrogen atoms. Furthermore, the nitrogen-containing heterocycle may contain heteroatoms other than the nitrogen atom. Specific examples thereof include a compound having an imidazole structure (2-phenylbenzimidazole, 2,4,5-triphenylimidazole and the like), a compound having a piperidine structure [N-hydroxyethylpiperidine, bis(1,2,2,6,6-pentamethyl-4-piperidyl)sebacate, and the like], a compound having a pyridine structure (4-dimethylaminopyridine and the like), and a compound having an antipyrine structure (antipyrine, hydroxyantipyrine, and the like).

Examples of the preferable compound having a nitrogen-containing heterocyclic structure include guanidine, aminopyridine, aminoalkyl pyridine, aminopyrrolidine, indazole, imidazole, pyrazole, pyrazine, pyrimidine, purine, imidazoline, pyrazoline, piperazine, aminomorpholine, and aminoalkyl morpholine. These may further have a substituent.

Examples of the preferable substituent include an amino group, an aminoalkyl group, an alkylamino group, an aminoaryl group, an arylamino group, an alkyl group, an alkoxy group, an acyl group, an acyloxy group, an aryl group, an aryloxy group, a nitro group, a hydroxyl group, and a cyano group.

Examples of a particularly preferable basic compound include imidazole, 2-methylimidazole, 4-methylimidazole, N-methylimidazole, 2-phenylimidazole, 4,5-diphenyl midazole, 2,4,5-triphenylimidazole, 2-aminopyridine, 3-aminopyridine, 4-aminopyridine, 2-dimethylaminopyridine, 4-dimethylaminopyridine, 2-diethylaminopyridine, 2-(aminomethyl)pyridine, 2-amino-3-methylpyridine, 2-amino-4-methylpyridine, 2-amino-5-methylpyridine, 2-amino-6-methylpyridine, 3-aminoethylpyridine, 4-aminoethyl yridine, 3-aminopyrrolidine, piperazine, N-(2-aminoethyl)piperazine, N-(2-aminoethyl) piperidine, 4-amino-2,2,6,6-tetramethylpiperidine, 4-piperidinopiperidine, 2-iminopiperidine, 1-(2-aminoethyl)pyrrolidine, pyrazole, 3-amino-5-methylpyrazole, 5-amino-3-methyl-1-p-tolylpyrazole, pyrazine, 2-(aminomethyl)-5-methyl pyrazine, pyrimidine, 2,4-diaminopyrimidine, 4,6-dihydroxypyrimidine, 2-pyrazoline, 3-pyrazoline, N-aminomorpholine, and N-(2-aminoethyl)morpholine.

In addition, a compound having two or more ring structures can also be suitably used. Specific examples thereof include 1,5-diazabicyclo[4.3.0]non-5-ene and 1,8-diazabicyclo[5.4.0]undeca-7-ene.

(3) Amine Compound Having Phenoxy Group

An amine compound having a phenoxy group is a compound having a phenoxy group at the terminal on the opposite side to the N atom of the alkyl group which is contained in an amine compound. The phenoxy group may have a substituent such as an alkyl group, an alkoxy group, a halogen atom, a cyano group, a nitro group, a carboxy group, a carboxylic acid ester group, a sulfonic acid ester group, an aryl group, an aralkyl group, an acyloxy group, or an aryloxy group.

The compound more preferably has at least one oxyalkylene chain between the phenoxy group and the nitrogen atom. The number of oxyalkylene chains in one molecule is preferably 3 to 9, and more preferably 4 to 6. Among the oxyalkylene chains, —CH₂CH₂O— is particularly preferable.

Specific examples thereof include 2-[2-{2-(2,2-dimethoxyphenoxyethoxy)ethyl}-bis-(2-methoxy-ethyl)-amine and the compounds (C1-1) to (C3-3) exemplified in paragraph “0066” in the specification of US2007/0224539A1.

An amine compound having a phenoxy group is obtained by, for example, heating a mixture of a primary or secondary amine having a phenoxy group and an haloalkyl ether to be reacted, by adding an aqueous solution of a strong base such as sodium hydroxide, potassium hydroxide, or tetraalkylammonium thereto, and by extracting the resultant product with an organic solvent such as ethyl acetate or chloroform. In addition, an amine compound having a phenoxy group can also be obtained by heating a mixture of a primary or secondary amine and an haloalkyl ether having a phenoxy group at the terminal to be reacted, by adding an aqueous solution of a strong base such as sodium hydroxide, potassium hydroxide, or tetraalkylammonium thereto, and by extracting the resultant product with an organic solvent such as ethyl acetate or chloroform.

(4) Ammonium Salt

It is also possible to suitably use an ammonium salt as the basic compound.

As the cation of the ammonium salt, a tetraalkylammonium cation in which an alkyl group having 1 to 18 carbon atoms is substituted is preferable, a tetramethylammonium cation, a tetraethylammonium cation, a tetra(n-butyl)ammonium cation, a tetra(n-heptyl)ammonium cation, atetra(n-octyl)ammonium cation, a dimethylhexadecylammonium cation, or a benzyltrimethylammonium cation is more preferable, and tetra(n-butyl)ammonium cation is most preferable.

Examples of the anion of the ammonium salt include hydroxide, carboxylate, halide, sulfonate, borate, and phosphate. Among these, hydroxide or carboxylate is particularly preferable.

As the halide, chloride, bromide, or iodide is particularly preferable.

As the sulfonate, an organic sulfonate having 1 to 20 carbon atoms is particularly preferable. Examples of the organic sulfonate include alkyl sulfonate and aryl sulfonate, having 1 to 20 carbon atoms.

The alkyl group included in the alkyl sulfonate may have a substituent. Examples of the substituent include a fluorine atom, a chlorine atom, a bromine atom, an alkoxy group, an acyl group, and an aryl group. Specific examples of the alkyl sulfonate include methanesulfonate, ethanesulfonate, butanesulfonate, hexanesulfonate, octanesulfonate, benzyl sulfonate, trifluoromethanesulfonate, pentafluoroethanesulfonate, and nonafluorobutanesulfonate.

Examples of the aryl group included in the aryl sulfonate include a phenyl group, a naphthyl group, and an anthryl group. These aryl groups may have a substituent. As the substituent, for example, a linear or branched alkyl group having 1 to 6 carbon atoms or a cycloalkyl group having 3 to 6 carbon atoms is preferable. Specifically, for example, a methyl group, an ethyl group, an n-propyl group, an isopropyl group, an n-butyl group, an i-butyl group, a t-butyl group, an n-hexyl group, or a cyclohexyl group is preferable. Examples of other substituents include an alkoxy group having 1 to 6 carbon atoms, a halogen atom, a cyano group, a nitro group, an acyl group, and an acyloxy group.

The carboxylate may be aliphatic carboxylate or aromatic carboxylate, and examples thereof include acetate, lactate, pyruvate, trifluoroacetate, adamantane carboxylate, hydroxyadamantane carboxylate, benzoate, naphthoate, salicylate, phthalate, and phenolate, and, in particular, benzoate, naphthoate, or phenolate is preferable, and benzoate is most preferable.

In this case, as the ammonium salt, tetra(n-butyl) ammonium benzoate or tetra(n-butyl) ammonium phenolate is preferable.

In the case of hydroxide, the ammonium salt is particularly preferably tetraalkylammonium hydroxide such as tetramethyl ammonium hydroxide, tetraethyl ammonium hydroxide, or tetra-(n-butyl) ammonium hydroxide having 1 to 8 carbon atoms.

(5) Compound (PA) which has Proton-Accepting Functional Group and Generates Compound in which Proton-Acceptability is Reduced or Lost, or which is Changed from being Proton-Accepting to be Acidic, by being Decomposed Due to Irradiation with Active Light or Radiation

The active light sensitive or radiation sensitive resin composition may further include a compound (hereinafter, referred to as a “compound (PA)”) which has a proton-accepting functional group and generates a compound in which the proton-acceptability is reduced or lost, or which is changed from being proton-accepting to be acidic, by being decomposed due to irradiation with active light or radiation, as a basic compound.

Regarding the compound (PA) which has a proton-accepting functional group and generates a compound in which the proton-acceptability is reduced or lost, or which is changed from being proton-accepting to be acidic, by being decomposed due to irradiation with active light or radiation, the description in paragraphs “0379” to “0425” of JP2012-32762A (which corresponds to paragraphs “0386” to “0435” of US2012/0003590A) can be referred to, and the contents thereof are incorporated in the present specification.

(6) Guanidine Compound

The composition of the present invention may further contain a guanidine compound having a structure represented by the following formula.

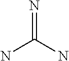

The guanidine compound exhibits strong basicity since the positive charge of the conjugate acid is dispersed and stabilized by the three nitrogen atoms.

For the basicity of the guanidine compound (A) of the present invention, the pKa of a conjugate acid is preferably 6.0 or greater, preferably 7.0 to 20.0 since neutralization reactivity with an acid is high and the roughness properties are excellent, and more preferably 8.0 to 16.0.

Due to such strong basicity, the diffusibility of an acid is suppressed, and the strong basicity can contribute to formation of an excellent pattern shape.

Moreover, the “pKa” here represents pKa in an aqueous solution, and for example, it is described in Chemical Handbook (II) (revised 4th edition, 1993, edited by The Chemical Society of Japan, published by Maruzen Co., Ltd.), and a smaller value means higher acidity. Specifically, the pKa in aqueous solution can be obtained by measuring the acid dissociation constant at 25° C. using an infinite dilution aqueous solution, and a value based on the database of Hammett substituent constants and known literature values can also be determined by calculation using the following software package 1. All of pKa values described in the present specification are values determined by calculation using this software package.

Software Package 1: Advanced Chemistry Development (ACD/Labs) Software V8.14 for Solaris (1994-2007 ACD/Labs).

In the present invention, log P is a logarithmic value of an n-octanol/water distribution coefficient (P), and with respect to a wide range of compounds, it is an effective parameter that can characterize the hydrophilicity/hydrophobicity. In general, the distribution coefficient is determined not by experiment but by calculation, and in the present invention, the distribution coefficient is a value calculated by a CS ChemDraw Ultra Ver. 8.0 software package (Crippen's fragmentation method).

In addition, the log P of the guanidine compound (A) is preferably 10 or less. In a case where the log P is the above value or less, the guanidine compound can be uniformly contained in a resist film.

The log P of the guanidine compound (A) in the present invention is preferably within a range of 2 to 10, more preferably within a range of 3 to 8, and particularly preferably within a range of 4 to 8.

In addition, the guanidine compound (A) in the present invention preferably does not have a nitrogen atom other than a guanidine structure.

Specific examples of the guanidine compound are shown below, but, the present invention is not limited thereto.

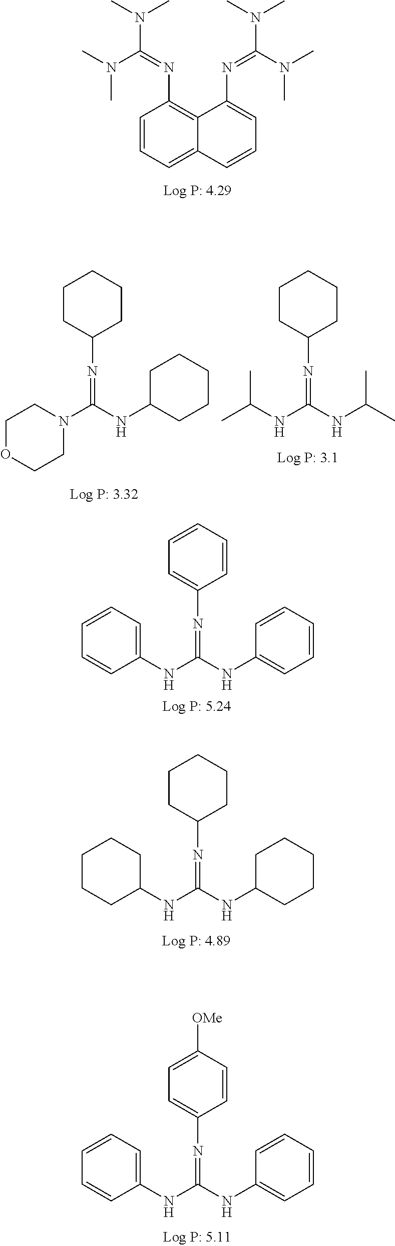

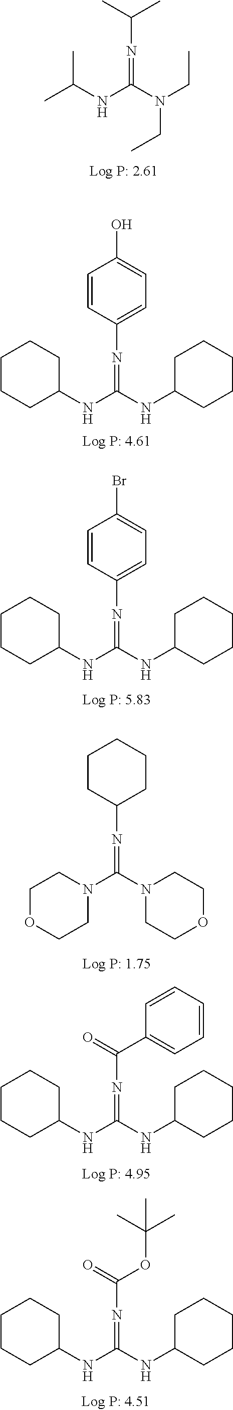 [SMILES: CCN(CC)C(=NC(C)C)NC(C)C ; Oc1ccc(N=C(NC2CCCCC2)NC2CCCCC2)cc1 ; Brc1ccc(N=C(NC2CCCCC2)NC2CCCCC2)cc1 ; C1CCC(N=C(N2CCOCC2)N2CCOCC2)CC1 ; O=C(N=C(NC1CCCCC1)NC1CCCCC1)c1ccccc1 ; CC(C)(C)OC(=O)N=C(NC1CCCCC1)NC1CCCCC1]

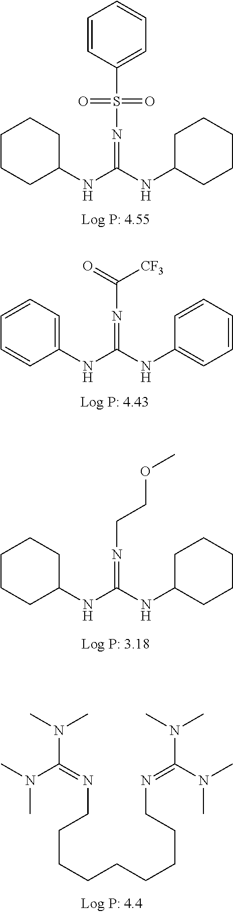

(7) Low Molecular Weight Compound Having Nitrogen Atom and Group Leaving Due to Action of Acid

The active light sensitive or radiation sensitive resin composition can contain a low molecular weight compound (hereinafter, also referred to as a “low molecular weight compound (D)” or “compound (D)”) having a nitrogen atom and a group leaving due to the action of an acid. The low molecular weight compound (D) preferably has basicity, after a group leaving due to the action of an acid leaves.

Regarding the low molecular compound (D), the description in paragraphs “0324” to “0337” of JP2012-133331A can be referred to, and the contents thereof are incorporated in the present specification.

In the present invention, the low molecular weight compound (D) may be used singly or in a mixture of two or more types thereof.

Other than this, examples of the compound which can be used in the composition according to the present invention include the compounds synthesized in Examples of JP2002-363146A and the compounds described in paragraph “0108” of JP2007-298569A.

As the basic compound, a photosensitive basic compound may be used. As the photosensitive basic compound, for example, the compounds described in JP2003-524799A, J. Photopolym. Sci. & Tech. Vol. 8, P. 543-553 (1995), and the like as can be used.

The molecular weight of the basic compound is typically 100 to 1500, preferably 150 to 1300, and more preferably 200 to 1000.

These basic compounds (D) may be used alone or two or more types thereof may be used in combination.

The content of the basic compound (D) included in the active light sensitive or radiation sensitive resin composition is preferably 0.01% by mass to 8.0% by mass, more preferably 0.1% by mass to 5.0% by mass, and particularly preferably 0.2% by mass to 4.0% by mass, based on the total solid content in the composition.

The molar ratio of the basic compound (D) with respect to the acid generator is preferably set to 0.01 to 10, more preferably set to 0.05 to 5, and still more preferably set to 0.1 to 3. In a case where the molar ratio is excessively large, sensitivity and/or resolution is reduced in some cases. In a case where the molar ratio is excessively small, there is a possibility that thinning of a pattern occurs, during exposure and heating (post-baking). The molar ratio is more preferably 0.05 to 5, and still more preferably 0.1 to 3. Moreover, the acid generator in the above molar ratio is based on the total amount of the repeating unit represented by General Formula (5), of the resin (A) and the acid generator which the resin (A) further may include.

[5] Compound that Generates Acid by being Decomposed Due to Action of Acid

The active light sensitive or radiation sensitive resin composition may further include one or two or more types of compound that generates an acid by being decomposed due to the action of an acid. The acid generated by the compound that generates an acid by being decomposed due to the action of an acid is preferably sulfonic acid, methide acid, or imidic acid.

Examples of the compound that generates an acid by being decomposed due to the action of an acid which can be used in the present invention will be shown below, but the present invention is not limited thereto.

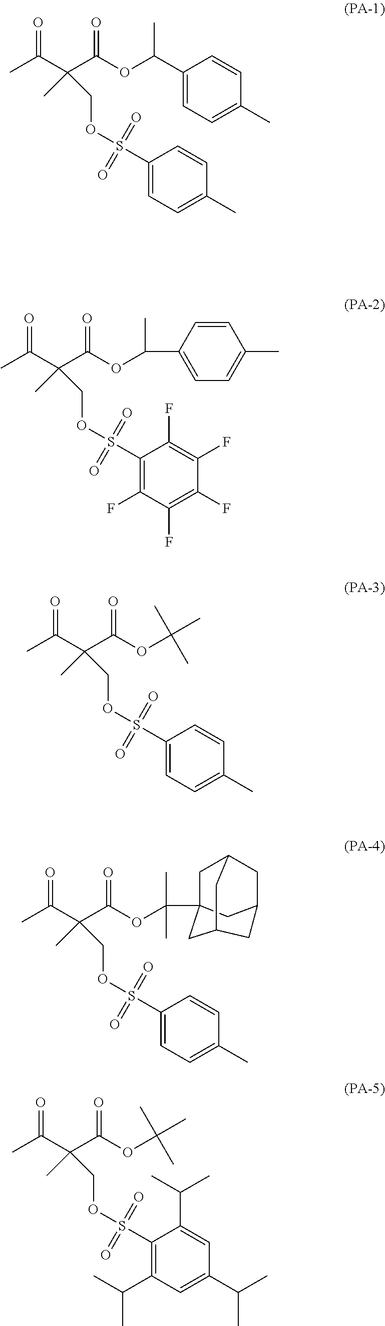

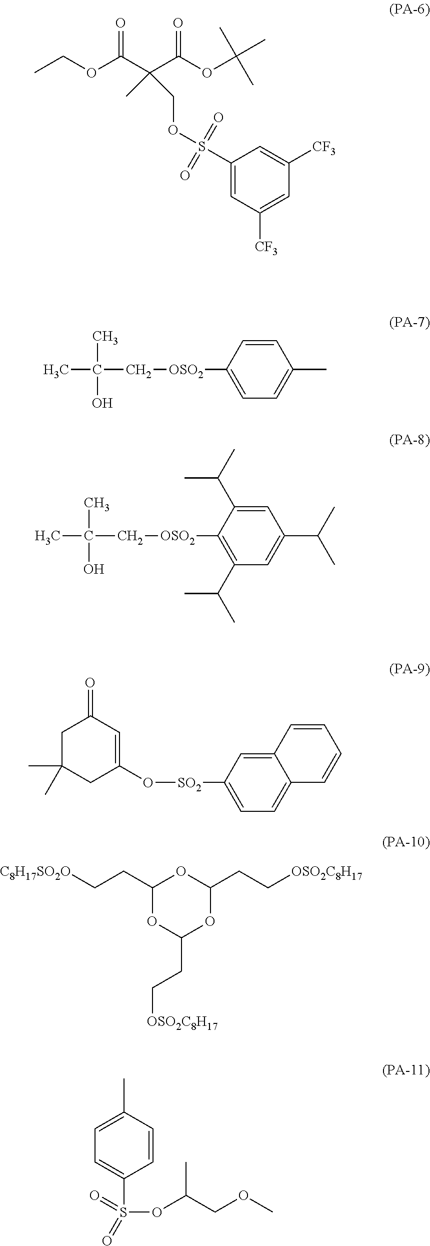

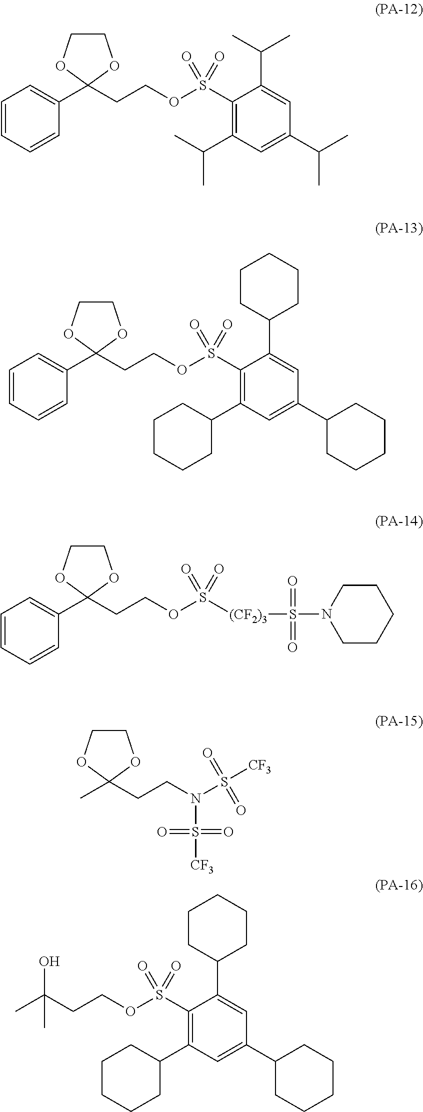

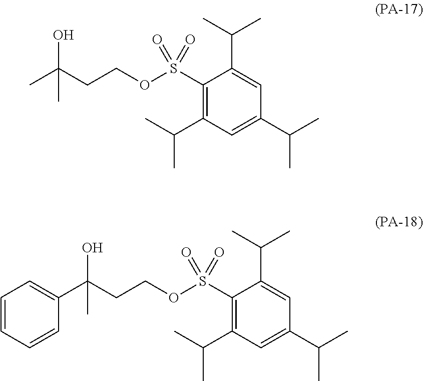 [SMILES: CC(C)c1cc(C(C)C)c(S(=O)(=O)OCCC(C)(C)O)c(C(C)C)c1 ; CC(C)c1cc(C(C)C)c(S(=O)(=O)OCCC(C)(O)c2ccccc2)c(C(C)C)c1]

The compound that generates an acid by being decomposed due to the action of an acid may be used alone or two or more types thereof can be used in combination.

The content of the compound that generates an acid by being decomposed due to the action of an acid is preferably 0.1% by mass to 40% by mass, more preferably 0.5% by mass to 30% by mass, and still more preferably 1.0% by mass to 20% by mass, based on the total solid content in the active light sensitive or radiation sensitive resin composition.

[6] Hydrophobic Resin (HR)

The active light sensitive or radiation sensitive resin composition of the present invention may have a hydrophobic resin (HR) separately from the resin (A).

The hydrophobic resin (HR) preferably contains a group having a fluorine atom, a group having a silicon atom, or a hydrocarbon group having 5 or more carbon atoms, in order to be unevenly distributed on a film surface. These groups may be contained in the main chain of the resin or may be substituted on the side chain. Specific examples of the hydrophobic resin (HR) will be shown below.

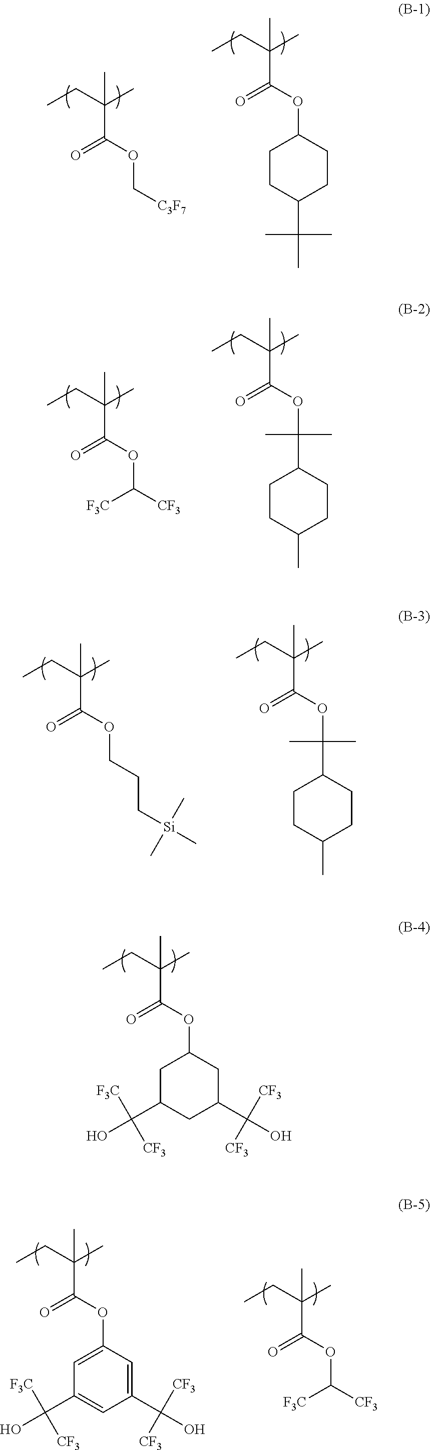

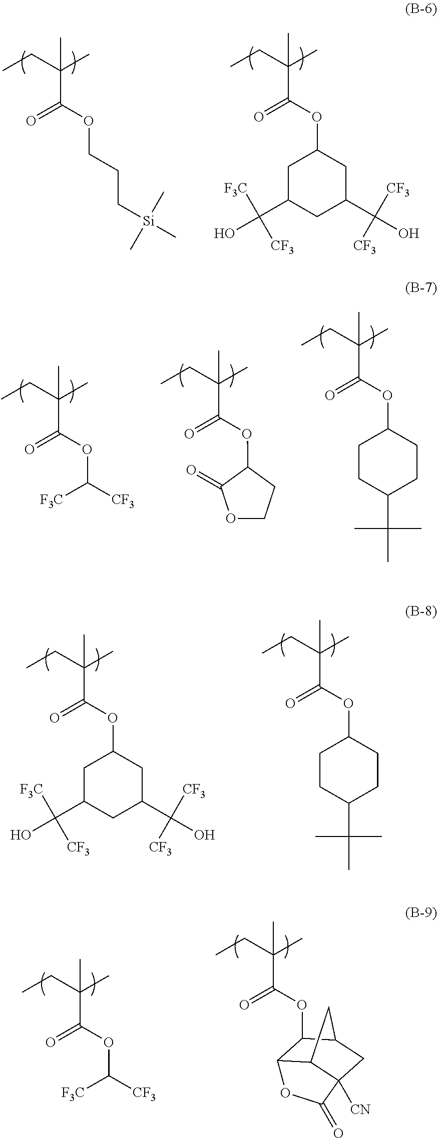

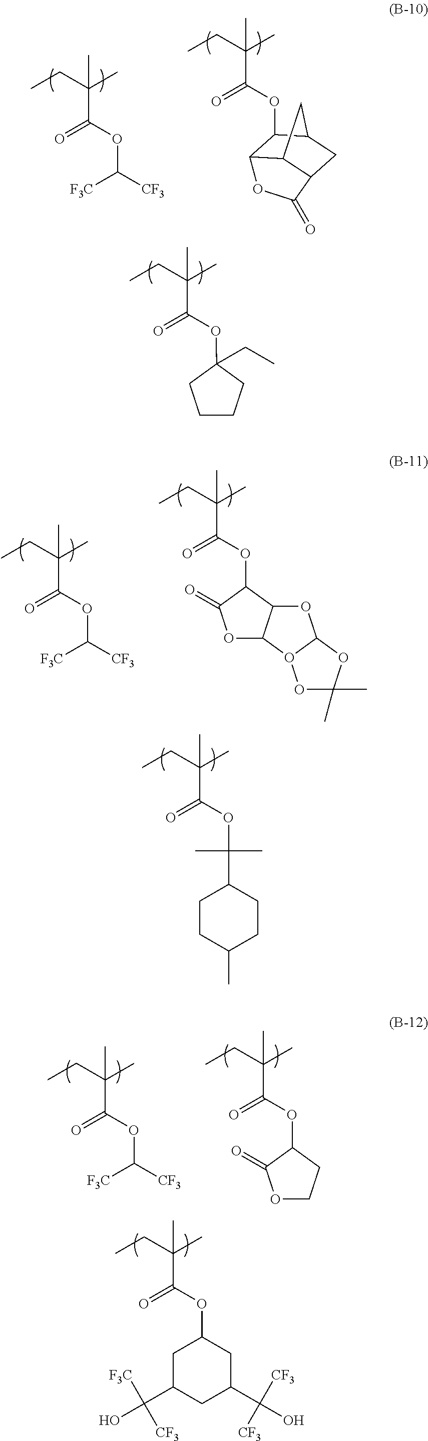

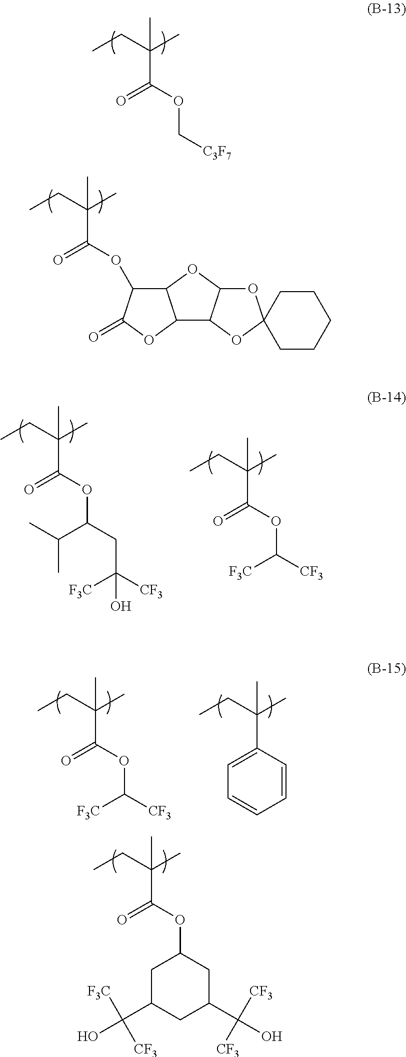

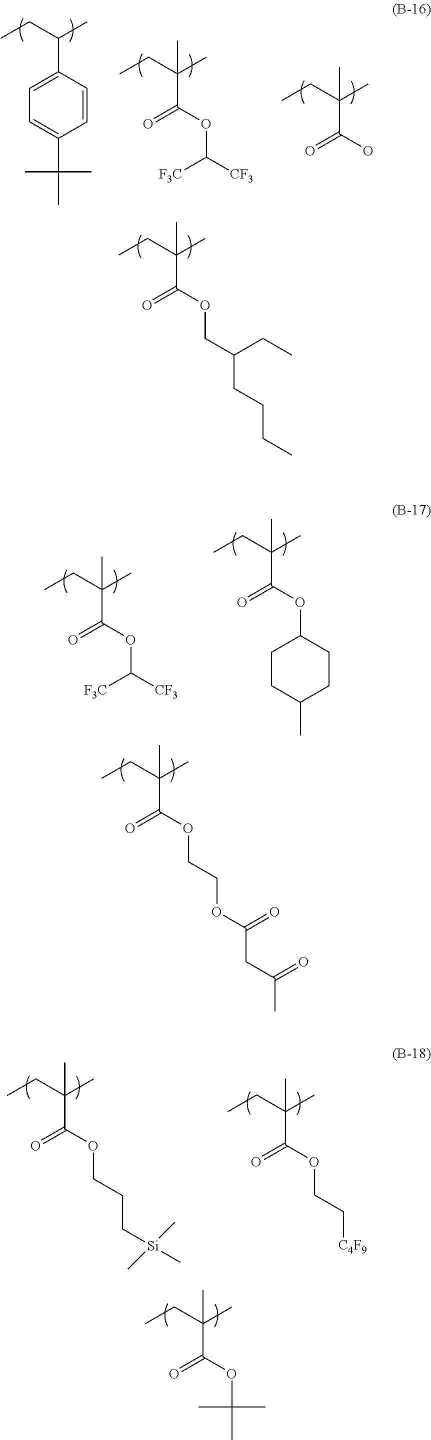

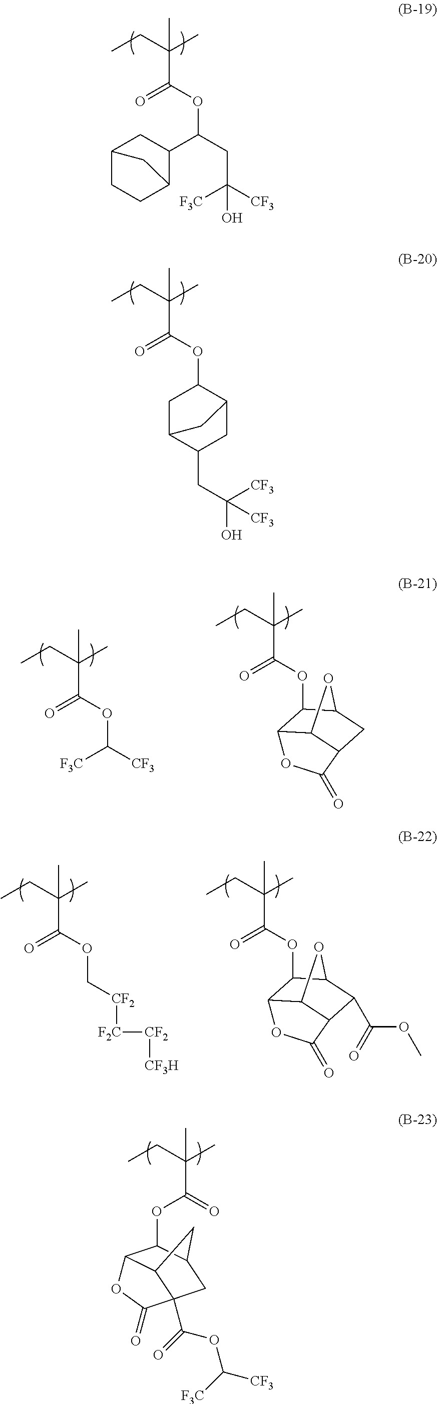

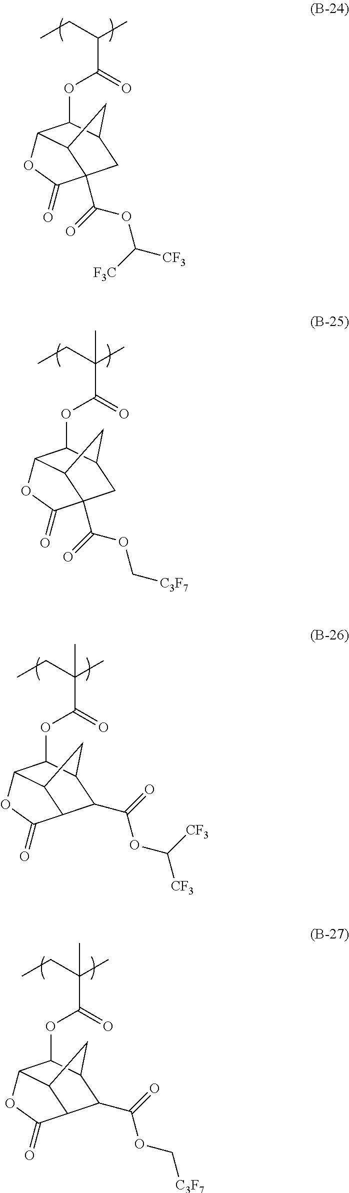

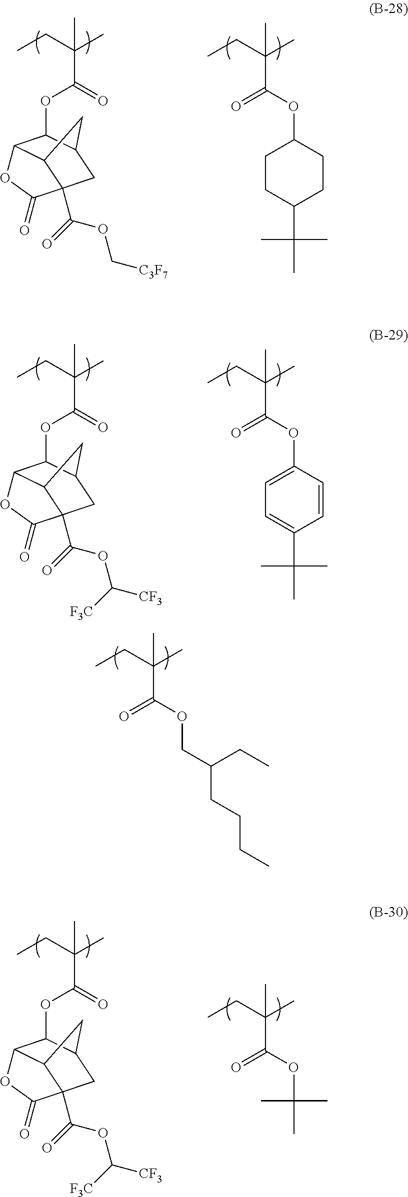

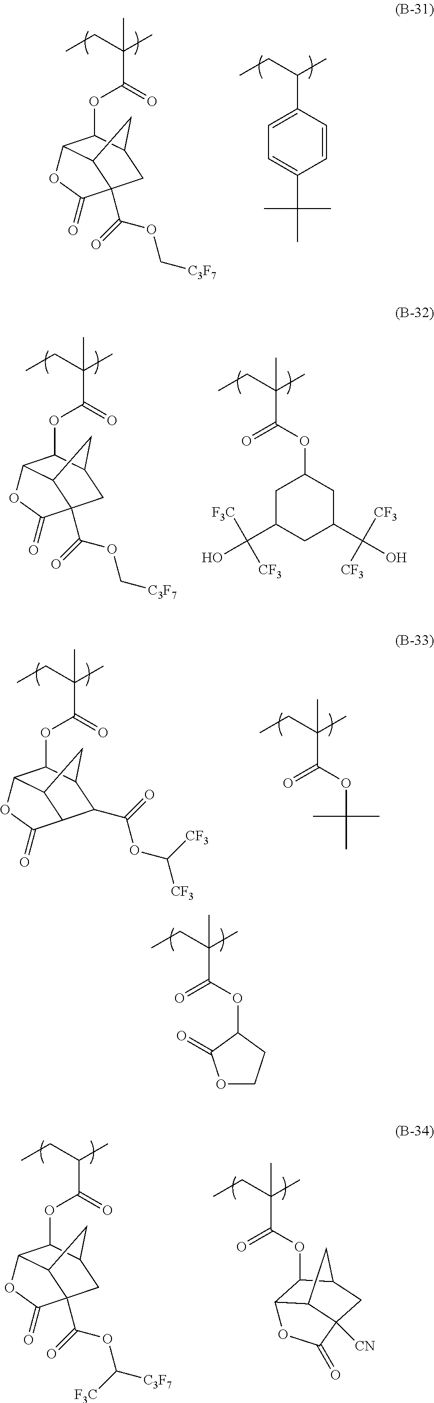

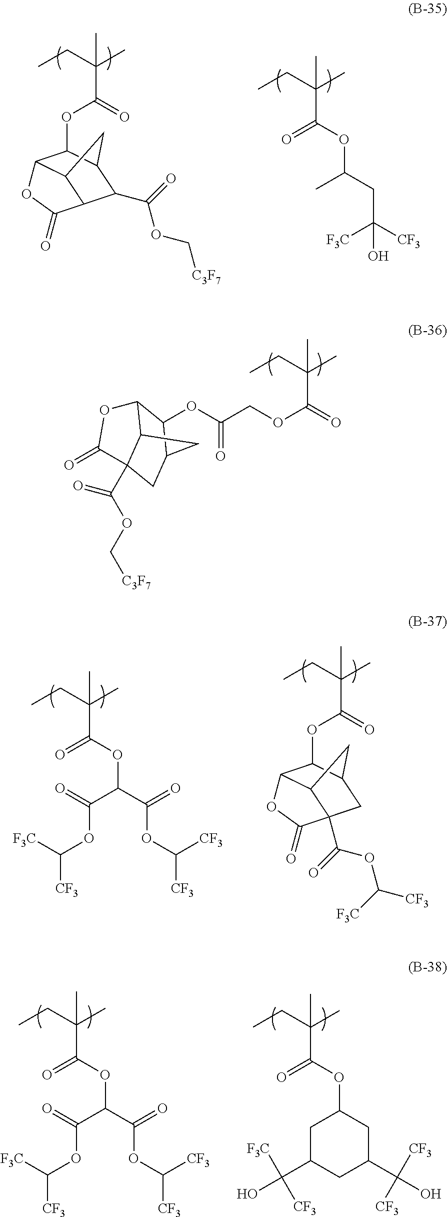

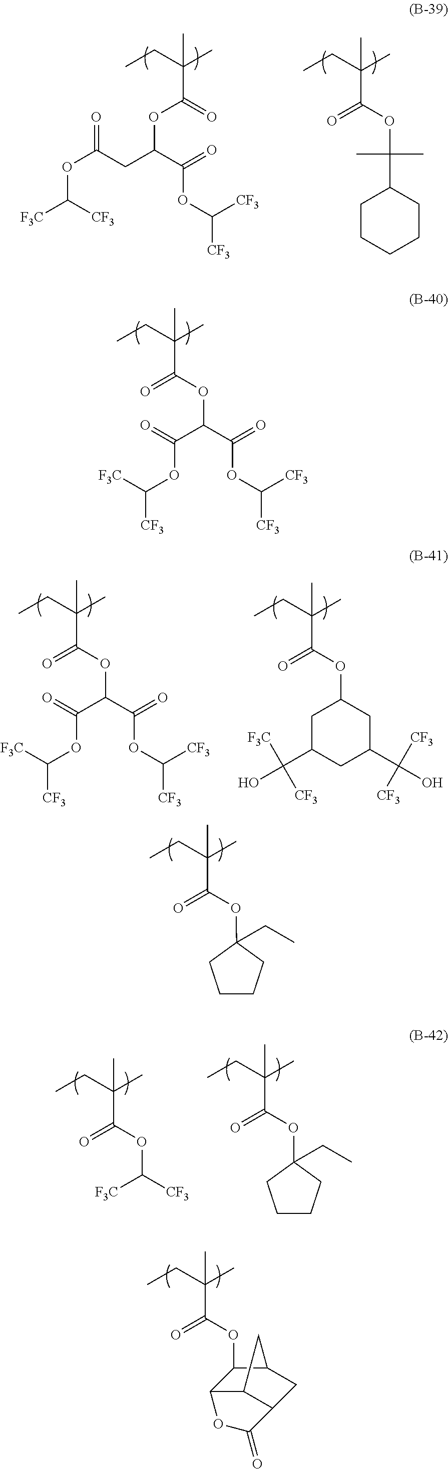

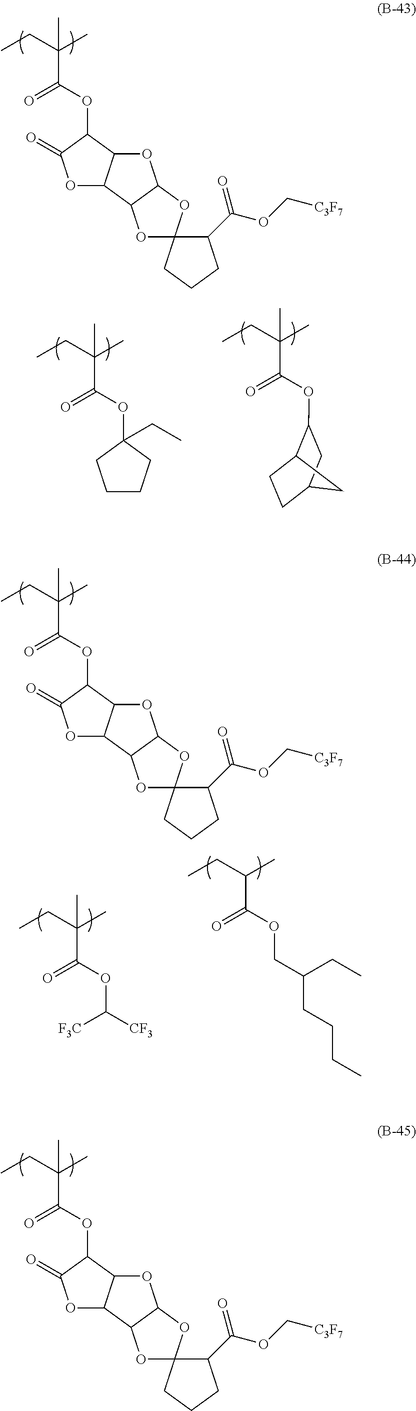

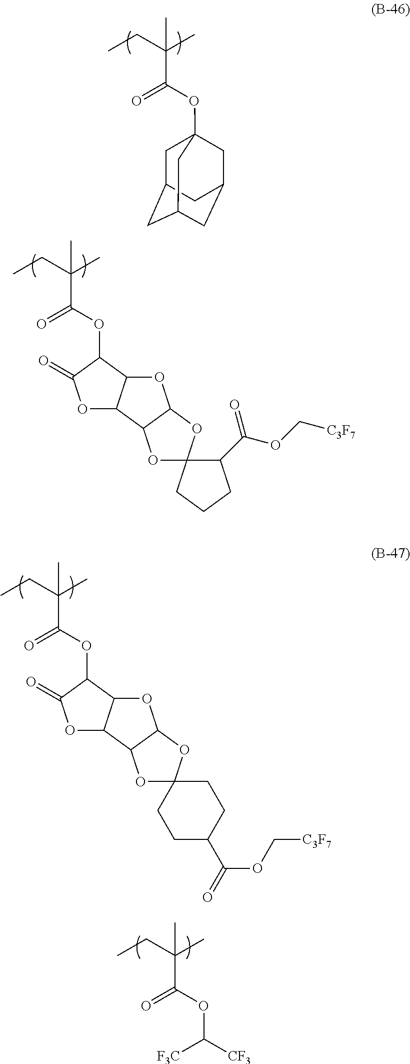

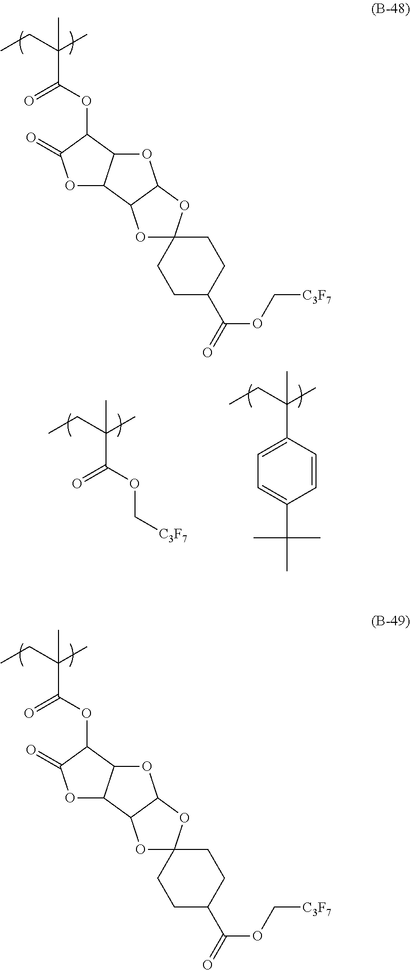

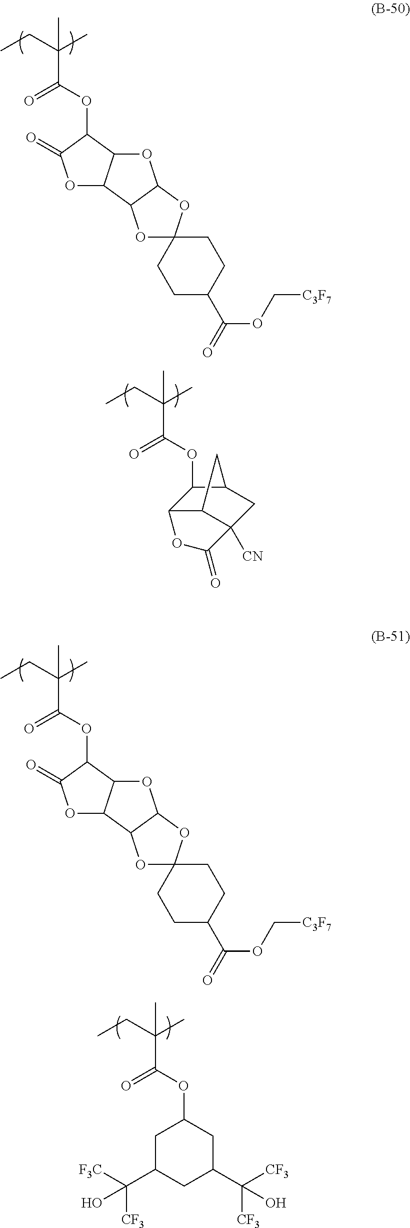

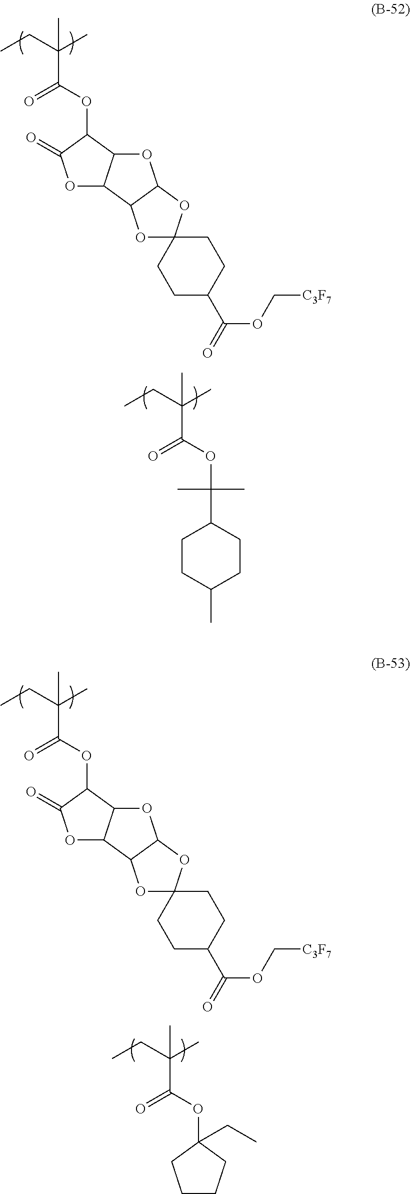

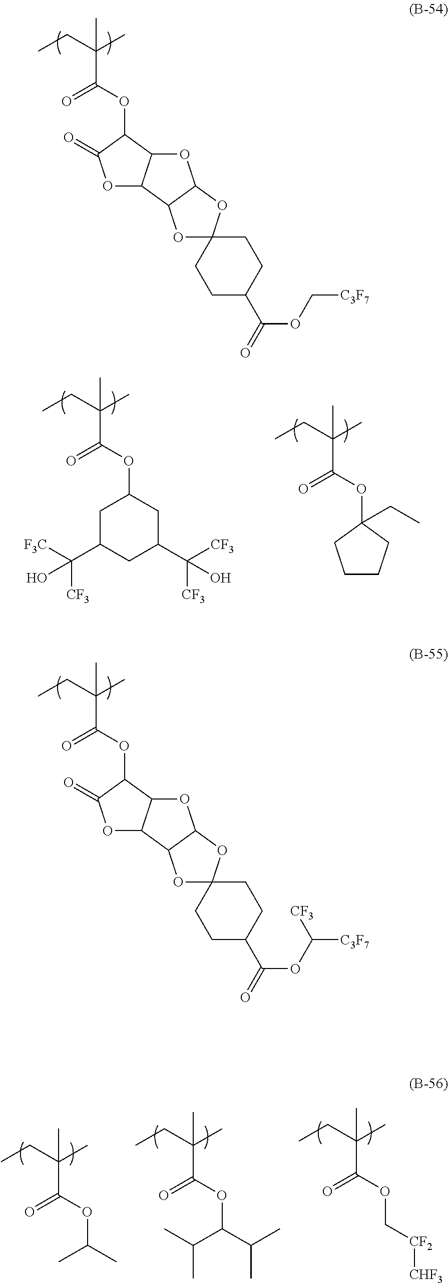

TABLE 1

| | Compositional ratio | | |
|---|---|---|---|
| Polymer | (mol %) | Mw | Mw/Mn |
| B-1 | 50/50 | 6000 | 1.5 |
| B-2 | 30/70 | 6500 | 1.4 |
| B-3 | 45/55 | 8000 | 1.4 |
| B-4 | 100 | 15000 | 1.7 |
| B-5 | 60/40 | 6000 | 1.4 |
| B-6 | 40/60 | 8000 | 1.4 |
| B-7 | 30/40/30 | 8000 | 1.4 |
| B-8 | 60/40 | 8000 | 1.3 |
| B-9 | 50/50 | 6000 | 1.4 |
| B-10 | 40/40/20 | 7000 | 1.4 |
| B-11 | 40/30/30 | 9000 | 1.6 |
| B-12 | 30/30/40 | 6000 | 1.4 |
| B-13 | 60/40 | 9500 | 1.4 |
| B-14 | 60/40 | 8000 | 1.4 |
| B-15 | 35/35/30 | 7000 | 1.4 |
| B-16 | 50/40/5/5 | 6800 | 1.3 |
| B-17 | 20/30/50 | 8000 | 1.4 |
| B-18 | 25/25/50 | 6000 | 1.4 |
| B-19 | 100 | 9500 | 1.5 |
| B-20 | 100 | 7000 | 1.5 |
| B-21 | 50/50 | 6000 | 1.6 |
| B-22 | 40/60 | 9600 | 1.3 |
| B-23 | 100 | 20000 | 1.7 |
| B-24 | 100 | 25000 | 1.4 |
| B-25 | 100 | 15000 | 1.7 |
| B-26 | 100 | 12000 | 1.8 |
| B-27 | 100 | 18000 | 1.3 |
| B-28 | 70/30 | 15000 | 2.0 |
| B-29 | 80/15/5 | 18000 | 1.8 |
| B-30 | 60/40 | 25000 | 1.8 |
| B-31 | 90/10 | 19000 | 1.6 |
| B-32 | 60/40 | 20000 | 1.8 |
| B-33 | 50/30/20 | 11000 | 1.6 |
| B-34 | 60/40 | 12000 | 1.8 |
| B-35 | 60/40 | 15000 | 1.6 |
| B-36 | 100 | 22000 | 1.8 |
| B-37 | 20/80 | 35000 | 1.6 |
| B-38 | 30/70 | 12000 | 1.7 |
| B-39 | 30/70 | 9000 | 1.5 |
| B-40 | 100 | 9000 | 1.5 |
| B-41 | 40/15/45 | 12000 | 1.9 |
| B-42 | 30/30/40 | 13000 | 2.0 |
| B-43 | 40/40/20 | 23000 | 2.1 |
| B-44 | 65/30/5 | 25000 | 1.6 |
| B-45 | 100 | 15000 | 1.7 |
| B-46 | 20/80 | 9000 | 1.7 |
| B-47 | 70/30 | 18000 | 1.5 |
| B-48 | 60/20/20 | 18000 | 1.8 |
| B-49 | 100 | 12000 | 1.4 |
| B-50 | 60/40 | 20000 | 1.6 |
| B-51 | 70/30 | 33000 | 2.0 |
| B-52 | 60/40 | 19000 | 1.8 |
| B-53 | 50/50 | 15000 | 1.5 |
| B-54 | 40/20/40 | 35000 | 1.9 |
| B-55 | 100 | 16000 | 1.4 |
| B-56 | 30/65/5 | 28000 | 1.7 |

In addition to the above hydrophobic resins, the hydrophobic resins described in JP2011-248019A, JP2010-175859A, or JP 2012-032544A can also be preferably used.

[7] Surfactant

The active light sensitive or radiation sensitive resin composition may further include a surfactant. Due to a surfactant being contained, in a case where an exposure light source having a wavelength of 250 nm or less, in particular, 220 nm or less, is used, a pattern having less adhesion and development defect can be formed with a good sensitivity and resolution.

As the surfactant, a fluorine-based surfactant and/or a silicon-based surfactant is particularly preferably used.

Examples of the fluorine-based surfactant and/or the silicon-based surfactant include surfactants described in paragraph “0276” in the specification of US2008/0248425A. In addition, F TOP EF301 or EF303 (manufactured by Shin-Akita Kasci Co., Ltd.); FLUORAD FC430, 431, or 4430 (manufactured by Sumitomo 3M Ltd.); MEGAFAC F171, F173, F176, F189, F113, F110, F177, F120, or R08 (manufactured by DIC Corporation); SURFLON S-382, SC101, 102, 103, 104, 105, or 106 (manufactured by Asahi Glass Co., Ltd.); TROYSOL S-366 (manufactured by Troy Chemical Corp.); GF-300 or GF-150 (manufactured by Toagosei Chemical Industry Co., Ltd.), SURFLON S-393 (manufactured by AGC Seimi Chemical Co., Ltd.); EFTOP EF121, EF122A, EF122B, RF122C, EF125M, EF135M, EF351, EF352, EF801, EF802, or EF601 (manufactured by Jemco Co., Ltd.); PF636, PF656, PF6320, or PF6520 (manufactured by OMNOVA Solutions Inc.); or FTX-204G, 208G, 218G, 230G, 204D, 208D, 212D, 218D, or 222D (manufactured by Neos Company Limited) may be used. Moreover, a polysiloxane polymer KP-341 (manufactured by Shin-Etsu Chemical Co., Ltd.) can also be used as a silicon-based surfactant.

In addition, in addition to the known surfactants as described above, the surfactant may be synthesized using a fluoroaliphatic compound prepared by a telomerization method (also referred to as a telomer method) or an oligomerization method (also referred to as an oligomer method). Specifically, a polymer having a fluoroaliphatic group derived from the fluoroaliphatic compound may be used as a surfactant. The fluoroaliphatic compound can be synthesized by the method described in JP2002-90991A.

As the polymer having a fluoroaliphatic group, a copolymer of a monomer having a fluoroaliphatic group and (poly(oxyalkylene))acrylate or methacrylate and/or (poly(oxyalkylene))methacrylate is preferable, and the polymer may be irregularly distributed, or may be a block copolymer.

Examples of the poly(oxyalkylene) group include a poly(oxyethylene) group, a poly(oxypropylene) group, and a poly(oxybutylene) group. In addition, the poly(oxyalkylene) group may be a unit having alkylenes having different chain lengths in the same chain, such as poly(block connector of oxyethylene, oxypropylene and oxyethylene) and poly(block connector of oxyethylene and oxypropylene).

Furthermore, a copolymer of a monomer having a fluoroaliphatic group and (poly(oxyalkylene))acrylate or methacrylate may be a ternary or higher copolymer formed by copolymerizing a monomer having different two or more types of fluoroaliphatic group and different two or more types of (poly(oxyalkylene))acrylate or methacrylate at the same time.

For example, examples of a commercially available surfactant include MEGAFAC F178, F-470, F-473, F-475, F-476, and F-472 (manufactured by DIC Corporation). Furthermore, examples of a commercially available surfactant include a copolymer of an acrylate or methacrylate having a C₆F₁₃ group and (poly(oxyalkylene))acrylate or methacrylate, a copolymer of an acrylate or methacrylate having a C₆F₁₃ group, (poly(oxyethylene))acrylate or methacrylate, and (poly(oxypropylene))acrylate or methacrylate, a copolymer of an acrylate or methacrylate having a C₆F₁₇ group and (poly(oxyalkylene))acrylate or methacrylate, and a copolymer of an acrylate or methacrylate having a C₆F₁₇ group, (poly(oxyethylene))acrylate or methacrylate, and (poly(oxypropylene))acrylate or methacrylate.

In addition, surfactants other than the fluorine-based surfactant and/or the silicon-based surfactant described in paragraph “0280” in the specification of US2008/0248425A may be used.

These surfactants may be used alone or in combination of two or more types thereof.

In a case where the active light sensitive or radiation sensitive resin composition includes a surfactant, the content thereof is preferably 0% by mass to 2% by mass, more preferably 0.0001% by mass to 2% by mass, and still more preferably 0.0005% by mass to 1% by mass, based on the total solid content in the composition.

[8] Other Additives

The active light sensitive or radiation sensitive resin composition can suitably contain carboxylic acid, an onium carboxylate salt, a dissolution inhibiting compound having a molecular weight of 3000 or less described in Proceeding of SPIE, 2724, 355 (1996) or the like, a dye, a plasticizer, a photosensitizer, a light absorber, or an antioxidant, in addition to the components described above.

In particular, carboxylic acid is suitably used to improve performance. As the carboxylic acid, aromatic dicarboxylic acid such as benzoic acid or naphthoic acid is preferable.

The content of the carboxylic acid is preferably 0.01% by mass to 10% by mass, more preferably 0.01% by mass to 5% by mass, and still more preferably 0.01% by mass to 3% by mass, with respect to the total solid content concentration in the active light sensitive or radiation sensitive resin composition.

As described above, the active light sensitive or radiation sensitive resin composition is preferably used in a film thickness of 10 nm to 250 nm, more preferably used in a film thickness of 20 nm to 200 nm, and still more preferably used in a film thickness of 30 nm to 100 nm, from the viewpoint of resolution improvement. By setting the solid content concentration in the composition within a suitable range to obtain suitable viscosity, coating properties and film-forming properties are improved, and as a result, such film thicknesses can be obtained.

The solid content concentration in the active light sensitive or radiation sensitive resin composition in the present invention is typically 1.0% by mass to 10% by mass, preferably 2.0% by mass to 5.7% by mass, and still more preferably 2.0% by mass to 5.3% by mass. In a case where the solid content concentration is within the above range, it is possible to uniformly apply a resist solution to a substrate, and it is possible to form a guide pattern having excellent line width roughness. The reason for this is not clear, but, it is thought that, by adjusting the solid content concentration to 10% by mass or less, preferably 5.7% by mass or less, aggregation of the material, in particular, the photoacid generator in an active light sensitive or radiation sensitive resin composition solution is suppressed, and as a result, an even active light sensitive or radiation sensitive film can be formed.

The solid content concentration is a percentage in terms of weight of the weight of the resist components excluding the solvent with respect to the total weight of the active light sensitive or radiation sensitive resin composition.

As the active light sensitive or radiation sensitive resin composition, the components described above are dissolved in a predetermined organic solvent, preferably, dissolved in the mixed solvent described above, then, the resultant product is filtered using a filter, and is applied to a predetermined support (substrate), and used. As the filter used in filtration, a filter made of polytetrafluoroethylene, made of polyethylene, or made of nylon, preferably having a pore size of 0.1 μm or less, more preferably having a pore size of 0.05 μm or less, and still more preferably having a pore size of 0.03 μm or less is preferable. In the filtration using a filter, for example, as in JP2002-62667A, circulation filtration may be performed, or filtration may be performed in a state of connecting a plurality of filters in series or in parallel. The composition may be filtered multiple times. Furthermore, before and after the filtration using a filter, the composition may be subjected to a deaeration treatment.

### EXAMPLES

Hereinafter, the present invention will be specifically described by examples, but the present invention is not limited to the following examples.

<Resin>

### Synthesis Example 1

### Synthesis of Resin (BP-1A)

In a nitrogen atmosphere, s-butyl lithium was added to 50 mL of tetrahydrofuran (THF), followed by stirring at room temperature for 1 hour, and the water in the system was removed. After the resultant product was cooled to −78° C., 0.31 mL (0.50 mmol) of n-butyl lithium (n-BuLi) and 5.75 mL (31.3 mmol) of t-butyl styrene (TBSt) were added thereto to initiate polymerization. After the resultant product was aged for 15 minutes, a THF solution of 0.13 mL (0.75 mmol) of 1,1-diphenyl ethylene (DPE) and 65.7 mg (1.55 mmol) of lithium chloride (LiCl) were added thereto, followed by stirring for 10 minutes. Next, 3.33 mL (31.3 mmol) of methyl methacrylate (MMA) was added to the reaction solution, followed by stirring for 1.5 hours. After stopping the reaction by adding methanol (MeOH) to the reaction solution, reprecipitation operation was performed with a methanol solvent, collection by filtration was performed, and the obtained filtrate was air-dried, whereby a resin (BP-1A) was obtained (Mn=19,700, Mw/Mn=1.05, TBSt block/MMA block=47/53% by weight, Tg=134° C., 145° C., ¹H-NMR (400 MHz, CDCl₃) δ (ppm) 7.2-6.8 (m, 2H), 6.7-6.2 (m, 2H), 3.6 (s, 1H), 2.2-1.7 (m, 1.7H), 1.7-1.5 (m, 2H), 1.5-1.1 (brs, 9H), 1.1-0.7 (m, 0.7H)).

The synthesis scheme of the resin (BP-1A) is shown below. In the following formulas, Me represents a methyl group and Ph represents a phenyl group.

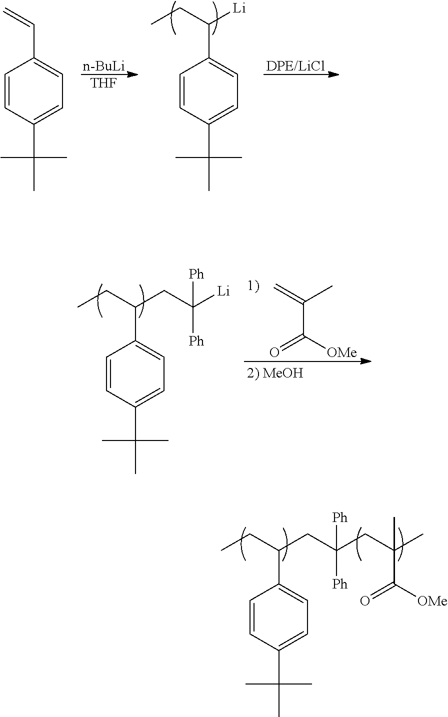

### Synthesis Example 2

### Synthesis of Resin (BP-2A)

The following resin (BP-2A) was obtained in the same manner as in Synthesis Example 1 (Mn=17,200, Mw/Mn=1.15, 2-vinyl naphthalene (2VN) block/MMA block=52/48% by weight, Tg=103° C., 136° C., ¹H-NMR (400 MHz, CDCl₃) δ (ppm) 7.8-6.3 (m, 7H), 3.6 (s, 1.3H), 2.0-0.1 (m, 3.9H), 1.1-0.8 (m, 1.3H).

The synthesis scheme of the resin (BP-2A) is shown below. In the following formulas, Me represents a methyl group and Ph represents a phenyl group.

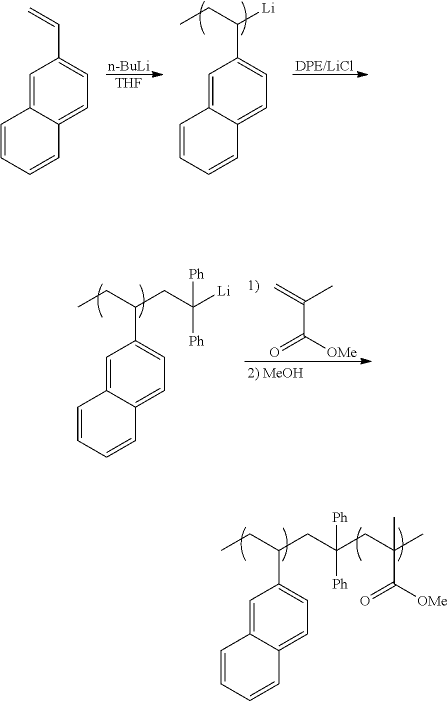

### Synthesis Example 3

### Synthesis of Resin (BP-3A)

The following resin (BP-3A) was obtained in the same manner as in Synthesis Example 1 (Mn=17,900, Mw/Mn=1.08, 4-vinyl biphenyl (VBPh) block/MMA block=52/48% by weight, Tg 107° C., 151° C., ¹H-NMR (400 MHz, CDCl₃) δ (ppm) 7.4-7.0 (m, 5H), 6.8-6.4 (m, 4H), 3.6 (s, 1.3H), 2.2-1.2 (m, 3.91H), 1.1-0.7 (m, 1.3H)).

The synthesis scheme of the resin (BP-3A) is shown below. In the following formulas, Me represents a methyl group and Ph represents a phenyl group.

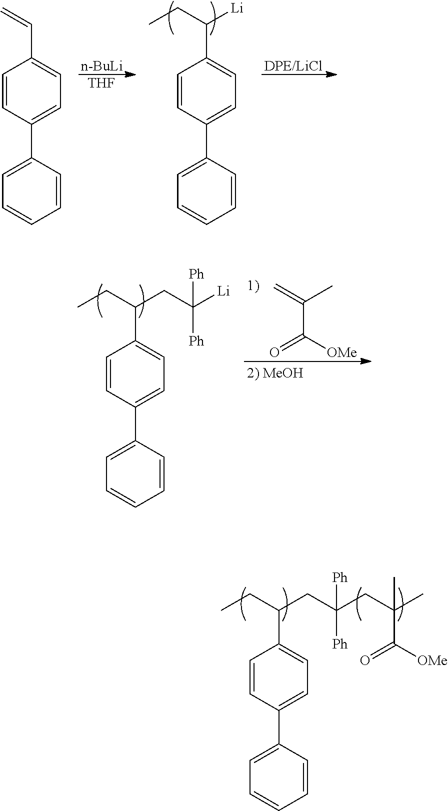

### Synthesis Example 4

### Synthesis of Resin (BP-4A)

The following resin (BP-4A) was obtained in the same manner as in Synthesis Example 1 (Mn=18,000, Mw/Mn=1.07, styrene (St) block/2-methoxyethyl methacrylate (MEMA) block=45155% by weight, Tg=37° C., 87° C., ¹H-NMR (400 MHz, CDCl₃) δ (ppm) 7.2-6.9 (m, 3H), 6.7-6.3 (m, 2H), 4.1 (s, 0.8H), 3.6 (s, 0.8H), 3.4 (s, 1.2H) 2.1-1.7 (m, 2.2H), 1.6-1.2 (brs, 2H), 1.2-0.8 (m, 2.4H)).

The synthesis scheme of the resin (BP-4A) is shown below. In the following formulas, Me represents a methyl group and Ph represents a phenyl group.

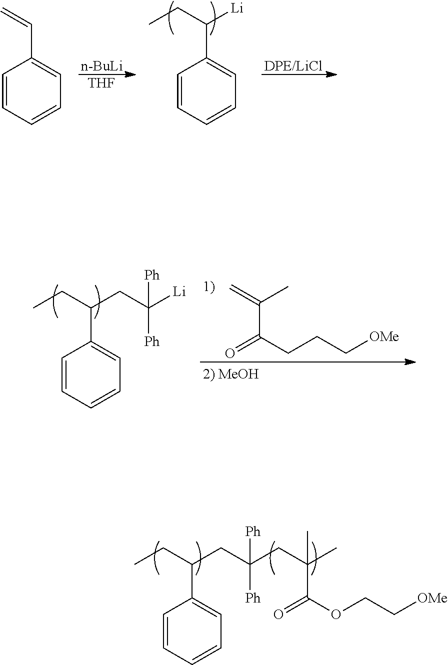

### Synthesis Example 5

### Synthesis of Resin (BP-5A)

The following resin (BP-5A) was obtained in the same manner as in Synthesis Example 1 (Mn=17,600, Mw/Mn=1.11, 4-t-butylstyrene (TBSt) block/2,2,2-trifluoroethyl methacrylate (TFEMA) block=51/49% by weight, Tg=76° C., 134° C., ¹H-NMR (400 MHz, CDCl₃) δ (ppm) 7.2-6.9 (m, 2H), 6.8-6.2 (m, 2H), 4.4 (s, 0.8H), 2.2-1.8 (m, 1.8H), 1.7-0.9 (m, 12, 2H)).

The synthesis scheme of the resin (BP-5A) is shown below. In the following formulas, Me represents a methyl group and Ph represents a phenyl group.

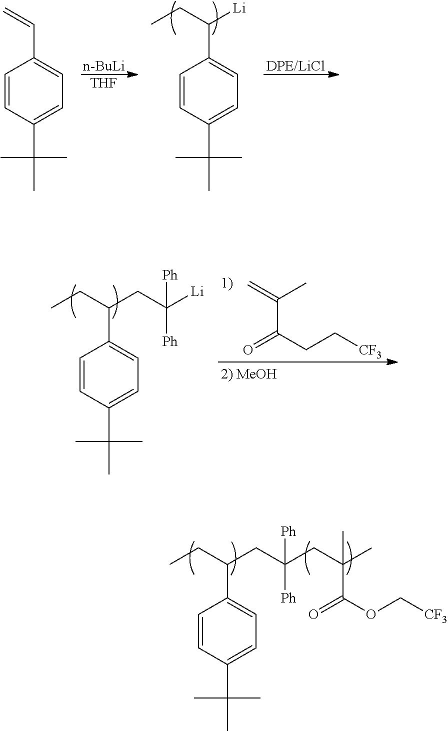

### Synthesis Example 6

### Synthesis of Resin (BP-6A)

The resin (BP-6A) was obtained in the same manner as in Synthesis Example 1 (Mn=18,000, Mw/Mn=1.08, TBSt block/MEMA block=48/52% by weight, Tg=49° C., 128° C., ¹H-NMR (400 MHz, CDCl₃) δ (ppm) 7.2-6.8 (m, 2H), 6.7-6.1 (m, 2H), 4.1 (s, 0.9H), 3.6 (m, 0.9H), 3.4 (m, 1.4H), 2.2-1.7 (m, 1.9H), 1.6-0.8 (m, 12.4H)).

The synthesis scheme of the resin (BP-6A) is shown below. In the following formulas, Me represents a methyl group and Ph represents a phenyl group.

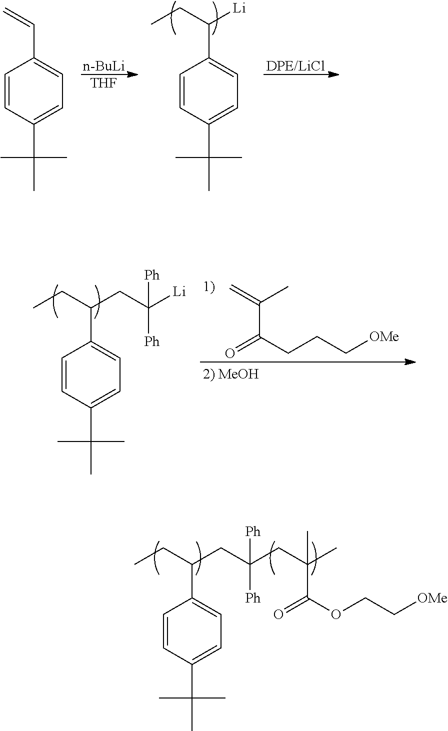

### Synthesis Example 7

### Synthesis of Resin (CBP-2A)

In a nitrogen atmosphere, 10.0 mL (82.5 mmol) of 2-hydroxyethyl methacrylate and 14.9 mL (107 mmol) of triethyl amine (Et₃N) were added to 100 mL of dichloromethane (CH₂Cl₂), followed by stirring for 5 minutes, and then, 14.9 g (98.9 mmol) of t-butyldimethylsilyl chloride was added thereto, followed by stirring at room temperature for 24 hours. After stopping the reaction by adding 3% by weight hydrochloric acid to the reaction solution, the resultant product was washed twice with 3% by weight hydrochloric acid and washed three times with distilled water, and extraction operation was performed with CH₂C₂. The resultant product was dried over MgSO₄, filtered, and concentrated, whereby 2-(t-butyldimethylsilyloxy)ethyl methacrylate (HEMA-TBS) was obtained.

In a nitrogen atmosphere, s-butyl lithium was added to 50 mL of THF, followed by stirring at room temperature for 1 hour, and the water in the system was removed. After the resultant product was cooled to −78° C. 0.31 mL (0.50 mmol) of n-butyl lithium and 4.88 mL (42.5 mmol) of styrene were added thereto to initiate polymerization. After the resultant product was aged for 15 minutes, a THF solution of 0.13 mL (0.75 mmol) of 1,1-diphenyl ethylene (DPE) and 65.7 mg (1.55 mmol) of lithium chloride were added thereto, followed by stirring for 10 minutes. Next, 10.4 g (42.5 mmol) of HEMA-TBS was added to the reaction solution, followed by stirring for 1.5 hours. After stopping the reaction by adding methanol to the reaction solution, reprecipitation operation was performed with a methanol solvent, collection by filtration was performed, and the obtained filtrate was air-dried, whereby a CBP-2A protected substance was obtained.

5.0 g of the CBP-2A protected substance was dissolved in 100 mL of CH₂C₂ and 10.0 mL of tetrabutylammonium fluoride was added thereto, followed by stirring at room temperature for 2 days. After stopping the reaction by adding 3% by weight hydrochloric acid to the reaction solution, the resultant product was washed three times with distilled water, and extraction operation was performed with CH₂Cl₂. The resultant product was dried over MgSO₄, filtered, and concentrated, and by adding the obtained solution dropwise to a hexane solution cooled to 0° C., reprecipitation operation was performed. Collection by filtration was performed on the resultant product and the obtained filtrate was air-dried, whereby a resin CBP-2A was obtained (Mn=18,200, Mw/Mn=1.11, St block/2-hydroxyethyl methacrylate (HEMA) block=47/53% by weight).

The synthesis scheme of the resin (CBP-2A) is shown below. In the following formulas, Me represents a methyl group and Ph represents a phenyl group.

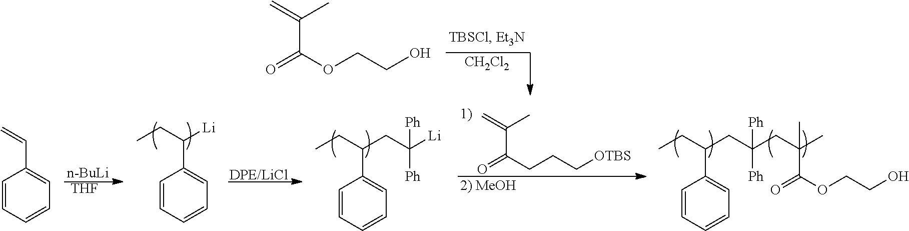

### Synthesis Example 8

### Synthesis of Resin (CBP-4A)

In a nitrogen atmosphere, s-butyl lithium was added to 50 mL of THF, followed by stirring at room temperature for 1 hour, and the water in the system was removed. After the resultant product was cooled to −78° C., 0.31 mL (0.50 mmol) of n-butyl lithium and 8.00 mL (42.5 mmol) of t-butoxystyrene were added thereto to initiate polymerization. After the resultant product was aged for 15 minutes, a THF solution of 0.13 mL (0.75 mmol) of 1,1-diphenyl ethylene and 65.7 mg (1.55 mmol) of lithium chloride were added thereto, followed by stirring for 10 minutes. Next, 6.05 mL (42.5 mmol) of 2,2,2-trifluoroethyl methacrylate was added to the reaction solution, followed by stirring for 1.5 hours. After stopping the reaction by adding methanol to the reaction solution, reprecipitation operation was performed with a mixed solution of methanol/water (volume ratio of 1:1), collection by filtration was performed, and the obtained filtrate was air-dried, whereby a CBP-4A protected substance was obtained.

5.0 g of the CBP-4A protected substance was dissolved in 100 mL of 1,4-dioxane and 20.0 mL of 37% by weight hydrochloric acid was added thereto, followed by stirring at 80° C. for 12 hours. After stopping the reaction by adding a 5% by weight NaOH aqueous solution to the reaction solution until the pH became 6 to 7, the resultant product was filtered and concentrated. After the precipitated solid was dissolved in THF, reprecipitation operation was performed with a mixed solution of methanol/water (1:1), collection by filtration was performed, and the obtained filtrate was air-dried, whereby a CBP-4A was obtained (Mn=18,500, Mw/Mn=1.14, 4-hydroxystyrene (HOST) block/TFEMA block=52/48% by weight).

The synthesis scheme of the resin (CBP-4A) is shown below. In the following formulas, Me represents a methyl group and Ph represents a phenyl group.

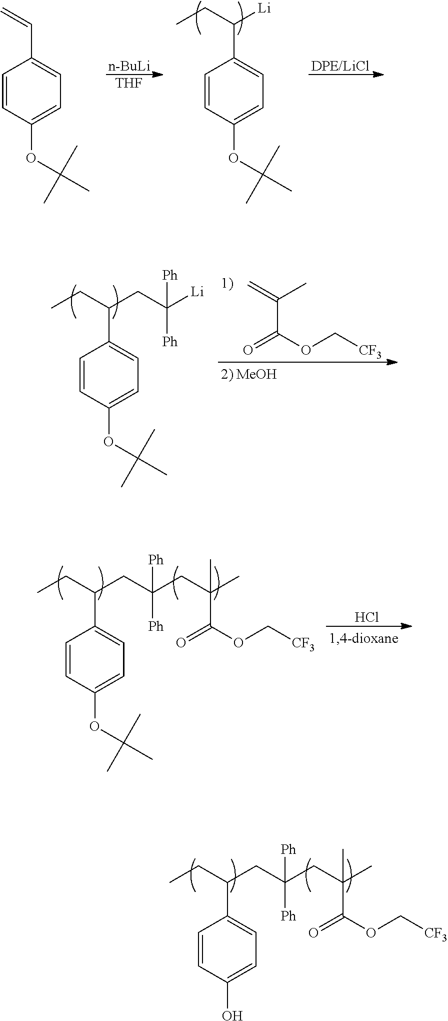

In the same method (a batch method) as in Synthesis Example 1, resins (BP-7A) to (BP-26A), resins (BP-1B) to (BP-26B), resins (BP-5C) to (BP-5F), resins (BP-6C) to (BP-6F), a resin (CBP-1A), a resin (CBP-3A), and resins (CBP1B) to (CBP4B) were synthesized.

### Synthesis Example 9

### Synthesis of Resin (BP-5A′) Using Microreactor

In the same method described in Example 10 of JP2010-180353A, a resin (BP-5A′) having the same chemical structure as the resin (BP-5A) was obtained by using a microreactor (Mn=16,300, Mw/Mn=1.07, TBSt block/TFEMA block=50/50% by weight).

In the same method (a method using a microreactor) as in Synthesis Example 9, a resin (BP-5B) was synthesized.

All of Synthesis Examples described above are synthesis examples in which, in production of a first block copolymer, a block of the repeating unit represented by General Formula (I) and a block of the repeating unit represented by General Formula (II) are formed by a living polymerization, and, in production of a second block copolymer, a block of the repeating unit represented by General Formula (III) and a block of the repeating unit represented by General Formula (IV) are formed by a living polymerization.

These block copolymers contained 1 ppm to 1000 ppm of metal ions, but by using a known filtration method, the amount of metal ions was reduced to 1 ppb to 50 ppb. Quantification of the metals was performed on a sample diluted 10-fold with MEK using a ICP-OES apparatus (Optima 7300 DV manufactured PerkinElmer Inc., an organic solvent mode) by an absolute calibration curve method.

The chemical structures (the compositional ratio of the repeating unit is in terms of a mass ratio), the number average molecular weights (Mn), and the dispersities (Mw/Mn) of resins (BP-1) to (BP-26) and resins (CBP-1) to (CBP-4) also including the resins synthesized in Synthesis Examples are shown below. In the following formulas, Me represents a methyl group. ΔSP represents the absolute value of a difference between the SP values described above.

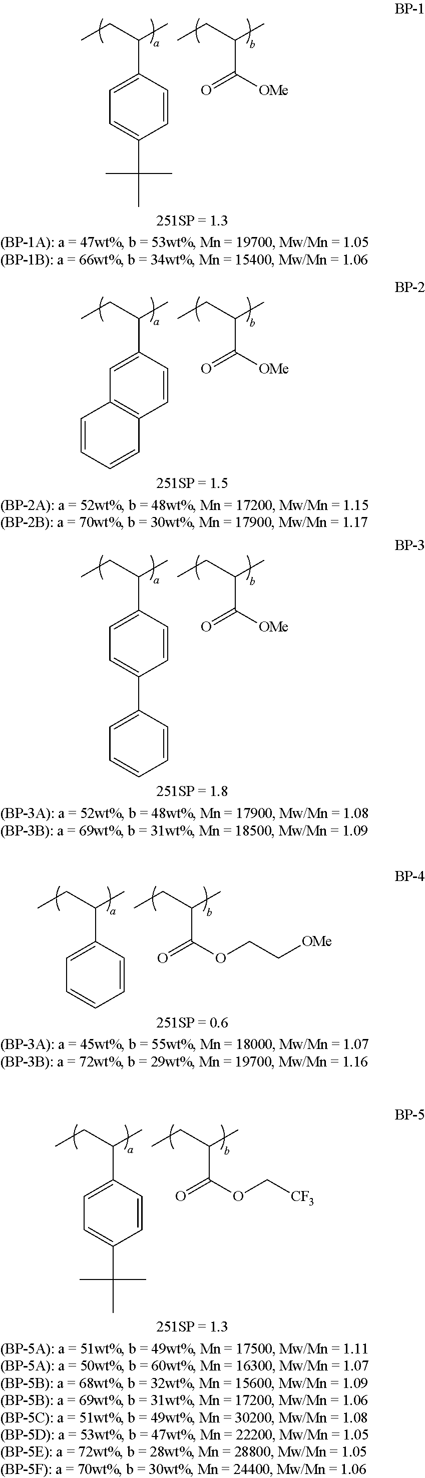

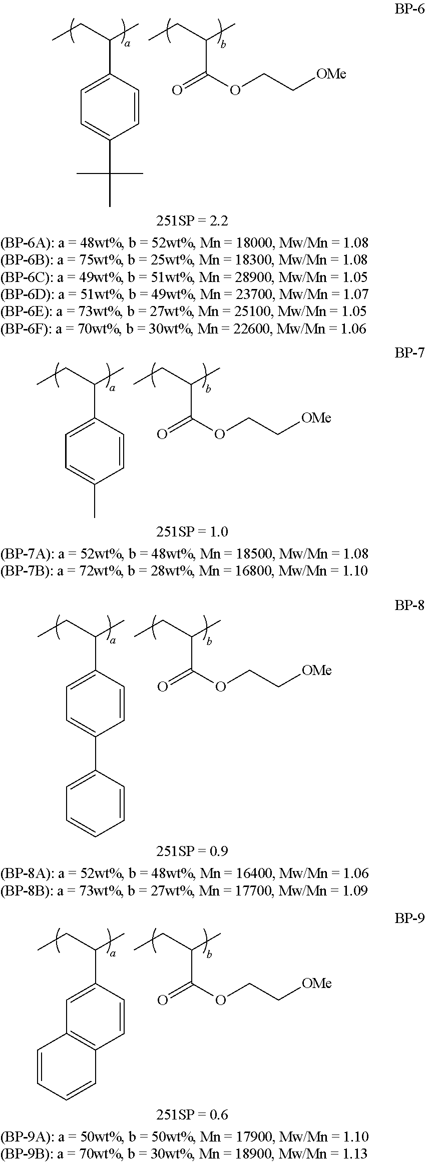

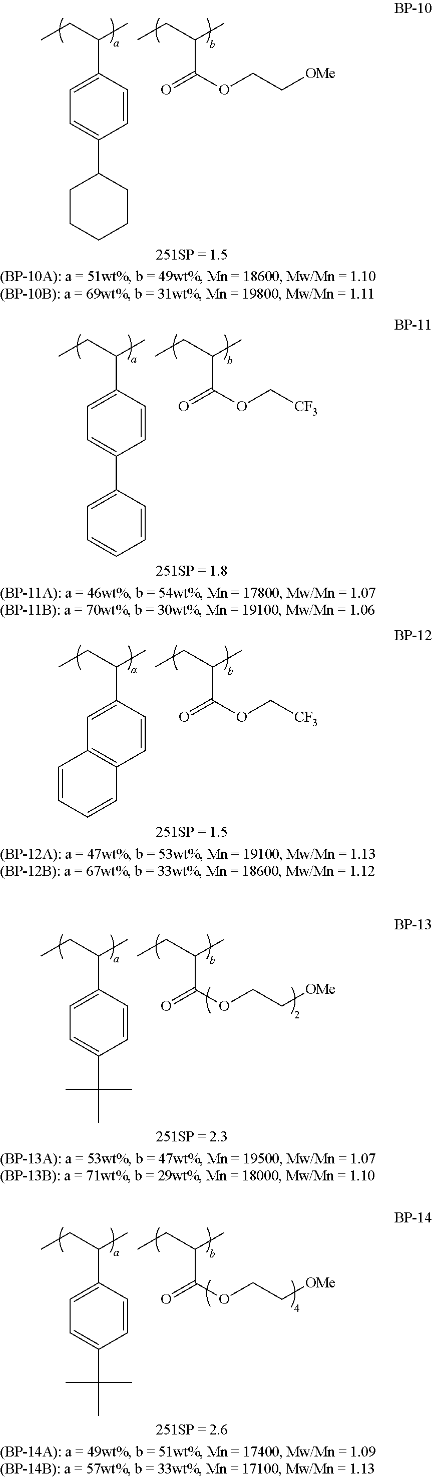

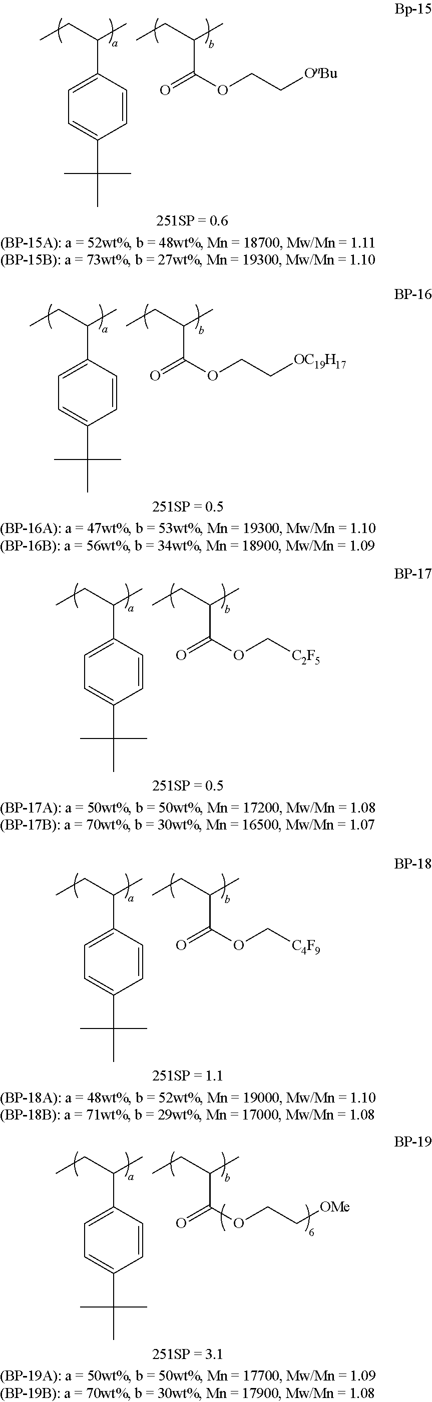

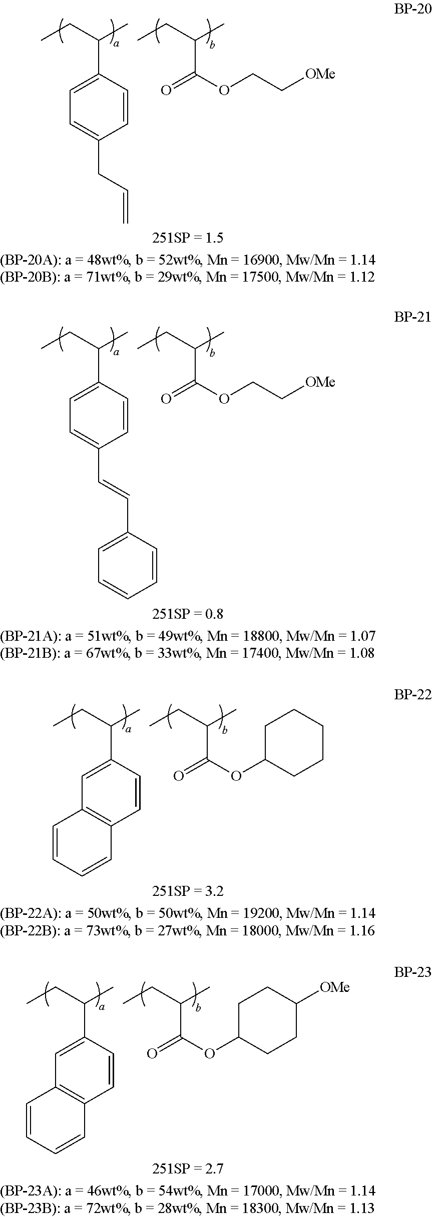

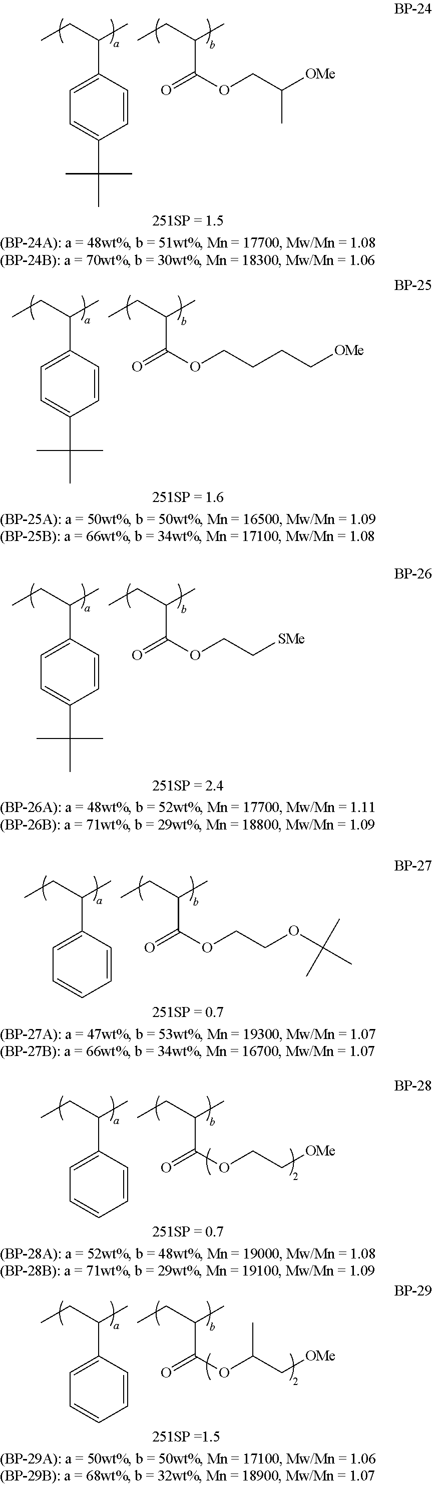

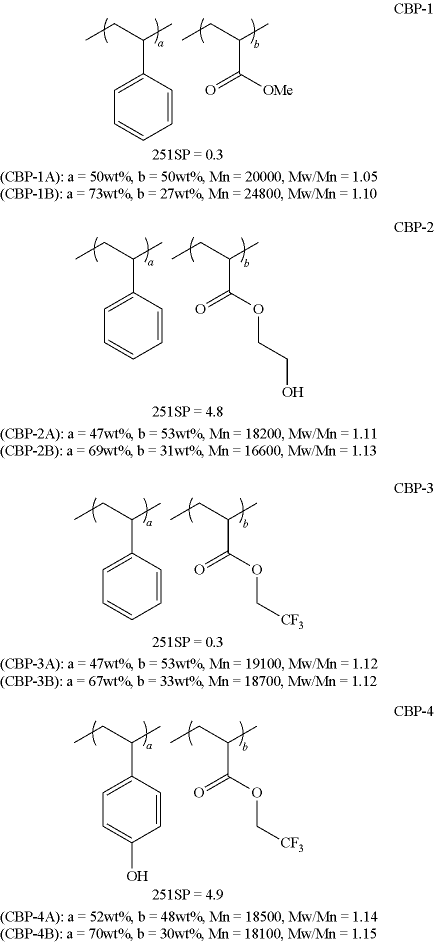

### Synthesis Example 10

### Synthesis of Resin (P-1)

20.0 g of poly(p-hydroxystyrene) (VP-2500, manufactured by Nippon Soda Co., Ltd.) was dissolved in 80.0 g of propylene glycol monomethyl ether acetate (PGMEA). To this solution, 10.3 g of 2-cyclohexylethyl vinyl ether and 10 mg of camphorsulfonic acid were added, followed by stirring at room temperature (25@C) for 3 hours. 84 mg of triethylamine was added thereto, after stirring for a while, the reaction liquid was transferred to a separatory funnel that contained 100 mL of ethyl acetate. This organic layer was washed three times with 50 mL of distilled water, and the organic layer was concentrated using an evaporator. After the obtained polymer was dissolved in 300 mL of acetone, the resultant product was added dropwise to 3000 g of hexane to precipitate, and the precipitate was filtered, whereby 17.5 g of a resin (P-1) was obtained.

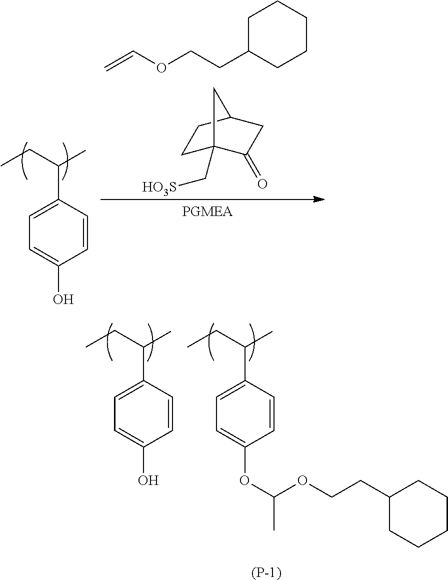

### Synthesis Example 11

### Synthesis of Resin (P-11)

10.00 g of p-acetoxystyrene was dissolved in 40 g of ethyl acetate, then, the resultant product was cooled to 0° C., and 4.76 g of sodium methoxide (a 28% by mass methanol solution) was added dropwise thereto over a period of 30 minutes, followed by stirring at room temperature for 5 hours. After ethyl acetate was added thereto, the organic layer was washed three times with distilled water, then, dried over anhydrous sodium sulfate, and the solvent was distilled off, whereby 13.17 g of p-hydroxystyrene (a compound represented by the following Formula (1), a 54% by mass ethyl acetate solution) was obtained. 6.66 g (in which 3.6 g of p-hydroxystyrene (1) was contained) of the 54% by mass ethyl acetate solution of the obtained p-hydroxystyrene (1), 14.3 g of a compound represented by the following Formula (2) (manufactured by KNC Laboratories Co., Ltd.), 2.2 g of a compound represented by the following Formula (3) (manufactured by Daicel Corporation), and 2.3 g of a polymerization initiator V-601 (manufactured by Wako Pure Chemical Industries, Ltd.) were dissolved in 14.2 g of propylene glycol monomethyl ether (PGME). 3.6 g of PGME was put into a reaction vessel, and the solution adjusted to 85° C. in advance was added dropwise thereto over a period of 4 hours in a nitrogen gas atmosphere. The reaction solution was heated and stirred for 2 hours, and then, cooled to room temperature. The obtained reaction solution was added dropwise to 889 g of a mixed solution of hexane/ethyl acetate (8/2 (mass ratio)) to precipitate, and the precipitate was filtered, whereby 14.9 g of a resin (P-11) was obtained.

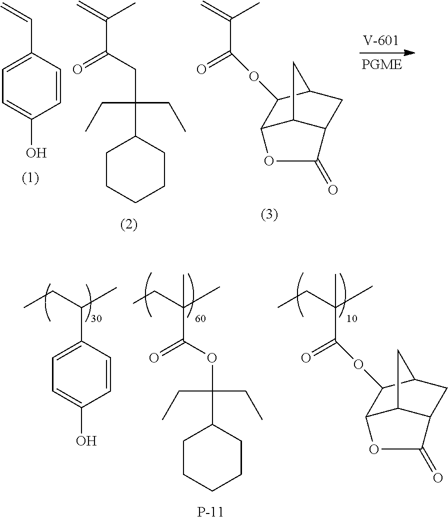

Hereinafter, in the same manner as in Synthesis Examples 10 and 11, resins (P-2) to (P-10) and (P-12) to (P-42) were synthesized.

The polymer structures, the weight average molecular weights (Mw), and the dispersities (Mw/Mn) of the resins (P-1) to (P-42) are shown below. In addition, the compositional ratio of each repeating unit of the following polymer structures is shown in a molar ratio.

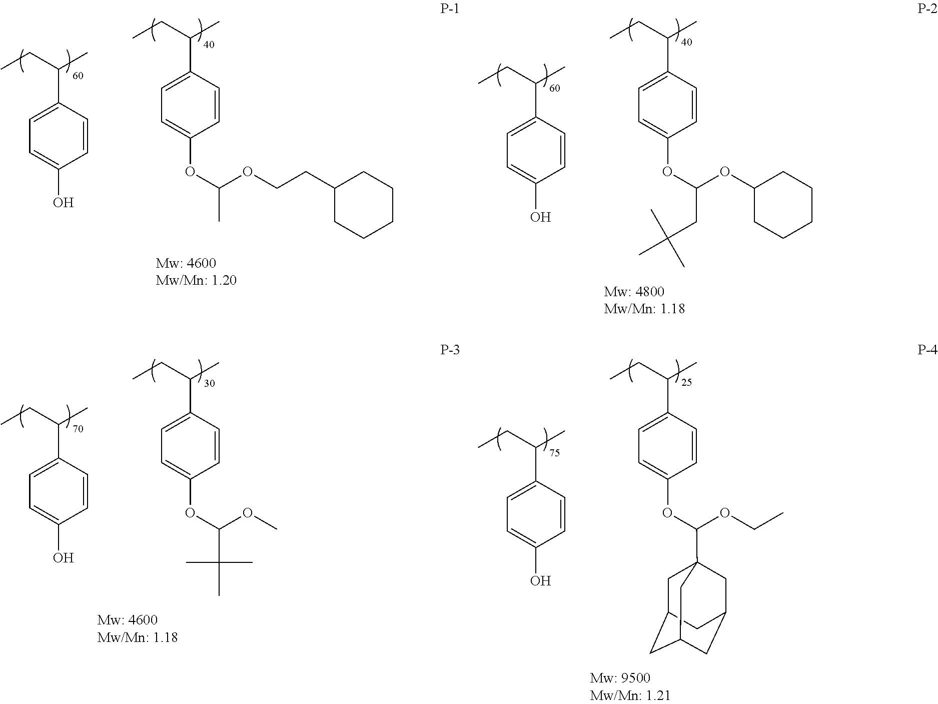

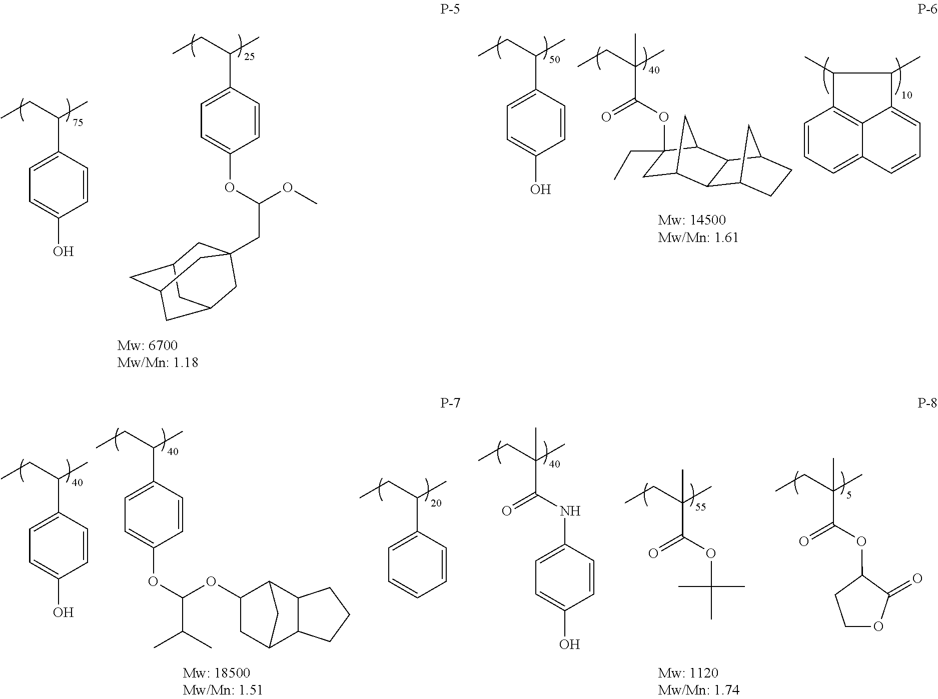

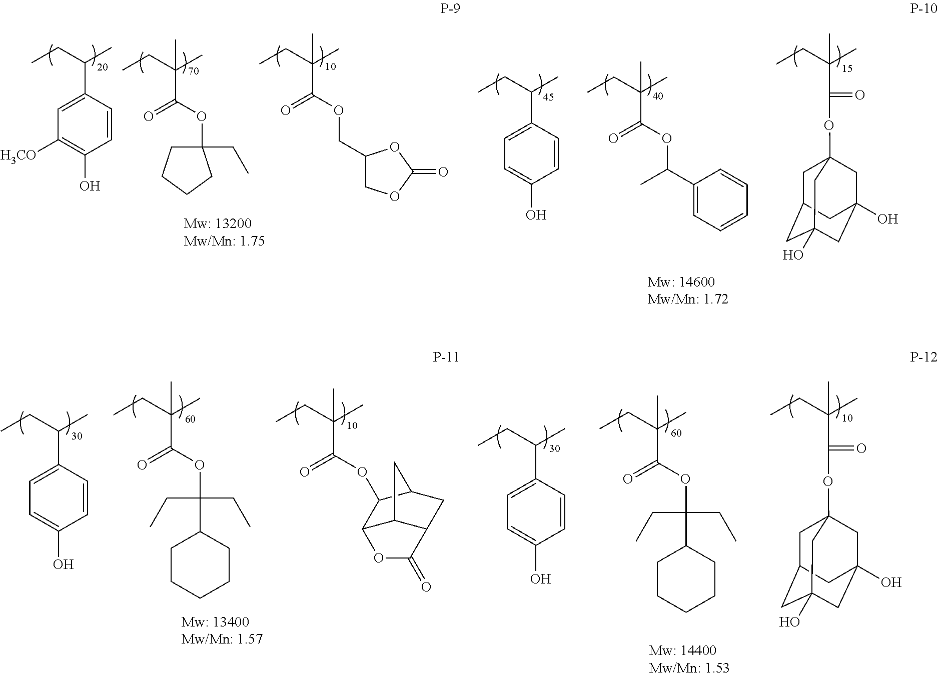

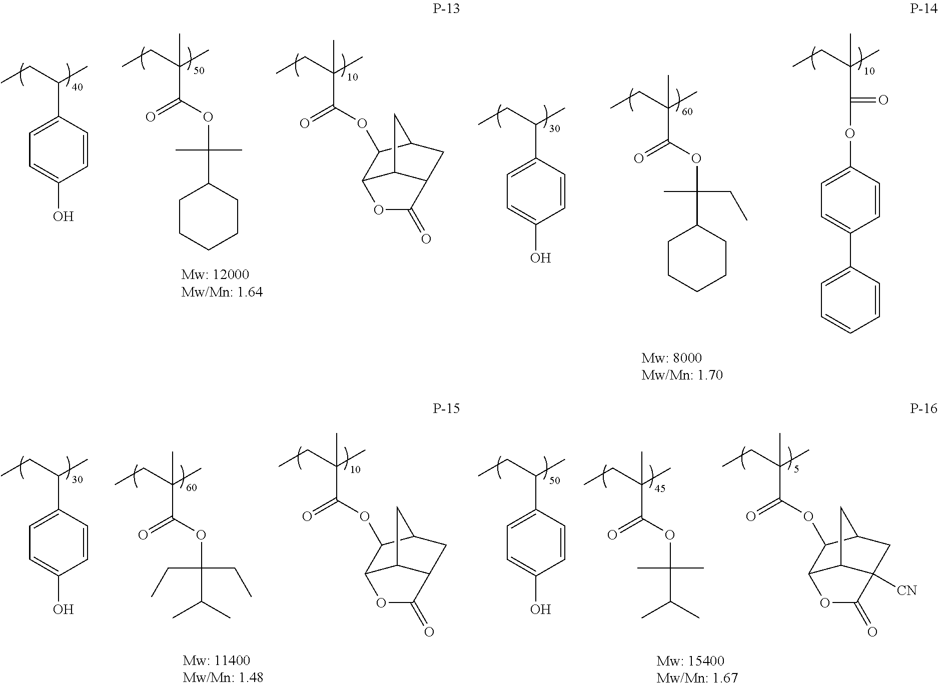

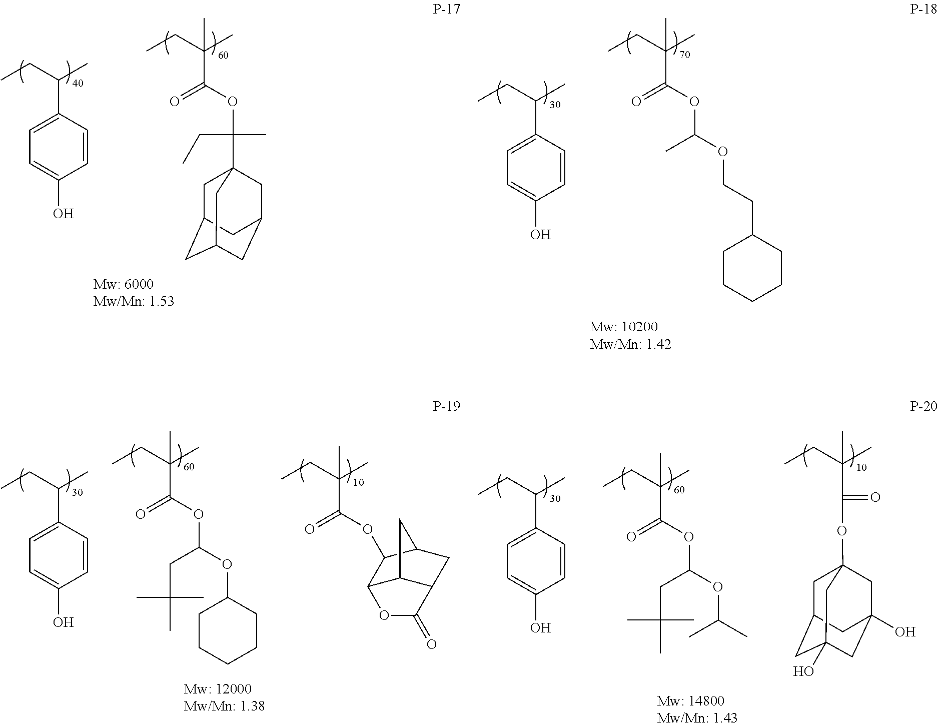

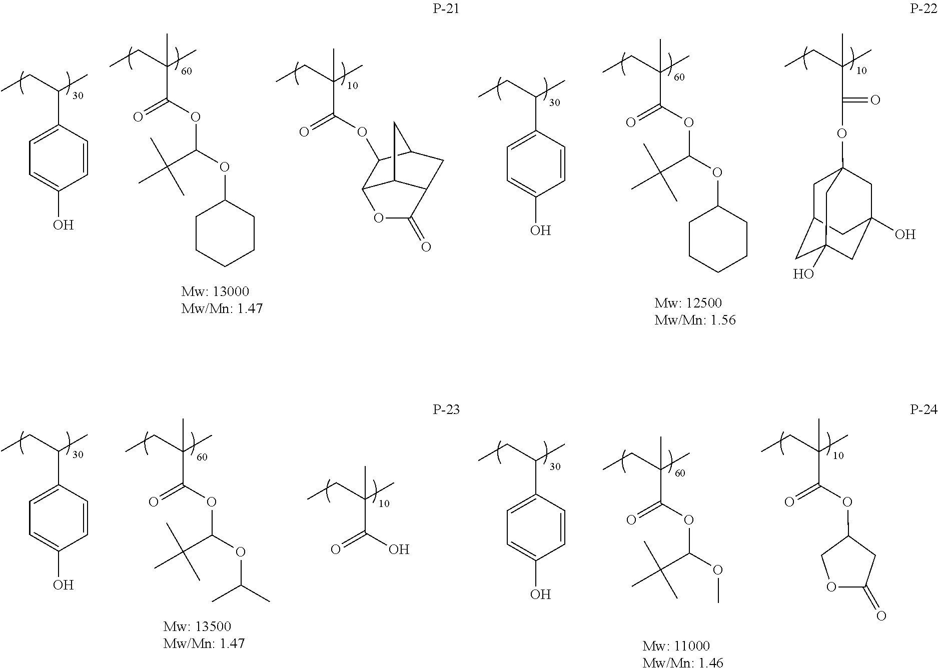

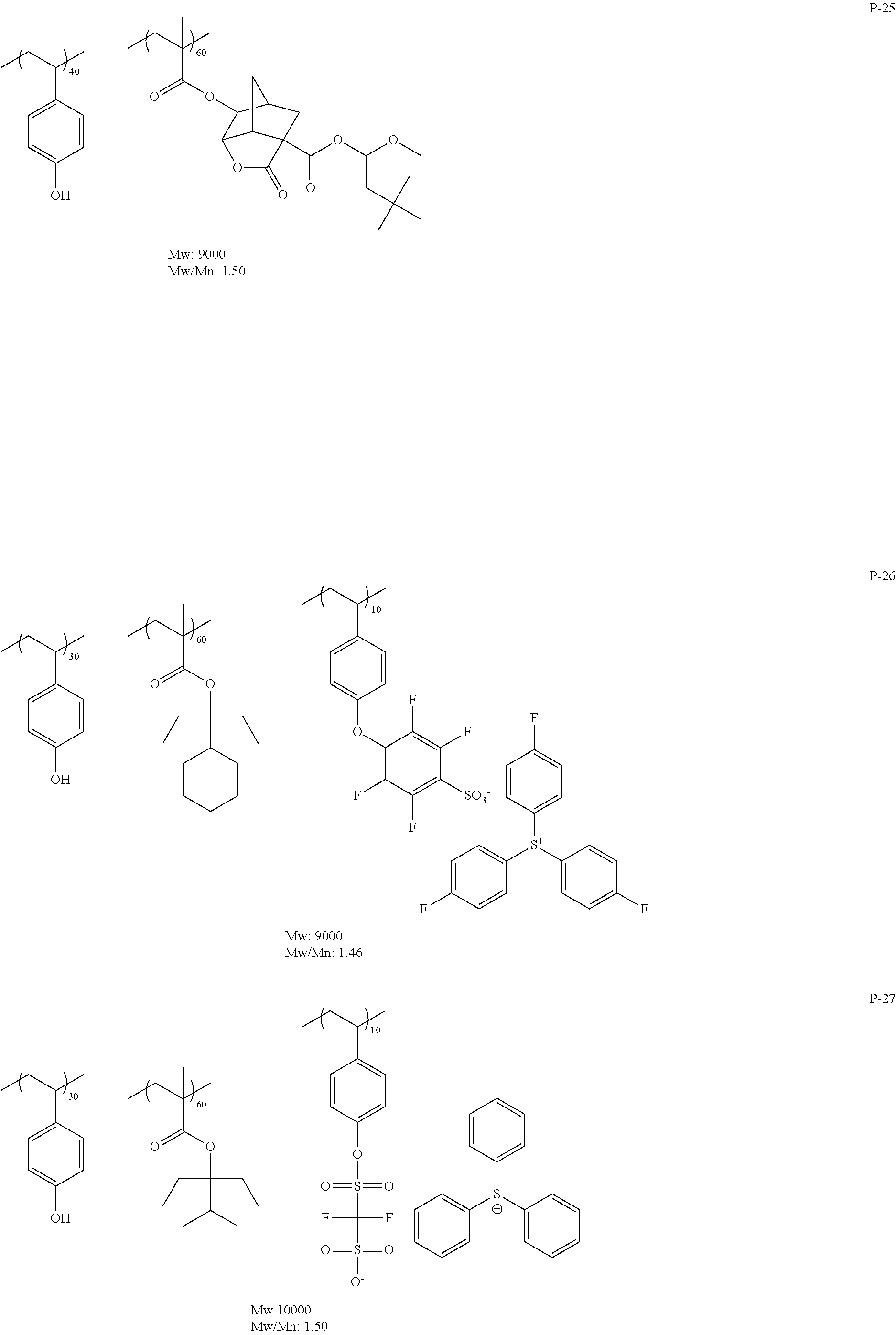

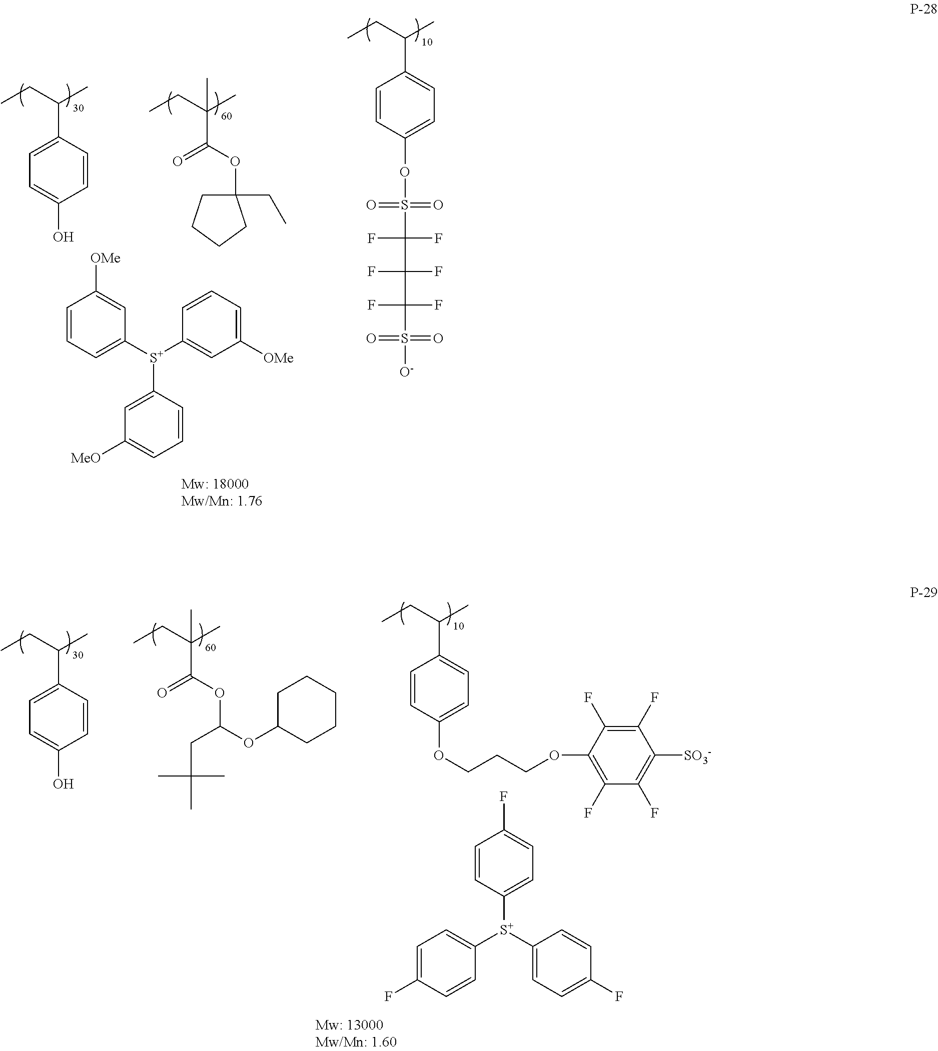

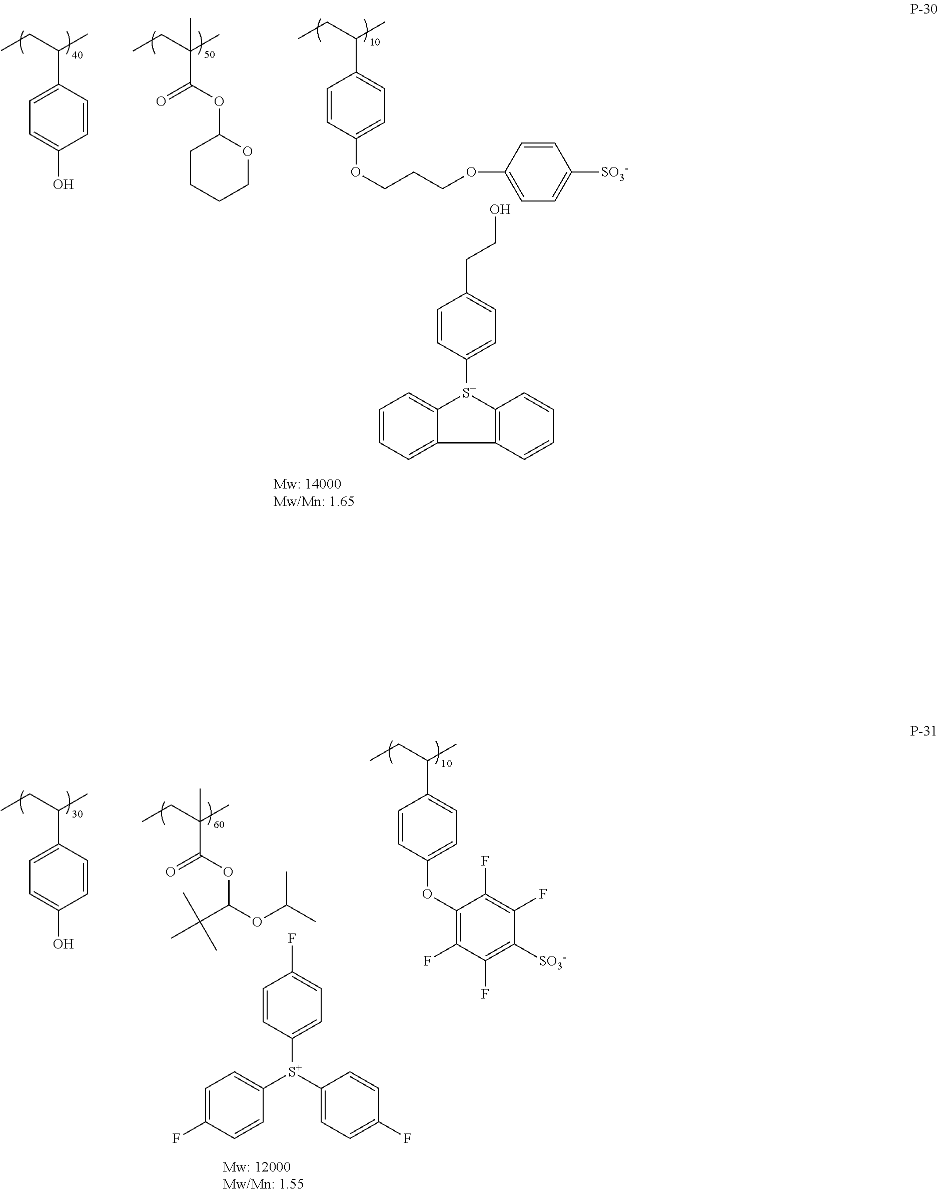

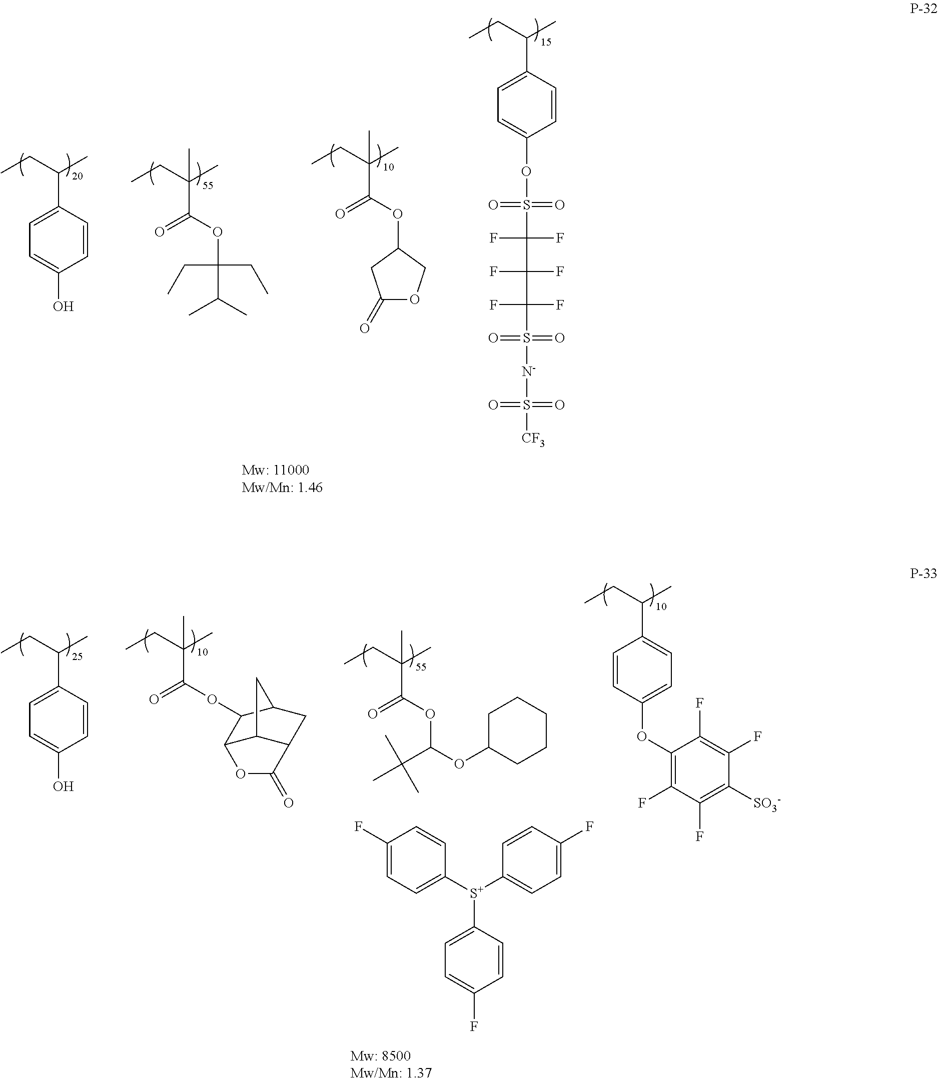

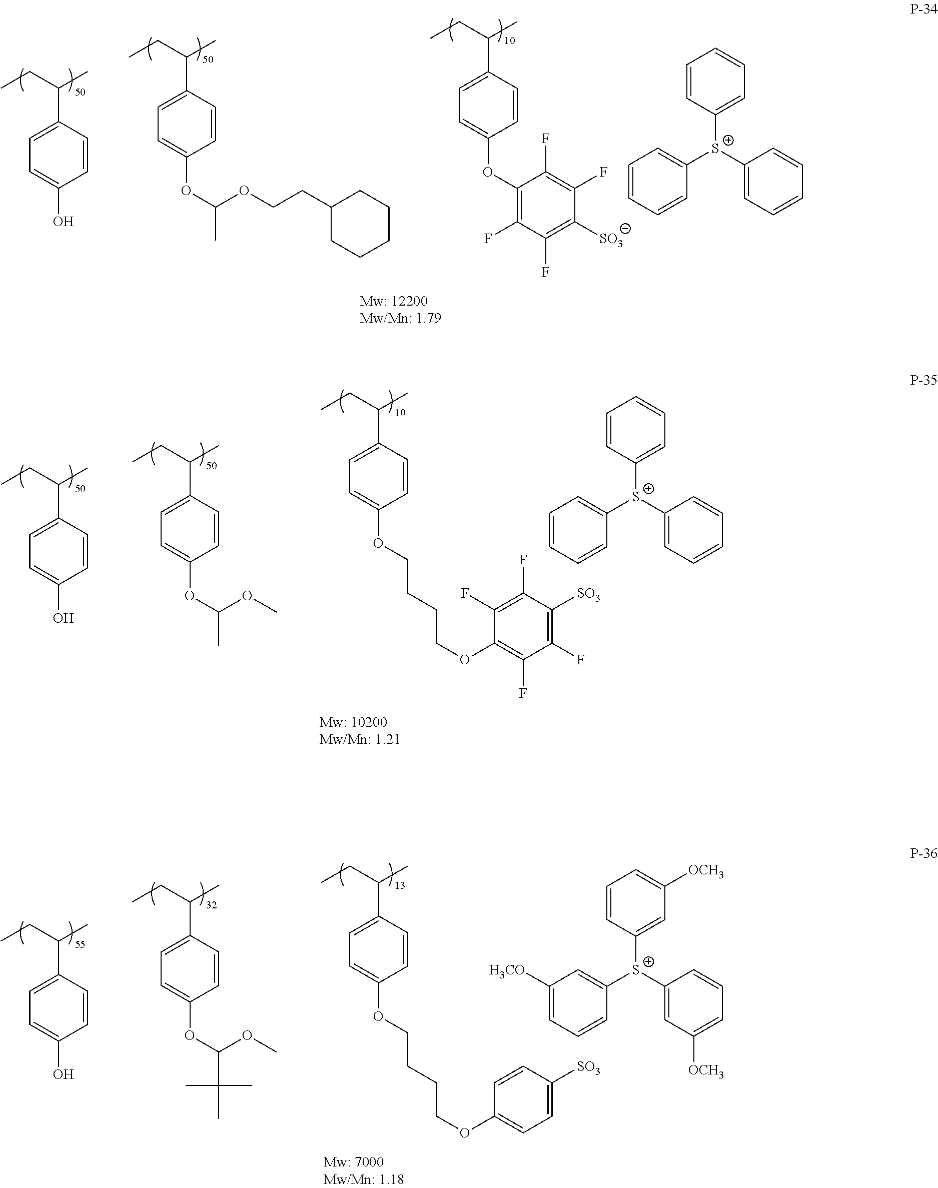

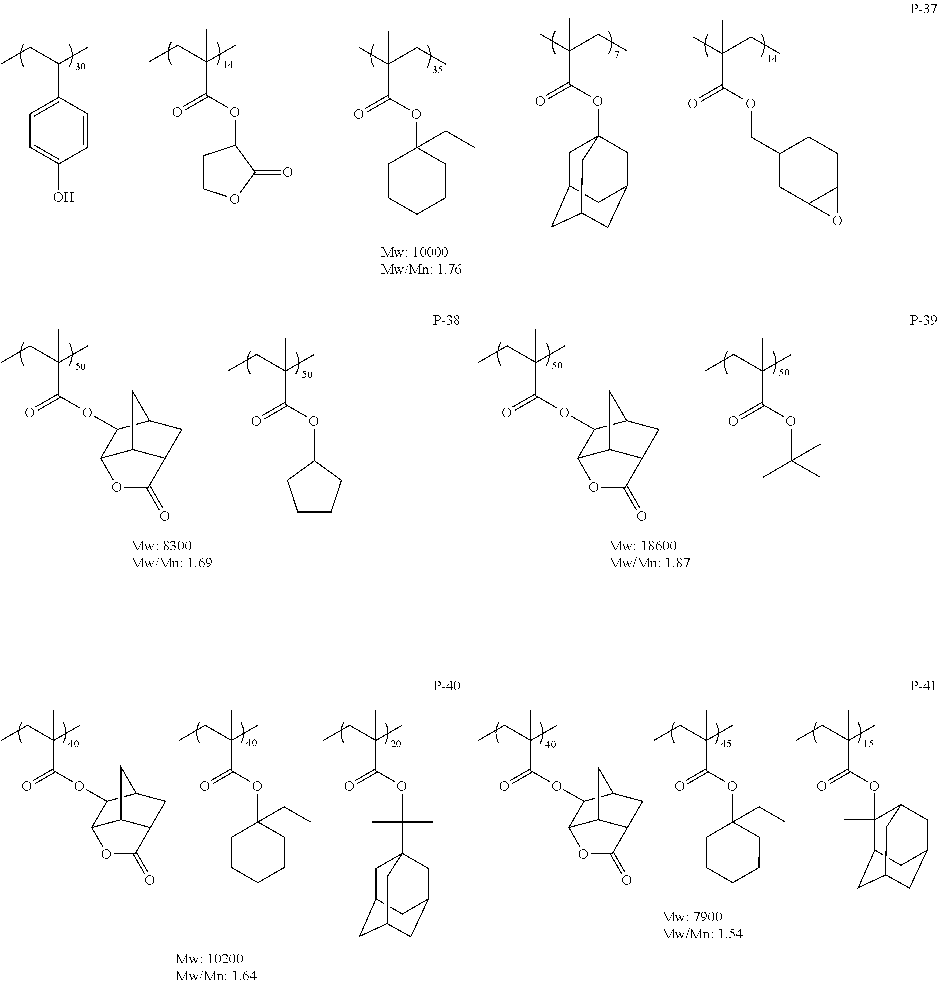

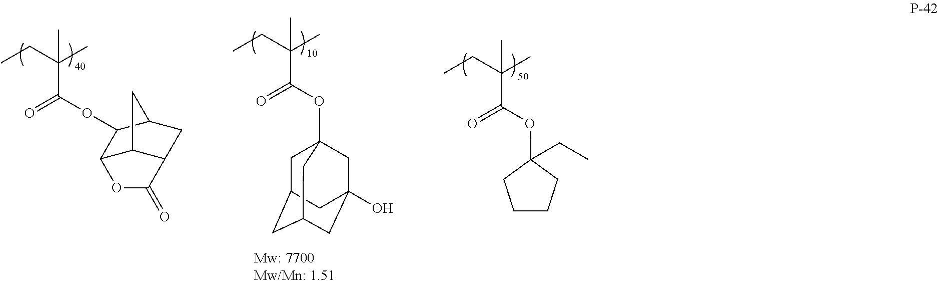

<Acid Generator>

As the acid generator, an acid generator suitably selected from the above-described acid generators z1 to z141 was used.

<Basic Compound>

As a basic compound, any one of the following Compounds (N-1) to (N-11) was used.

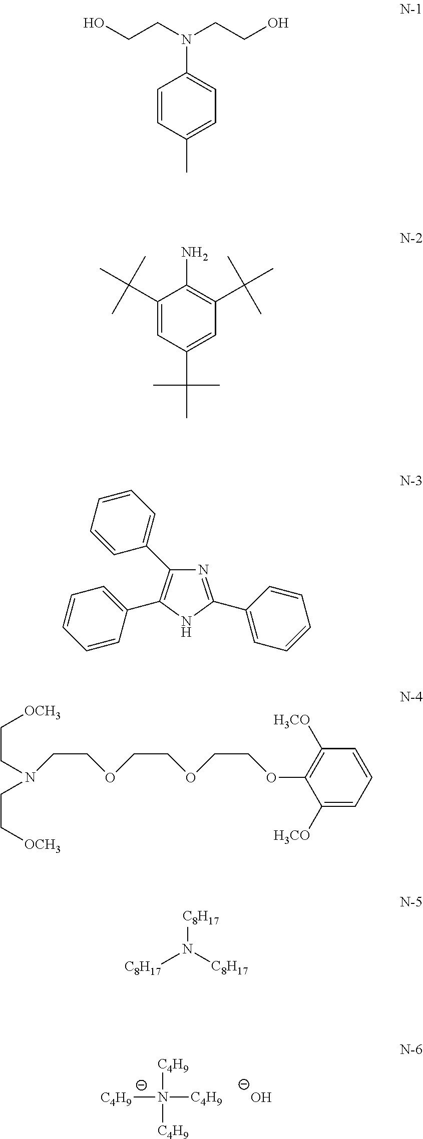

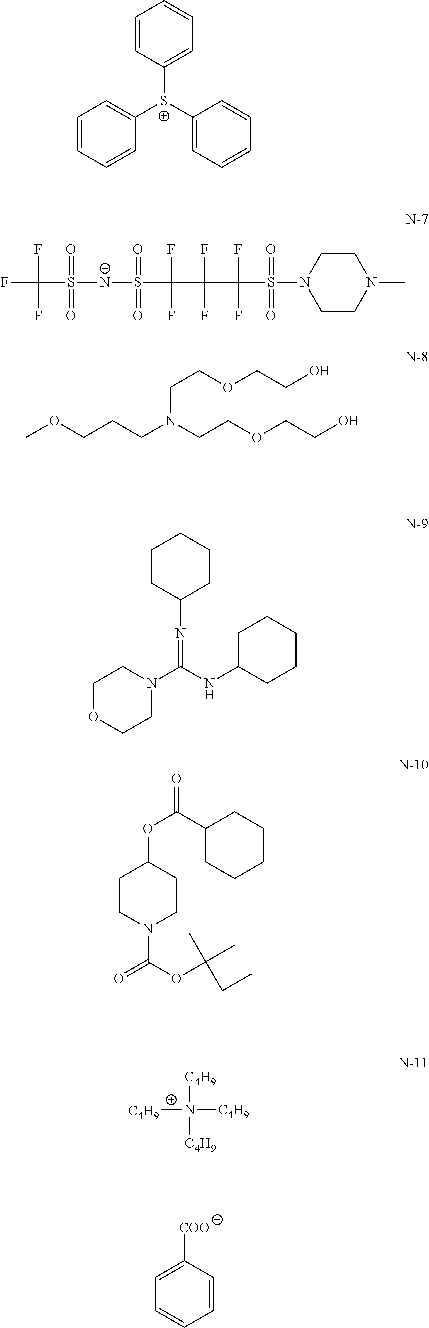

<Surfactant>

As a surfactant, the following W-1 to W-4 were used.

W-1: MEGAFAC R₀₈ (manufactured by DIC Corporation; fluorine-based surfactant or silicon-based surfactant)

W-2: Polysiloxane polymer KP-341 (manufactured by Shin-Etsu Chemical Co., Ltd.; silicon-based surfactant)

W-3: TROYSOL S-366 (manufactured by Troy Chemical Corp.; fluorine-based surfactant)

W-4: PF6320 (manufactured by OMNOVA Solutions Inc.; fluorine-based surfactant)

<Coating Solvent>

As a coating solvent, the following were used.

S1: propylene glycol monomethyl ether acetate (PGMEA)

S2: propylene glycol monomethyl ether (PGME)

S3: ethyl lactate

S4: cyclohexanone

<Developer>

As a developer, the following were used.

SG-1: anisole

SG-2: methyl amyl ketone (2-heptanone)

SG-3: butyl acetate

<Rinse Liquid>

In the case of using a rinse liquid, the followings were used.

SR-1: 2-pentanol

SR-2: 1-hexanol

SR-3: methylisobutylcarbinol

[Phase Separation of Block Copolymer Layer Using Line-and-Space Pattern as Guide Pattern]

(1) Coating Liquid Preparation and Application of Active Light Sensitive or Radiation Sensitive Resin Composition

A coating liquid composition having the compositional ratio of Example 1-3 shown in the following Table 2 was microfiltered using a membrane filter having a pore size of 0.05 μm, whereby an active light sensitive or radiation sensitive resin composition (resist composition) solution (solid content concentration: 1.5% by mass) was obtained.

This active light sensitive or radiation sensitive resin composition solution was applied to a 6-inch Si wafer subjected to a hexamethyldisilazane (HMDS) treatment in advance using a spin coater MARK 8 manufactured by Tokyo Electron Limited, and dried on a hot plate at 100° C. for 60 seconds, whereby an active light sensitive or radiation sensitive film having a film thickness of 50 nm was obtained.

(2) EUV Exposure and Development

Using an EUV exposure device (MICRO EXPOSURE TOOL manufactured by Exitech Corporation, NA0.3, Quadrupole, outer sigma of 0.68, inner sigma of 0.36), pattern exposure was performed on the wafer to which the resist film obtained in the above (1) had been applied using an exposure mask (line width/space width=1/5). After irradiation, the resultant product was heated on a hot plate at 110° C. for 60 seconds, immersed in a 2.38% by mass tetramethylammonium hydroxide (TMAH) aqueous solution for 60 seconds, washed with water for 30 seconds, and dried, whereby a guide pattern of a 1:5 line-and-space pattern having a line width of 20 nm and a space width of 100 nm was obtained.

(3) Formation of Block Copolymer Layer and Implementation of Phase Separation

A 1.9% by mass toluene solution of each resin for DSA described in the following Table 3 was applied to a substrate on which the 1:5 line-and-space pattern having a line width of 20 nm and a space width of 100 nm had been formed using a spinner (rotational speed: 1000 rpm, 60 seconds) and the resultant product was dried by being baked on a hot plate at 110° C. for 60 seconds, whereby a block copolymer layer having a film thickness of 25 nm was formed.

Next, the substrate on which the block copolymer layer had been formed was heated at 240° C. under a nitrogen gas flow until a phase separation structure was formed.

Thereafter, the substrate was subjected to an oxygen plasma treatment (200 sccm, 40 Pa, 200 W, 30 seconds) using TCA-3822 (product name, manufactured by TOKYO OHKA KOGYO CO., LTD.), whereby the phase formed of a block of the repeating unit represented by General Formula (II) or (IV) was selectively removed.

(4) Evaluation of Pattern

The surface of the obtained substrate was observed using a scanning electron microscope SU8000 (manufactured by Hitachi High-Technologies Corporation), and regarding lamella formation, a case where a clear vertical lamella was observed was evaluated as A, a case where a comparatively clear vertical lamella was observed was evaluated as B, a case where a vertical lamella with problem-free quality was observed was evaluated as C, a case where an unclear vertical lamella was observed was evaluated as D, and a case where a vertical lamella was not observed was evaluated as E, regarding the lamella shape, a case where a clear interface state of a vertical lamella was observed was evaluated as A, a case where a comparatively clear interface state of a vertical lamella was observed was evaluated as B, and a case where an unclear interface state of a vertical lamella was observed was evaluated as C, and regarding the formation time of a phase separation structure, a case where the formation time was less than 30 minutes was evaluated as A, a case where the formation time was 30 minutes to 1 hour was evaluated as B, and a case where the formation time was longer than 1 hour was evaluated as C. In addition, the pitch {a line width of a collective phase formed of one removal phase (which corresponds to one removal phase 32 in FIG. 1(c)) and one nonremoval phase (which corresponds to one nonremoval phase 33 in FIG. 1(c)} of a vertical lamella was also measured.

The evaluation results are shown in the following Table 3. In Table 3, the “ASP value” represents the absolute value of a difference between the solubility parameter (SP value) of the repeating unit represented by General Formula (I) and the solubility parameter (SP value) of the repeating unit represented by General Formula (II), for a resin corresponding to the first block copolymer, and the absolute value of a difference between the solubility parameter (SP value) of the repeating unit represented by General Formula (III) and the solubility parameter (SP value) of the repeating unit represented by General Formula (IV), for a resin corresponding to the second block copolymer. The “ST ratio” represents the content (% by mass) of the block of the repeating unit represented by General Formula (I) with respect to the total amount of block of the repeating unit represented by General Formula (I) and block of the repeating unit represented by General Formula (II), for a resin corresponding to the first block copolymer, and represents the content (% by mass) of the block of the repeating unit represented by General Formula (III) with respect to the total amount of block of the repeating unit represented by General Formula (III) and block of the repeating unit represented by General Formula (IV), for a resin corresponding to the second block copolymer. The annotations described above are the same for the table described below having a column of the “ΔSP value” or the “St ratio”.

TABLE 2

| | | | | | | | Solvent | Surfactant | |
|---|---|---|---|---|---|---|---|---|---|
| | | Concen- | Acid | Concen- | Basic | Concen- | (mass | (mass | Concen- |
| | Resin | tration | generator | tration | compound | tration | ratio) | ratio) | tration |
| Example 1-1 | P-1 | 67.95 | z113 | 30 | N-6 | 2 | S1/S2 | W-1 | 0.05 |
| | | | | | | | (40/60) | | |
| Example 1-2 | P-2 | 72.95 | z112 | 25 | N-11 | 2 | S1/S2 | W-1 | 0.05 |
| | | | | | | | (40/60) | | |
| Example 1-3 | P-3 | 67.95 | z113 | 30 | N-11 | 2 | S1/S2 | W-1 | 0.05 |
| | | | | | | | (40/60) | | |
| Example 1-4 | P-4 | 62.95 | z113 | 35 | N-11 | 2 | S1/S2 | W-1 | 0.05 |
| | | | | | | | (40/60) | | |
| Example 1-5 | P-5 | 57.95 | z128 | 40 | N-6 | 2 | S1/S2 | W-2 | 0.05 |
| | | | | | | | (40/60) | | |
| Example 1-6 | P-6 | 78.95 | z118 | 20 | N-8 | 1 | S1/S2 | W-4 | 0.05 |
| | | | | | | | (40/60) | | |
| Example 1-7 | P-7 | 87.95 | z29 | 10 | N-1 | 2 | S1/S3 | W-4 | 0.05 |
| | | | | | | | (40/60) | | |
| Example 1-8 | P-10 | 77.95 | z117 | 20 | N-4 | 2 | S1/S2 | W-3 | 0.05 |
| | | | | | | | (20/80) | | |
| Example 1-9 | P-11 | 67.95 | z124 | 30 | N-11 | 2 | S1/S2 | W-1 | 0.05 |
| | | | | | | | (40/60) | | |
| Example 1-10 | P-15 | 72.95 | z115 | 25 | N-11 | 2 | S1/S4 | W-1 | 0.05 |
| | | | | | | | (40/60) | | |
| Example 1-11 | P-19 | 66.95 | z113 | 30 | N-6 | 3 | S1/S2 | W-2 | 0.05 |
| | | | | | | | (40/60) | | |
| Example 1-12 | P-21 | 62.95 | z135 | 35 | N-11 | 2 | S1/S2 | W-1 | 0.05 |
| | | | | | | | (40/60) | | |
| Example 1-13 | P-26 | 97.95 | | | N-11 | 2 | S1/S2 | W-1 | 0.05 |
| | | | | | | | (40/60) | | |
| Example 1-14 | P-31 | 97.95 | | | N-11 | 2 | S1/S2 | W-1 | 0.05 |
| | | | | | | | (40/60) | | |
| Example 1-15 | P-34 | 97.95 | | | N-11 | 2 | S1/S2 | W-1 | 0.05 |
| | | | | | | | (40/60) | | |
| Example 1-16 | P-35 | 97.95 | | | N-6 | 2 | S1/S2 | W-1 | 0.05 |
| | | | | | | | (40/60) | | |
| Example 1-17 | P-36 | 97.95 | | | N-11 | 2 | S1/S2 | W-1 | 0.05 |
| | | | | | | | (40/60) | | |
| Example 1-18 | P-37 | 72.95 | z124 | 25 | N-5 | 2 | S1/S2 | W-1 | 0.05 |
| | | | | | | | (40/60) | | |
| Example 1-19 | P-41 | 67.95 | z113 | 30 | N-11 | 2 | S1/S2 | W-1 | 0.05 |
| | | | | | | | (40/60) | | |
| Example 1-20 | P-42 | 67.95 | z113 | 30 | N-11 | 2 | S1/S2 | W-1 | 0.05 |
| | | | | | | | (40/60) | | |

The concentration of each component represents a concentration (% by mass) in total solid content concentration.

TABLE 3

| | Resin for DSA | | | | | | | | | Formation |
|---|---|---|---|---|---|---|---|---|---|---|
| | | ΔSP | Polymer- | | | St ratio | | Lamella | | time of phase |
| | | value | ization | | | (% by | Lamella | pitch | Lamella | separation |
| | Resin | (MPa^{1/2}) | method | Mn | Dispersity | weight) | formation | (nm) | shape | structure |
| Example 2-1 | BP-1A | 1.3 | Batch | 19,700 | 1.05 | 47 | B | 40 | A | A |
| Example 2-2 | BP-2A | 1.5 | Batch | 17,200 | 1.15 | 52 | B | 40 | B | A |
| Example 2-3 | BP-3A | 1.8 | Batch | 17,900 | 1.08 | 52 | B | 40 | A | A |
| Example 2-4 | BP-4A | 0.6 | Batch | 18,000 | 1.07 | 45 | B | 40 | A | A |
| Example 2-5 | BP-5A | 1.3 | Batch | 17,600 | 1.11 | 51 | A | 40 | B | A |
| Example 2-6 | BP-6A | 2.2 | Batch | 18,000 | 1.08 | 48 | A | 40 | A | A |
| Example 2-7 | BP-7A | 1.0 | Batch | 18,500 | 1.08 | 52 | A | 40 | A | A |
| Example 2-8 | BP-8A | 0.9 | Batch | 16,400 | 1.06 | 52 | A | 40 | A | A |
| Example 2-9 | BP-9A | 0.6 | Batch | 17,900 | 1.10 | 50 | A | 40 | A | A |
| Example 2-10 | BP-10A | 1.5 | Batch | 18,800 | 1.10 | 51 | A | 40 | A | A |
| Example 2-11 | BP-11A | 1.8 | Batch | 17,800 | 1.07 | 46 | A | 40 | A | A |
| Example 2-12 | BP-12A | 1.5 | Batch | 19,100 | 1.13 | 47 | A | 40 | B | A |
| Example 2-13 | BP-13A | 2.3 | Batch | 19,500 | 1.07 | 53 | A | 40 | A | A |
| Example 2-14 | BP-14A | 2.6 | Batch | 17,400 | 1.09 | 49 | B | 40 | A | B |
| Example 2-15 | BP-15A | 0.6 | Batch | 18,700 | 1.11 | 52 | A | 40 | B | B |
| Example 2-16 | BP-16A | 0.5 | Batch | 19,300 | 1.10 | 47 | B | 40 | 8 | B |
| Example 2-17 | BP-17A | 0.5 | Batch | 17,200 | 1.08 | 50 | A | 40 | A | A |
| Example 2-18 | BP-18A | 1.1 | Batch | 19,000 | 1.10 | 48 | B | 40 | A | A |
| Example 2-19 | BP-19A | 3.1 | Batch | 17,700 | 1.09 | 50 | C | 40 | A | B |
| Example 2-20 | BP-5A′ | 1.3 | Microreactor | 16,300 | 1.07 | 50 | A | 40 | A | A |
| Example 2-21 | BP-20A | 1.5 | Batch | 16,900 | 1.14 | 48 | A | 40 | B | A |
| Example 2-22 | BP-21A | 0.8 | Batch | 18,800 | 1.07 | 51 | B | 40 | A | A |
| Example 2-23 | BP-22A | 3.2 | Batch | 19,200 | 1.14 | 50 | A | 40 | B | A |
| Example 2-24 | BP-23A | 2.7 | Batch | 17,000 | 1.14 | 46 | A | 40 | B | A |
| Example 2-25 | BP-24A | 1.5 | Batch | 17,700 | 1.08 | 49 | B | 40 | A | A |
| Example 2-26 | BP-25A | 1.6 | Batch | 16,500 | 1.09 | 50 | A | 40 | A | B |
| Example 2-27 | BP-26A | 2.4 | Batch | 17,700 | 1.11 | 48 | A | 40 | B | B |
| Example 2-28 | BP-27A | 0.7 | Batch | 19,300 | 1.07 | 47 | A | 40 | A | B |
| Example 2-29 | BP-28A | 0.7 | Batch | 18,000 | 1.08 | 52 | A | 40 | A | B |
| Example 2-30 | BP-29A | 1.5 | Batch | 17,100 | 1.06 | 50 | A | 40 | A | B |
| Comparative | CBP-1A | 0.3 | Batch | 20,000 | 1.05 | 50 | E | — | — | — |
| Example 2-1 | | | | | | | | | | |
| Comparative | CBP-2A | 4.8 | Batch | 18,200 | 1.11 | 47 | C | 40 | B | C |
| Example 2-2 | | | | | | | | | | |
| Comparative | CBP-3A | 0.3 | Batch | 19,100 | 1.12 | 47 | D | 40 | B | A |
| Example 2-3 | | | | | | | | | | |
| Comparative | CBP-4A | 4.9 | Batch | 18,500 | 1.14 | 52 | C | 40 | B | C |
| Example 2-4 | | | | | | | | | | |

From Table 2, it was found that, in Examples 2-1 to 2-30 in which a block copolymer corresponding to the first block copolymer or the second block copolymer was used, high miniaturization (refer to the lamella pitch value in the table) of patterns could be achieved with high quality and high efficiency (refer to the evaluation results of lamella formation, the lamella shape, and the formation time of a phase separation structure in the table).

On the other hand, in Comparative Examples 2-1 and 2-3 in which a block copolymer not corresponding to the first block copolymer or the second block copolymer, having a ASP value less than 0.5 (MPa^{1/2}), was used, the phase separability of the block was low, and it was not possible to obtain good results in lamella formation.

In addition, in Comparative Examples 2-2 and 2-4 in which a block copolymer not corresponding to the first block copolymer or the second block copolymer, having a ΔSP value greater than 4.0 (MPa^{1/2}), was used, the diffusion rate of the block copolymer was slow, and it was not possible to obtain good results in lamella formation and the formation time of a phase separation structure.

It was possible to obtain the same evaluation results as in Examples 2-1 to 2-30 by performing the same operation as in Examples 2-1 to 2-30 except that the coating liquid composition (solid content concentration: 1.5% by mass) having the compositional ratio of Example 1-3 used in formation of the guide patterns in Examples 2-1 to 2-30 was replaced with each coating liquid composition having the compositional ratio of each of Examples 1-1, 1-2, and 1-4 to 1-20 shown in Table 2.

Here, in the example used in the coating liquid composition having the compositional ratio of each of Examples 1-19 and 1-20, as the above form described with reference to FIG. 2(a) to FIG. 2(e), liquid immersion exposure (immersion liquid: ultrapure water) was performed through a 6% halftone mask of a 1:2 line-and-space pattern having a line width of 50 nm and a space width of 100 nm by using an ArF excimer laser liquid immersion scanner (XT1700i manufactured by ASML, NA1.20, C-Quad, outer sigma of 0.960, inner sigma of 0.709, XY deflection), whereby a guide pattern of a 1:2 line-and-space pattern having a line width of 50 nm and a space width of 100 nm was obtained. Next, by going through the above “(3) Formation of Block Copolymer Layer and Implementation of Phase Separation”, a vertical lamella having a pitch {a line width of a collective phase formed of one removal phase (which corresponds to one removal phase 32 in FIG. 2(c)) and one nonremoval phase (which corresponds to one nonremoval phase 33 in FIG. 2(c))} of 40 nm was formed with high quality and high efficiency.

Preparation of the active light sensitive or radiation sensitive resin composition, formation of guide patterns, formation and phase separation of a block copolymer layer were performed in the same manner as in Examples 2-1 to 2-30 except that each coating liquid composition (solid content concentration: 1.5% by mass) having the compositional ratio of each of Examples 3-1 to 3-36 shown in Table 4 was used instead of the coating liquid composition having the compositional ratio of Example 1-3 used in formation of the guide patterns in Examples 2-1 to 2-30, an exposure mask (line width/space width=5/1) was used instead of the exposure mask (line width/space width=1/5), development was performed by using the developer (organic-based developer) described in Table 4 instead of the alkaline aqueous solution (TMAH; a 2.38% by mass tetramethylammonium hydroxide aqueous solution), the rinse liquid described in Table 4 was used instead of water, and a 1.9% by mass propylene glycol monomethyl ether acetate (PGMEA) solution of each resin for DSA described in Table 3 was used instead of the 1.9% by mass toluene solution of each resin for DSA described in Table 3. Moreover, in Table 4, in an example in which a rinse liquid was not described in the column of the rinse liquid, rinsing was not performed. From the above results, the same evaluation results as in Examples 2-1 to 2-30 could be obtained.

TABLE 4

| | | | Acid | | | | | | | | |
|---|---|---|---|---|---|---|---|---|---|---|---|
| | | | generator | | | | Solvent | Surfactant | | | |
| | | Concen- | (mass | Concen- | Basic | Concen- | (mass | (mass | Concen- | | Rinse |
| | Resin | tration | ratio) | tration | compound | tration | ratio) | ratio) | tration | Developer | liquid |
| Example 3-1 | P-1 | 67.95 | z113 | 30 | N-6 | 2 | S1/S2 | W-1 | 0.05 | SG-3 | |
| | | | | | | | (40/60) | | | | |
| Example 3-2 | P-3 | 67.95 | z134 | 30 | N-11 | 2 | S1/S2 | W-1 | 0.05 | SG-3 | |
| | | | | | | | (40/60) | | | | |
| Example 3-3 | P-7 | 87.95 | z29 | 10 | N-1 | 2 | S1/S3 | W-4 | 0.05 | SG-3 | SR-2 |
| | | | | | | | (40/60) | | | | |
| Example 3-4 | P-8 | 82.95 | z2 | 15 | N-2 | 2 | S1/S2 | W-1/W-2 | 0.05 | SG-2 | |
| | | | | | | | (40/60) | (1/1) | | | |
| Example 3-5 | P-9 | 73.00 | z108 | 25 | N-5 | 2 | S1/S2/S3 | Not | | SG-1 | SR-3 |
| | | | | | | | (30/60/10) | present | | | |
| Example 3-6 | P-10 | 77.95 | z117 | 20 | N-4 | 2 | S1/S2 | W-3 | 0.05 | SG-3 | SR-1 |
| | | | | | | | (20/80) | | | | |
| Example 3-7 | P-11 | 67.95 | z124 | 30 | N-11 | 2 | S1/S2 | W-1 | 0.05 | SG-3 | |
| | | | | | | | (40/60) | | | | |
| Example 3-8 | P-11 | 67.95 | z126 | 30 | N-11 | 2 | S1/S2 | W-1 | 0.05 | SG-3 | |
| | | | | | | | (40/60) | | | | |
| Example 3-9 | P-12 | 62.95 | z135 | 35 | N-8 | 2 | S1/S2 | W-3 | 0.05 | SG-3 | |
| | | | | | | | (40/60) | | | | |
| Example 3-10 | P-13 | 67.95 | z132 | 30 | N-11 | 2 | S1/S2 | W-1 | 0.05 | SG-3 | |
| | | | | | | | (40/60) | | | | |
| Example 3-11 | P-14 | 77.00 | z4/z112 | 20 | N-4 | 3 | S1/S2/S3 | Not | | SG-3 | |
| | | | (1/1) | | | | (30/60/10) | present | | | |
| Example 3-12 | P-15 | 72.95 | z115 | 25 | N-11 | 2 | S1/S4 | W-1 | 0.05 | SG-3 | |
| | | | | | | | (40/60) | | | | |
| Example 3-13 | P-16 | 82.95 | z99 | 15 | N-10 | 2 | S1/S4 | W-1 | 0.05 | SG-3 | |
| | | | | | | | (40/60) | | | | |
| Example 3-14 | P-17 | 58.95 | z130 | 40 | N-9 | 1 | S1/S4 | W-1 | 0.05 | SG-3 | |
| | | | | | | | (40/60) | | | | |
| Example 3-15 | P-18 | 71.95 | z124 | 25 | N-6 | 3 | S1/S4 | W-2 | 0.05 | SG-3 | |
| | | | | | | | (40/60) | | | | |
| Example 3-16 | P-19 | 66.95 | z113 | 30 | N-6 | 3 | S1/S2 | W-2 | 0.05 | SG-3 | |
| | | | | | | | (40/60) | | | | |
| Example 3-17 | P-19 | 67.95 | z137 | 30 | N-11 | 2 | S1/S2 | W-1 | 0.05 | SG-3 | |
| | | | | | | | (40/60) | | | | |
| Example 3-18 | P-20 | 62.95 | z128 | 35 | N-9 | 2 | S1/S3 | W-3 | 0.05 | SG-3 | |
| | | | | | | | (40/60) | | | | |
| Example 3-19 | P-21 | 67.95 | z124 | 30 | N-11 | 2 | S1/S2 | W-1 | 0.05 | SG-3 | |
| | | | | | | | (40/60) | | | | |
| Example 3-20 | P-21 | 62.95 | z135 | 35 | N-11 | 2 | S1/S2 | W-1 | 0.05 | SG-3 | |
| | | | | | | | (40/60) | | | | |
| Example 3-21 | P-22 | 62.95 | z134 | 35 | N-11 | 2 | S1/S2 | W-1 | 0.05 | SG-3 | |
| | | | | | | | (40/60) | | | | |
| Example 3-22 | P-23 | 66.95 | z133 | 30 | N-7 | 3 | S1/S2 | W-1 | 0.05 | SG-3 | |
| | | | | | | | (40/60) | | | | |
| Example 3-23 | P-24 | 67.95 | z125 | 30 | N-3 | 2 | S1/S2 | W-1 | 0.05 | SG-3 | |
| | | | | | | | (40/60) | | | | |
| Example 3-24 | P-25 | 72.95 | z108 | 25 | N-10 | 2 | S1/S2 | W-1 | 0.05 | SG-3 | |
| | | | | | | | (40/60) | | | | |
| Example 3-25 | P-26 | 97.95 | | | N-11 | 2 | S1/S2 | W-1 | 0.05 | SG-3 | |
| | | | | | | | (40/60) | | | | |
| Example 3-26 | P-27 | 97.95 | | | N-11 | 2 | S1/S3 | W-1 | 0.05 | SG-3 | |
| | | | | | | | (40/60) | | | | |
| Example 3-27 | P-28 | 97.95 | | | N-11 | 2 | S1/S2 | W-2 | 0.05 | SG-2 | |
| | | | | | | | (40/60) | | | | |
| Example 3-28 | P-29 | 97.95 | | | N-11 | 2 | S1/S2 | W-1 | 0.05 | SG-3 | |
| | | | | | | | (40/60) | | | | |
| Example 3-29 | P-30 | 97.95 | | | N-11 | 2 | S1/S2 | W-4 | 0.05 | SG-3 | |
| | | | | | | | (40/60) | | | | |
| Example 3-30 | P-31 | 97.95 | | | N-11 | 2 | S1/S2 | W-1 | 0.05 | SG-3 | |
| | | | | | | | (40/60) | | | | |
| Example 3-31 | P-32 | 97.95 | | | N-4 | 2 | S1/S2 | W-1 | 0.05 | SG-1 | |
| | | | | | | | (40/60) | | | | |
| Example 3-32 | P-33 | 97.95 | | | N-6 | 2 | S1/S2 | W-1 | 0.05 | SG-3 | |
| | | | | | | | (40/60) | | | | |
| Example 3-33 | P-37 | 72.95 | z132 | 25 | N-5 | 2 | S1/S2 | W-1 | 0.05 | SG-3 | |
| | | | | | | | (40/60) | | | | |
| Example 3-34 | P-38 | 67.95 | z124 | 30 | N-5 | 2 | S1/S2 | W-1 | 0.05 | SG-3 | |
| | | | | | | | (40/60) | | | | |
| Example 3-35 | P-39 | 67.95 | z124 | 30 | N-5 | 2 | S1/S2 | W-1 | 0.05 | SG-3 | |
| | | | | | | | (40/60) | | | | |
| Example 3-36 | P-40 | 67.95 | z124 | 30 | N-5 | 2 | S1/S2 | W-1 | 0.05 | SG-3 | |
| | | | | | | | (40/60) | | | | |

The concentration of each component represents a concentration (% by mass) in total solid content concentration.

[Phase Separation of Block Copolymer Layer Using Hole Pattern as Guide Pattern]

(1) Coating Liquid Preparation and Application of Active Light Sensitive or Radiation Sensitive Resin Composition

A coating liquid composition of the solid content concentration of 2.5% by mass, having the compositional ratio of Example 1-3 shown in Table 2, was microfiltered using a membrane filter having a pore size of 0.05 μm, whereby an active light sensitive or radiation sensitive resin composition (resist composition) solution was obtained.

This active light sensitive or radiation sensitive resin composition was applied to a 6-inch Si wafer subjected to a hexamethyldisilazane (HMDS) treatment in advance using a spin coater MARK 8 manufactured by Tokyo Electron Limited, and dried on a hot plate at 100° C. for 60 seconds, whereby an active light sensitive or radiation sensitive film having a film thickness of 50 nm was obtained.

(2) EUV Exposure and Development

Using an EUV exposure device (MICRO EXPOSURE TOOL manufactured by Exitech Corporation, NA0.3, Quadrupole, outer sigma of 0.68, inner sigma of 0.36), pattern exposure was performed on the wafer to which the resist film obtained in the above (1) had been applied through a squarely arrayed halftone mask having a diameter of a hole portion of 28 nm and a pitch between holes of 56 nm (here, for positive image formation, portions other than the portions corresponding to the holes were light-shielded). After irradiation, the water was heated on a hot plate at 110° C. for 60 seconds, developed by paddling the 2.38% by mass tetramethylammonium hydroxide (TMAH) aqueous solution for 30 seconds, rinsed with water, rotated for 30 seconds at a rotation speed of 4000 rpm, and baked at 90° C. for 60 seconds, whereby a guide pattern of a contact hole pattern having a hole diameter of 28 nm was obtained.

(3) Formation of Block Copolymer Layer and Implementation of Phase Separation

A 1.9% by mass toluene solution of each resin for DSA described in the following Table 5 was applied to a substrate on which the contact hole pattern having a hole diameter of 28 nm had been formed using a spinner (rotational speed: 1000 rpm, 60 seconds) and the resultant product was dried by being baked on a hot plate at 110° C. for 60 seconds, whereby a block copolymer layer having a film thickness of 25 nm was obtained.

Next, the substrate on which the block copolymer layer had been formed was heated at 240° C. under a nitrogen gas flow until a phase separation structure was formed.

Thereafter, the substrate was subjected to an oxygen plasma treatment (200 sccm, 40 Pa, 200 W, 30 seconds) using TCA-3822 (product name, manufactured by TOKYO OHKA KOGYO CO., LTD.), whereby the phase formed of a block of the repeating unit represented by General Formula (II) or (1V) was selectively removed.

(4) Evaluation of Pattern

The surface of the obtained substrate was observed using a scanning electron microscope SU8000 (manufactured by Hitachi High-Technologies Corporation), and regarding cylinder formation, a case where a clear cylinder was observed was evaluated as A, a case where a comparatively clear cylinder was observed was evaluated as B, a case where a cylinder with problem-free quality was observed was evaluated as C, a case where an unclear vertical lamella was observed was evaluated as D, and a case where a cylinder was not observed was evaluated as E, regarding the cylinder shape, a case where a clear interface state of a cylinder was observed was evaluated as A, a case where a comparatively clear interface state of a cylinder was observed was evaluated as B, and a case where an unclear interface state of a cylinder was observed was evaluated as C, and regarding the formation time of a phase separation structure, a case where the formation time was less than 30 minutes was evaluated as A, a case where the formation time was 30 minutes to 1 hour was evaluated as B, and a case where the formation time was longer than 1 hour was evaluated as C. In addition, the pitch of a cylinder {a diameter of a removal phase (which corresponds to one removal phase 37 in FIG. 3(c))} was also measured.

The evaluation results are shown in the following Table 5.

TABLE 5

| | Resin for DSA | | | | | | | | | Formation |
|---|---|---|---|---|---|---|---|---|---|---|
| | | ΔSP | Polymer- | | | St ratio | | Cylinder | | time of phase |
| | | value | ization | | | (% by | Cylinder | pitch | Cylinder | separation |
| | Resin | (MPa^{1/2}) | method | Mn | Dispersity | weight) | formation | (nm) | shape | structure |
| Example 4-1 | BP-1B | 1.3 | Batch | 15,400 | 1.06 | 66 | B | 20 | A | A |
| Example 4-2 | BP-2B | 1.5 | Batch | 17,900 | 1.17 | 70 | B | 20 | B | A |
| Example 4-3 | BP-3B | 1.8 | Batch | 18,500 | 1.09 | 69 | B | 20 | A | A |
| Example 4-4 | BP-4B | 0.6 | Batch | 19,700 | 1.16 | 72 | B | 20 | B | A |
| Example 4-5 | BP-5B | 1.3 | Batch | 15,600 | 1.12 | 68 | A | 20 | B | A |
| Example 4-6 | BP-6B | 2.2 | Batch | 18,300 | 1.08 | 75 | A | 20 | A | A |
| Example 4-6 | BP-7B | 1.0 | Batch | 16,800 | 1.10 | 72 | A | 20 | A | A |
| Example 4-8 | BP-8B | 0.9 | Batch | 17,700 | 1.09 | 73 | A | 20 | A | A |
| Example 4-9 | BP-9B | 0.6 | Batch | 18,900 | 1.13 | 70 | A | 20 | B | A |
| Example 4-10 | BP-10B | 1.5 | Batch | 19,800 | 1.11 | 69 | A | 20 | B | A |
| Example 4-11 | BP-11B | 1.8 | Batch | 19,100 | 1.06 | 70 | A | 20 | A | A |
| Example 4-12 | BP-12B | 1.5 | Batch | 18,600 | 1.12 | 67 | A | 20 | B | A |
| Example 4-13 | BP-13B | 2.3 | Batch | 18,000 | 1.10 | 71 | A | 20 | A | A |
| Example 4-14 | BP-14B | 2.6 | Batch | 17,100 | 1.13 | 67 | B | 20 | B | B |
| Example 4-15 | BP-15B | 0.6 | Batch | 19,300 | 1.10 | 73 | A | 20 | A | B |
| Example 4-16 | BP-16B | 0.5 | Batch | 18,900 | 1.09 | 66 | B | 20 | B | B |
| Example 4-17 | BP-17B | 0.5 | Batch | 16,500 | 1.07 | 70 | A | 20 | A | A |
| Example 4-18 | BP-18B | 1.1 | Batch | 17,000 | 1.08 | 71 | B | 20 | A | A |
| Example 4-19 | BP-19B | 3.1 | Batch | 17,900 | 1.08 | 70 | C | 20 | A | B |
| Example 4-20 | BP-5B′ | 1.3 | Microreactor | 17,200 | 1.09 | 69 | A | 20 | A | A |
| Example 4-21 | BP-20B | 1.5 | Batch | 17,500 | 1.12 | 71 | A | 20 | B | A |
| Example 4-22 | BP-21B | 0.8 | Batch | 17,400 | 1.08 | 67 | B | 20 | A | A |
| Example 4-23 | BP-22B | 3.2 | Batch | 18,000 | 1.16 | 73 | A | 20 | B | A |
| Example 4-24 | BP-23B | 2.7 | Batch | 18,300 | 1.13 | 72 | A | 20 | B | A |
| Example 4-25 | BP-24B | 1.5 | Batch | 18,300 | 1.06 | 70 | B | 20 | A | A |
| Example 4-26 | BP-25B | 1.6 | Batch | 17,100 | 1.08 | 66 | A | 20 | A | B |
| Example 4-27 | BP-26B | 2.4 | Batch | 18,800 | 1.09 | 71 | A | 20 | A | B |
| Example 4-28 | BP-27B | 0.7 | Batch | 16,700 | 1.07 | 66 | A | 20 | A | B |
| Example 4-29 | BP-28B | 0.7 | Batch | 19,100 | 1.09 | 71 | A | 20 | A | B |
| Example 4-30 | BP-29B | 1.5 | Batch | 18,900 | 1.07 | 68 | A | 20 | A | B |
| Comparative | CBP-1B | 0.3 | Batch | 24,800 | 1.10 | 73 | E | — | — | — |
| Example 4-1 | | | | | | | | | | |
| Comparative | CBP-2B | 4.8 | Batch | 16,600 | 1.13 | 69 | C | 20 | B | C |
| Example 4-2 | | | | | | | | | | |
| Comparative | CBP-3B | 0.3 | Batch | 18,700 | 1.12 | 67 | D | 20 | B | A |
| Example 4-3 | | | | | | | | | | |
| Comparative | CBP-4B | 4.9 | Batch | 18,100 | 1.15 | 70 | C | 20 | B | C |
| Example 4-4 | | | | | | | | | | |

From Table 5, it was found that, in Examples 4-1 to 4-30 in which a block copolymer corresponding to the first block copolymer or the second block copolymer was used, high miniaturization of patterns (refer to the cylinder pitch value in the table) could be achieved with high quality and high efficiency (refer to the evaluation results of cylinder formation, the cylinder shape, and the formation time of a phase separation structure in the table).

On the other hand, in Comparative Examples 4-1 and 4-3 in which a block copolymer not corresponding to the first block copolymer or the second block copolymer, having a ASP value less than 0.5 (MPa^{1/2}), was used, the phase separability of the block was low, and it was not possible to obtain good results in cylinder formation.

In addition, in Comparative Examples 4-2 and 4-4 in which a block copolymer not corresponding to the first block copolymer or the second block copolymer, having a ΔSP value greater than 4.0 (MPa^{1/2}), was used, the diffusion rate of the block copolymer was slow, and it was not possible to obtain good results in cylinder formation and the formation time of a phase separation structure.

It was possible to obtain the same evaluation results as in Examples 4-1 to 4-30 by performing the same operation as in Examples 4-1 to 4-30 except that the coating liquid composition (solid content concentration: 2.5% by mass) having the compositional ratio of Example 1-3 used in formation of the guide patterns in Examples 4-1 to 4-30 was replaced with each coating liquid composition having the compositional ratio of each of Examples 1-1, 1-2, and 1-4 to 1-18 shown in Table 2.

Preparation of the active light sensitive or radiation sensitive resin composition, formation of guide patterns, formation and phase separation of a block copolymer layer were performed in the same manner as in Examples 4-1 to 4-30 except that each coating liquid composition (solid content concentration: 2.5% by mass) having the compositional ratio of each of Examples 3-1 to 3-35 shown in Table 4 was used instead of the coating liquid composition having the compositional ratio of Example 1-3 used in formation of the guide patterns in Examples 4-1 to 4-30, a squarely arrayed halftone mask having a hole portion of 28 nm and a pitch between holes of 56 nm (here, for negative image formation, the portions corresponding to the holes were light-shielded) was used, development was performed by using the developer (organic-based developer) described in Table 4 instead of the alkaline aqueous solution (TMAH; a 2.38% by mass tetramethylammonium hydroxide aqueous solution), the rinse liquid described in Table 4 was used instead of water, and a 1.9% by mass propylene glycol monomethyl ether acetate (PGMEA) solution of each resin for DSA described in Table 5 was used. Moreover, in Table 4, in an example in which a rinse liquid was not described in the column of the rinse liquid, rinsing was not performed. From the above results, the same evaluation results as in Examples 4-1 to 4-30 could be obtained.

[Phase Separation (Lamella Formation) of Block Copolymer Layer not Using Guide Pattern]

Formation and phase separation of a block copolymer layer were performed and evaluation was performed in the same manner as in Example 2-1 except that a substrate on which a guide pattern that had not been formed (that is, a 6-inch Si wafer subjected to a hexamethyldisilazane (HMDS) treatment in advance) was used instead of the substrate on which a guide pattern had been formed used in Example 2-1, and a 1.9% by mass propylene glycol monomethyl ether acetate (PGMEA) solution of each resin for DSA described in the following Table 6 was used instead of the 1.9% by mass toluene solution of a resin for DSA used in Example 2-1.

The evaluation results are shown in the following Table 6.

TABLE 6

| | | | | | | | | | Formation |
|---|---|---|---|---|---|---|---|---|---|
| | | Polymer- | | | St ratio | | Lamella | | time of phase |
| | | ization | | | (% by | Lamella | pitch | Lamella | separation |
| | Resin | method | Mn | Dispersity | weight) | formation | (nm) | shape | structure |
| Example 5-1 | BP-5C | Batch | 30,200 | 1.06 | 51 | A | 50 | A | B |
| Example 5-2 | BP-5D | Batch | 22,200 | 1.08 | 53 | A | 45 | A | A |
| Example 5-3 | BP-5A | Batch | 17,600 | 1.11 | 51 | A | 40 | B | A |
| Example 5-4 | BP-6C | Batch | 28,900 | 1.05 | 49 | A | 50 | A | B |
| Example 5-5 | BP-6D | Batch | 23,700 | 1.07 | 51 | A | 45 | A | A |
| Example 5-6 | BP-6A | Batch | 18,000 | 1.08 | 48 | A | 40 | A | A |
| Example 5-7 | BP-5A′ | Microreactor | 16,300 | 1.07 | 50 | A | 40 | A | A |
| Comparative | CBP-1A | Batch | 20,000 | 1.05 | 50 | E | — | — | — |
| Example 5-1 | | | | | | | | | |
| Comparative | CBP-3A | Batch | 18,200 | 1.11 | 47 | C | 40 | B | C |
| Example 5-2 | | | | | | | | | |
| Comparative | CBP-3A | Batch | 19,100 | 1.12 | 47 | D | 40 | A | A |
| Example 5-3 | | | | | | | | | |
| Comparative | CBP-4A | Batch | 18,500 | 1.14 | 52 | C | 40 | B | C |
| Example 5-4 | | | | | | | | | |

From Table 6, it was found that, in Examples 5-1 to 5-7 in which a block copolymer corresponding to the specific block copolymer 1 was used, high miniaturization of patterns (refer to the lamella pitch value in the table) could be achieved with high quality and high efficiency (refer to the evaluation results of lamella formation, the lamella shape, and the formation time of a phase separation structure in the table), compared to Comparative Examples 5-1 to 5-4.

[Phase Separation (Cylinder Formation) of Block Copolymer Layer not Using Guide Pattern]

Formation of a block copolymer layer and phase separation were performed and evaluation was performed in the same manner as in Example 4-1 except that a substrate on which a guide pattern had not been formed (that is, a 6-inch Si wafer subjected to a hexamethyldisilazane (HMDS) treatment in advance) was used instead of the substrate on which a guide pattern had been formed used in Example 4-1, and a 1.9% by mass propylene glycol monomethyl ether acetate (PGMEA) solution of each resin for DSA described in the following Table 7 was used instead of the 1.9% by mass toluene solution of a resin for DSA used in Example 4-1.

The evaluation results are shown in the following Table 7.

TABLE 7

| | | | | | | | | | Formation |
|---|---|---|---|---|---|---|---|---|---|
| | | Polymer- | | | St ratio | | Cylinder | | time of phase |
| | | ization | | | (% by | Cylinder | pitch | Cylinder | separation |
| | Resin | method | Mn | Dispersity | weight) | formation | (nm) | shape | structure |
| Example 6-1 | BP-5E | Batch | 28,800 | 1.05 | 72 | A | 24 | A | B |
| Example 6-2 | BP-5F | Batch | 24,400 | 1.06 | 70 | A | 22 | A | A |
| Example 6-3 | BP-5B | Batch | 15,600 | 1.12 | 68 | A | 20 | B | A |
| Example 6-4 | BP-6E | Batch | 25,100 | 1.05 | 73 | A | 24 | A | B |
| Example 6-5 | BP-6F | Batch | 22,600 | 1.06 | 70 | A | 22 | A | A |
| Example 6-6 | BP-6B | Batch | 18,300 | 1.08 | 75 | A | 20 | A | A |
| Example 6-7 | BP-5B′ | Microreactor | 17,200 | 1.09 | 69 | A | 20 | A | A |
| Comparative | CBP-1B | Batch | 24,800 | 1.10 | 73 | E | — | — | — |
| Example 6-1 | | | | | | | | | |
| Comparative | CBP-2B | Batch | 16,600 | 1.13 | 69 | C | 20 | B | C |
| Example 6-2 | | | | | | | | | |
| Comparative | CBP-3B | Batch | 18,700 | 1.12 | 67 | D | 20 | B | A |
| Example 6-3 | | | | | | | | | |
| Comparative | CBP-4B | Batch | 18,100 | 1.15 | 70 | C | 20 | B | C |
| Example 6-4 | | | | | | | | | |

From Table 7, it was found that, in Examples 6-1 to 6-7 in which a block copolymer corresponding to the specific block copolymer 1 was used, high miniaturization of patterns (refer to the cylinder pitch value in the table) could be achieved with high quality and high efficiency (refer to the evaluation results of cylinder formation, the cylinder shape, and the formation time of a phase separation structure in the table), compared to Comparative Examples 6-1 to 6-4.

As described above, the block copolymer corresponding to the specific block copolymer 1 exhibits excellent phase separability even on a substrate on which a guide pattern has not been formed, and thus, the block copolymer corresponding to the specific block copolymer 1 can be suitably used in a variety of applications using microphase separation of a block copolymer.

According to the present invention, it is possible to provide a pattern forming method in which, in self-organization lithography using a graphoepitaxy, high miniaturization of patterns can be achieved with high quality and high efficiency (for example, a line-and-space pattern having a pitch of 60 nm or less or a hole pattern having a hole diameter of 30 nm or less can be formed with high quality and high efficiency), an electronic device manufacturing method using the pattern forming method and the electronic device, and a block copolymer used in the pattern forming method and the production method thereof.

The present invention has been described in detail and with reference to specific embodiments, and it is apparent to those skilled in the art that various modifications and changes are possible without departing from the spirit and the scope of the present invention.

This application is based on Japanese Patent Application (JP2013-253598) filed on Dec. 6, 2013, and the contents thereof are incorporated herein by reference.

### EXPLANATION OF REFERENCES

10 substrate
21, 22 guide pattern
31, 35 block copolymer layer
32, 37 removal phase
33, 36 nonremoval phase

What is claimed is:

1. A pattern forming method, comprising:
(i) a step of forming a block copolymer layer containing a first block copolymer having a block of a repeating unit represented by the following General Formula (I) and a block of a repeating unit represented by the following General Formula (II) or a second block copolymer having a block of a repeating unit represented by the following General Formula (III) and a block of a repeating unit represented by the following General Formula (IV) on a substrate on which a guide pattern has been formed;
(ii) a step of phase-separating the block copolymer layer; and
(iii) a step of selectively removing at least one phase of a plurality of phases of the block copolymer layer, 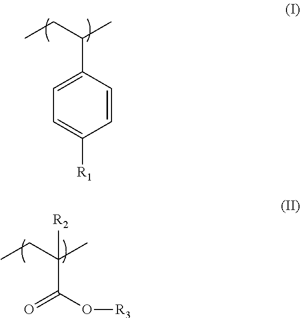
wherein, in General Formula (I), R₁ represents an alkyl group, an alkenyl group, an alkynyl group, a cycloalkyl group, an aryl group, or an aralkyl group, and R₁ may be condensed with a benzene ring by bonding to a carbon atom adjacent to the carbon atom to which R₁ has been bonded,
wherein, in General Formula (II), R₂ represents a hydrogen atom, an alkyl group, or a cycloalkyl group, and R₃ represents an alkyl group or a cycloalkyl group which may be substituted with a halogen atom or a group including an oxygen atom or a sulfur atom, and 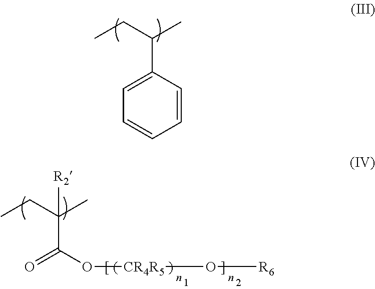
wherein, in General Formula (IV),
R₂′ represents a hydrogen atom, an alkyl group, or a cycloalkyl group,
each of R₄ and R₅ independently represents a hydrogen atom or a methyl group, and a plurality of R₄'s and a plurality of R₅'s may be the same as or different from each other, respectively,
R₆ represents an alkyl group having 1 to 4 carbon atoms, and
n₁ represents 2 to 4, and n₂ represents 1 to 6.

2. The pattern forming method according to claim 1,
wherein the block of the repeating unit represented by General Formula (II) in the first block copolymer is a block of a repeating unit represented by any one of the following General Formulas (II-1) to (II-3), and 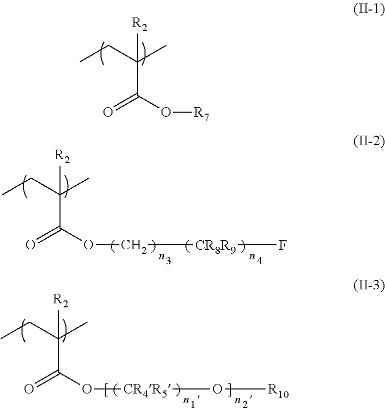
wherein, in General Formulas (II-1) to (II-3),
R₂ has the same meaning as R₂ in General Formula (II),
each of R₄′ and R₅′ independently represents a hydrogen atom or a methyl group, and a plurality of R₄'s and a plurality of R₅'s may be the same as or different from each other, respectively,
R₇ represents an unsubstituted alkyl group having 1 to 12 carbon atoms or an unsubstituted cycloalkyl group having 3 to 12 carbon atoms,
each of R₈ and R₉ independently represents a hydrogen atom or a fluorine atom, here, at least one of R₈ or R₉ represents a fluorine atom, and in a case where a plurality of R₈'s and a plurality of R₉'s are present, respectively, the plurality of R₈'s and the plurality of R₉'s may be the same as or different from each other, respectively,
R₁₀ represents a hydrogen atom, an alkyl group, a cycloalkyl group, or an aryl group, and
n₁′ represents 2 to 4, n₂′ represents 1 to 6, n₃ represents 1 or 2, and n₄ represents 1 to 8.

3. The pattern forming method according to claim 1,
wherein the absolute value of a difference between the solubility parameter (SP value) of the repeating unit represented by General Formula (I) and the solubility parameter (SP value) of the repeating unit represented by General Formula (II) in the first block copolymer is 0.5 to 4.0 (MPa^{1/2}) and the absolute value of a difference between the solubility parameter (SP value) of the repeating unit represented by General Formula (III) and the solubility parameter (SP value) of the repeating unit represented by General Formula (IV) in the second block copolymer is 0.5 to 4.0 (MPa^{1/2}).

4. The pattern forming method according to claim 1,
wherein the number average molecular weight of each of the first block copolymer and the second block copolymer is less than 25000.

5. The pattern forming method according to claim 4,
wherein the number average molecular weight of each of the first block copolymer and the second block copolymer is less than 20000.

6. The pattern forming method according to claim 1,
wherein the guide pattern is a guide pattern formed by exposing an active light sensitive or radiation sensitive film to an ArF excimer laser, extreme ultraviolet rays, or an electron beam, and by developing the exposed active light sensitive or radiation sensitive film using a developer.

7. The pattern forming method according to claim 1,
wherein an underlayer containing an undercoat agent is formed on the substrate and the block copolymer layer is formed on the underlayer.

8. The pattern forming method according to claim 1,
wherein a top coating layer is formed on the block copolymer layer between the step (i) and the step (ii).

9. An electronic device manufacturing method, comprising:
the pattern forming method according to claim 1.

10. An electronic device manufactured by the electronic device manufacturing method according to claim 9.

11. A block copolymer, comprising:
a block of a repeating unit represented by the following General Formula (I); and
a block of a repeating unit represented by the following General Formula (II-2) or (II-3), 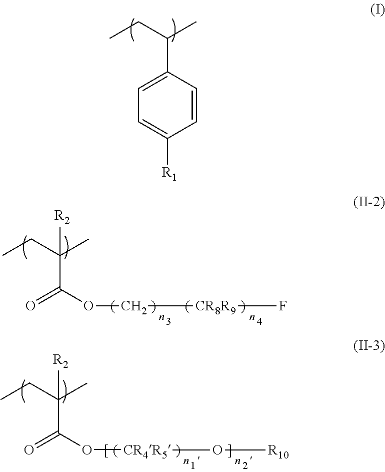
wherein, in General Formula (I), R₁ represents an alkyl group, an alkenyl group, an alkynyl group, a cycloalkyl group, an aryl group, or an aralkyl group, and R₁ may be condensed with a benzene ring by bonding to a carbon atom adjacent to the carbon atom to which R₁ has been bonded,
wherein, in General Formulas (II-2) and (II-3),
R₂ represents a hydrogen atom, an alkyl group, or a cycloalkyl group,
each of R₄′ and R₅′ independently represents a hydrogen atom or a methyl group, and a plurality of R₄'s and a plurality of R₅'s may be the same as or different from each other, respectively,
each of R₈ and R₉ independently represents a hydrogen atom or a fluorine atom, here, at least one of R₈ or R₉ represents a fluorine atom, and in a case where a plurality of R₈'s and a plurality of R₉'s are present, respectively, the plurality of R₈'s and the plurality of R₉'s may be the same as or different from each other, respectively,
R₁₀ represents a hydrogen atom, an alkyl group, a cycloalkyl group, or an aryl group, and
n₁′ represents 2 to 4, n₂′ represents 1 to 6, n₃ represents 1 or 2, and n₄ represents 1 to 8.

12. The block copolymer according to claim 11,
wherein the number average molecular weight of the block copolymer is less than 25000.

13. The block copolymer according to claim 12,
wherein the number average molecular weight of the block copolymer is less than 20000.

14. A block copolymer production method,
wherein the block copolymer according to claim 11 is synthesized by living polymerization.

15. The block copolymer production method according to claim 14,
wherein the living polymerization is living anion polymerization.

16. The block copolymer production method according to claim 15,
wherein a microreactor is used.

17. A pattern forming method, comprising:
(i) a step of forming a block copolymer layer containing a block copolymer on a substrate on which a guide pattern has been formed;
(ii) a step of phase-separating the block copolymer layer; and
(iii) a step of selectively removing at least one phase of a plurality of phases of the block copolymer layer,
wherein the block copolymer is a block copolymer having a block of a first repeating unit and a block of a second repeating unit, and the absolute value of a difference between the solubility parameter (SP value) of the first repeating unit and the solubility parameter (SP value) of the second repeating unit is 0.5 to 4.0 (MPa^{1/2}).

18. A block copolymer for manufacturing semiconductors, comprising:
a block of a first repeating unit; and
a block of a second repeating unit,
wherein the absolute value of a difference between the solubility parameter (SP value) of the first repeating unit and the solubility parameter (SP value) of the second repeating unit is 0.5 to 4.0 (MPa^{1/2}).
